(19) United States
(12) Patent Application Publication
(10) Pub. No.: US 2019/0181350 A1
(43) Pub. Date: Jun. 13, 2019

(54) DEUTERIUM-SUBSTITUTED POLYCYCLIC AROMATIC COMPOUND

(71) Applicants: Kwansei Gakuin Educational Foundation, Nishinomiya-shi (JP); JNC Corporation, Tokyo (JP)

(72) Inventors: Takuji Hatakeyama, Hyogo (JP); Takayuki HIROTA, Chiba (JP); Kazushi SHIREN, Chiba (JP); Yasuyuki SASADA, Chiba (JP)

(73) Assignees: Kwansei Gakuin Educational Foundation, Nishinomiya-shi (JP); JNC Corporation, Tokyo (JP)

(21) Appl. No.: 16/213,021

(22) Filed: Dec. 7, 2018

(30) Foreign Application Priority Data
Dec. 11, 2017 (JP) 2017-236889
Mar. 9, 2018 (JP) 2018-042879
Oct. 12, 2018 (JP) 2018-193398

(51) Int. Cl. H01L 51/00; C07F 5/02

(52) U.S. Cl. CPC H01L 51/0059; C07F 5/027; H01L 51/0061; H01L 51/5016; H01L 51/0067; H01L 51/0073; H01L 51/0072

(57) ABSTRACT

By introducing deuterium at a natural abundance ratio or higher into a novel polycyclic aromatic compound in which a plurality of aromatic rings is linked via a boron atom, an oxygen atom, or the like, options of a material for an organic device such as a material for an organic EL element are increased. Furthermore, by using a novel deuterium-substituted polycyclic aromatic compound as a material for an organic EL element, for example, an organic EL element having excellent luminous efficiency and element lifetime is provided.

### BACKGROUND

### Technical Field

The present invention relates to a deuterium-substituted polycyclic aromatic compound, and an organic electroluminescent element, an organic field effect transistor, and an organic thin film solar cell using the deuterium-substituted polycyclic aromatic compound, as well as a display apparatus and a lighting apparatus. Incidentally, here, the term “organic electroluminescent element” may be referred to as “organic EL element” or simply “element”.

### Related Art

Conventionally, a display apparatus employing a luminescent element that is electroluminescent can be subjected to reduction in power consumption and reduction in thickness, and therefore various studies have been conducted thereon. Moreover, an organic electroluminescent element formed of an organic material has been studied actively because reduction in weight and expansion in size are easily achieved. Particularly, active research has been hitherto conducted on development of an organic material having luminescence characteristics for blue light, which is one of the three primary colors of light, and development of an organic material having charge transport capability for holes, electrons, and the like (having a potential for serving as a semiconductor or a superconductor), irrespective of whether the organic material is a polymer compound or a low molecular weight compound.

An organic EL element has a structure having a pair of electrodes composed of a positive electrode and a negative electrode, and a single layer or a plurality of layers which are disposed between the pair of electrodes and contain an organic compound. The layer containing an organic compound includes a light emitting layer, a charge transport/injection layer for transporting or injecting charges such as holes or electrons, and the like, and various organic materials suitable for these layers have been developed.

As a material for the light emitting layer, for example, a benzofluorene-based compound or the like has been developed (WO 2004/061047 A). Furthermore, as a hole transport material, for example, a triphenylamine-based compound or the like has been developed (JP 2001-172232 A). Furthermore, as an electron transport material, for example, an anthracene-based compound or the like has been developed (JP 2005-170911 A).

Furthermore, in recent years, a material obtained by improving a triphenylamine derivative has also been reported as a material used in an organic EL element or an organic thin film solar cell (WO 2012/118164 A). This material is characterized in that flatness thereof has been increased by linking aromatic rings constituting triphenylamine with reference to N,N′-diphenyl-N,N′-bis(3-methylphenyl)-1,1′-biphenyl-4,4′-diamine (TPD) which has been already put to practical use. In this literature, for example, evaluation of the charge transporting characteristics of a NO-linked system compound (compound 1 of page 63) has been made. However, there is no description on a method for manufacturing materials other than the NO-linked system compound. Furthermore, when elements to be linked are different, the overall electron state of the compound is different. Therefore, the characteristics obtainable from materials other than the NO-linked system compound are not known. Examples of such a compound are also found elsewhere (WO 2011/107186 A). For example, since a compound having a conjugated structure involving high energy of triplet exciton (T1) can emit phosphorescent light having a shorter wavelength, the compound is useful as a material for a blue light emitting layer. Furthermore, there is also a demand for a novel compound having a conjugated structure with high T1 as each of an electron transport material and a hole transport material with a light emitting layer interposed therebetween.

A host material for an organic EL element is generally a molecule in which a plurality of existing aromatic rings of benzene, carbazole, and the like is linked to one another via a single bond, a phosphorus atom, or a silicon atom. This is because a large HOMO-LUMO gap required for a host material (band gap Eg in a thin film) is secured by linking many aromatic rings each having a relatively small conjugated system. Furthermore, a host material for an organic EL element, using a phosphorescent material or a thermally activated delayed fluorescent material needs high triplet excitation energy (E_{T}). However, the triplet excitation energy (E_{T}) can be increased by localizing SOMO1 and SOMO2 in a triplet excited state (T1) by linking a donor-like or acceptor-like aromatic ring or substituent to a molecule, and thereby reducing an exchange interaction between the two orbitals. However, an aromatic ring having a small conjugated system does not have sufficient redox stability, and an element using a molecule obtained by linking existing aromatic rings as a host material does not have a sufficient lifetime. Meanwhile, a polycyclic aromatic compound having an extended n-conjugated system generally has excellent redox stability. However, since the HOMO-LUMO gap (band gap Eg in a thin film) or triplet excitation energy (E_{T}) is low, the polycyclic aromatic compound has been considered to be unsuitable as a host material.

### PRIOR ART REFERENCES

### WO 2004/061047 A

### JP 2001-172232 A

### JP 2005-170911 A

### WO 2012/118164 A

### WO 2011/107186 A

### WO 2015/102118 A

### SUMMARY

As described above, various materials have been developed as a material used for an organic EL element. However, in order to increase a selection range of the material for the organic EL element, it is desired to develop a material formed from a compound different from conventional compounds. Particularly, characteristics of an organic EL element obtained from a material other than NO-linked system compounds reported in WO 2004/061047 A, JP 2001-172232 A, JP 2005-170911 A, and WO 2012/118164 A, and a method for manufacturing the organic EL element are not known.

Furthermore, WO 2015/102118 A has reported a boron-containing polycyclic aromatic compound and an organic EL element using the polycyclic aromatic compound. However, in order to further improve characteristics of the element, a material for a light emitting layer capable of improving luminous efficiency and element lifetime, particularly a dopant material is required.

As a result of intensive studies to solve the above problems, the present inventors have found that an excellent organic EL element is obtained by disposing a layer containing a polycyclic aromatic compound into which deuterium has been introduced at a natural abundance ratio or higher between a pair of electrodes to constitute, for example, an organic EL element, and have completed the present invention. That is, the present invention provides such a deuterium-substituted polycyclic aromatic compound as follows or a multimer thereof, and further provides a material for an organic device containing such a deuterium-substituted polycyclic aromatic compound as follows or a multimer thereof, such as an organic EL element.

Item 1.

A polycyclic aromatic compound represented by the following general formula (1) or a multimer of a polycyclic aromatic compound having a plurality of structures each represented by the following general formula (1).

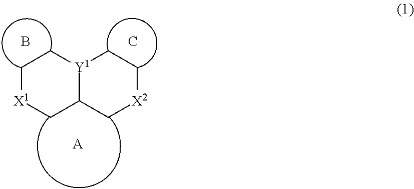

(In the above formula (1),

ring A, ring B, and ring C each independently represent an aryl ring or a heteroaryl ring, while at least one hydrogen atom in these rings may be substituted,

Y¹ represents B, P, P═O, P═S, Al, Ga, As, Si—R, or Ge—R, while R in the Si—R and Ge—R represents an aryl, an alkyl or a cycloalkyl,

X¹ and X² each independently represent O, N—R, S, or Se, while R of the N—R represents an optionally substituted aryl, an optionally substituted heteroaryl, an optionally substituted alkyl, or an optionally substituted cycloalkyl, and R in the N—R may be bonded to the ring A, ring B, and/or ring C via a linking group or a single bond,

at least one hydrogen atom in a compound or a structure represented by formula (1) may be substituted by cyano or a halogen atom, and

at least one hydrogen atom in the compound or the structure represented by formula (1) is substituted by a deuterium atom.)

Item 2.

The polycyclic aromatic compound or the multimer thereof according to item 1, in which

the ring A, ring B, and ring C each independently represent an aryl ring or a heteroaryl ring, while at least one hydrogen atom in these rings may be substituted by a substituted or unsubstituted aryl, a substituted or unsubstituted heteroaryl, a substituted or unsubstituted diarylamino, a substituted or unsubstituted diheteroarylamino, a substituted or unsubstituted arylheteroarylamino, a substituted or unsubstituted alkyl, a substituted or unsubstituted cycloalkyl, a substituted or unsubstituted alkoxy, or a substituted or unsubstituted aryloxy, and each of these rings has a 5-membered or 6-membered ring sharing a bond with a fused bicyclic structure at the center of the above formula constituted by Y¹, X¹, and X²,

Y¹ represents B, P, P═O, P═S, Al, Ga, As, Si—R, or Ge—R, while R in the Si—R and Ge—R represents an aryl, an alkyl or a cycloalkyl,

X¹ and X² each independently represent O, N—R, S, or Se, while R in the N—R represents an aryl optionally substituted by an alkyl or a cycloalkyl, a heteroaryl optionally substituted by an alkyl or a cycloalkyl, a cycloalkyl optionally substituted by an alkyl or a cycloalkyl, or alkyl optionally substituted by an alkyl or a cycloalkyl, R in the N—R may be bonded to the ring A, ring B, and/or ring C via —O—, —S—, —C(—R)₂—, or a single bond, and R in the —C(—R)₂— represents a hydrogen atom or an alkyl or a cycloalkyl,

at least one hydrogen atom in a compound or a structure represented by formula (1) may be substituted by cyano or a halogen atom,

in a case of a multimer, the multimer is a dimer or a trimer having two or three structures each represented by general formula (1), and

at least one hydrogen atom in the compound or the structure represented by formula (1) is substituted by a deuterium atom.

Item 3.

The polycyclic aromatic compound according to item 1, represented by the following general formula (2).

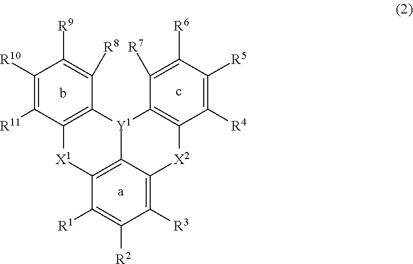

(In the above formula (2),

R¹ to and R¹¹ each independently represent a hydrogen atom, an aryl, a heteroaryl, a diarylamino, a diheteroarylamino, an arylheteroarylamino, an alkyl, a cycloalkyl, an alkoxy, or an aryloxy, while at least one hydrogen atom in these may be substituted by an aryl, a heteroaryl, an alkyl, or a cycloalkyl, adjacent groups among R¹ to R¹¹ may be bonded to each other to form an aryl ring or a heteroaryl ring together with ring a, ring b, or ring c, at least one hydrogen atom in the ring thus formed may be substituted by an aryl, a heteroaryl, a diarylamino, a diheteroarylamino, an arylheteroarylamino, an alkyl, a cycloalkyl, an alkoxy, or an aryloxy, and at least one hydrogen atom in these may be substituted by an aryl, a heteroaryl, an alkyl, or a cycloalkyl,

Y¹ represents B, P, P═O, P═S, Al, Ga, As, Si—R, or Ge—R, while R in the Si—R and Ge—R represents an aryl having 6 to 12 carbon atoms, an alkyl having 1 to 6 carbon atoms or a cycloalkyl having 3 to 14 carbon atoms,

X¹ and X² each independently represent O, N—R, S, or Se, while R in the N—R represents an aryl having 6 to 12 carbon atoms, a heteroaryl having 2 to 15 carbon atoms, an alkyl having 1 to 6 carbon atoms, or a cycloalkyl having 3 to 14 carbon atoms, R in the N—R may be bonded to the ring a, ring b, and/or ring c via —O—, —S—, —C(—R)₂—, or a single bond, and R in the —C(—R)₂— represents an alkyl having 1 to 6 carbon atoms or a cycloalkyl having 3 to 14 carbon atoms,

at least one hydrogen atom in a compound represented by formula (2) may be substituted by cyano or a halogen atom, and

at least one hydrogen atom in the compound represented by formula (2) is substituted by a deuterium atom.)

Item 4.

The polycyclic aromatic compound according to item 3, in which

R¹ to R¹¹ each independently represent a hydrogen atom, an aryl having 6 to 30 carbon atoms, a heteroaryl having 2 to 30 carbon atoms, a diarylamino (the aryl is an aryl having 6 to 12 carbon atoms), an alkyl having 1 to 24 carbon atoms, or a cycloalkyl having 3 to 24 carbon atoms, adjacent groups among R¹ to R¹¹ may be bonded to each other to form an aryl ring having 9 to 16 carbon atoms or a heteroaryl ring having 6 to 15 carbon atoms together with the ring a, ring b, or ring c, and at least one hydrogen atom in the ring thus formed may be substituted by an aryl having 6 to 10 carbon atoms, an alkyl having 1 to 12 carbon atoms, or a cycloalkyl having 3 to 16 carbon atoms,

Y¹ represents B, P, P═O, P═S, or Si—R, while R in the Si—R represents an aryl having 6 to 10 carbon atoms, an alkyl having 1 to 4 carbon atoms or a cycloalkyl having 5 to 10 carbon atoms,

X¹ and X² each independently represent O, N—R, or S, while R in the N—R represents an aryl having 6 to 10 carbon atoms, an alkyl having 1 to 4 carbon atoms, or a cycloalkyl having 5 to 10 carbon atoms,

at least one hydrogen atom in a compound represented by formula (2) may be substituted by cyano or a halogen atom, and

at least one hydrogen atom in the compound represented by formula (2) is substituted by a deuterium atom.

Item 5.

The polycyclic aromatic compound according to item 3, in which

R¹ to R¹¹ each independently represent a hydrogen atom, an aryl having 6 to 16 carbon atoms, a heteroaryl having 2 to 20 carbon atoms, a diarylamino (the aryl is an aryl having 6 to 10 carbon atoms), an alkyl having 1 to 12 carbon atoms, or a cycloalkyl having 3 to 16 carbon atoms,

Y¹ represents B, P, P═O, or P═S,

X¹ and X² each independently represent O or N—R, while R in the N—R represents an aryl having 6 to 10 carbon atoms, an alkyl having 1 to 4 carbon atoms or a cycloalkyl having 5 to 10 carbon atoms, and

at least one hydrogen atom in a compound represented by formula (2) is substituted by a deuterium atom.

Item 6.

The polycyclic aromatic compound according to item 3, in which

R¹ to R¹¹ each independently represent a hydrogen atom, an aryl having 6 to 16 carbon atoms, a diarylamino (the aryl is an aryl having 6 to 10 carbon atoms), an alkyl having 1 to 12 carbon atoms, or a cycloalkyl having 3 to 16 carbon atoms,

Y¹ represents B,

X¹ and X² both represent N—R, or X¹ represents N—R and X² represents O, and R in the N—R represents an aryl having 6 to 10 carbon atoms, an alkyl having 1 to 4 carbon atoms or a cycloalkyl having 5 to 10 carbon atoms, and

at least one hydrogen atom in a compound represented by formula (2) is substituted by a deuterium atom.

Item 7.

The polycyclic aromatic compound or the multimer thereof according to any one of items 1 to 6, substituted by a deuterium-substituted diarylamino group, a deuterium-substituted carbazolyl group, or a deuterium-substituted benzocarbazolyl group.

Item 8.

The polycyclic aromatic compound according to any one of items 3 to 6, in which R² is a deuterium-substituted diarylamino group or a deuterium-substituted carbazolyl group.

Item 9.

The polycyclic aromatic compound or the multimer thereof according to any one of items 1 to 8, in which the halogen is fluorine.

Item 10.

A polycyclic aromatic compound represented by any one of the following structural formulas.

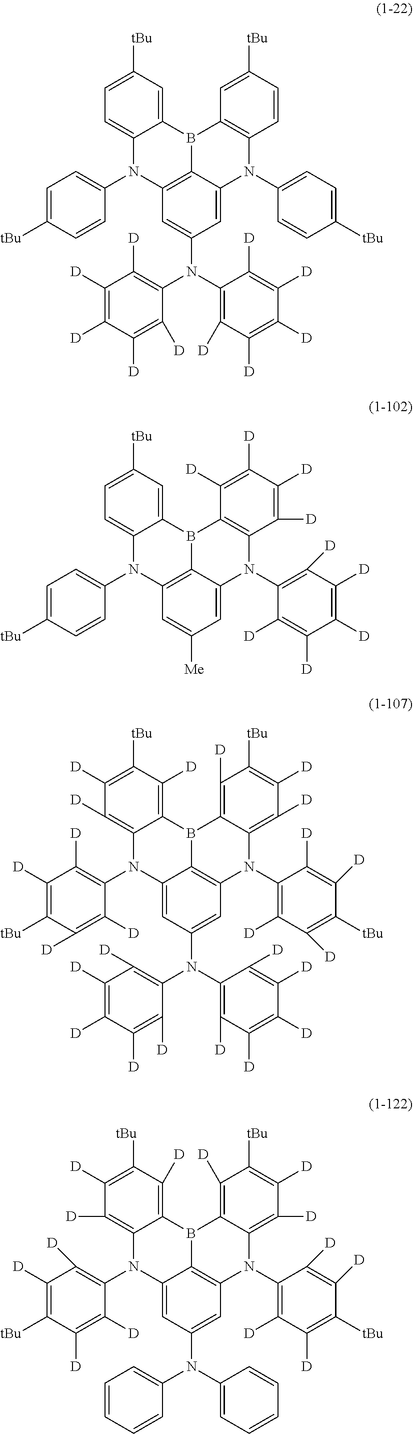

Item 11.

A material for an organic device, including the polycyclic aromatic compound or the multimer thereof according to any one of items 1 to 10.

Item 12.

The material for an organic device according to item 11, in which the material for an organic device is a material for an organic electroluminescent element, a material for an organic field effect transistor, or a material for an organic thin film solar cell.

Item 13.

The material for an organic electroluminescent element according to item 12, in which the material for an organic electroluminescent element is a material for a light emitting layer.

Item 14.

An organic electroluminescent element including: a pair of electrodes composed of a positive electrode and a negative electrode; and a light emitting layer disposed between the pair of electrodes and containing the material for a light emitting layer according to item 13.

Item 15.

The organic electroluminescent element according to item 14, in which the light emitting layer includes a host and the material for a light emitting layer as a dopant.

Item 16.

The organic electroluminescent element according to item 15, in which the host is an anthracene-based compound, a fluorene-based compound, or a dibenzochrysene-based compound.

Item 17.

The organic electroluminescent element according to any one of items 14 to 16, further including an electron transport layer and/or an electron injection layer disposed between the negative electrode and the light emitting layer, in which at least one of the electron transport layer and the electron injection layer contains at least one selected from the group consisting of a borane derivative, a pyridine derivative, a fluoranthene derivative, a BO-based derivative, an anthracene derivative, a benzofluorene derivative, a phosphine oxide derivative, a pyrimidine derivative, a carbazole derivative, a triazine derivative, a benzimidazole derivative, a phenanthroline derivative, and a quinolinol-based metal complex.

Item 18.

The organic electroluminescent element according to item 17, in which the electron transport layer and/or the electron injection layer further include/includes at least one selected from the group consisting of an alkali metal, an alkaline earth metal, a rare earth metal, an oxide of an alkali metal, a halide of an alkali metal, an oxide of an alkaline earth metal, a halide of an alkaline earth metal, an oxide of a rare earth metal, a halide of a rare earth metal, an organic complex of an alkali metal, an organic complex of an alkaline earth metal, and an organic complex of a rare earth metal.

Item 19.

A display apparatus or a lighting apparatus including the organic electroluminescent element according to any one of items 14 to 18.

According to a preferable embodiment of the present invention, a novel deuterium-substituted polycyclic aromatic compound that can be used as a material for an organic device such as a material for an organic EL element can be provided, and an excellent organic device such as an organic EL element can be provided by using this deuterium-substituted polycyclic aromatic compound.

Specifically, the present inventors have found that a polycyclic aromatic compound (basic skeleton portion) in which aromatic rings are linked to each other via a hetero element such as boron, phosphorus, oxygen, nitrogen, or sulfur has a large HOMO-LUMO gap (band gap Eg in a thin film) and high triplet excitation energy (E_{T}). It is considered that this is because a decrease in the HOMO-LUMO gap that comes along with extension of a conjugated system is suppressed due to low aromaticity of a 6-membered ring containing a hetero element, and SOMO1 and SOMO2 in a triplet excited state (T1) are localized by electronic perturbation of the hetero element. Furthermore, the polycyclic aromatic compound (basic skeleton portion) containing a hetero element according to an aspect of the present invention reduces an exchange interaction between the two orbitals due to the localization of SOMO1 and SOMO2 in the triplet excited state (T1), and therefore an energy difference between the triplet excited state (T1) and a singlet excited state (S1) is small. The polycyclic aromatic compound exhibits thermally activated delayed fluorescence, and therefore is also useful as a fluorescent material for an organic EL element. Furthermore, a material having high triplet excitation energy (E_{T}) is also useful as an electron transport layer or a hole transport layer of a phosphorescence organic EL element or an organic EL element using thermally activated delayed fluorescence. Moreover, the polycyclic aromatic compound (basic skeleton portion) can arbitrarily shift energy of HOMO and LUMO by introducing a substituent, and therefore ionization potential or electron affinity can be optimized in accordance with a peripheral material.

In addition to the characteristics of the basic skeleton portion, the compound according to an aspect of the present invention can improve luminous efficiency by an isotope effect due to a change in bonding form (effect due to a change in bond extension/contraction because of a change from C—H bond to C-D bond) by introduction of a deuterium atom and can improve element lifetime by a reaction kinetic isotope effect (effect of suppressing compound deterioration based on improvement of bonding energy because of a change from C—H bond to C-D bond). However, the present invention is not particularly limited to these principles.

Furthermore, by introducing a cycloalkyl group into the compound according to an aspect of the present invention, it can be expected to lower a melting point or a sublimation temperature. This means that thermal decomposition of a material and the like can be avoided because purification can be performed at a relatively low temperature in sublimation purification which is almost indispensable as a purification method for a material for an organic device such as an organic EL element, requiring high purity. Furthermore, this also applies to a vacuum vapor deposition process which is a powerful means for manufacturing an organic device such as an organic EL element. Since the process can be performed at a relatively low temperature, thermal decomposition of a material can be avoided. As a result, a high performance compound for an organic device can be obtained. Furthermore, since many of polycyclic aromatic compound multimers have a high sublimation temperature due to high molecular weight, high planarity, and the like, it is more effective to lower the sublimation temperature by introducing a cycloalkyl group. Furthermore, since solubility in an organic solvent is improved by introducing a cycloalkyl group, application to manufacture of an element using a coating process is also possible. However, the present invention is not particularly limited to these principles.

### BRIEF DESCRIPTION OF DRAWINGS

FIG. 1 is a schematic cross-sectional view illustrating an organic EL element according to the present embodiment.

### DETAILED DESCRIPTION

1. Deuterium-Substituted Polycyclic Aromatic Compound and Multimer Thereof

The invention of the present application is a polycyclic aromatic compound represented by the following general formula (1) or a multimer of a polycyclic aromatic compound having a plurality of structures each represented by the following general formula (1), and is preferably a polycyclic aromatic compound represented by the following general formula (2) or a multimer of a polycyclic aromatic compound having a plurality of structures each represented by the following general formula (2). At least one hydrogen atom in these compounds or structures is substituted by a deuterium atom.

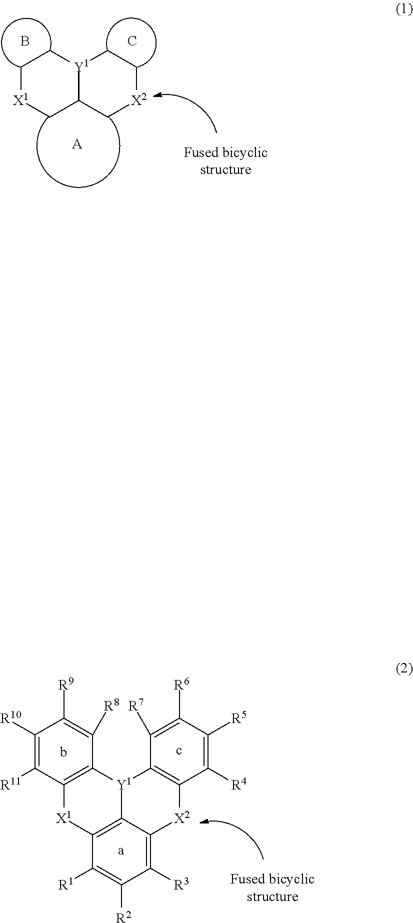

The ring A, ring B, and ring C in general formula (1) each independently represent an aryl ring or a heteroaryl ring, and at least one hydrogen atom in these rings may be substituted by a substituent. This substituent is preferably a substituted or unsubstituted aryl, a substituted or unsubstituted heteroaryl, a substituted or unsubstituted diarylamino, a substituted or unsubstituted diheteroarylamino, a substituted or unsubstituted arylheteroarylamino (an amino group having an aryl and a heteroaryl), a substituted or unsubstituted alkyl, a substituted or unsubstituted cycloalkyl, a substituted or unsubstituted alkoxy, or a substituted or unsubstituted aryloxy. In a case where these groups have substituents, examples of the substituents include an aryl, a heteroaryl, an alkyl, and a cycloalkyl. Furthermore, the aryl ring or heteroaryl ring preferably has a 5-membered ring or 6-membered ring sharing a bond with a fused bicyclic structure at the center of general formula (1) constituted by Y¹, X¹, and X².

Here, the “fused bicyclic structure” means a structure in which two saturated hydrocarbon rings including Y¹, X¹, and X² and indicated at the center of general formula (1) are fused. Furthermore, the “6-membered ring sharing a bond with the fused bicyclic structure” means, for example, ring a (benzene ring (6-membered ring)) fused to the fused bicyclic structure as represented by the above general formula (2). Furthermore, the phrase “aryl ring or heteroaryl ring (which is ring A) has this 6-membered ring” means that the ring A is formed only from this 6-membered ring, or other rings and the like are further fused to this 6-membered ring so as to include this 6-membered ring to form the ring A. In other words, the “aryl ring or heteroaryl ring (which is ring A) having a 6-membered ring” as used herein means that the 6-membered ring constituting the entirety or a part of the ring A is fused to the fused bicyclic structure. Similar description applies to the “ring B (ring b)”, “ring C (ring c)”, and the “5-membered ring”.

The ring A (or ring B or ring C) in general formula (1) corresponds to ring a and its substituents R¹ to R³ in general formula (2) (or ring b and its substituents R⁴ to R⁷, or ring c and its substituents R⁸ to R¹¹). That is, general formula (2) corresponds to a structure in which “rings A to C having 6-membered rings” have been selected as the rings A to C of general formula (1). For this meaning, the rings of general formula (2) are represented by small letters a to c.

In general formula (2), adjacent groups among the substituents R¹ to R¹¹ of the ring a, ring b, and ring c may be bonded to each other to form an aryl ring or a heteroaryl ring together with the ring a, ring b, or ring c, and at least one hydrogen atom in the ring thus formed may be substituted by an aryl, a heteroaryl, a diarylamino, a diheteroarylamino, an arylheteroarylamino, an alkyl, a cycloalkyl, an alkoxy, or an aryloxy, while at least one hydrogen atom in these may be substituted by an aryl, a heteroaryl, an alkyl, or a cycloalkyl. Therefore, in a polycyclic aromatic compound represented by general formula (2), a ring structure constituting the compound changes as represented by the following formulas (2-1) and (2-2) according to a mutual bonding form of substituents in the ring a, ring b, and ring c. Ring A′, ring B′, and ring C′ in the formulas correspond to the ring A, ring B, and ring C in general formula (1), respectively.

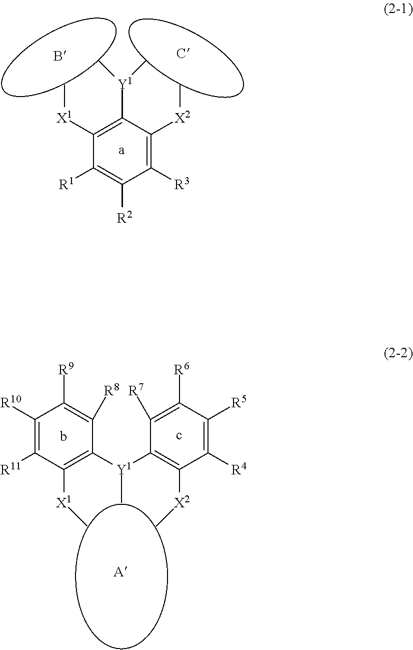

The ring A′, ring B′ and, ring C′ in the above formulas (2-1) and (2-2) each represent, to be described in connection with general formula (2), an aryl ring or a heteroaryl ring formed by bonding adjacent groups among the substituents R¹ to R¹¹ together with the ring a, ring b, and ring c, respectively (may also be referred to as a fused ring obtained by fusing another ring structure to the ring a, ring b, or ring c). Incidentally, although not indicated in the formula, there is also a compound in which all of the ring a, ring b, and ring c have been changed to the ring A′, ring B′ and ring C′. Furthermore, as apparent from the above formulas (2-1) and (2-2), for example, R⁸ of the ring b and R⁷ of the ring c, R¹¹ of the ring b and R¹ of the ring a, R⁴ of the ring c and R³ of the ring a, and the like do not correspond to “adjacent groups”, and these groups are not bonded to each other. That is, the term “adjacent groups” means adjacent groups on the same ring.

The compound represented by formula (2-1) or (2-2) is, for example, a compound having ring A′ (or ring B′ or ring C′) that is formed by fusing a benzene ring, an indole ring, a pyrrole ring, a benzofuran ring, or a benzothiophene ring to a benzene ring which is ring a (or ring b or ring c), and the fused ring A′ (or fused ring B′ or fused ring C′) that has been formed is a naphthalene ring, a carbazole ring, an indole ring, a dibenzofuran ring, or a dibenzothiophene ring.

Y¹ in general formula (1) represents B, P, P═O, P═S, Al, Ga, As, Si—R, or Ge—R, and R of the Si—R and Ge—R represents an aryl, an alkyl or a cycloalkyl. In a case Y¹ represents P═O, P═S, Si—R, or Ge—R, an atom bonded to the ring A, ring B, or ring C is P, Si, or Ge. Y¹ is preferably B, P, P═O, P═S, or Si—R, and B is particularly preferable. This description also applies to Y¹ in general formula (2).

X¹ and X² in general formula (1) each independently represent O, N—R, S, or Se, R in the N—R represents an optionally substituted aryl, an optionally substituted heteroaryl, an optionally substituted alkyl, or an optionally substituted cycloalkyl, and R in the N—R may be bonded to the ring B and/or ring C via a linking group or a single bond. The linking group is preferably —O—, —S—, or —C(—R)₂—. Note that R of the “—C(—R)₂—” represents a hydrogen atom, an alkyl or a cycloalkyl. This description also applies to X¹ and X² in general formula (2).

Here, the provision that “R in the N—R is bonded to the ring A, ring B, and/or ring C via a linking group or a single bond” for general formula (1) corresponds to the provision that “R in the N—R is bonded to the ring a, ring b, and/or ring c via —O—, —S—, —C(—R)₂— or a single bond” for general formula (2).

This provision can be expressed by a compound having a ring structure represented by the following formula (2-3-1), in which X¹ and X² are incorporated into the fused rings B′ and C′, respectively. That is, for example, the compound is a compound having ring B′ (or ring C′) formed by fusing another ring to a benzene ring which is ring b (or ring c) in general formula (2) so as to incorporate X¹ (or X²). The formed fused ring B′ (or fused ring C′) is, for example, a phenoxazine ring, a phenothiazine ring, or an acridine ring.

Furthermore, the above provision can be expressed by a compound having a ring structure in which X¹ and/or X² are/is incorporated into the fused ring A′, represented by the following formula (2-3-2) or (2-3-3). That is, for example, the compound is a compound having ring A′ formed by fusing another ring to a benzene ring which is ring a in general formula (2) so as to incorporate X¹ (and/or X²). The formed fused ring A′ is, for example, a phenoxazine ring, a phenothiazine ring, or an acridine ring.

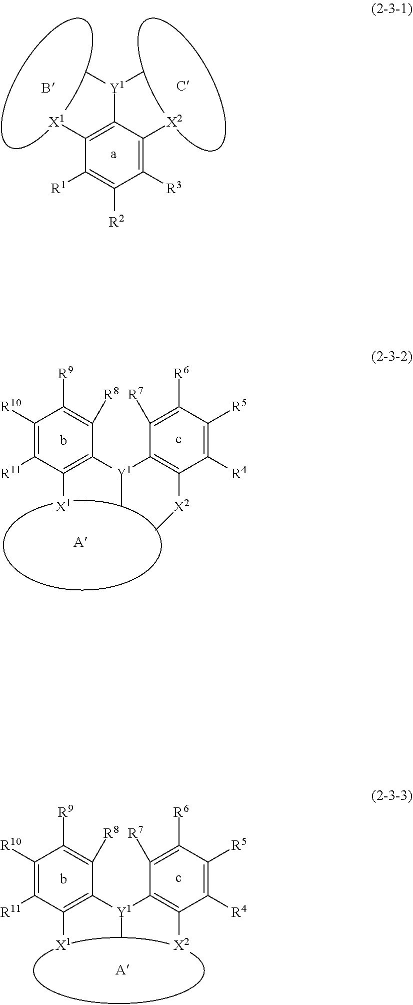

The “aryl ring” as the ring A, ring B, or ring C of general formula (1) is, for example, an aryl ring having 6 to 30 carbon atoms, and the aryl ring is preferably an aryl ring having 6 to 16 carbon atoms, more preferably an aryl ring having 6 to 12 carbon atoms, and particularly preferably an aryl ring having 6 to 10 carbon atoms. Incidentally, this “aryl ring” corresponds to the “aryl ring formed by bonding adjacent groups among R¹ to R¹¹ together with the ring a, ring b, or ring c” defined by general formula (2). Furthermore, ring a (or ring b or ring c) is already constituted by a benzene ring having 6 carbon atoms, and therefore the carbon number of 9 in total of a fused ring obtained by fusing a 5-membered ring to this benzene ring is a lower limit of the carbon number.

Specific examples of the “aryl ring” include a benzene ring which is a monocyclic system; a biphenyl ring which is a bicyclic system; a naphthalene ring which is a fused bicyclic system; a terphenyl ring (m-terphenyl, o-terphenyl, or p-terphenyl) which is a tricyclic system; an acenaphthylene ring, a fluorene ring, a phenalene ring, and a phenanthrene ring which are fused tricyclic systems; a triphenylene ring, a pyrene ring, and a naphthacene ring which are fused tetracyclic systems; and a perylene ring and a pentacene ring which are fused pentacyclic systems.

The “heteroaryl ring” as the ring A, ring B, or ring C of general formula (1) is, for example, a heteroaryl ring having 2 to 30 carbon atoms, and the heteroaryl ring is preferably a heteroaryl ring having 2 to 25 carbon atoms, more preferably a heteroaryl ring having 2 to 20 carbon atoms, still more preferably a heteroaryl ring having 2 to 15 carbon atoms, and particularly preferably a heteroaryl ring having 2 to 10 carbon atoms. Furthermore, examples of the “heteroaryl ring” include a heterocyclic ring containing 1 to 5 heteroatoms selected from an oxygen atom, a sulfur atom, and a nitrogen atom in addition to a carbon atom as a ring-constituting atom. Incidentally, this “heteroaryl ring” corresponds to the “heteroaryl ring formed by bonding adjacent groups among the R¹ to R¹¹ together with the ring a, ring b, or ring c” defined by general formula (2). Furthermore, the ring a (or ring b or ring c) is already constituted by a benzene ring having 6 carbon atoms, and therefore the carbon number of 6 in total of a fused ring obtained by fusing a 5-membered ring to this benzene ring is a lower limit of the carbon number.

Specific examples of the “heteroaryl ring” include a pyrrole ring, an oxazole ring, an isoxazole ring, a thiazole ring, an isothiazole ring, an imidazole ring, an oxadiazole ring, a thiadiazole ring, a triazole ring, a tetrazole ring, a pyrazole ring, a pyridine ring, a pyrimidine ring, a pyridazine ring, a pyrazine ring, a triazine ring, an indole ring, an isoindole ring, a 1H-indazole ring, a benzimidazole ring, a benzoxazole ring, a benzothiazole ring, a 1H-benzotriazole ring, a quinoline ring, an isoquinoline ring, a cinnoline ring, a quinazoline ring, a quinoxaline ring, a phthalazine ring, a naphthyridine ring, a purine ring, a pteridine ring, a carbazole ring, an acridine ring, a phenoxathiin ring, a phenoxazine ring, a phenothiazine ring, a phenazine ring, an indolizine ring, a furan ring, a benzofuran ring, an isobenzofuran ring, a dibenzofuran ring, a thiophene ring, a benzothiophene ring, a dibenzothiophene ring, a furazane ring, and a thianthrene ring.

At least one hydrogen atom in the above “aryl ring” or “heteroaryl ring” may be substituted by a substituted or unsubstituted “aryl”, a substituted or unsubstituted “heteroaryl”, a substituted or unsubstituted “diarylamino”, a substituted or unsubstituted “diheteroarylamino”, a substituted or unsubstituted “arylheteroarylamino”, a substituted or unsubstituted “alkyl”, a substituted or unsubstituted “cycloalkyl”, a substituted or unsubstituted “alkoxy”, or a substituted or unsubstituted “aryloxy”, which is a primary substituent. Examples of the aryl of the “aryl”, “heteroary,” and “diarylamino”, the heteroaryl of the “diheteroarylamino”, the aryl and the heteroaryl of the “arylheteroarylamino”, and the aryl of the “aryloxy” as the primary substituents include a monovalent group of the “aryl ring” or “heteroaryl ring” described above.

Furthermore, the “alkyl” as the primary substituent may be either linear or branched, and examples thereof include a linear alkyl having 1 to 24 carbon atoms and a branched alkyl having 3 to 24 carbon atoms. An alkyl having 1 to 18 carbon atoms (branched alkyl having 3 to 18 carbon atoms) is preferable, an alkyl having 1 to 12 carbon atoms (branched alkyl having 3 to 12 carbon atoms) is more preferable, an alkyl having 1 to 6 carbon atoms (branched alkyl having 3 to 6 carbon atoms) is still more preferable, and an alkyl having 1 to 4 carbon atoms (branched alkyl having 3 to 4 carbon atoms) is particularly preferable.

Specific examples of the alkyl include methyl, ethyl, n-propyl, isopropyl, n-butyl, isobutyl, s-butyl, t-butyl, n-pentyl, isopentyl, neopentyl, t-pentyl, n-hexyl, 1-methylpentyl, 4-methyl-2-pentyl, 3,3-dimethylbutyl, 2-ethylbutyl, n-heptyl, 1-methylhexyl, n-octyl, t-octyl, 1-methylheptyl, 2-ethylhexyl, 2-propylpentyl, n-nonyl, 2,2-dimethylheptyl, 2,6-dimethyl-4-heptyl, 3,5,5-trimethylhexyl, n-decyl, n-undecyl, 1-methyldecyl, n-dodecyl, n-tridecyl, 1-hexylheptyl, n-tetradecyl, n-pentadecyl, n-hexadecyl, n-heptadecyl, n-octadecyl, and n-eicosyl.

Examples of the “cycloalkyl” as the primary substituent include a cycloalkyl having 3 to 24 carbon atoms, a cycloalkyl having 3 to 20 carbon atoms, a cycloalkyl having 3 to 16 carbon atoms, a cycloalkyl having 3 to 14 carbon atoms, a cycloalkyl having 5 to 10 carbon atoms, a cycloalkyl having 5 to 8 carbon atoms, a cycloalkyl having 5 or 6 carbon atoms, and a cycloalkyl having 5 carbon atoms.

Specific examples of the cycloalkyl include cyclopropyl, methylcyclopropyl, cyclobutyl, methylcyclobutyl, cyclopentyl, methylcyclopentyl, cyclohexyl, methylcyclohexyl, cycloheptyl, methylcycloheptyl, cyclooctyl, methylcyclooctyl, cyclononyl, methylcyclononyl, cyclodecyl, methylcyclodecyl, bicyclo[1.0.1]butyl, bicyclo[1.1.1]pentyl, bicyclo[2.0.1]pentyl, bicyclo[1.2.1]hexyl, bicyclo[3.0.1]hexyl, bicyclo[2.1.2]heptyl, bicyclo[2.2.2]octyl, adamantyl, diamantyl, decahydronaphthalenyl, and decahydroazulenyl.

Furthermore, examples of the “alkoxy” as the primary substituent include a linear alkoxy having 1 to 24 carbon atoms and a branched alkoxy having 3 to 24 carbon atoms. An alkoxy having 1 to 18 carbon atoms (branched alkoxy having 3 to 18 carbon atoms) is preferable, an alkoxy having 1 to 12 carbon atoms (branched alkoxy having 3 to 12 carbon atoms) is more preferable, an alkoxy having 1 to 6 carbon atoms (branched alkoxy having 3 to 6 carbon atoms) is still more preferable, and an alkoxy having 1 to 4 carbon atoms (branched alkoxy having 3 or 4 carbon atoms) is particularly preferable.

Specific examples of the alkoxy include methoxy, ethoxy, propoxy, isopropoxy, butoxy, isobutoxy, s-butoxy, t-butoxy, pentyloxy, hexyloxy, heptyloxy, and octyloxy.

In the substituted or unsubstituted “aryl”, substituted or unsubstituted “heteroaryl”, substituted or unsubstituted “diarylamino”, substituted or unsubstituted “diheteroarylamino”, substituted or unsubstituted “arylheteroarylamino”, substituted or unsubstituted “alkyl”, substituted or unsubstituted “cycloalkyl”, substituted or unsubstituted “alkoxy”, or substituted or unsubstituted “aryloxy”, which is the primary substituent, at least one hydrogen atom may be substituted by a secondary substituent, as described to be substituted or unsubstituted. Examples of this secondary substituent include an aryl, a heteroaryl, an alkyl, and a cycloalkyl and for the details thereof, reference can be made to the above description on the monovalent group of the “aryl ring” or “heteroaryl ring” and the “alkyl” and the “cycloalkyl” as the primary substituent. Furthermore, regarding the aryl or heteroaryl as the secondary substituent, an aryl or heteroaryl in which at least one hydrogen atom is substituted by an aryl such as a phenyl (specific examples are described above), an alkyl such as methyl (specific examples are described above), or a cycloalkyl such as cyclohexyl (specific examples are described above), is also included in the aryl or heteroaryl as the secondary substituent. For example, when the secondary substituent is a carbazolyl group, a carbazolyl group in which at least one hydrogen atom at the 9-position is substituted by an aryl such as a phenyl, an alkyl such as methyl, or a cycloalkyl such as cyclohexyl, is also included in the heteroaryl as the secondary substituent.

Examples of the aryl, the heteroaryl, the aryl of the diarylamino, the heteroaryl of the diheteroarylamino, the aryl and heteroaryl of the arylheteroarylamino, or the aryl of the aryloxy in R¹ to R¹¹ of general formula (2) include the monovalent groups of the “aryl ring” or “heteroaryl ring” described in general formula (1). Furthermore, regarding the alkyl, cycloalkyl, or alkoxy for R¹ to R¹¹, reference can be made to the description on the “alkyl”, “cycloalkyl”, or “alkoxy” as the primary substituent in the above description of general formula (1). In addition, the same also applies to the aryl, heteroaryl, alkyl, or a cycloalkyl as the substituents for these groups.

Furthermore, the same also applies to the heteroaryl, diarylamino, diheteroarylamino, arylheteroarylamino, alkyl, cycloalkyl, alkoxy, or aryloxy in a case of forming an aryl ring or a heteroaryl ring by bonding adjacent groups among R¹ to R¹¹ together with the ring a, ring b, or ring c, and the aryl, heteroaryl, alkyl, or a cycloalkyl as a further substituent.

R in the Si—R and Ge—R in Y¹ of general formula (1) represents an aryl, an alkyl or a cycloalkyl, and examples of this aryl, alkyl or a cycloalkyl include those described above. Particularly, an aryl having 6 to 10 carbon atoms (for example, phenyl or naphthyl) and an alkyl having 1 to 4 carbon atoms (for example, methyl or ethyl) are preferable. This description also applies to Y¹ in general formula (2).

R in the N—R in X¹ and X² of general formula (1) represents an aryl, a heteroaryl, an alkyl, or a cycloalkyl which may be substituted by the secondary substituent described above, and at least one hydrogen atom in the aryl, heteroaryl, alkyl, or cycloalkyl may be substituted by, for example, an alkyl or a cycloalkyl. Examples of this aryl, heteroaryl, alkyl, or cycloalkyl include those described above. Particularly, an aryl having 6 to 10 carbon atoms (for example, phenyl or naphthyl), a heteroaryl having 2 to 15 carbon atoms (for example, carbazolyl), an alkyl having 1 to 4 carbon atoms (for example, methyl or ethyl), and a cycloalkyl having 3 to 16 carbon atoms (for example, bicyclooctyl or adamantyl) are preferable. This description also applies to X¹ and X² in general formula (2).

R of the “—C(—R)₂—” as a linking group for general formula (1) represents a hydrogen atom, an alkyl or a cycloalkyl, and examples of this alkyl or cycloalkyl include those described above. Particularly, an alkyl having 1 to 4 carbon atoms (for example, methyl or ethyl) is preferable. This description also applies to “—C(—R)₂—” as a linking group for general formula (2).

Furthermore, the invention of the present application is a multimer of a polycyclic aromatic compound having a plurality of unit structures each represented by general formula (1), and preferably a multimer of a polycyclic aromatic compound having a plurality of unit structures each represented by general formula (2). The multimer is preferably a dimer to a hexamer, more preferably a dimer to a trimer, and a particularly preferably a dimer. The multimer only needs to have the plurality of unit structures described above in one compound. For example, the multimer may have a form in which the plurality of unit structures is bonded to one another with a linking group such as a single bond, an alkylene group having 1 to 3 carbon atoms, a phenylene group, or a naphthylene group. In addition, the multimer may have a form in which a plurality of unit structures is bonded such that any ring contained in the unit structure (ring A, ring B, or ring C, or ring a, ring b, or ring c) is shared by the plurality of unit structures, or may have a form in which the unit structures are bonded to one another such that any rings contained in the unit structures (ring A, ring B, or ring C, or ring a, ring b, or ring c) are fused to each other.

Examples of such a multimer include multimer compounds represented by the following formulas (2-4), (2-4-1), (2-4-2), (2-5-1) to (2-5-4), and (2-6). To be described in connection with general formula (2), the multimer compound represented by the following formula (2-4) includes a plurality of unit structures each represented by general formula (2) in one compound so as to share a benzene ring as ring a. Furthermore, to be described in connection with general formula (2), the multimer compound represented by the following formula (2-4-1) includes two unit structures each represented by general formula (2) in one compound so as to share a benzene ring as ring a. Furthermore, to be described in connection with general formula (2), the multimer compound represented by the following formula (2-4-2) includes three unit structures each represented by general formula (2) in one compound so as to share a benzene ring as ring a. Furthermore, to be described in connection with general formula (2), each of the multimer compounds represented by the following formulas (2-5-1) to (2-5-4) includes a plurality of unit structures each represented by general formula (2) in one compound so as to share a benzene ring as ring b (or ring c). Furthermore, to be described in connection with general formula (2), for example, the multimer compound represented by the following formula (2-6) includes a plurality of unit structures each represented by general formula (2) in one compound such that a benzene ring as ring b (or ring a or ring c) of a certain unit structure and a benzene ring as ring b (or ring a or ring c) of a certain unit structure are fused.

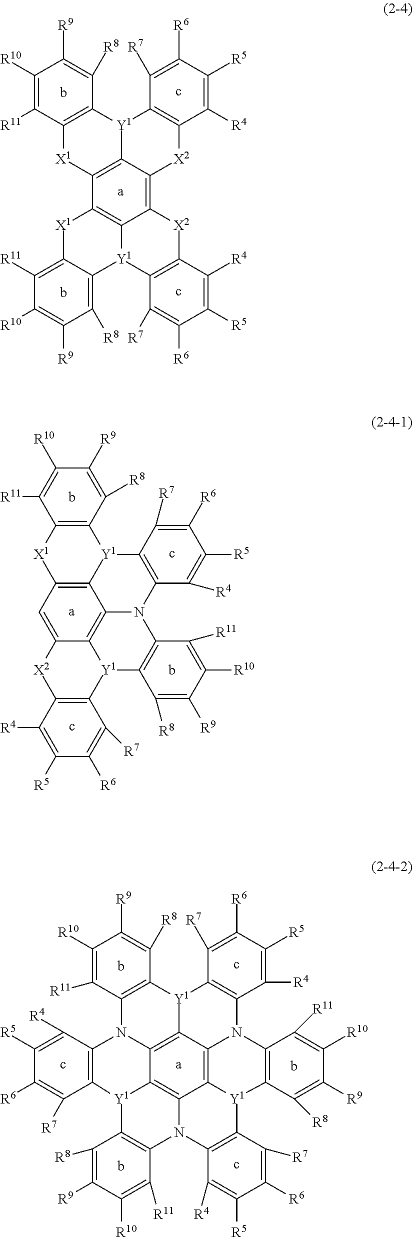

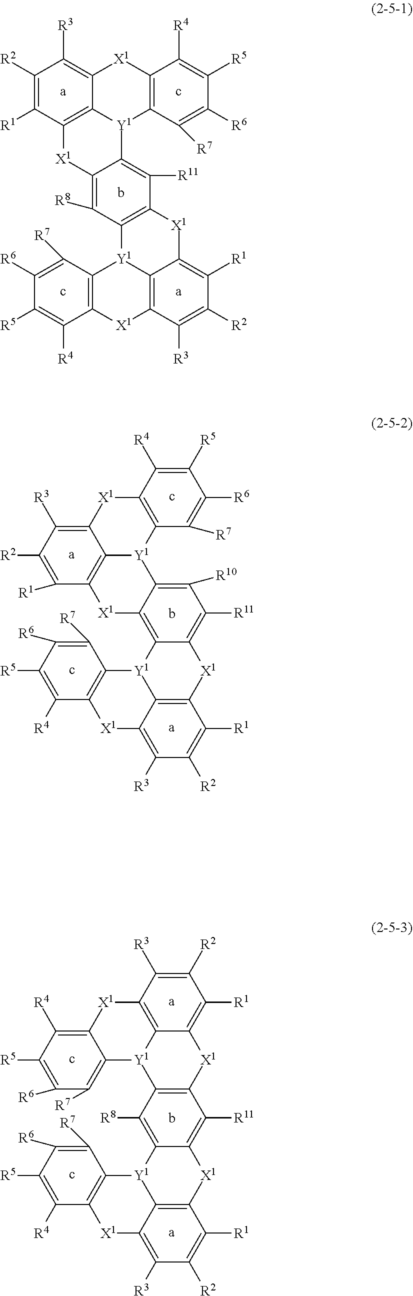

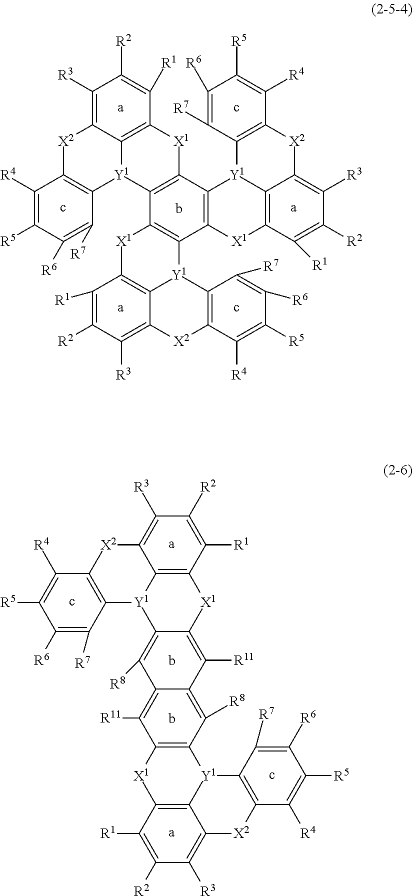

The multimer compound may be a multimer in which a multimer form represented by formula (2-4), (2-4-1), or (2-4-2) and a multimer form represented by any one of formula (2-5-1) to (2-5-4) or (2-6) are combined, may be a multimer in which a multimer form represented by any one of formulas (2-5-1) to (2-5-4) and a multimer form represented by formula (2-6) are combined, or may be a multimer in which a multimer form represented by formula (2-4), (2-4-1), or (2-4-2), a multimer form represented by any one of formulas (2-5-1) to (2-5-4), and a multimer form represented by formula (2-6) are combined.

Furthermore, all or a part of the hydrogen atoms in the chemical structures of the polycyclic aromatic compound represented by general formula (1) or (2) and a multimer thereof may be cyanos or halogen atoms. For example, in formula (1), a hydrogen atom in the ring A, ring B, ring C (ring A to ring C are aryl rings or heteroaryl rings), substituents on the ring A to ring C, R (=an alkyl, a cycloalkyl or an aryl) when Y¹ represents Si—R or Ge—R, and R (=an aryl, a heteroaryl, an alkyl, or a cycloalkyl) when X¹ and X² each represent N—R can be substituted by cyano or a halogen atom. Among these, a form in which all or a part of the hydrogen atoms in the aryl or heteroaryl have been substituted by cyanos or halogen atoms may be mentioned. The halogen is fluorine, chlorine, bromine, or iodine, preferably fluorine, chlorine, or bromine, and more preferably fluorine or chlorine.

Furthermore, the polycyclic aromatic compound and the multimer according to an aspect of the present invention can be used as a material for an organic device. Examples of the organic device include an organic electroluminescent element, an organic field effect transistor, and an organic thin film solar cell. Particularly, in the organic electroluminescent element, a compound in which Y¹ represents B, and X¹ and X² each represent N—R, a compound in which Y¹ represents B, X¹ represents O, and X² represents N—R, and a compound in which Y¹ represents B, and X¹ and X² each represent O are preferably used as a dopant material for a light emitting layer. A compound in which Y¹ represents B, X¹ represents O, and X² represents N—R, and a compound in which Y¹ represents B, and X¹ and X² each represent O are preferably used as a host material for a light emitting layer. A compound in which Y¹ represents B, and X¹ and X² each represent O, and a compound in which Y¹ represents P═O, and X¹ and X² each represent O are preferably used as an electron transport material.

Furthermore, at least one hydrogen atom in the chemical structures of the polycyclic aromatic compound represented by general formula (1) or (2) and a multimer thereof is substituted by a deuterium atom, and all or a part of the hydrogen atoms may be deuterium atoms.

Examples of another form of deuterium substitution include a form in which the polycyclic aromatic compound represented by the general formula (1) or (2) and a multimer thereof are each substituted by a deuterium-substituted diarylamino group, a deuterium-substituted carbazolyl group, or a deuterium-substituted benzocarbazolyl group. Examples of the “diarylamino group” include those described as the “primary substituent” above. Examples of a form of deuterium substitution on a diarylamino group, a carbazolyl group, and a benzocarbazolyl group include a form in which a part or all of the hydrogen atoms of the aryl ring or the benzene ring in these groups are substituted by deuterium atoms.

Furthermore, more specific examples thereof include a form in which R² in the polycyclic aromatic compound represented by general formula (2) and a multimer thereof is a deuterium-substituted diarylamino group or a deuterium-substituted carbazolyl group.

Examples thereof include a polycyclic aromatic compound represented by the following general formula (2-A) and a multimer of a polycyclic aromatic compound having a plurality of structures represented by the following general formula (2-A). The definition of each reference numeral in the structural formula is the same as the definition of each reference numeral in general formula (2).

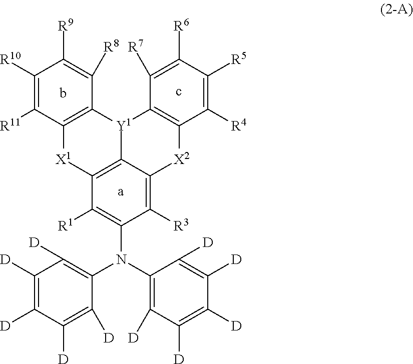

Furthermore, specific examples of the deuterium-substituted polycyclic aromatic compound and the multimer thereof according to an aspect of the present invention include a compound in which at least one hydrogen atom in one or more aromatic rings in the compound is substituted by one or more deuterium atoms, such as a compound substituted by 1 or 2 deuterium atoms.

Specific examples thereof include compounds represented by the following formulas (1-1-D) to (1-4401-D). In each of the following formulas, n's each independently represent 0 to 2, preferably 1. Incidentally, “D” in the following structural formulas represents a deuterium atom, “OPh” represents a phenoxy group, and “Me” represents a methyl group.

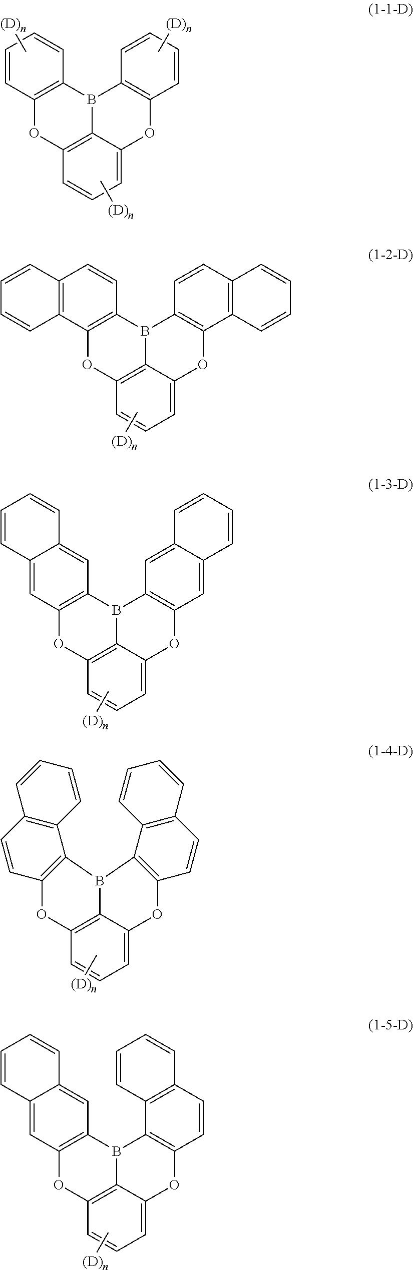

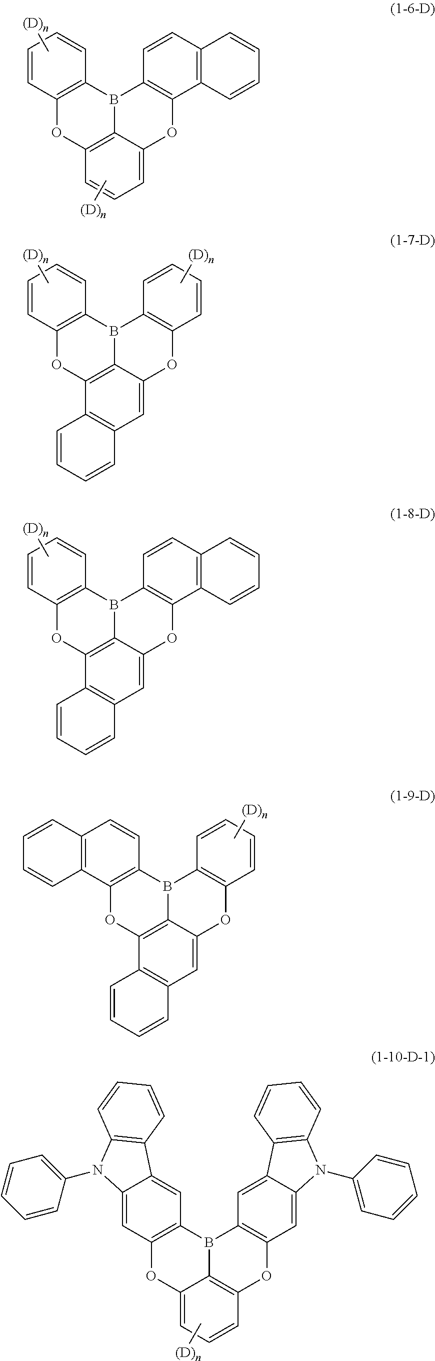

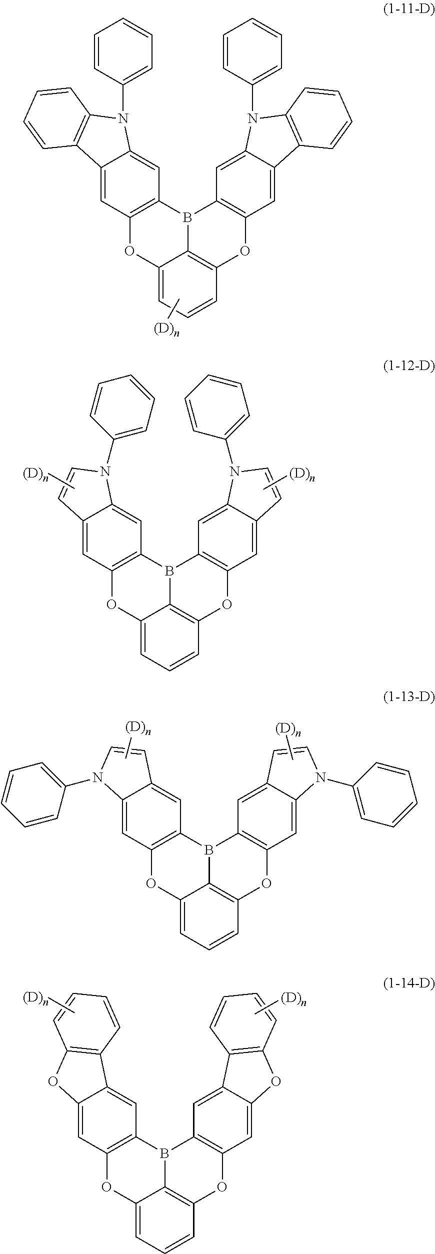

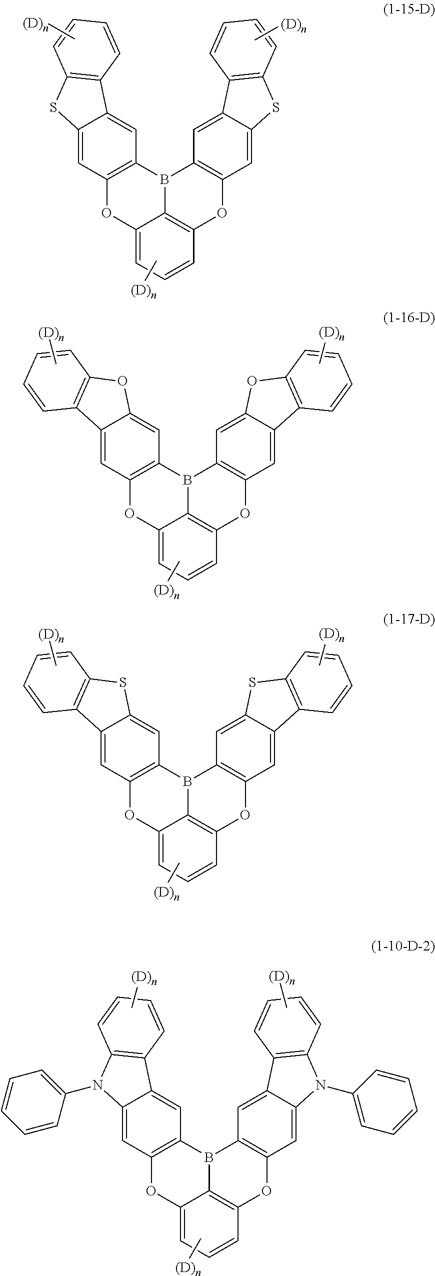

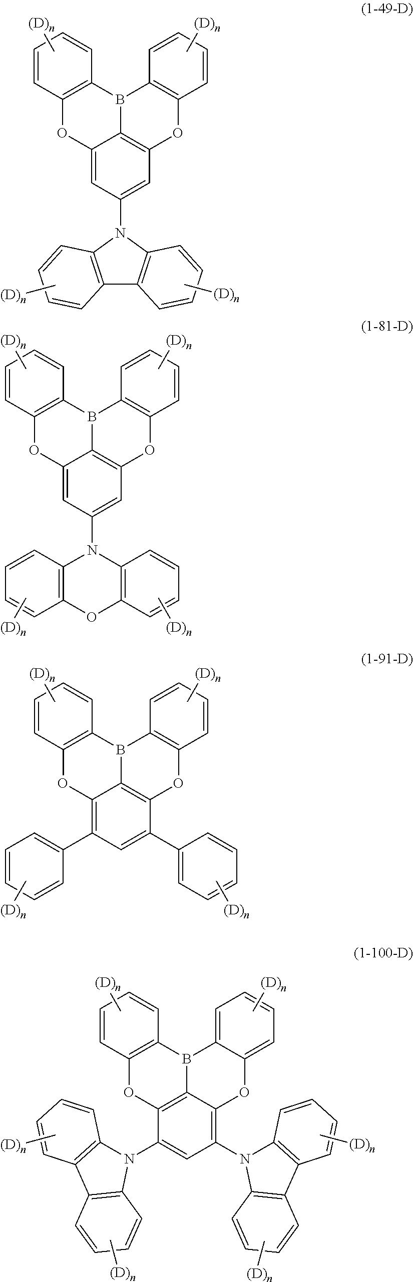

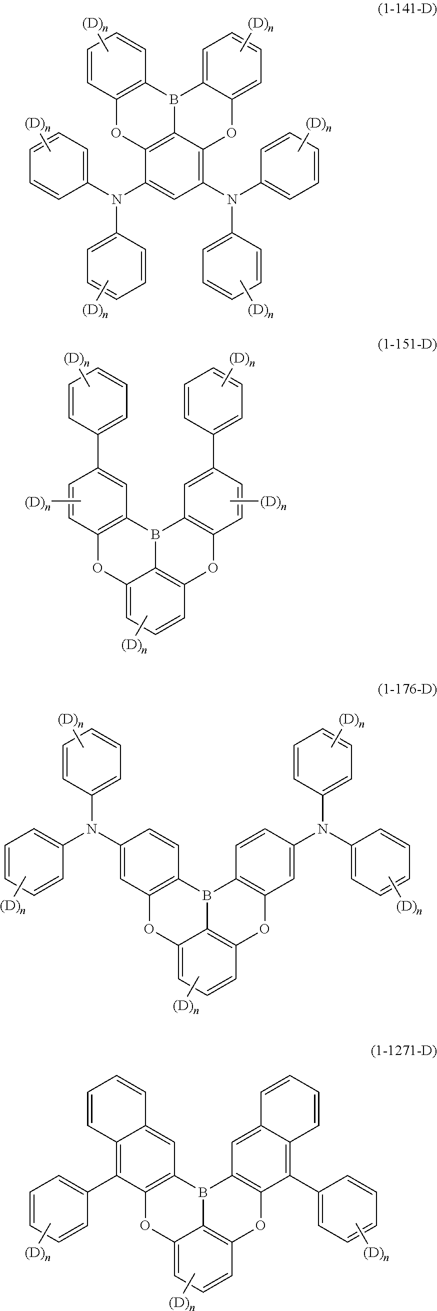

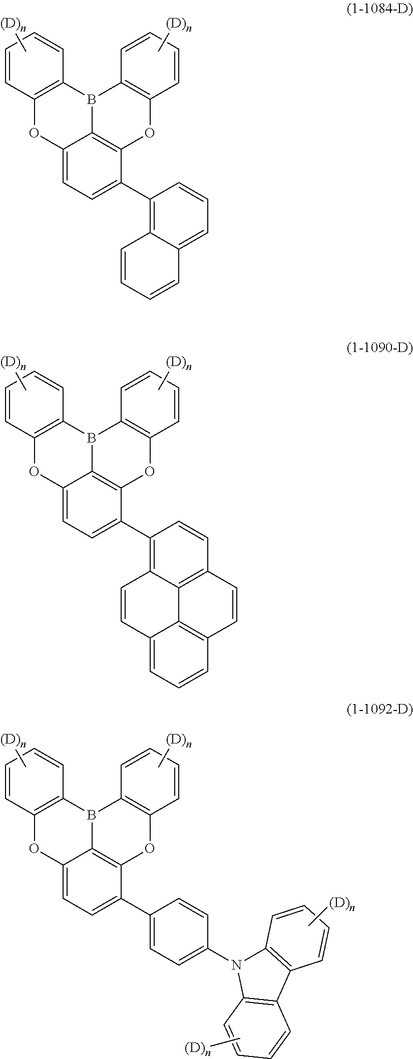

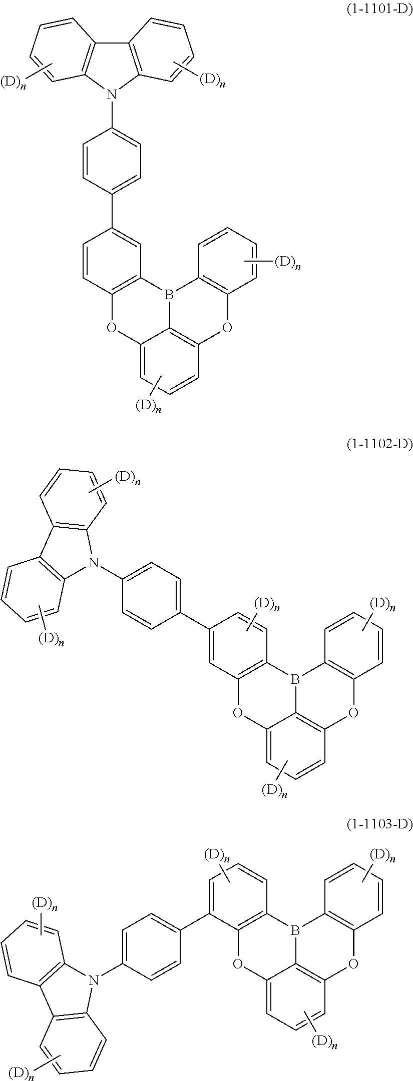

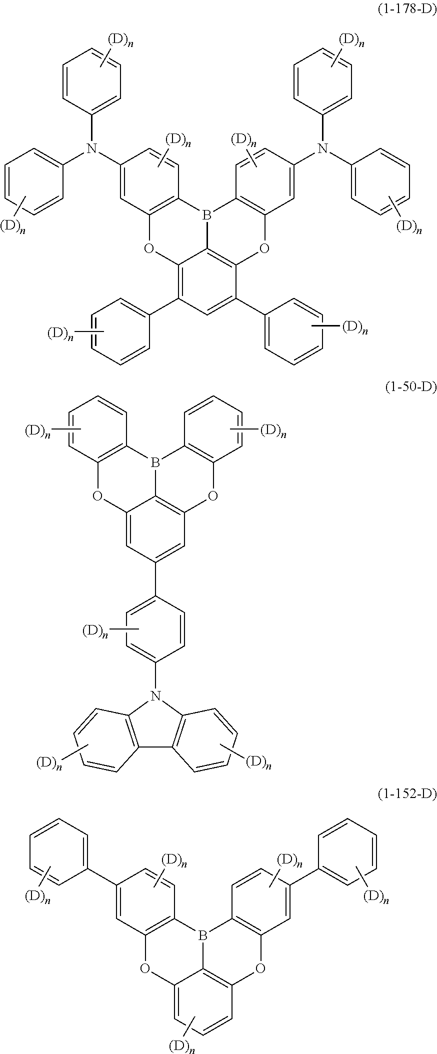

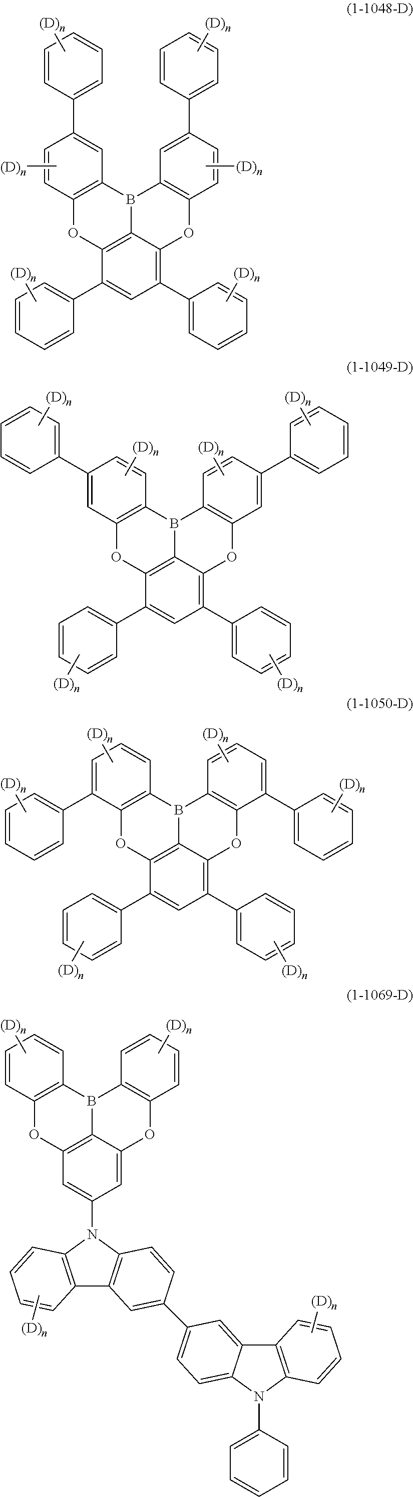

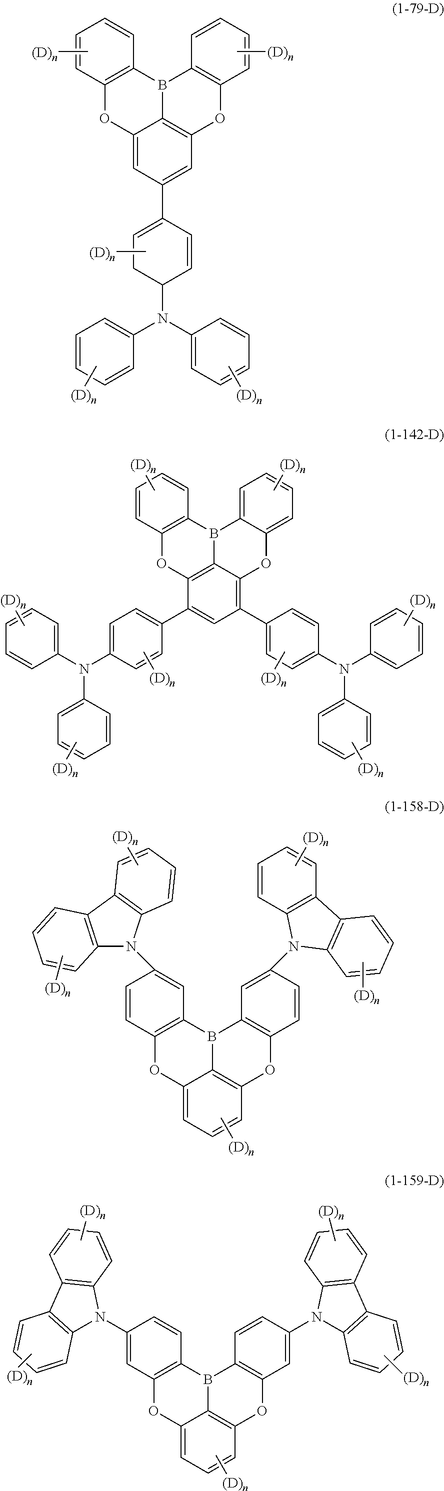

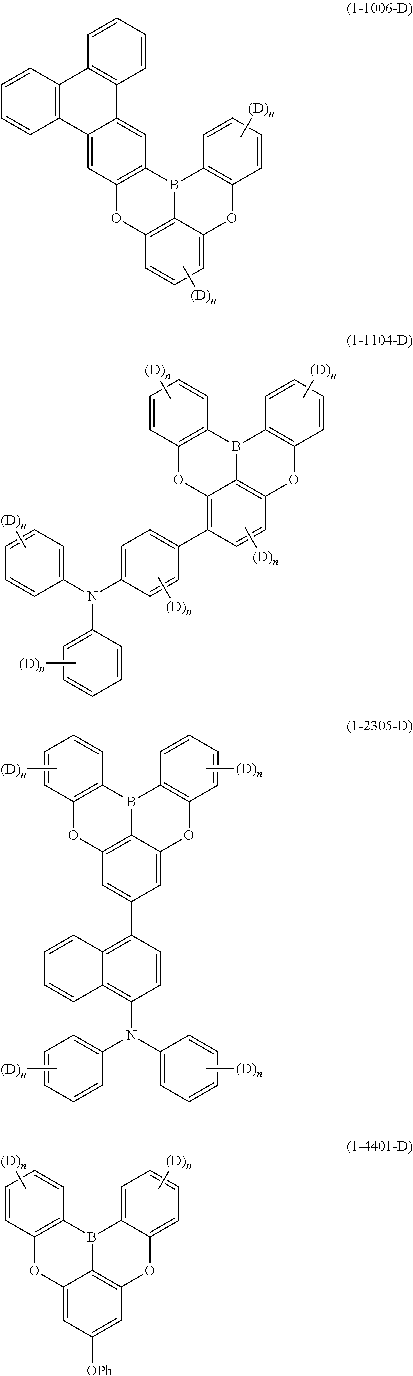

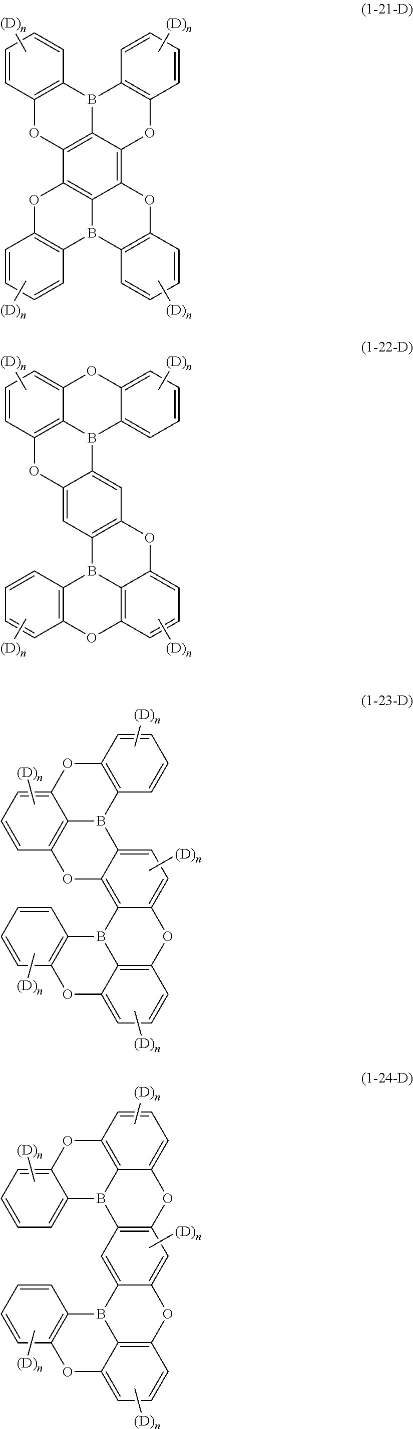

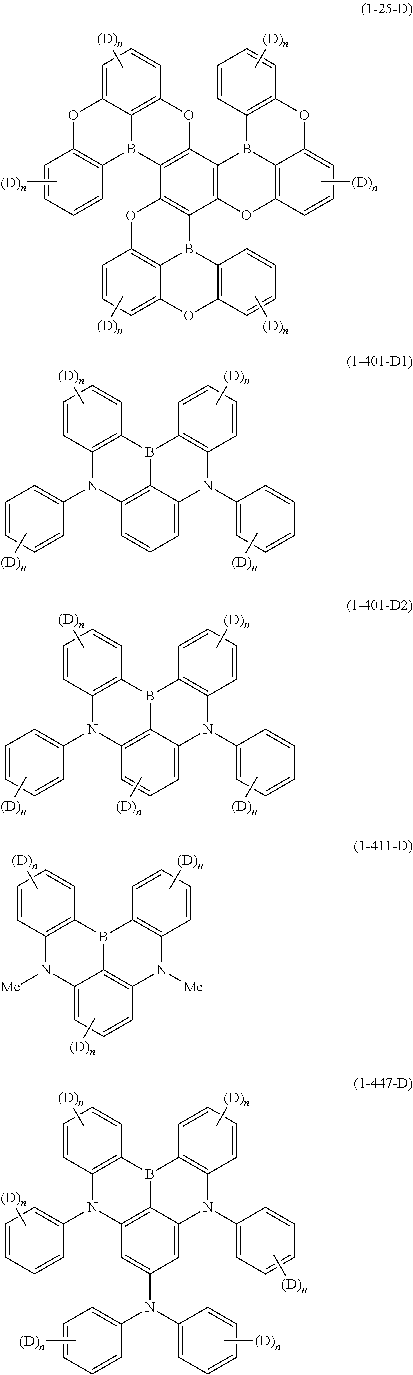

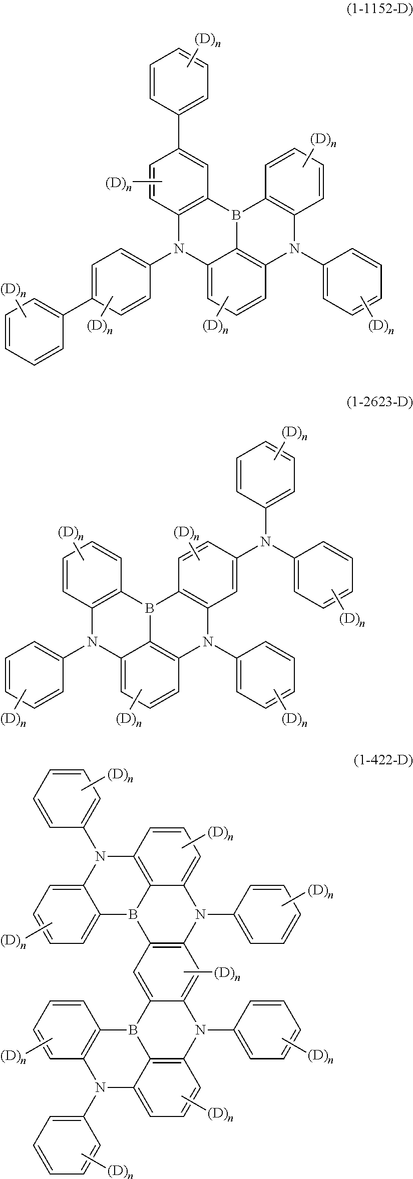

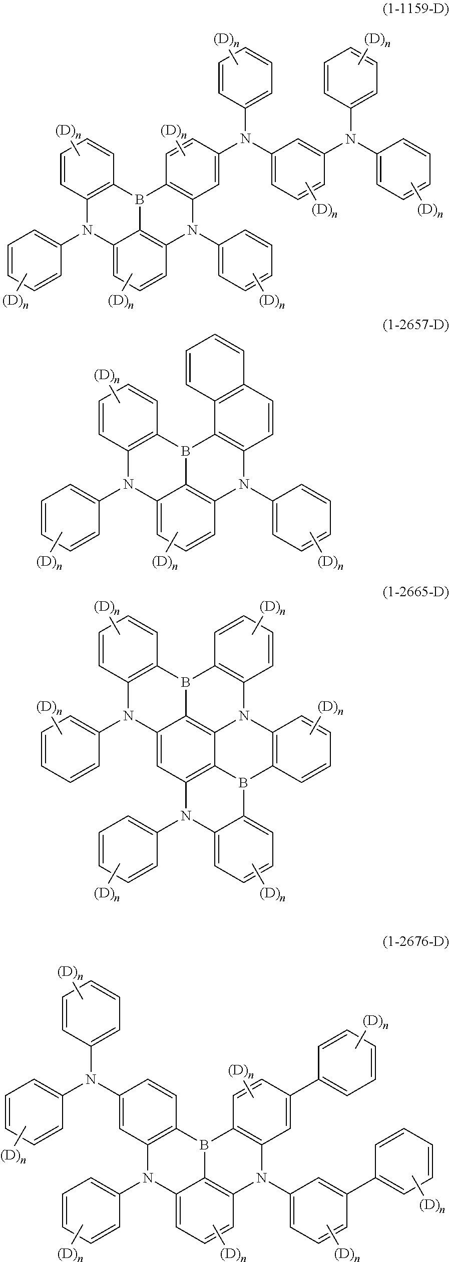

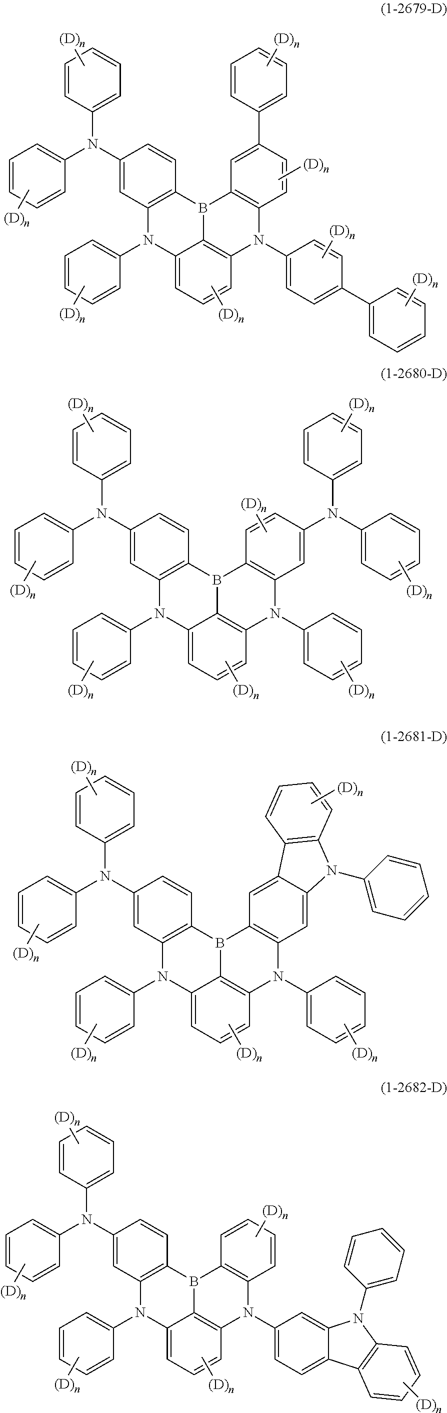

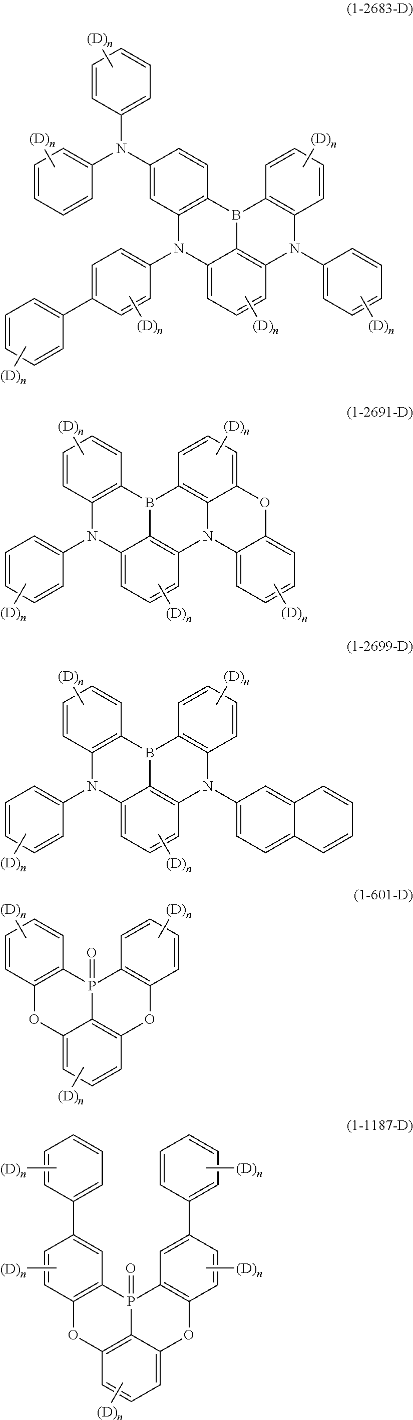

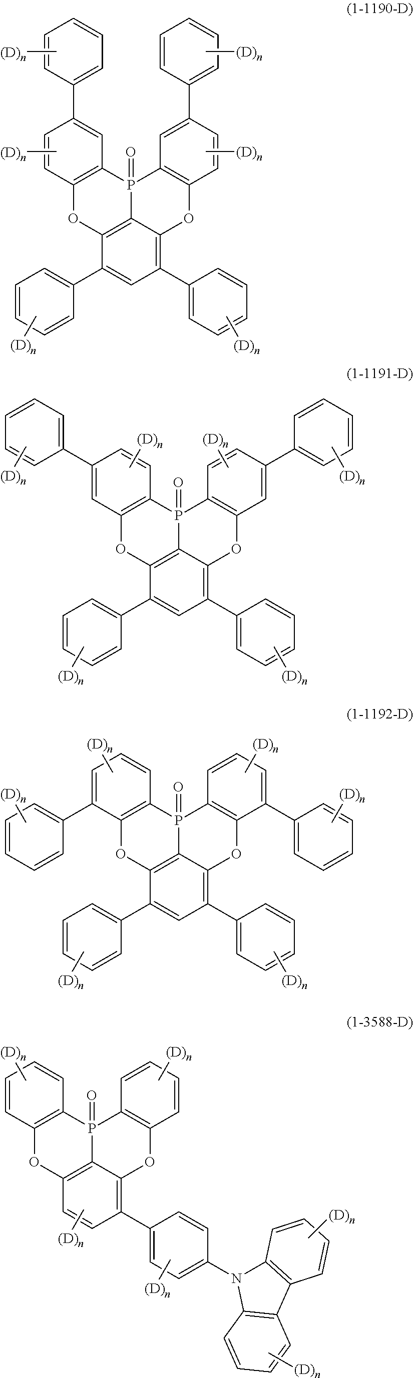

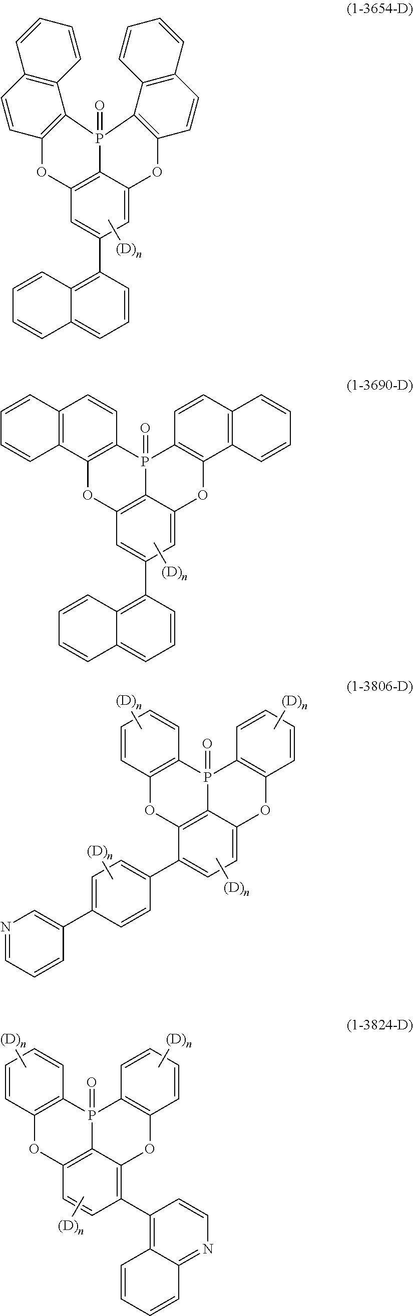

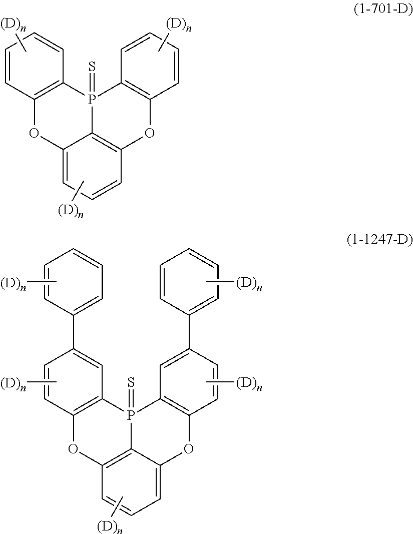

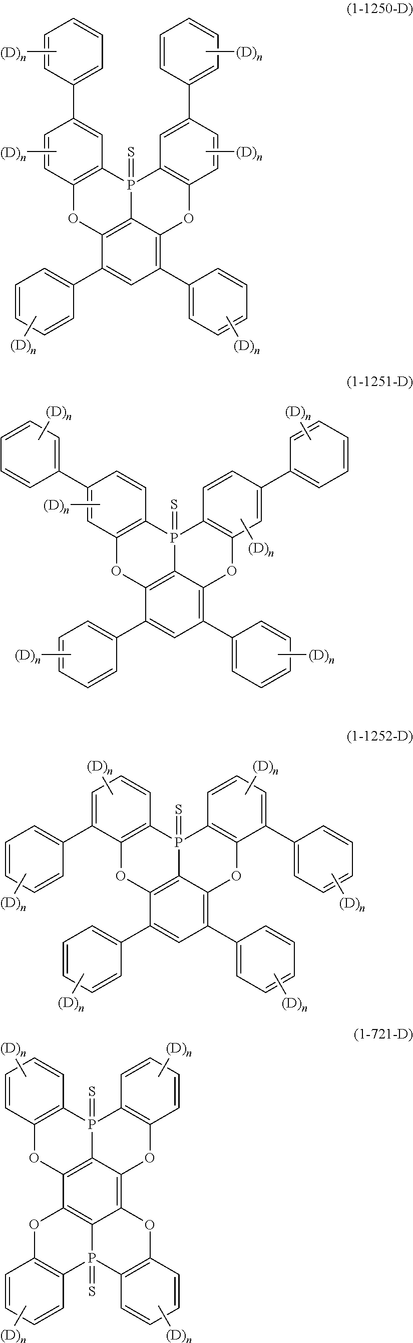

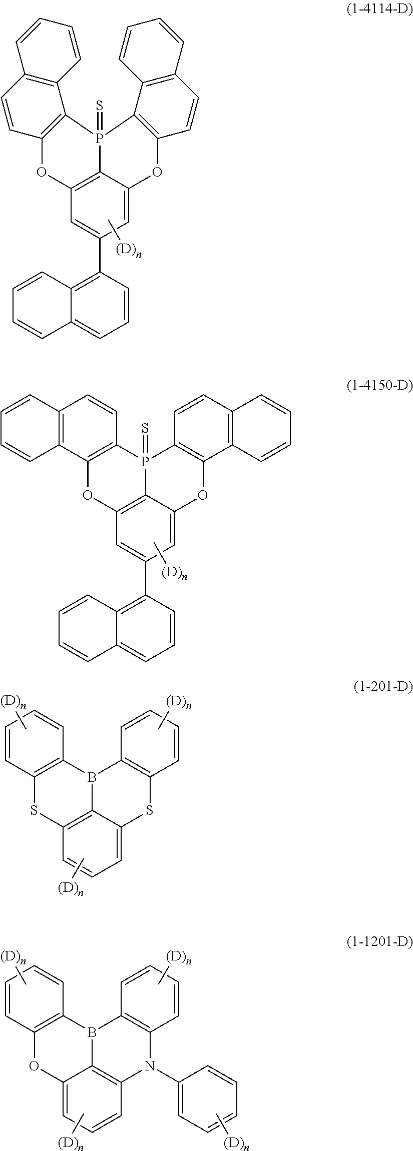

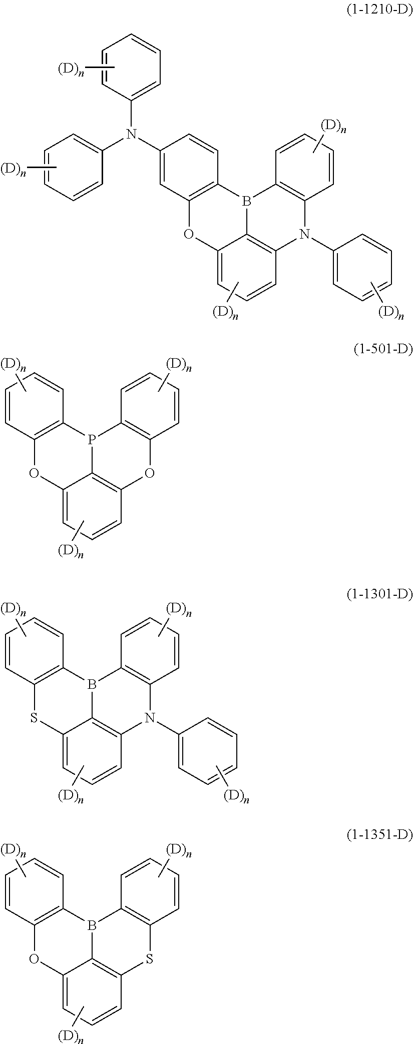

More specific examples of the deuterium-substituted polycyclic aromatic compound according to an aspect of the present invention include compounds represented by the following structural formulas. Incidentally, “D” in the following structural formulas represents a deuterium atom, “Me” represents a methyl group, and “tBu” represents a tertiary butyl group

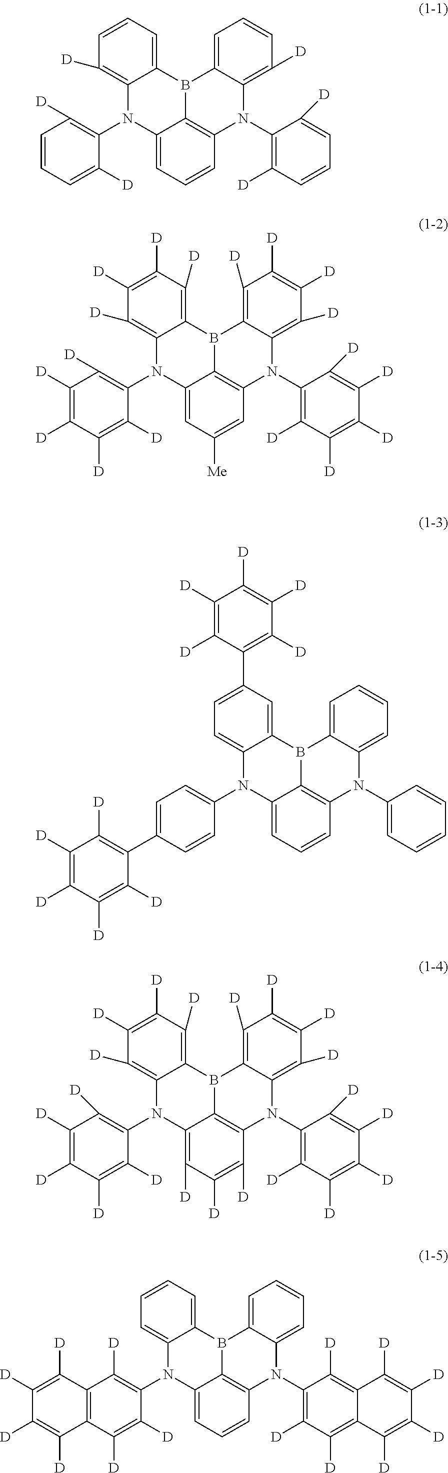

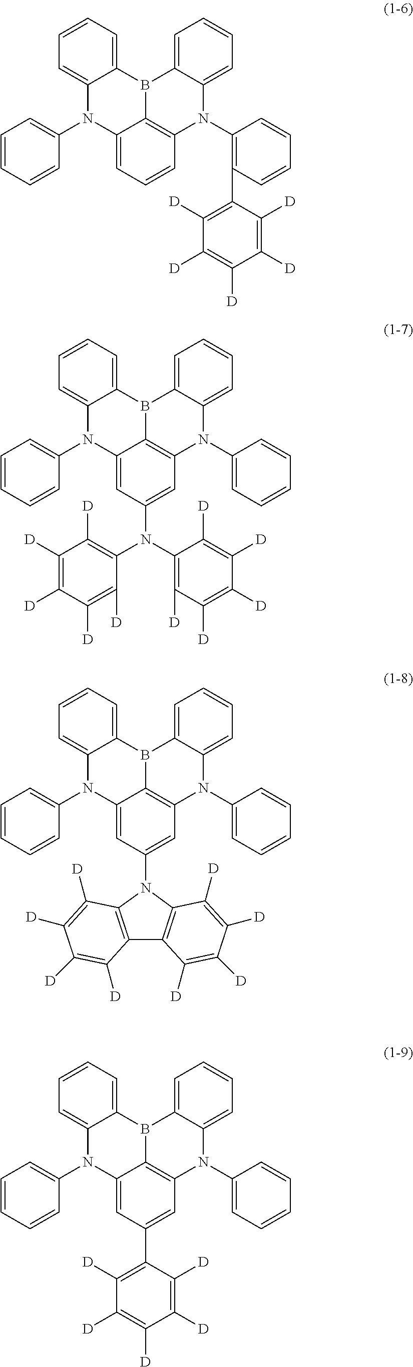 [SMILES: [2H]c1c([2H])c([2H])c(-c2ccccc2N2c3ccccc3B3c4ccccc4N(c4ccccc4)c4cccc2c43)c([2H])c1[2H] ; [2H]c1c([2H])c([2H])c(N(c2cc3c4c(c2)N(c2ccccc2)c2ccccc2B4c2ccccc2N3c2ccccc2)c2c([2H])c([2H])c([2H])c([2H])c2[2H])c([2H])c1[2H] ; [2H]c1c([2H])c([2H])c2c(c1[2H])c1c([2H])c([2H])c([2H])c([2H])c1n2-c1cc2c3c(c1)N(c1ccccc1)c1ccccc1B3c1ccccc1N2c1ccccc1 ; [2H]c1c([2H])c([2H])c(-c2cc3c4c(c2)N(c2ccccc2)c2ccccc2B4c2ccccc2N3c2ccccc2)c([2H])c1[2H]]

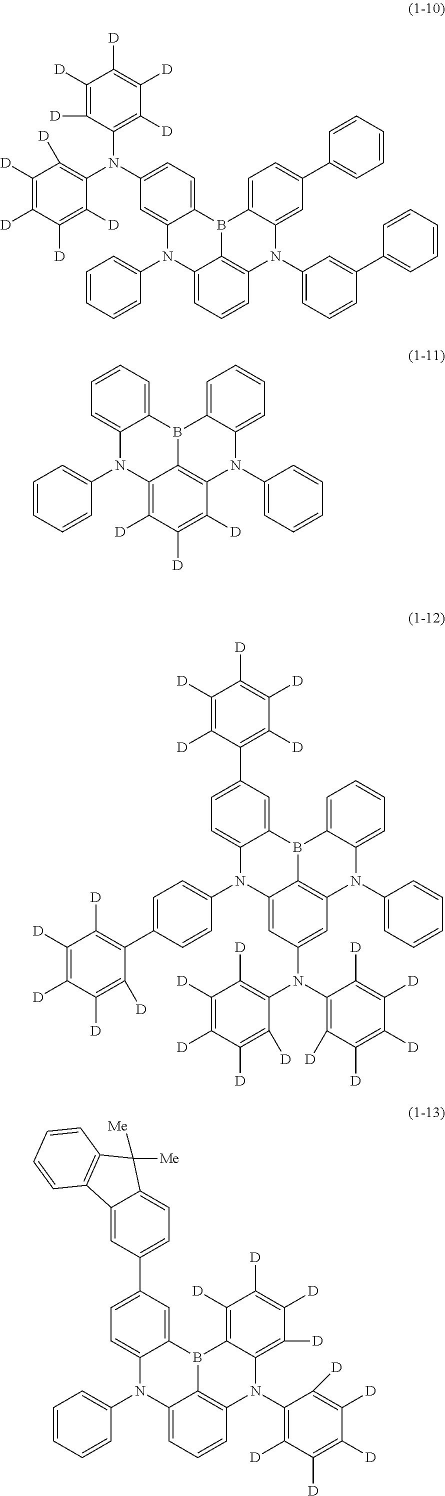

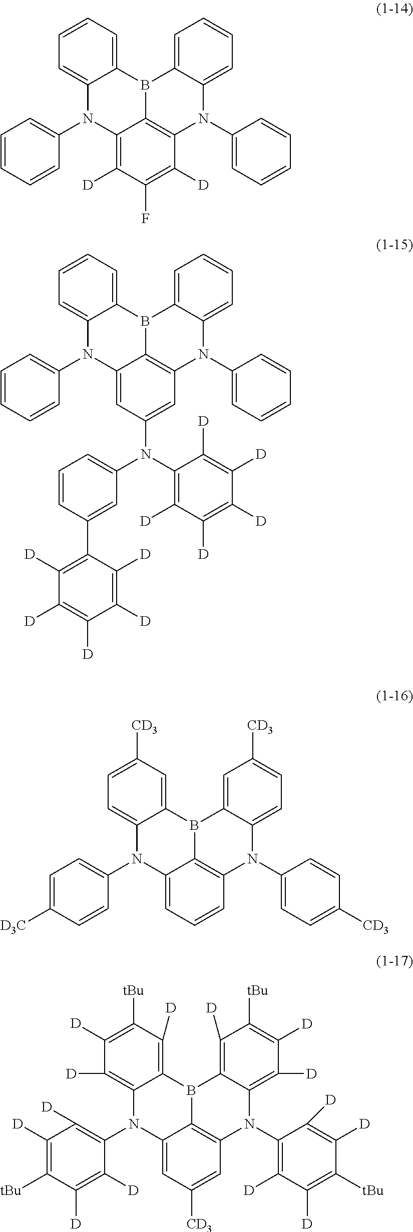

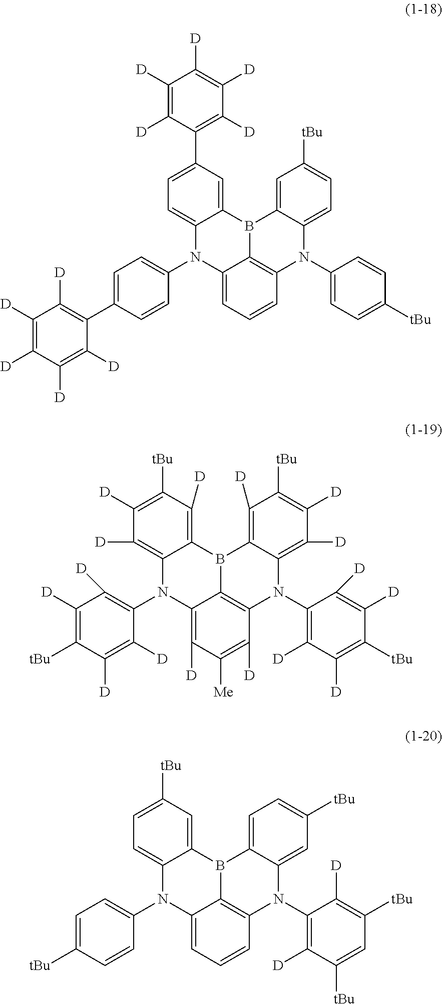 [SMILES: [2H]c1c([2H])c([2H])c(-c2ccc(N3c4ccc(-c5c([2H])c([2H])c([2H])c([2H])c5[2H])cc4B4c5cc(C(C)(C)C)ccc5N(c5ccc(C(C)(C)C)cc5)c5cccc3c54)cc2)c([2H])c1[2H] ; [2H]c1c([2H])c(C(C)(C)C)c([2H])c([2H])c1N1c2c([2H])c([2H])c(C(C)(C)C)c([2H])c2B2c3c([2H])c(C(C)(C)C)c([2H])c([2H])c3N(c3c([2H])c([2H])c(C(C)(C)C)c([2H])c3[2H])c3c([2H])c(C)c([2H])c1c32 ; [2H]c1c(C(C)(C)C)cc(C(C)(C)C)c([2H])c1N1c2cc(C(C)(C)C)ccc2B2c3cc(C(C)(C)C)ccc3N(c3ccc(C(C)(C)C)cc3)c3cccc1c32]

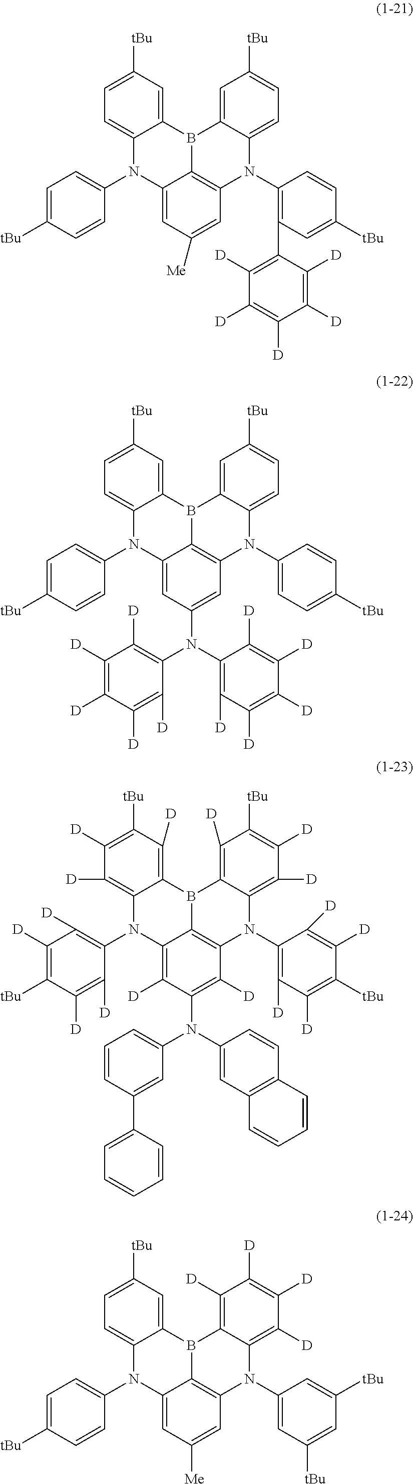

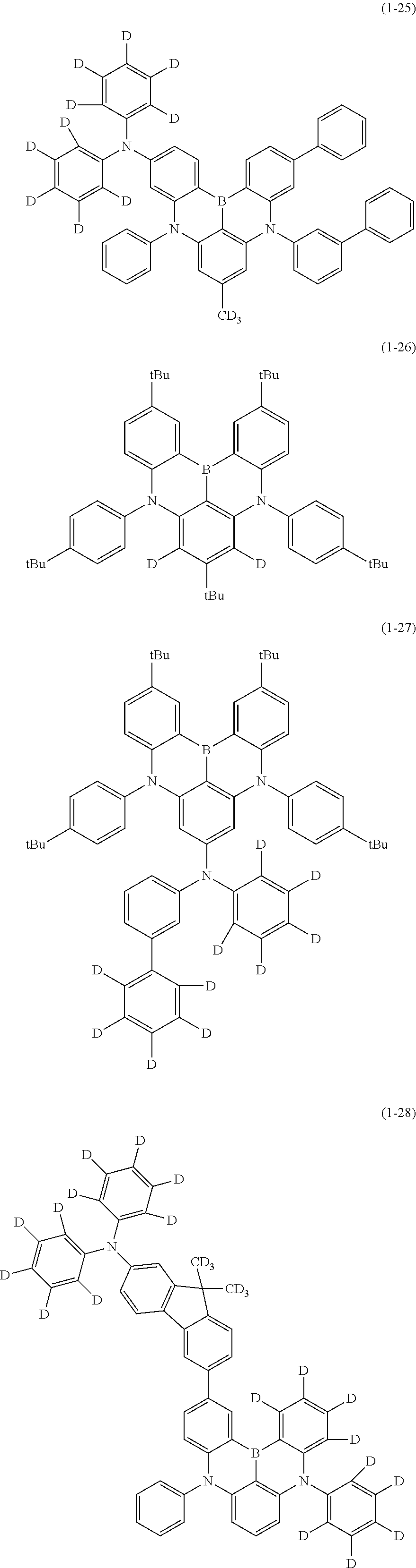

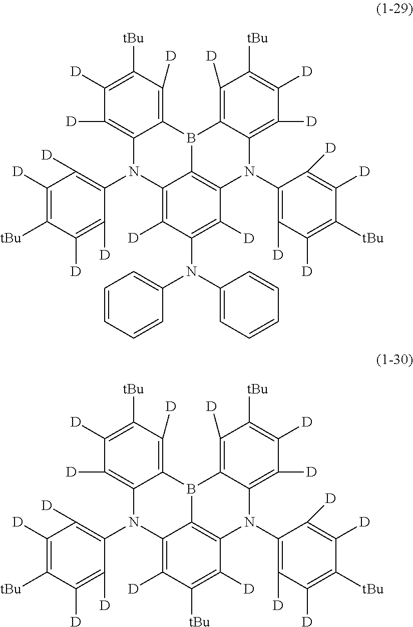 [SMILES: [2H]c1c([2H])c(C(C)(C)C)c([2H])c([2H])c1N1c2c([2H])c([2H])c(C(C)(C)C)c([2H])c2B2c3c([2H])c(C(C)(C)C)c([2H])c([2H])c3N(c3c([2H])c([2H])c(C(C)(C)C)c([2H])c3[2H])c3c([2H])c(N(c4ccccc4)c4ccccc4)c([2H])c1c32 ; [2H]c1c([2H])c(C(C)(C)C)c([2H])c([2H])c1N1c2c([2H])c([2H])c(C(C)(C)C)c([2H])c2B2c3c([2H])c(C(C)(C)C)c([2H])c([2H])c3N(c3c([2H])c([2H])c(C(C)(C)C)c([2H])c3[2H])c3c([2H])c(C(C)(C)C)c([2H])c1c32]

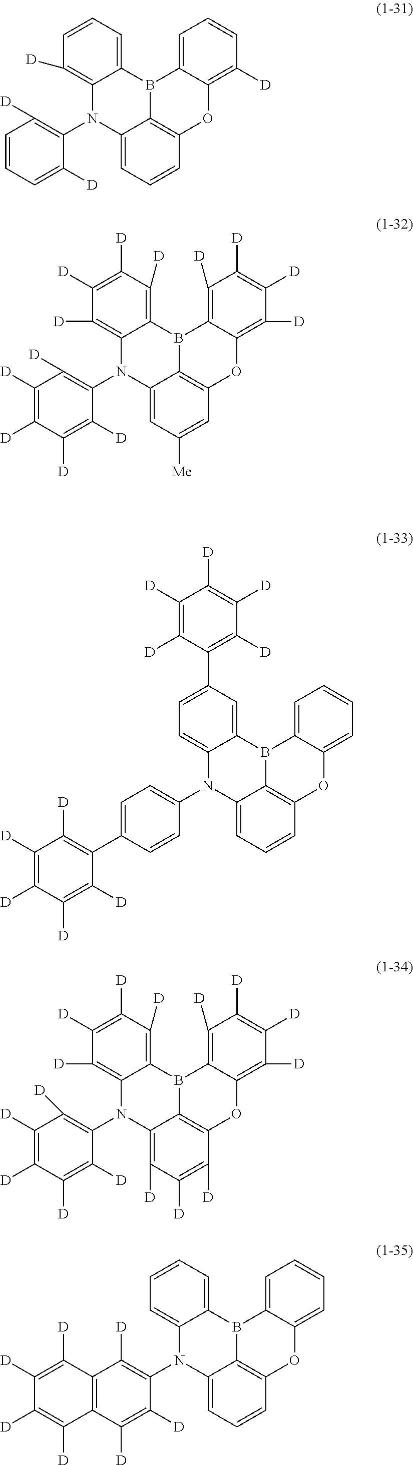

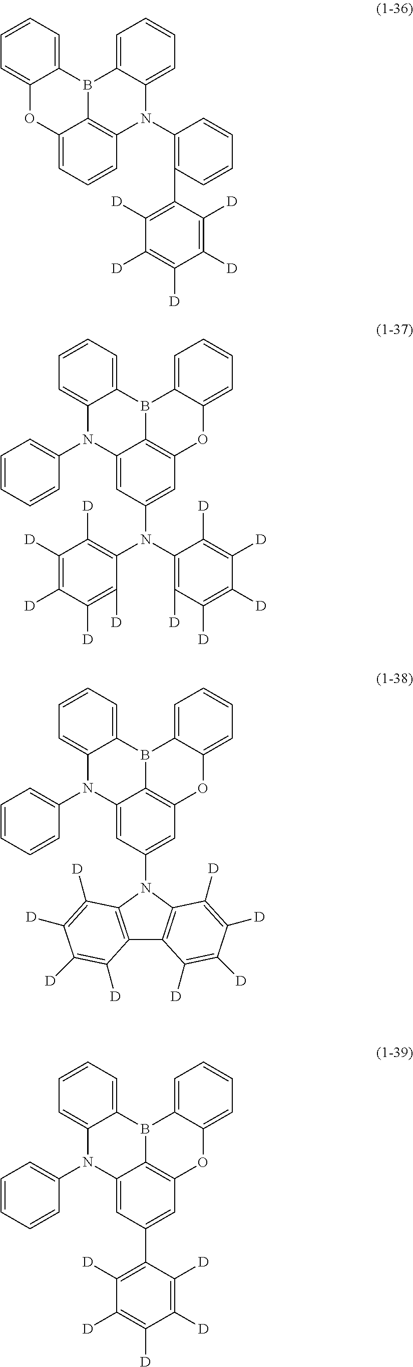 [SMILES: [2H]c1c([2H])c([2H])c(-c2ccccc2N2c3ccccc3B3c4ccccc4Oc4cccc2c43)c([2H])c1[2H] ; [2H]c1c([2H])c([2H])c(N(c2cc3c4c(c2)N(c2ccccc2)c2ccccc2B4c2ccccc2O3)c2c([2H])c([2H])c([2H])c([2H])c2[2H])c([2H])c1[2H] ; [2H]c1c([2H])c([2H])c2c(c1[2H])c1c([2H])c([2H])c([2H])c([2H])c1n2-c1cc2c3c(c1)N(c1ccccc1)c1ccccc1B3c1ccccc1O2 ; [2H]c1c([2H])c([2H])c(-c2cc3c4c(c2)N(c2ccccc2)c2ccccc2B4c2ccccc2O3)c([2H])c1[2H]]

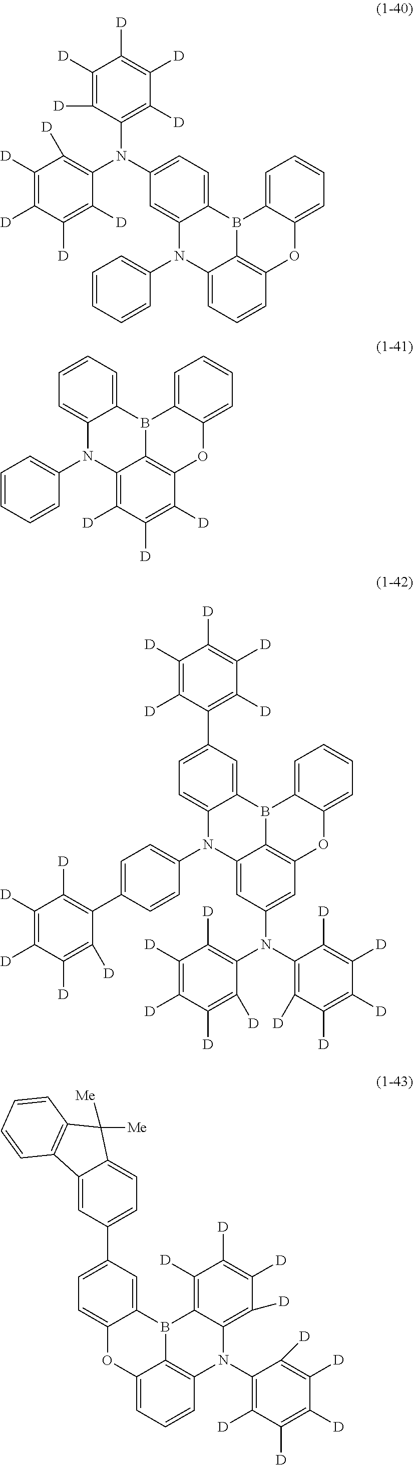 [SMILES: [2H]c1c([2H])c([2H])c(N(c2ccc3c(c2)N(c2ccccc2)c2cccc4c2B3c2ccccc2O4)c2c([2H])c([2H])c([2H])c([2H])c2[2H])c([2H])c1[2H] ; [2H]c1c([2H])c2c3c(c1[2H])N(c1ccccc1)c1ccccc1B3c1ccccc1O2 ; [2H]c1c([2H])c([2H])c(-c2ccc(N3c4ccc(-c5c([2H])c([2H])c([2H])c([2H])c5[2H])cc4B4c5ccccc5Oc5cc(N(c6c([2H])c([2H])c([2H])c([2H])c6[2H])c6c([2H])c([2H])c([2H])c([2H])c6[2H])cc3c54)cc2)c([2H])c1[2H] ; [2H]c1c([2H])c([2H])c(N2c3cccc4c3B(c3cc(-c5ccc6c(c5)-c5ccccc5C6(C)C)ccc3O4)c3c([2H])c([2H])c([2H])c([2H])c32)c([2H])c1[2H]]

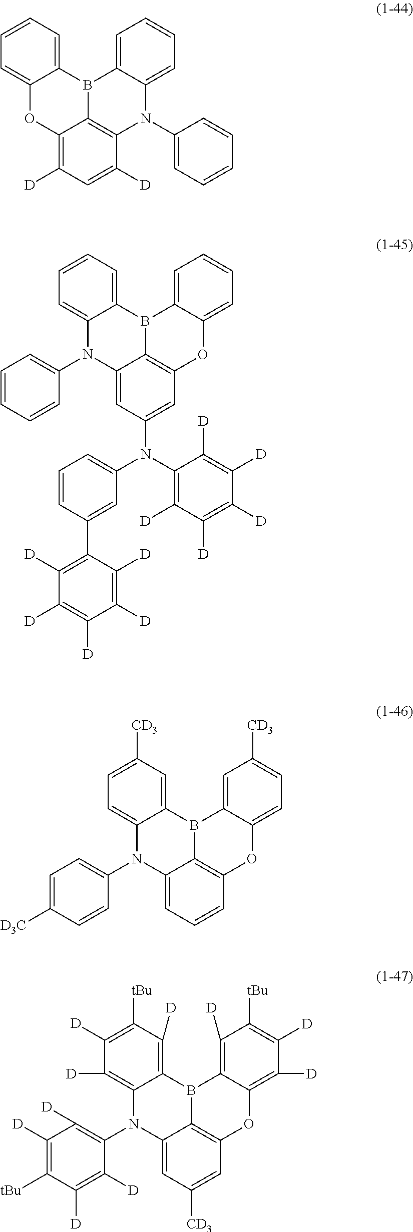 [SMILES: [2H]c1cc([2H])c2c3c1Oc1ccccc1B3c1ccccc1N2c1ccccc1 ; [2H]c1c([2H])c([2H])c(-c2cccc(N(c3cc4c5c(c3)N(c3ccccc3)c3ccccc3B5c3ccccc3O4)c3c([2H])c([2H])c([2H])c([2H])c3[2H])c2)c([2H])c1[2H] ; [2H]C([2H])([2H])c1ccc(N2c3ccc(C([2H])([2H])[2H])cc3B3c4cc(C([2H])([2H])[2H])ccc4Oc4cccc2c43)cc1 ; [2H]c1c([2H])c(C(C)(C)C)c([2H])c2c1Oc1cc(C([2H])([2H])[2H])cc3c1B2c1c([2H])c(C(C)(C)C)c([2H])c([2H])c1N3c1c([2H])c([2H])c(C(C)(C)C)c([2H])c1[2H]]

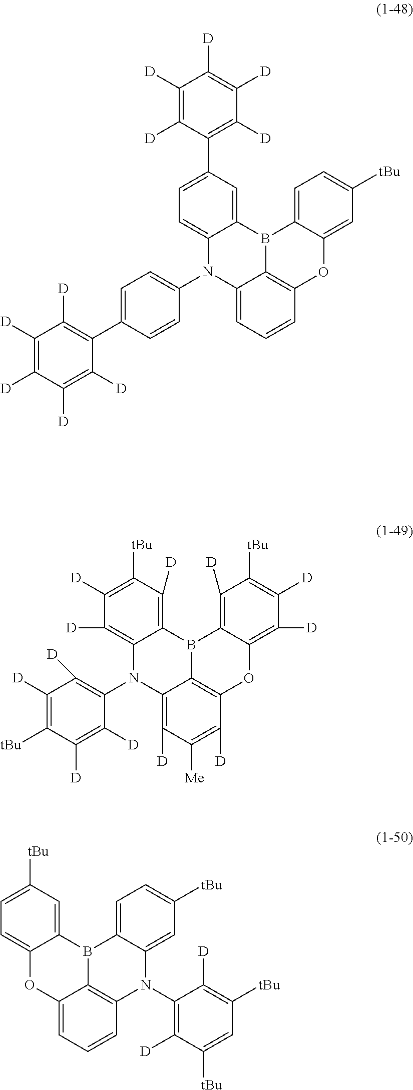 [SMILES: [2H]c1c([2H])c([2H])c(-c2ccc(N3c4ccc(-c5c([2H])c([2H])c([2H])c([2H])c5[2H])cc4B4c5ccc(C(C)(C)C)cc5Oc5cccc3c54)cc2)c([2H])c1[2H] ; [2H]c1c([2H])c(C(C)(C)C)c([2H])c2c1Oc1c([2H])c(C)c([2H])c3c1B2c1c([2H])c(C(C)(C)C)c([2H])c([2H])c1N3c1c([2H])c([2H])c(C(C)(C)C)c([2H])c1[2H] ; [2H]c1c(C(C)(C)C)cc(C(C)(C)C)c([2H])c1N1c2cc(C(C)(C)C)ccc2B2c3cc(C(C)(C)C)ccc3Oc3cccc1c32]

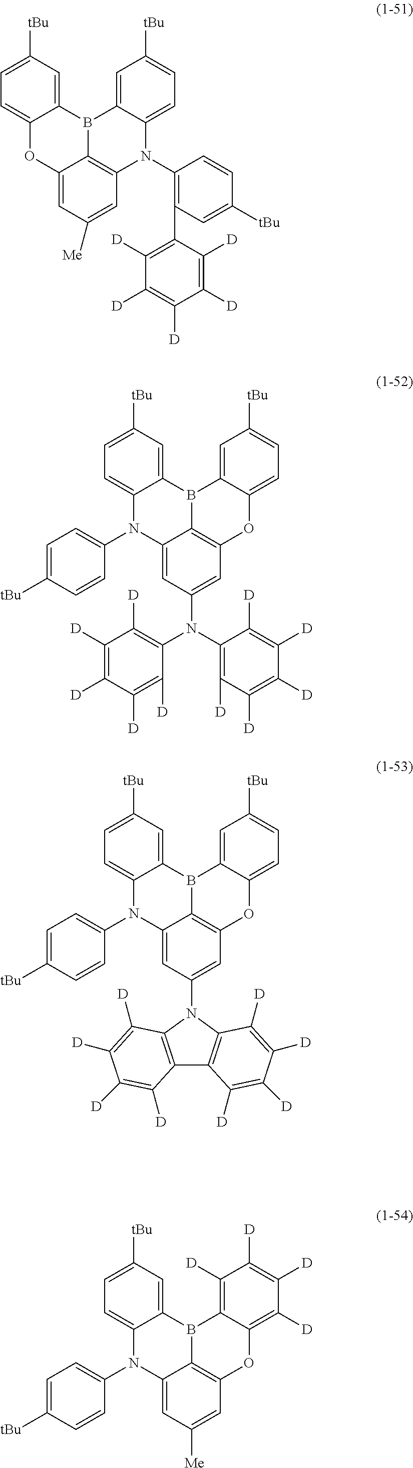 [SMILES: [2H]c1c([2H])c([2H])c(-c2cc(C(C)(C)C)ccc2N2c3ccc(C(C)(C)C)cc3B3c4cc(C(C)(C)C)ccc4Oc4cc(C)cc2c43)c([2H])c1[2H] ; [2H]c1c([2H])c([2H])c(N(c2cc3c4c(c2)N(c2ccc(C(C)(C)C)cc2)c2ccc(C(C)(C)C)cc2B4c2cc(C(C)(C)C)ccc2O3)c2c([2H])c([2H])c([2H])c([2H])c2[2H])c([2H])c1[2H] ; [2H]c1c([2H])c([2H])c2c(c1[2H])c1c([2H])c([2H])c([2H])c([2H])c1n2-c1cc2c3c(c1)N(c1ccc(C(C)(C)C)cc1)c1ccc(C(C)(C)C)cc1B3c1cc(C(C)(C)C)ccc1O2 ; [2H]c1c([2H])c([2H])c2c(c1[2H])Oc1cc(C)cc3c1B2c1cc(C(C)(C)C)ccc1N3c1ccc(C(C)(C)C)cc1]

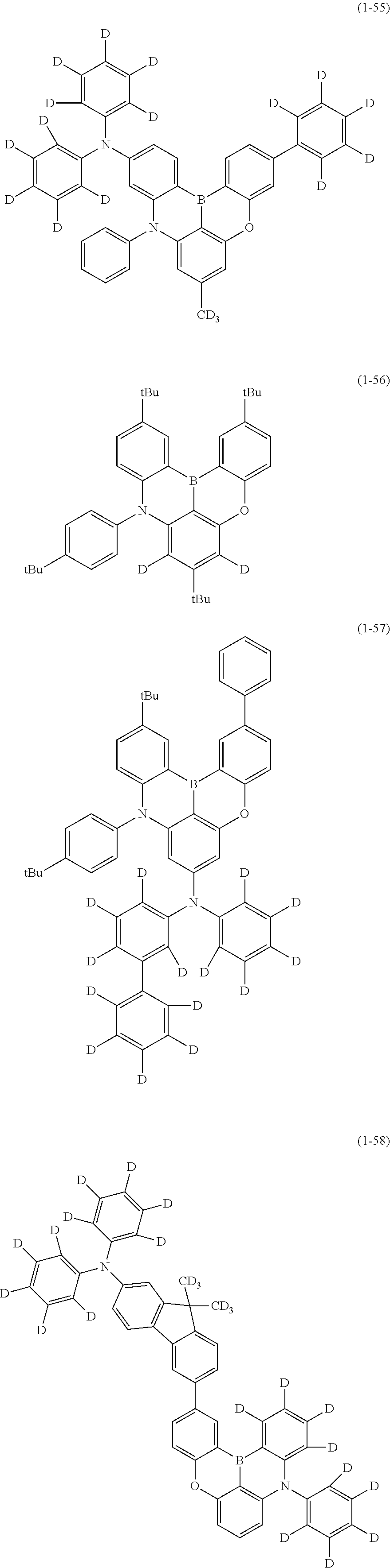

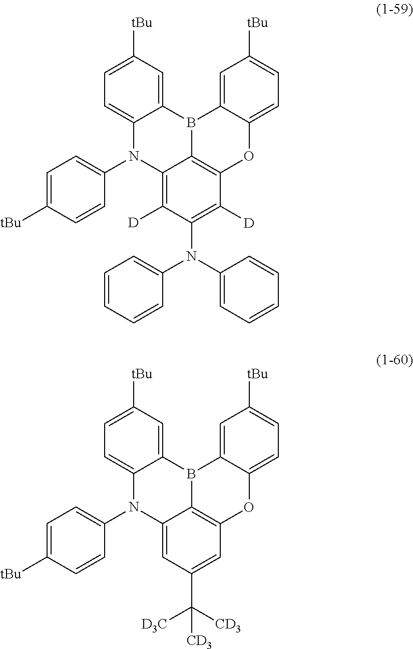 [SMILES: [2H]c1c2c3c(c([2H])c1N(c1ccccc1)c1ccccc1)N(c1ccc(C(C)(C)C)cc1)c1ccc(C(C)(C)C)cc1B3c1cc(C(C)(C)C)ccc1O2 ; [2H]C([2H])([2H])C(c1cc2c3c(c1)N(c1ccc(C(C)(C)C)cc1)c1ccc(C(C)(C)C)cc1B3c1cc(C(C)(C)C)ccc1O2)(C([2H])([2H])[2H])C([2H])([2H])[2H]]

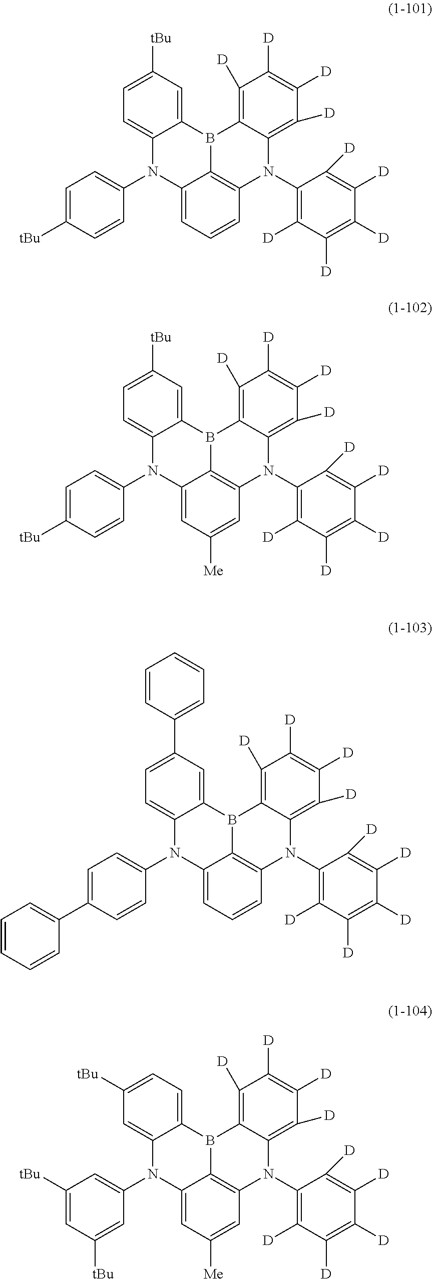

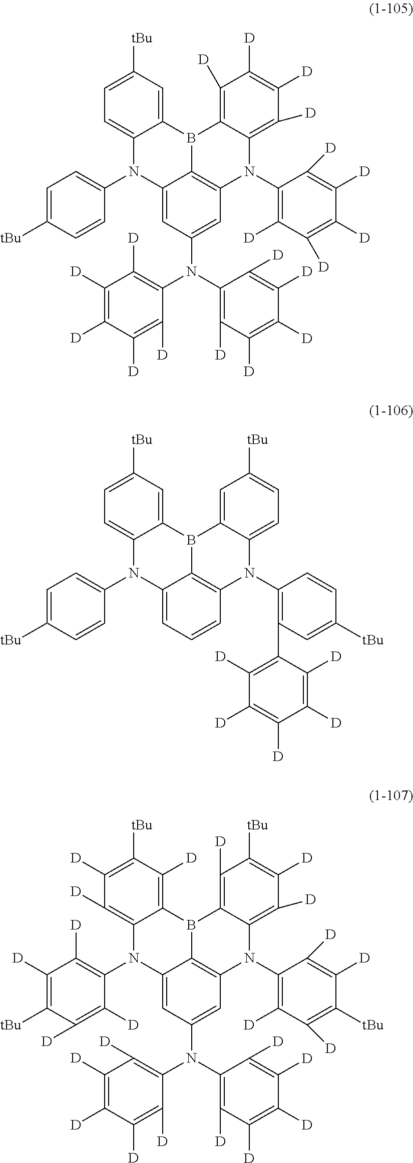

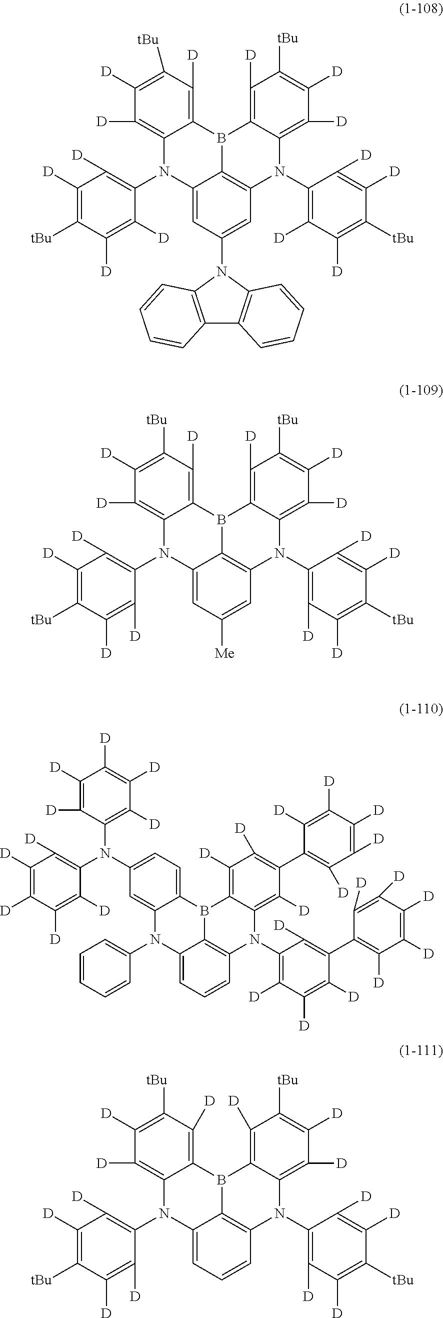

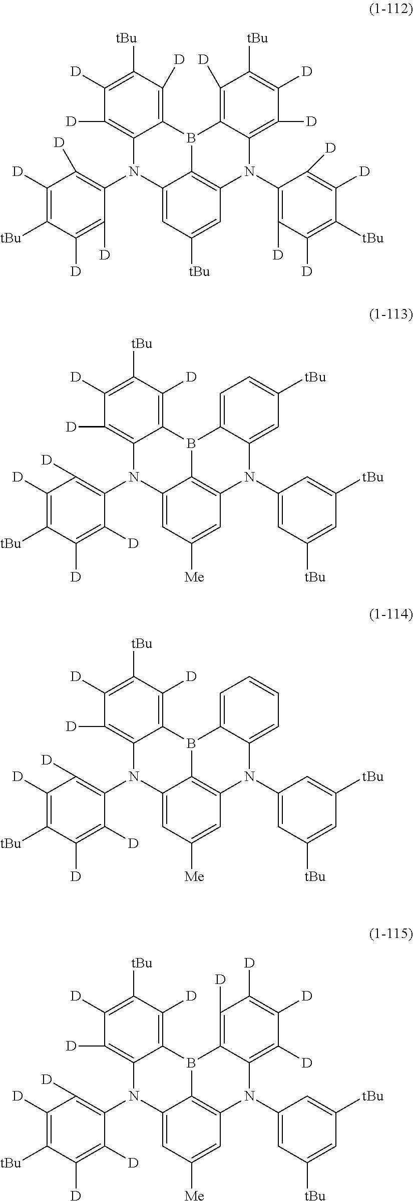

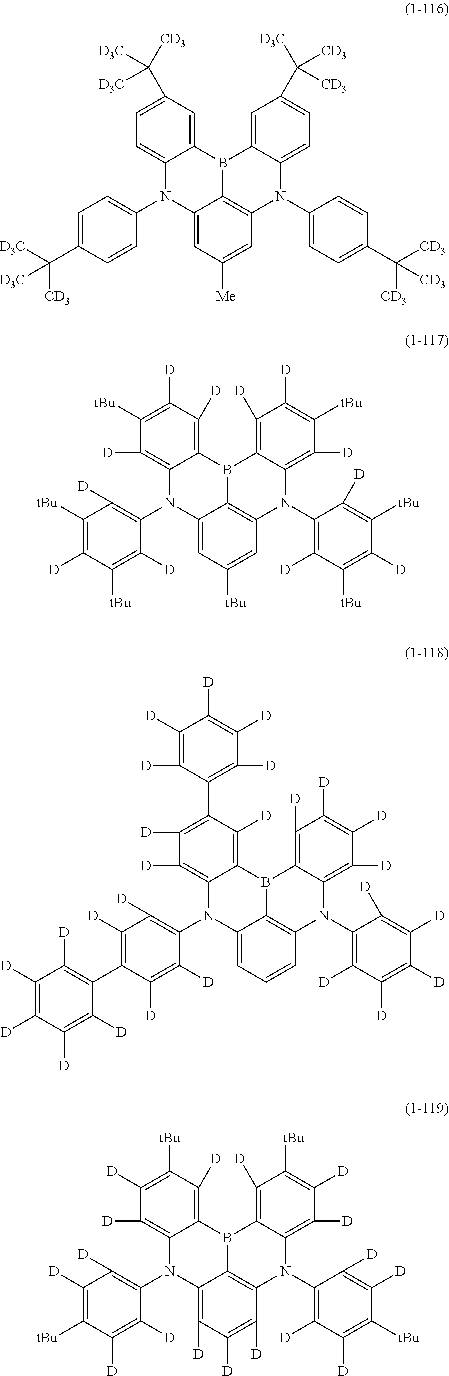

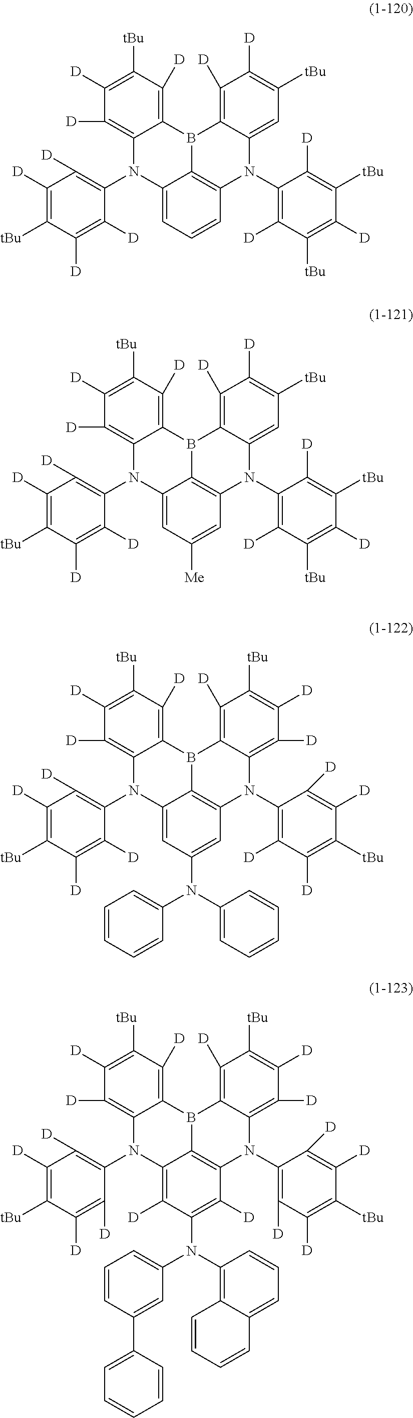

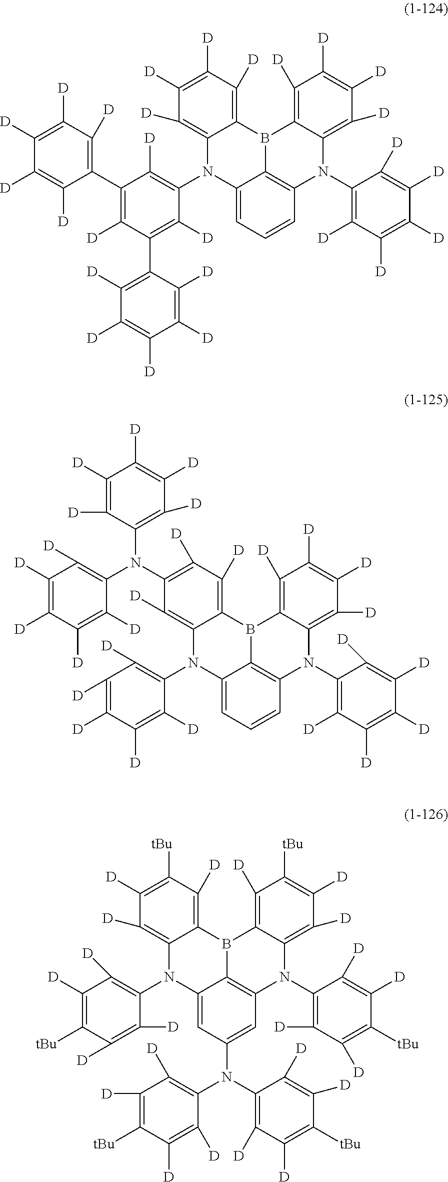

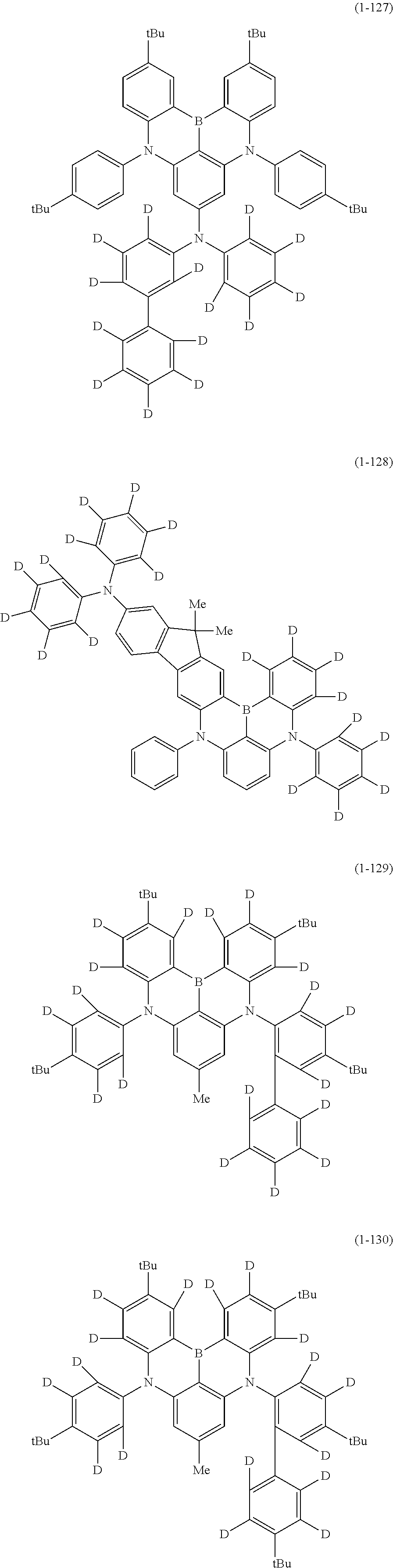

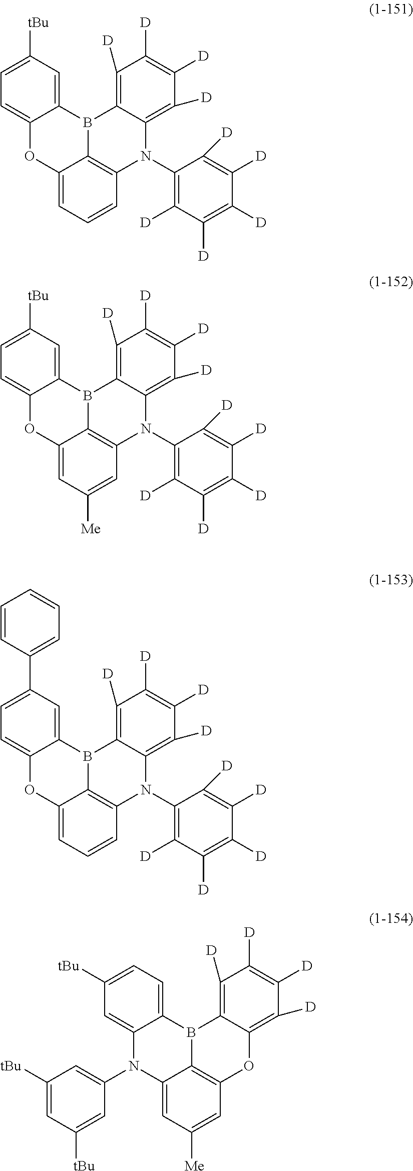 [SMILES: [2H]c1c([2H])c([2H])c(N2c3cccc4c3B(c3cc(C(C)(C)C)ccc3O4)c3c([2H])c([2H])c([2H])c([2H])c32)c([2H])c1[2H] ; [2H]c1c([2H])c([2H])c(N2c3cc(C)cc4c3B(c3cc(C(C)(C)C)ccc3O4)c3c([2H])c([2H])c([2H])c([2H])c32)c([2H])c1[2H] ; [2H]c1c([2H])c([2H])c(N2c3cccc4c3B(c3cc(-c5ccccc5)ccc3O4)c3c([2H])c([2H])c([2H])c([2H])c32)c([2H])c1[2H] ; [2H]c1c([2H])c([2H])c2c(c1[2H])Oc1cc(C)cc3c1B2c1ccc(C(C)(C)C)cc1N3c1cc(C(C)(C)C)cc(C(C)(C)C)c1]

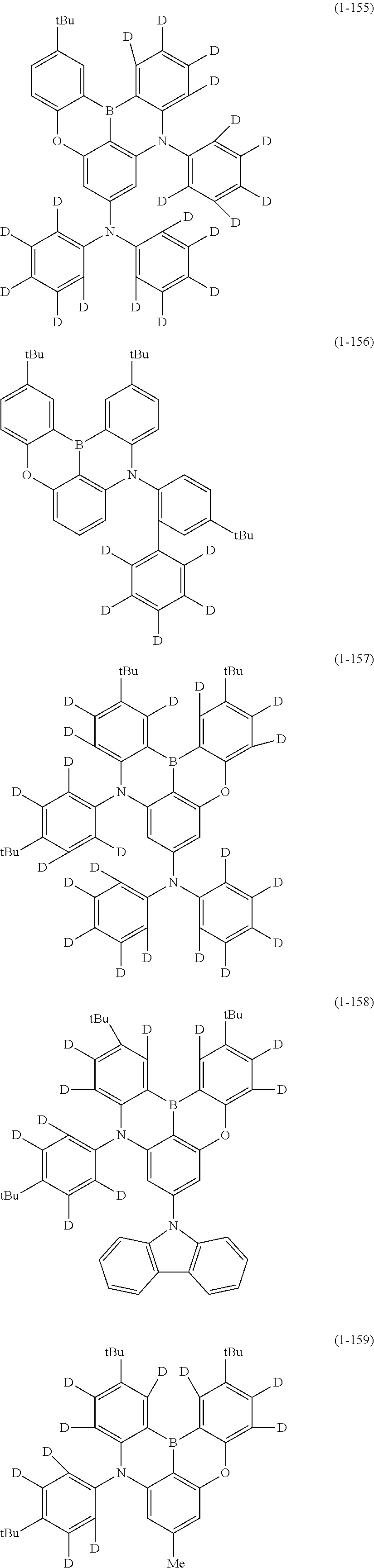

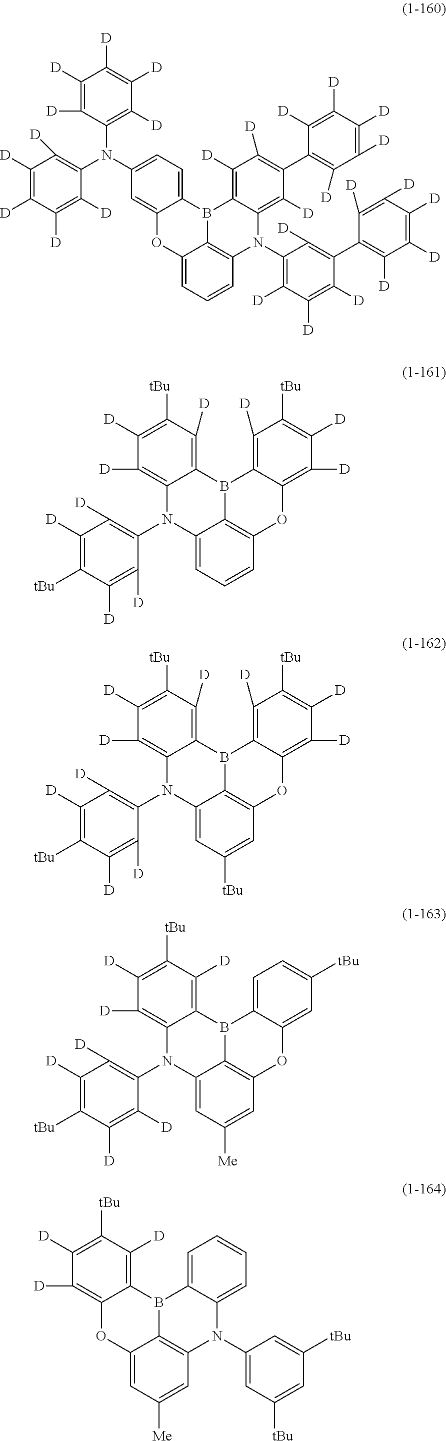

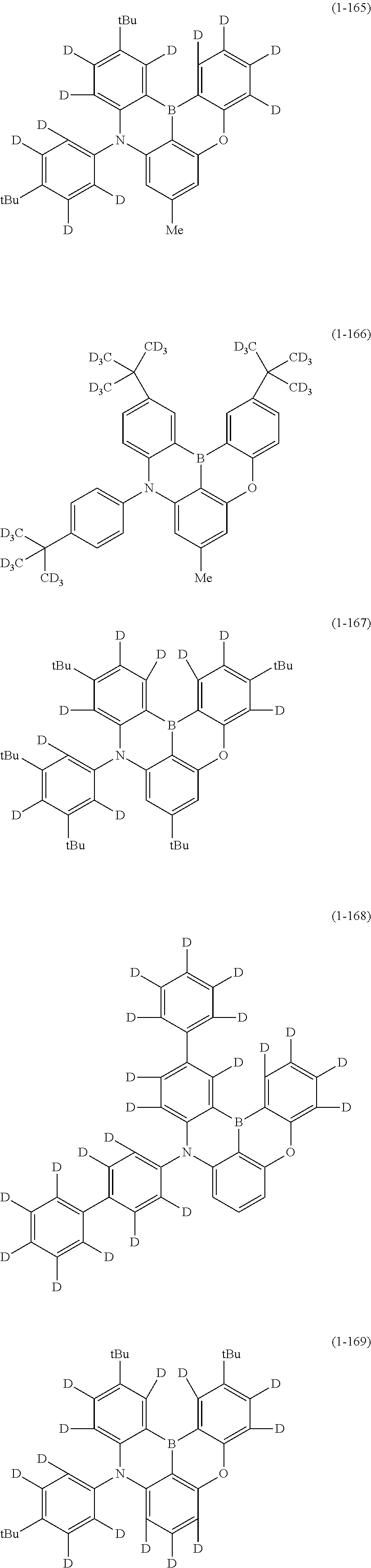

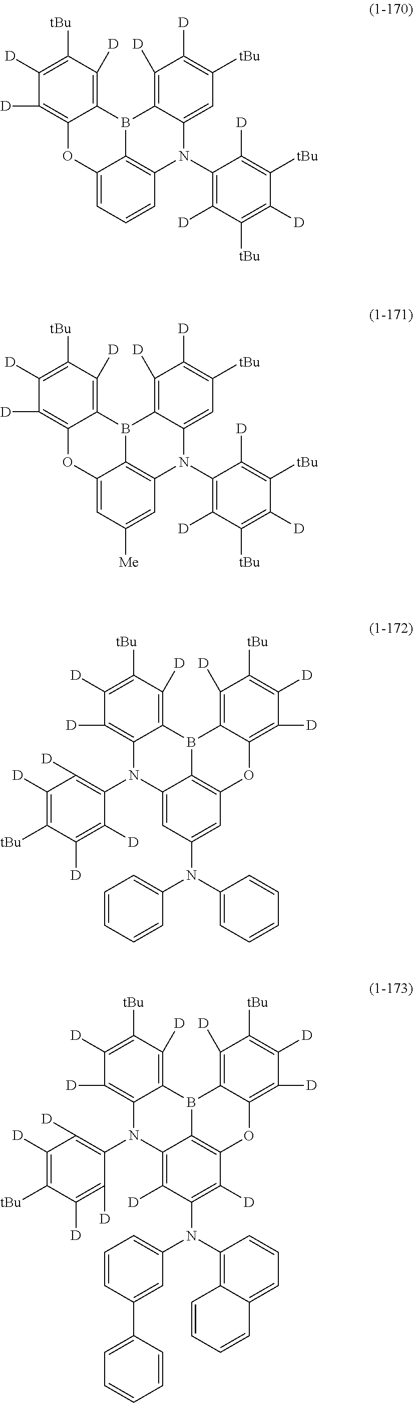

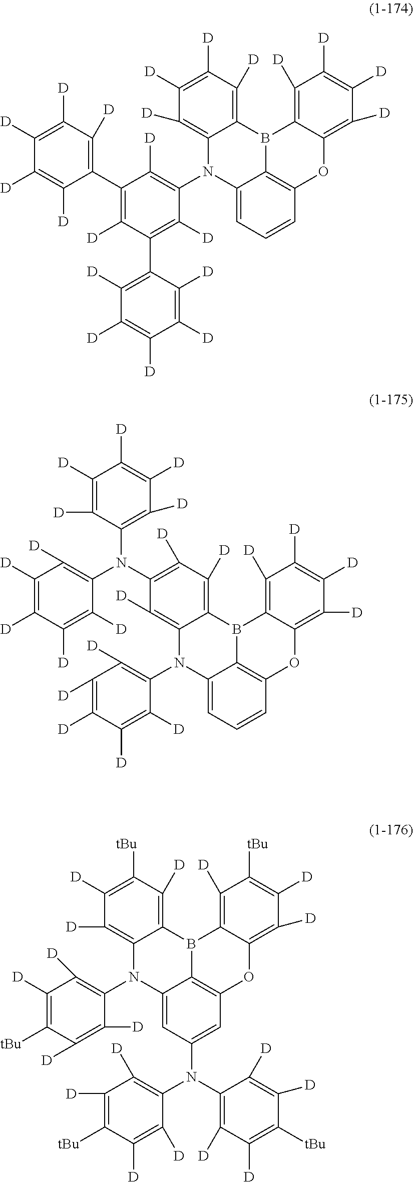

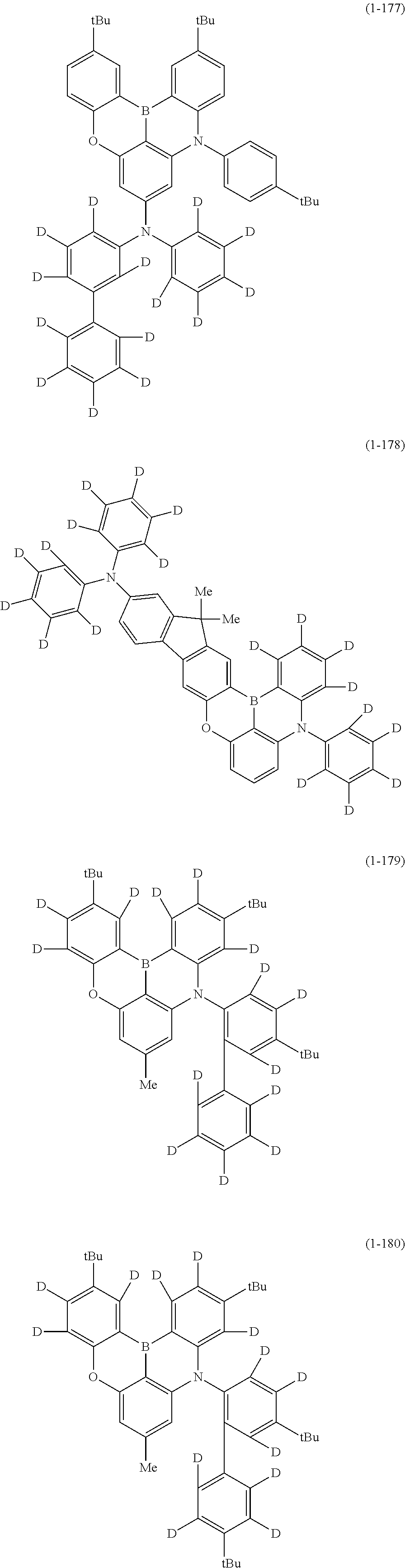

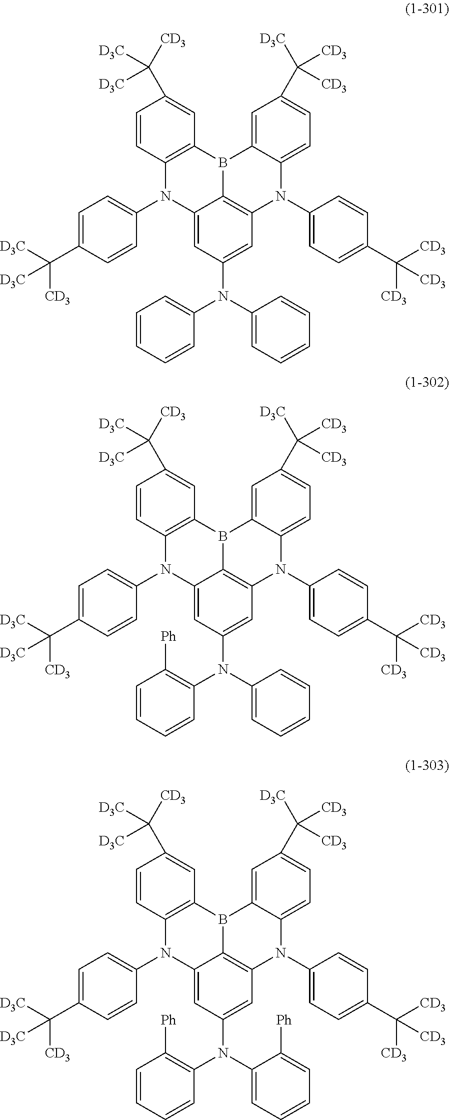

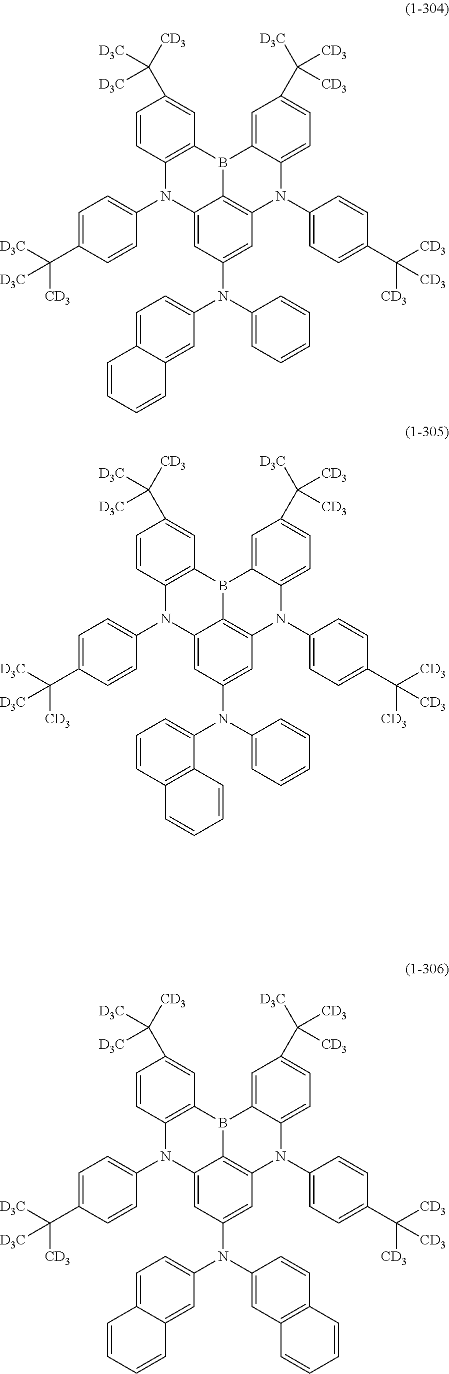

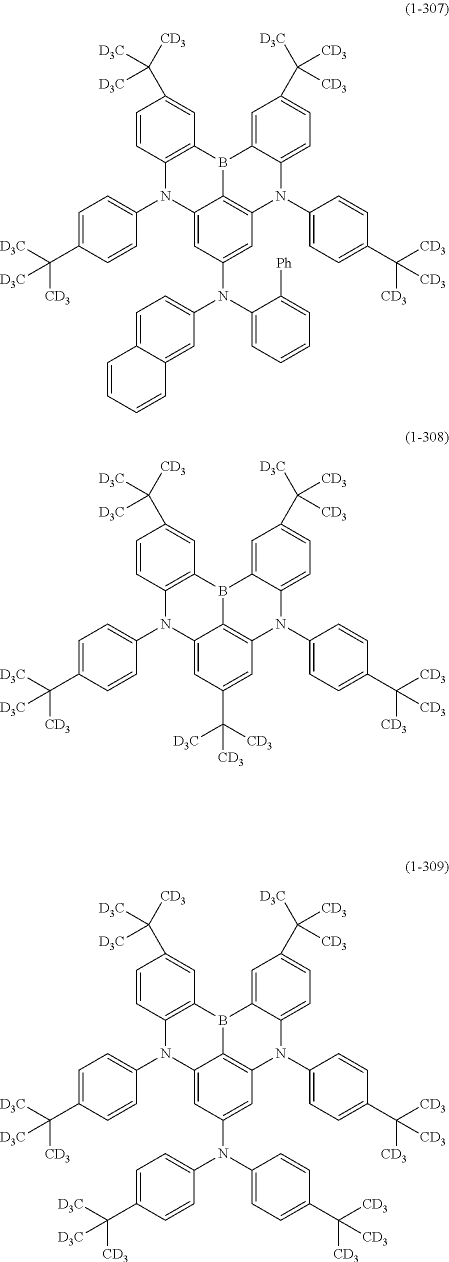

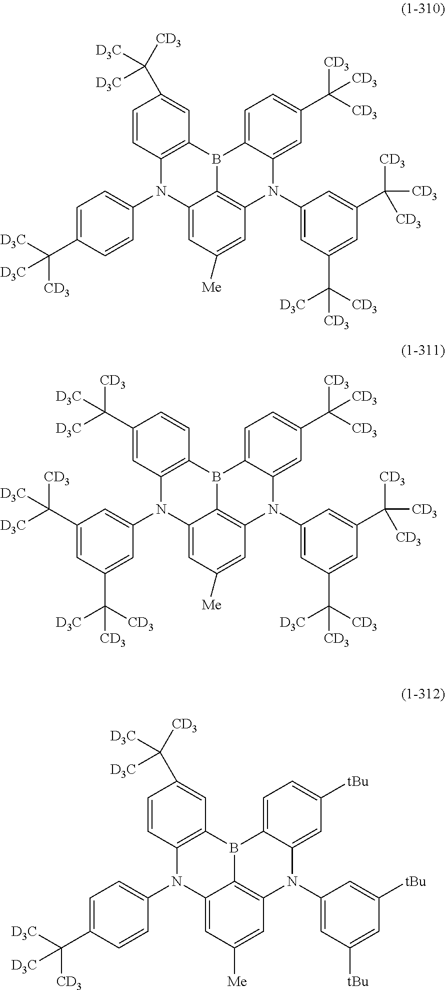

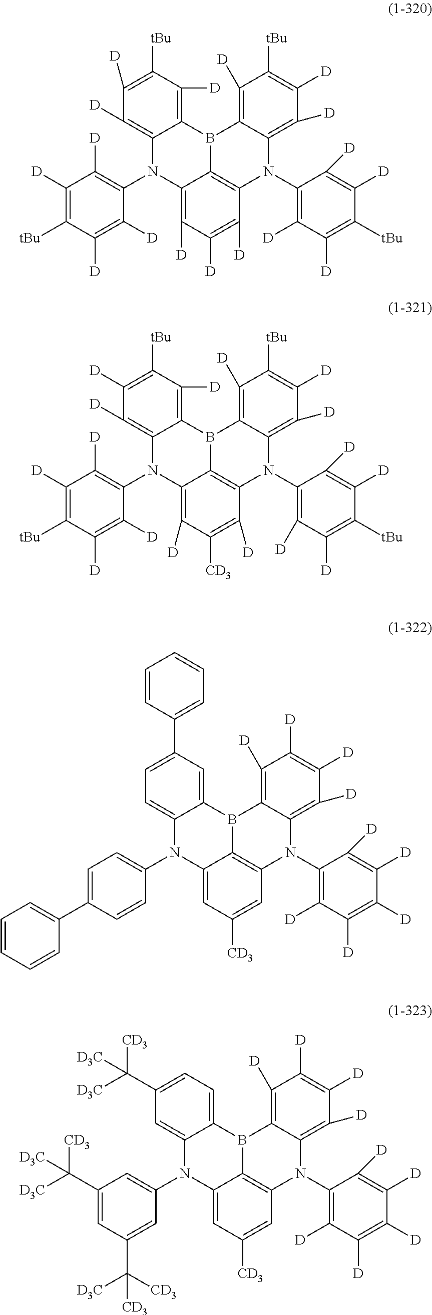

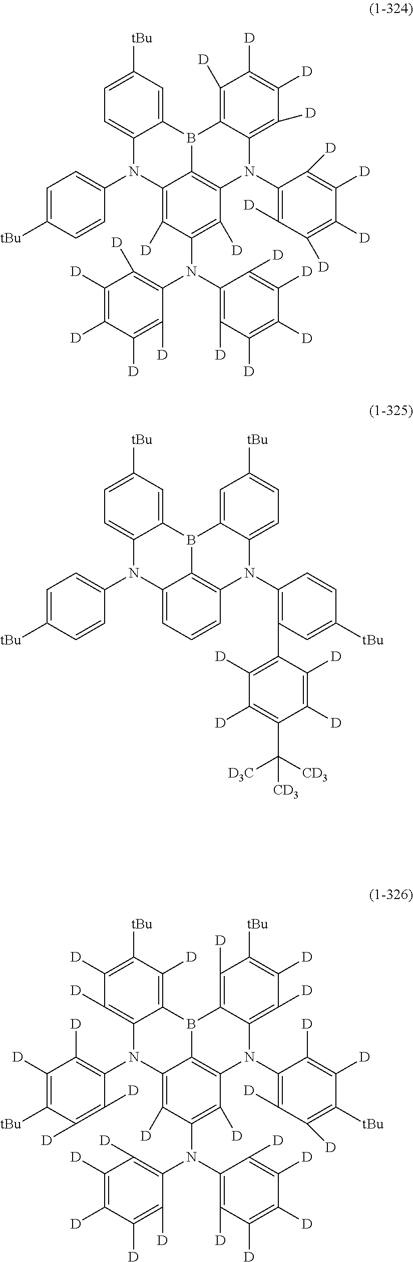

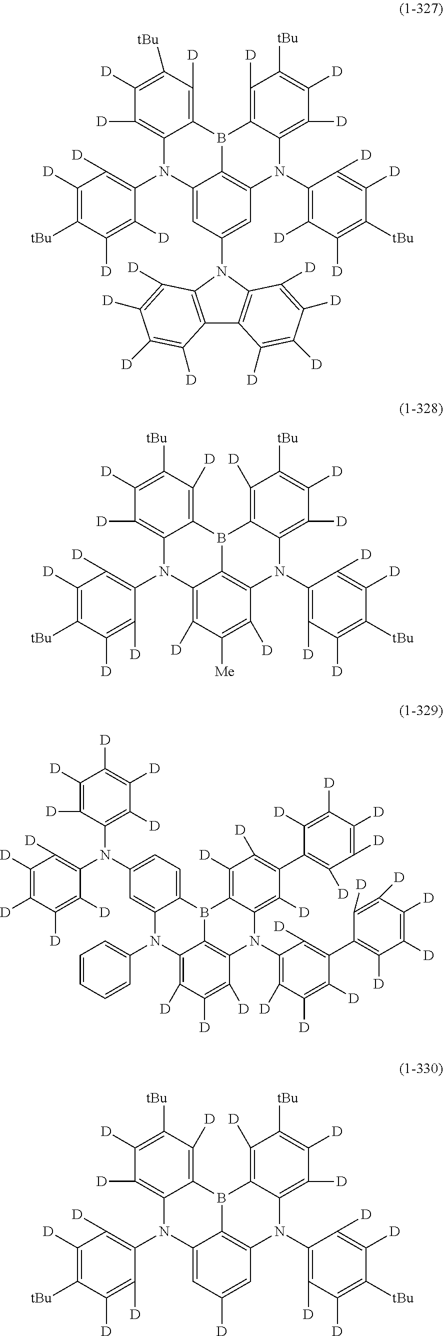

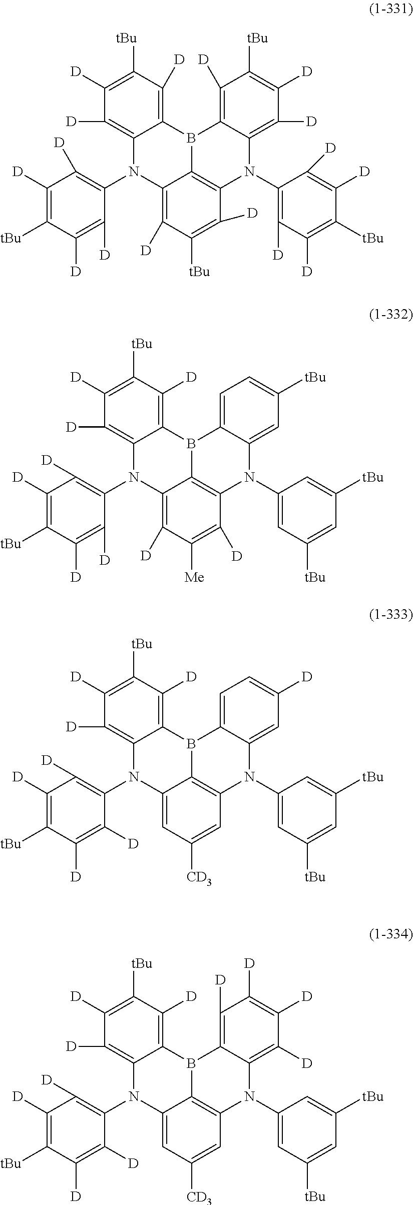

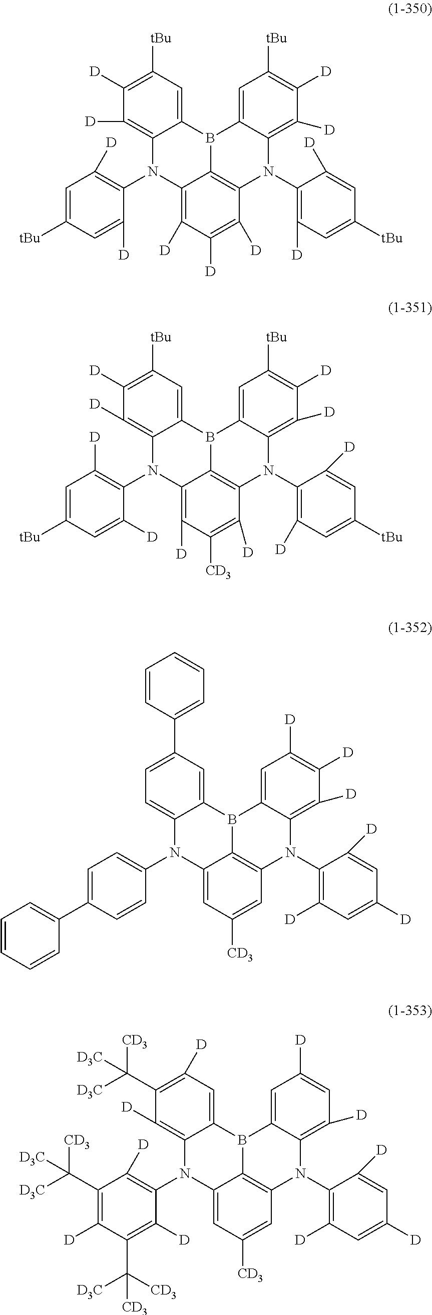

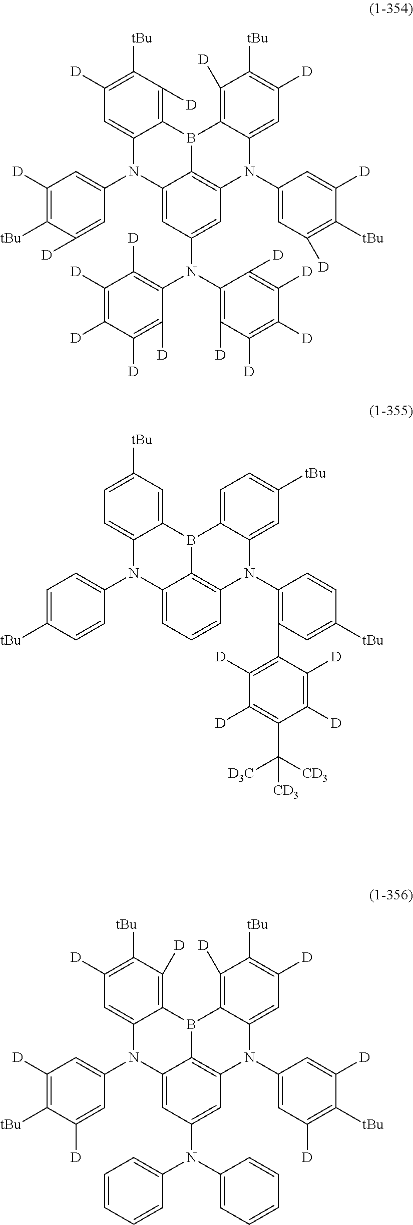

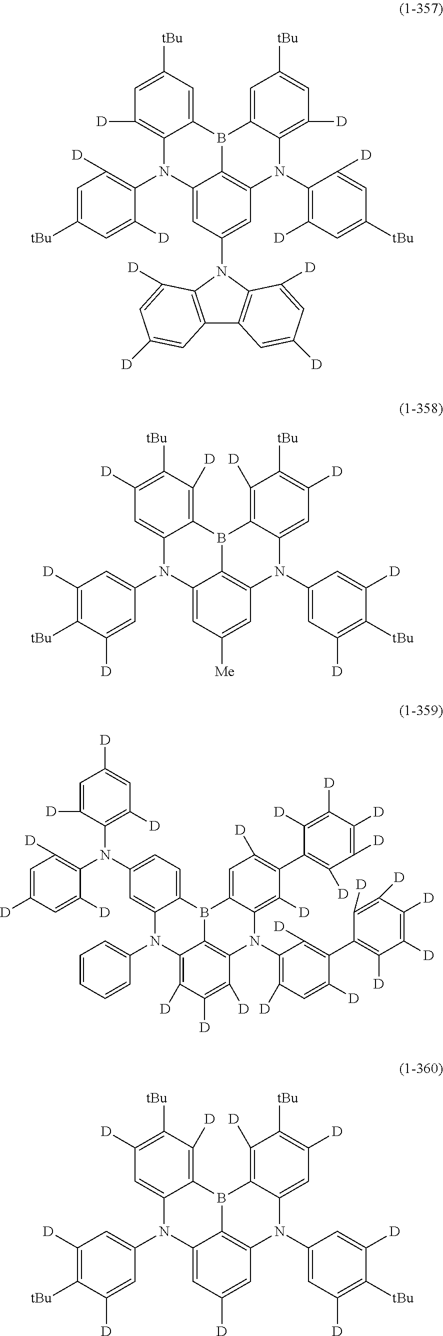

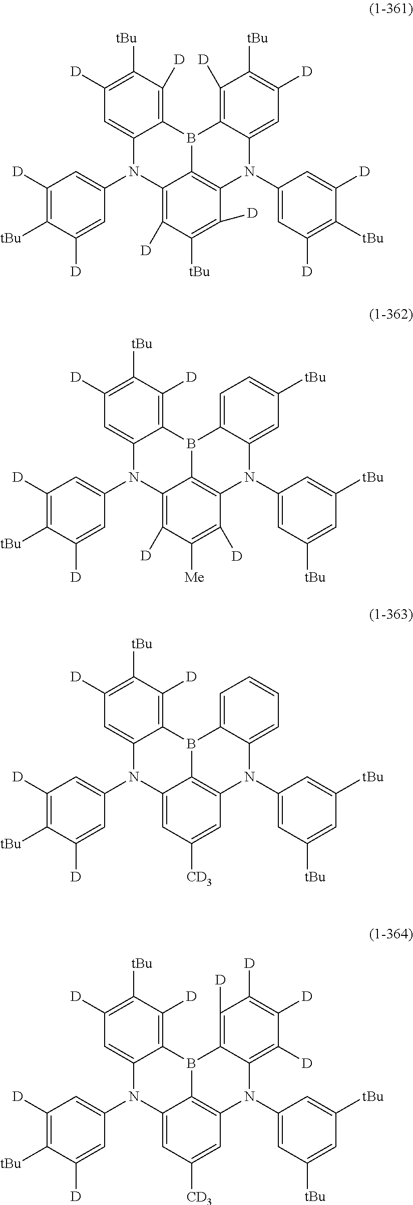

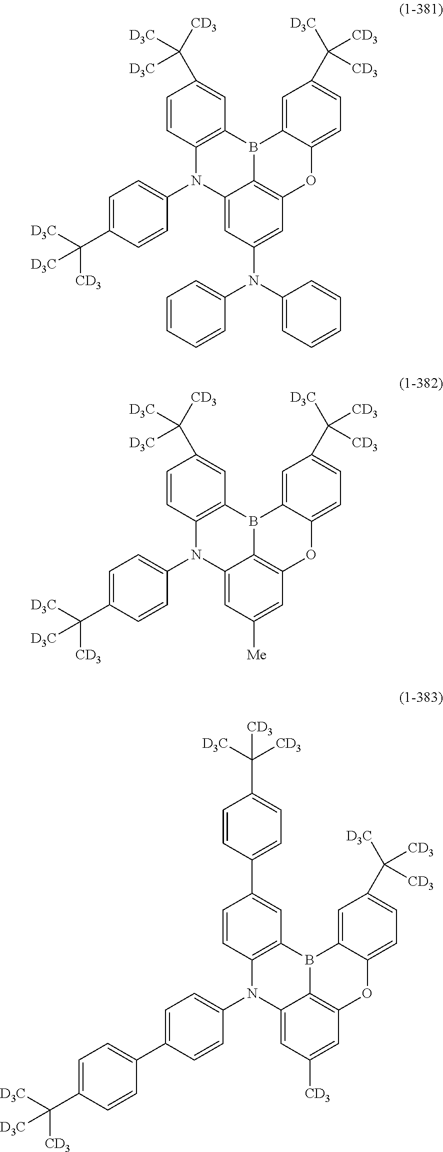

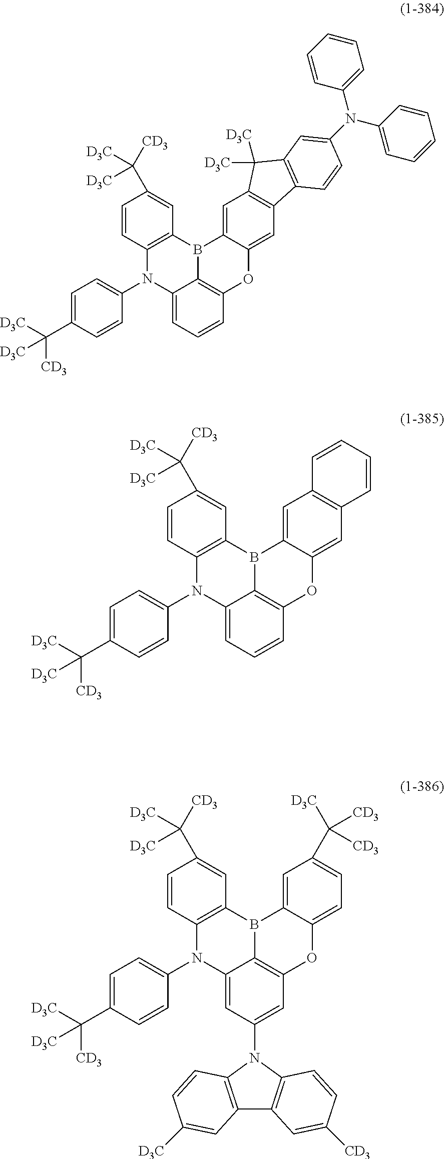

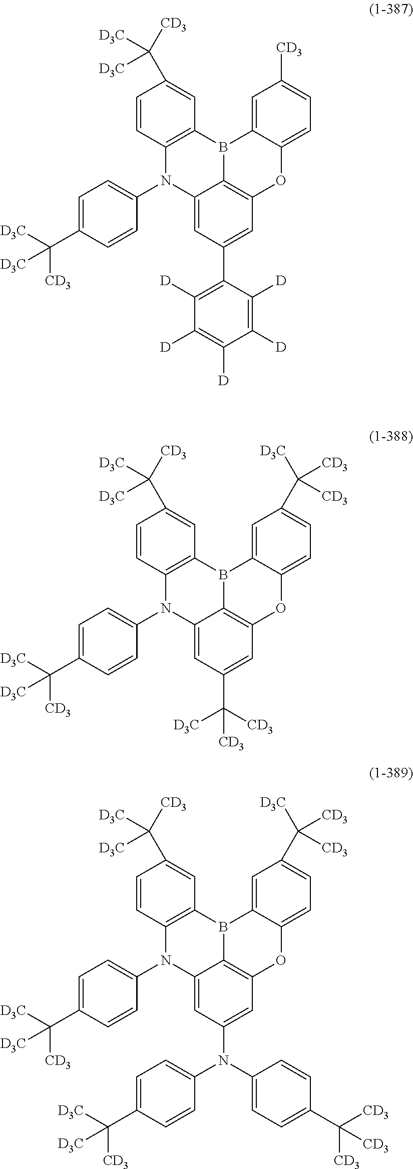

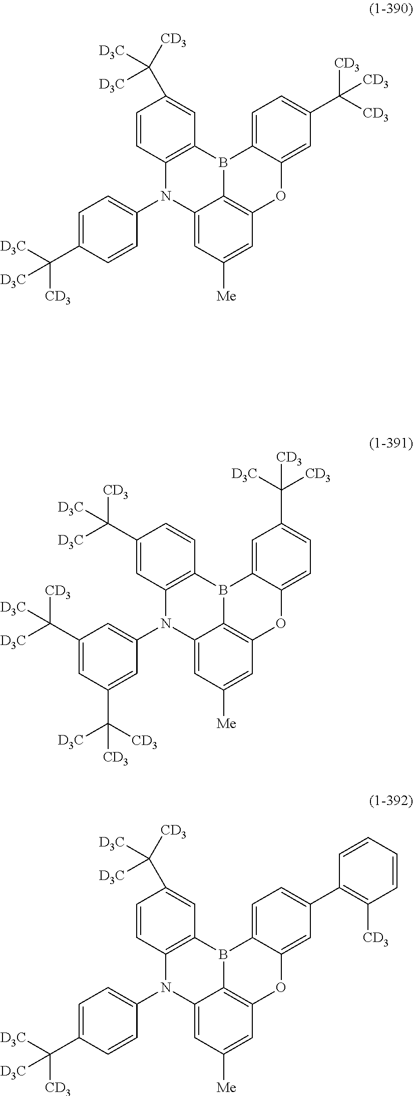

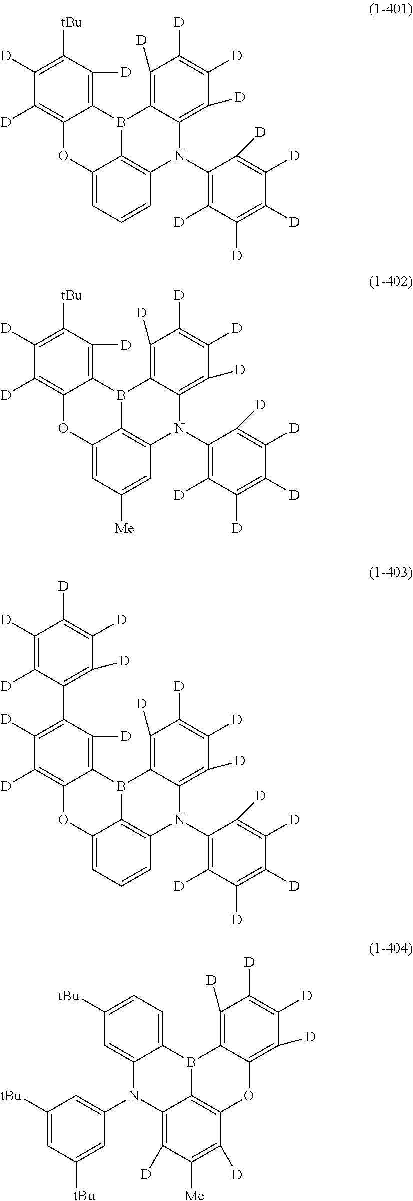

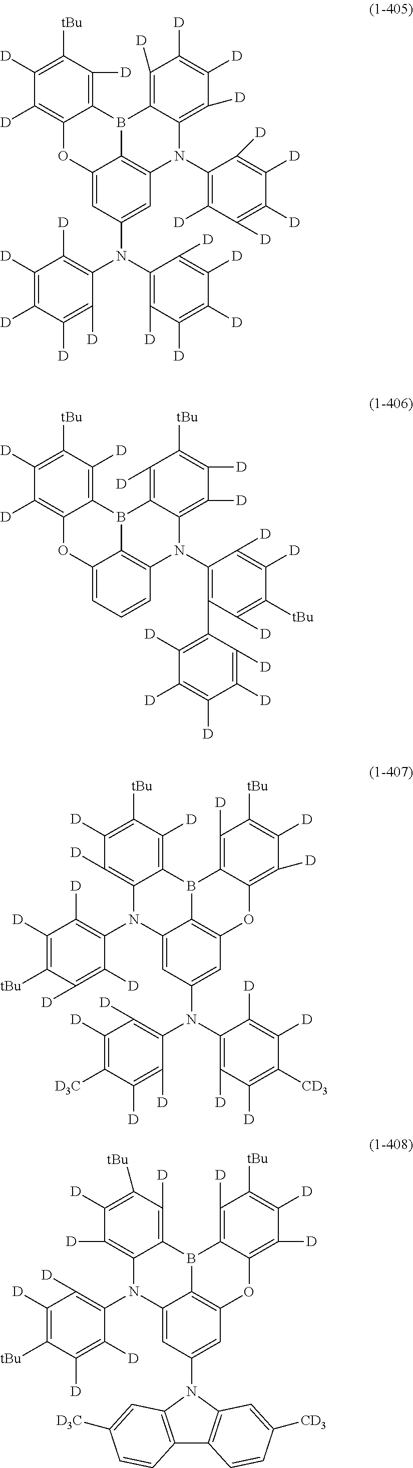

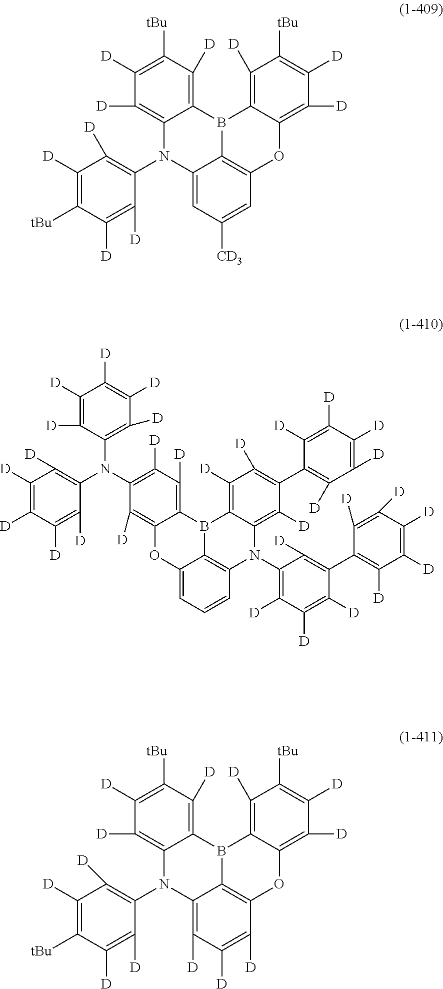

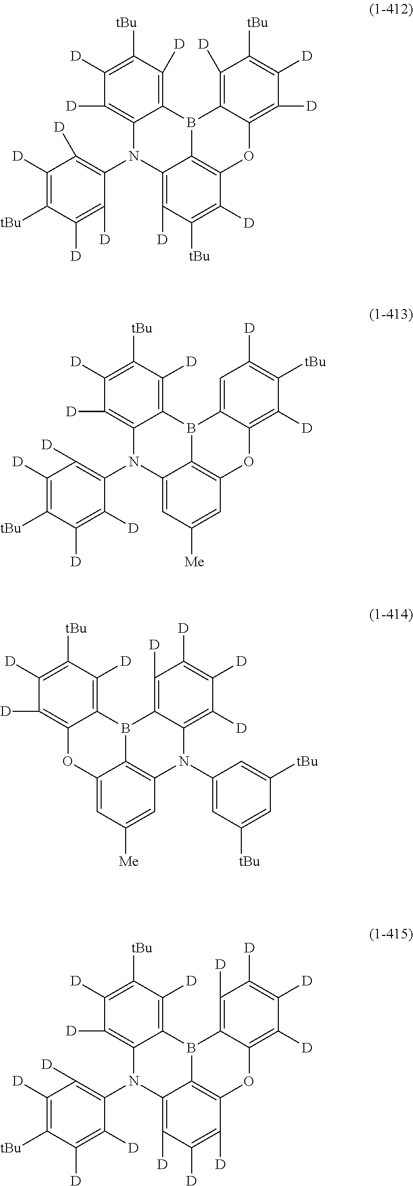

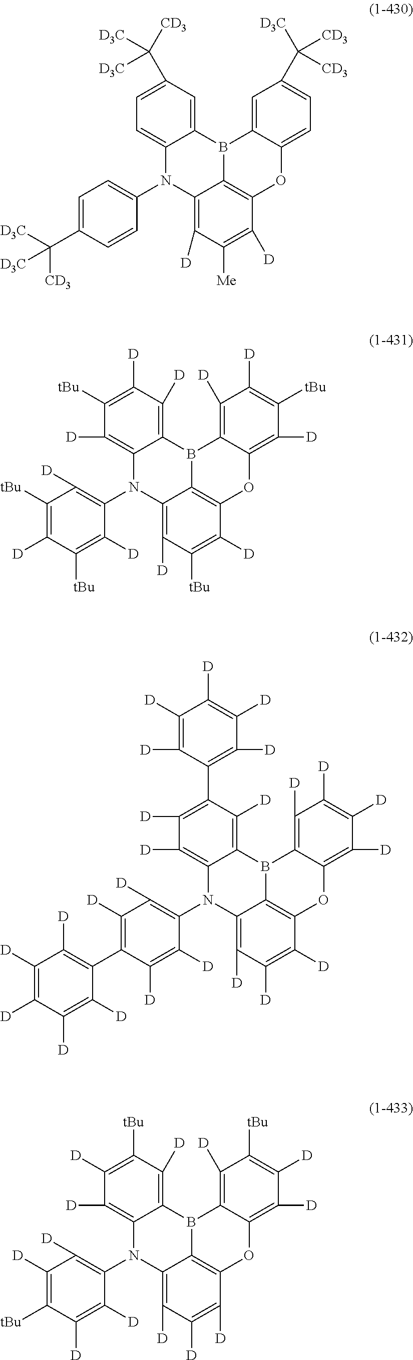

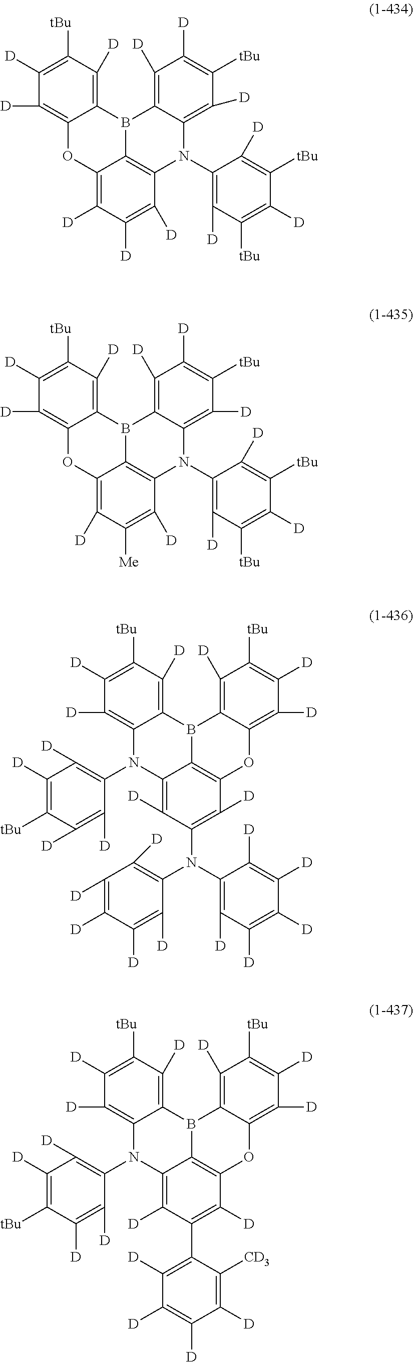

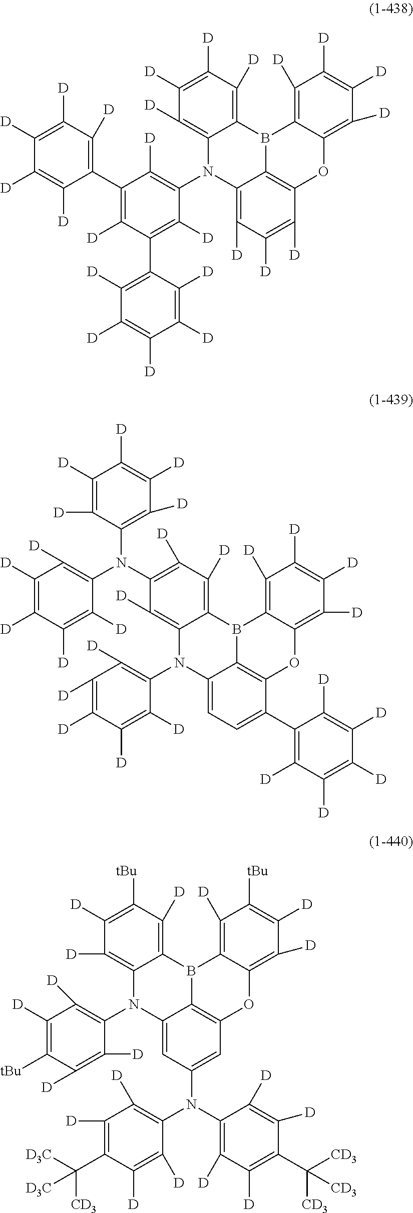

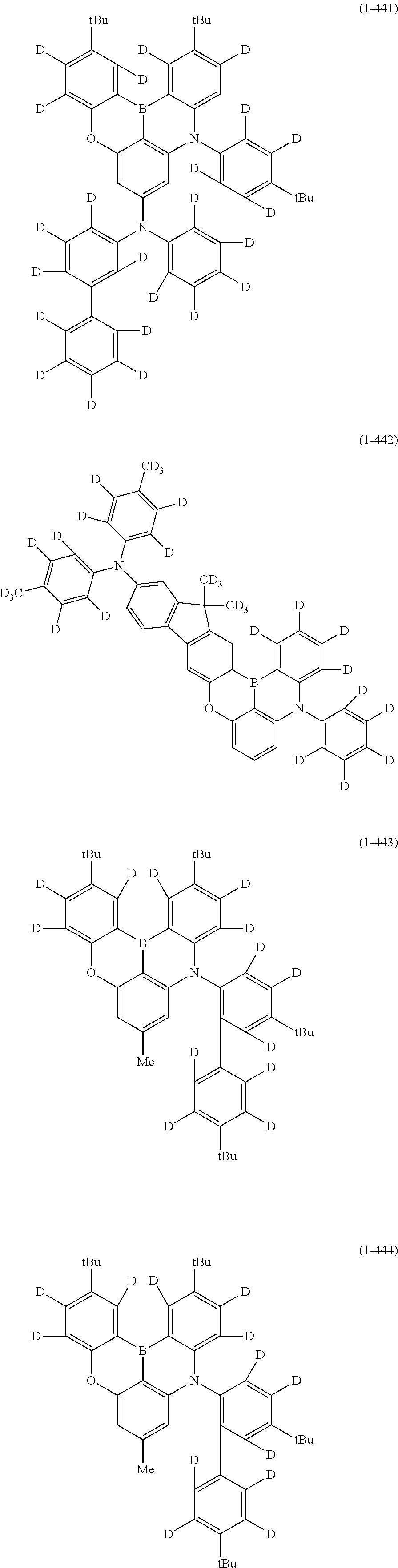

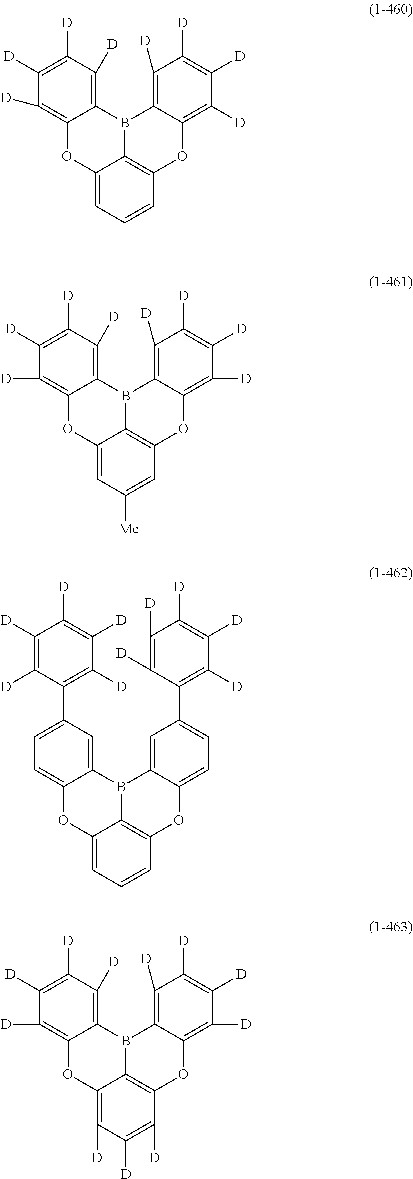 [SMILES: [2H]c1c([2H])c([2H])c2c(c1[2H])Oc1cccc3c1B2c1c([2H])c([2H])c([2H])c([2H])c1O3 ; [2H]c1c([2H])c([2H])c2c(c1[2H])Oc1cc(C)cc3c1B2c1c([2H])c([2H])c([2H])c([2H])c1O3 ; [2H]c1c([2H])c([2H])c(-c2ccc3c(c2)B2c4cc(-c5c([2H])c([2H])c([2H])c([2H])c5[2H])ccc4Oc4cccc(c42)O3)c([2H])c1[2H] ; [2H]c1c([2H])c([2H])c2c(c1[2H])Oc1c([2H])c([2H])c([2H])c3c1B2c1c([2H])c([2H])c([2H])c([2H])c1O3]

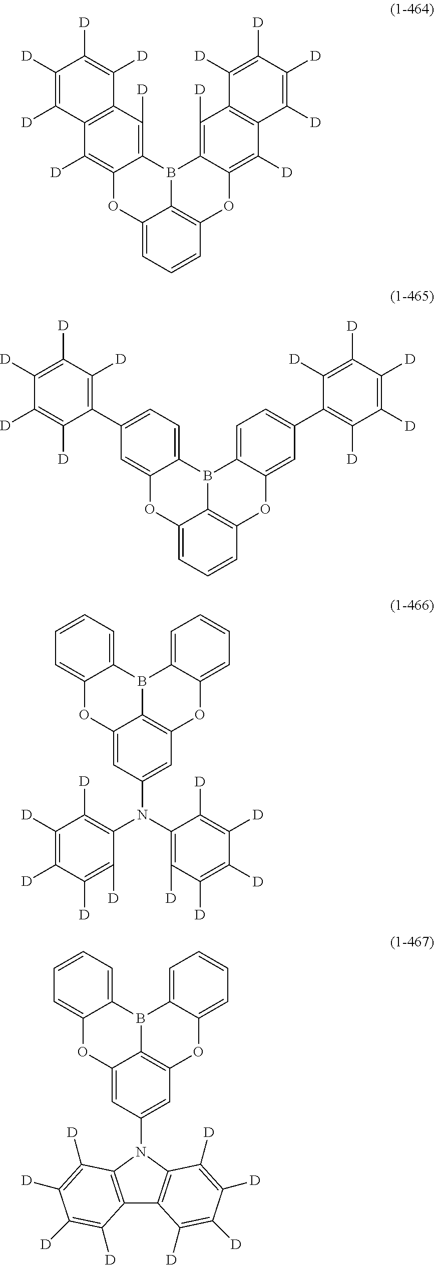

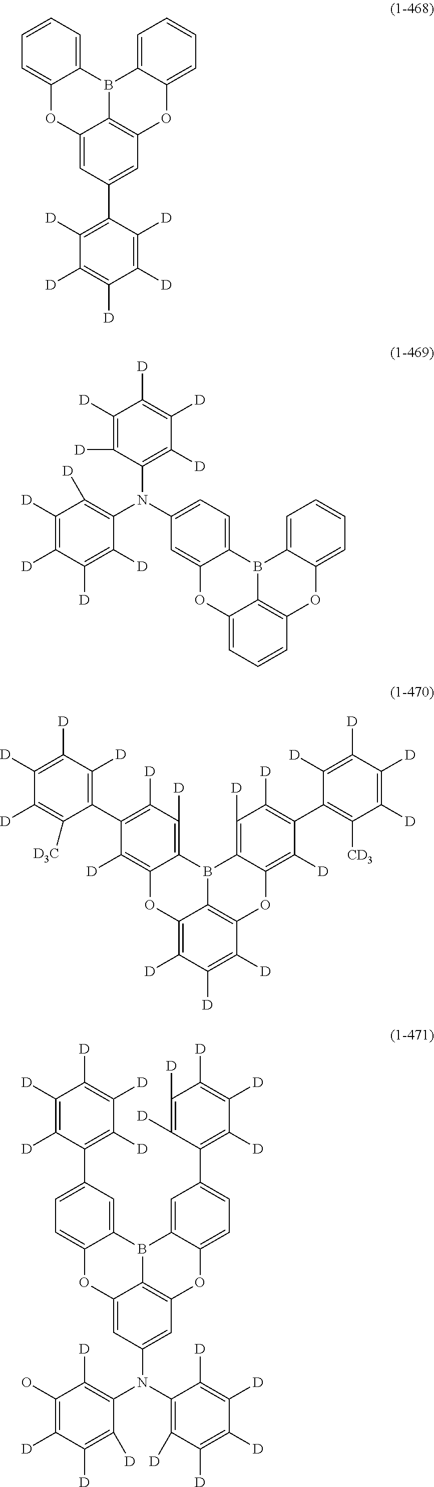

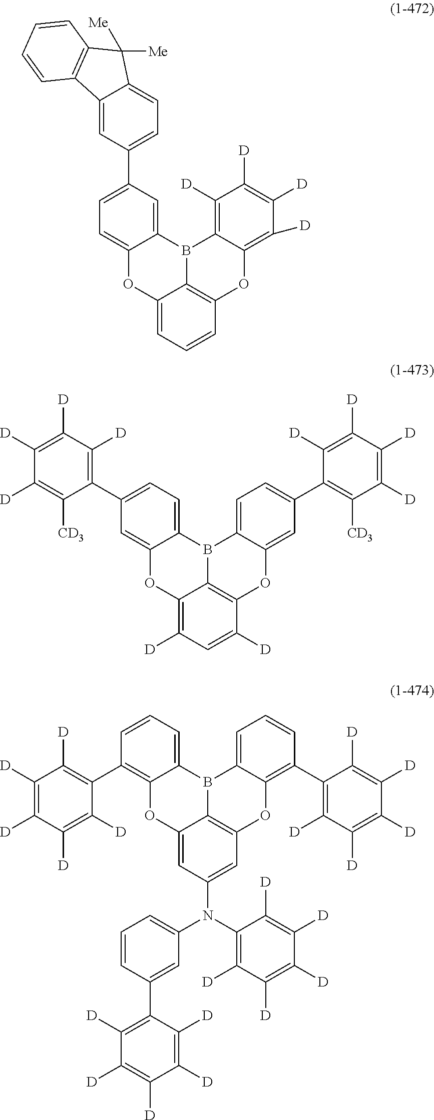 [SMILES: [2H]c1c([2H])c([2H])c2c(c1[2H])Oc1cccc3c1B2c1cc(-c2ccc4c(c2)-c2ccccc2C4(C)C)ccc1O3 ; [2H]c1cc([2H])c2c3c1Oc1cc(-c4c([2H])c([2H])c([2H])c([2H])c4C([2H])([2H])[2H])ccc1B3c1ccc(-c3c([2H])c([2H])c([2H])c([2H])c3C([2H])([2H])[2H])cc1O2 ; [2H]c1c([2H])c([2H])c(-c2cccc(N(c3cc4c5c(c3)Oc3c(cccc3-c3c([2H])c([2H])c([2H])c([2H])c3[2H])B5c3cccc(-c5c([2H])c([2H])c([2H])c([2H])c5[2H])c3O4)c3c([2H])c([2H])c([2H])c([2H])c3[2H])c2)c([2H])c1[2H]]

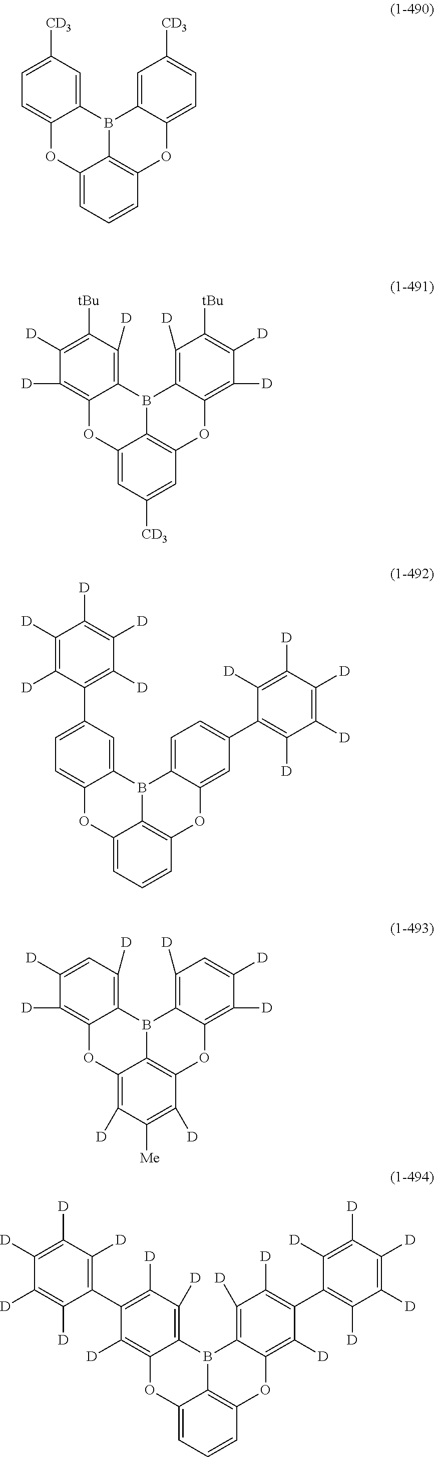

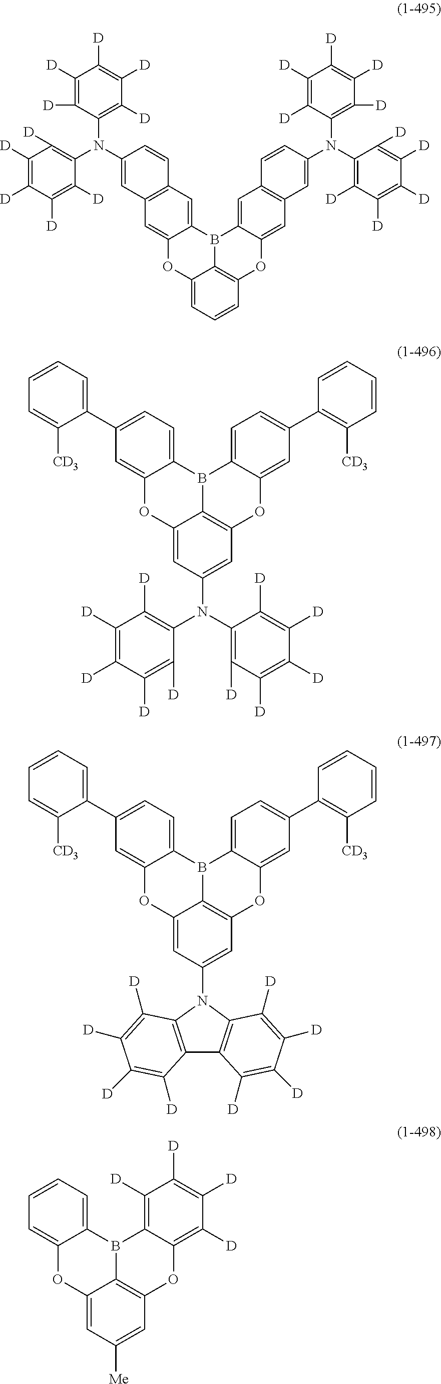

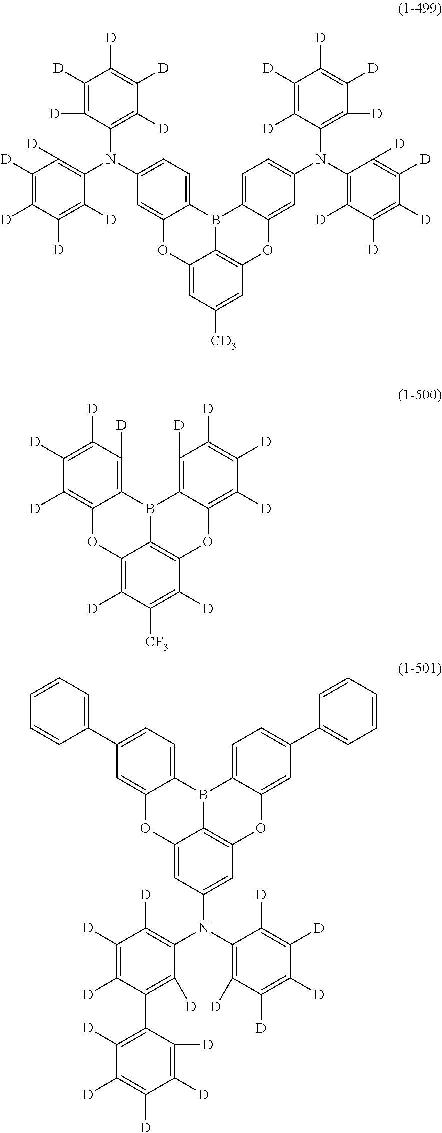 [SMILES: [2H]c1c([2H])c([2H])c(N(c2ccc3c(c2)Oc2cc(C([2H])([2H])[2H])cc4c2B3c2ccc(N(c3c([2H])c([2H])c([2H])c([2H])c3[2H])c3c([2H])c([2H])c([2H])c([2H])c3[2H])cc2O4)c2c([2H])c([2H])c([2H])c([2H])c2[2H])c([2H])c1[2H] ; [2H]c1c([2H])c([2H])c2c(c1[2H])Oc1c([2H])c(C(F)(F)F)c([2H])c3c1B2c1c([2H])c([2H])c([2H])c([2H])c1O3 ; [2H]c1c([2H])c([2H])c(-c2c([2H])c([2H])c([2H])c(N(c3cc4c5c(c3)Oc3cc(-c6ccccc6)ccc3B5c3ccc(-c5ccccc5)cc3O4)c3c([2H])c([2H])c([2H])c([2H])c3[2H])c2[2H])c([2H])c1[2H]]

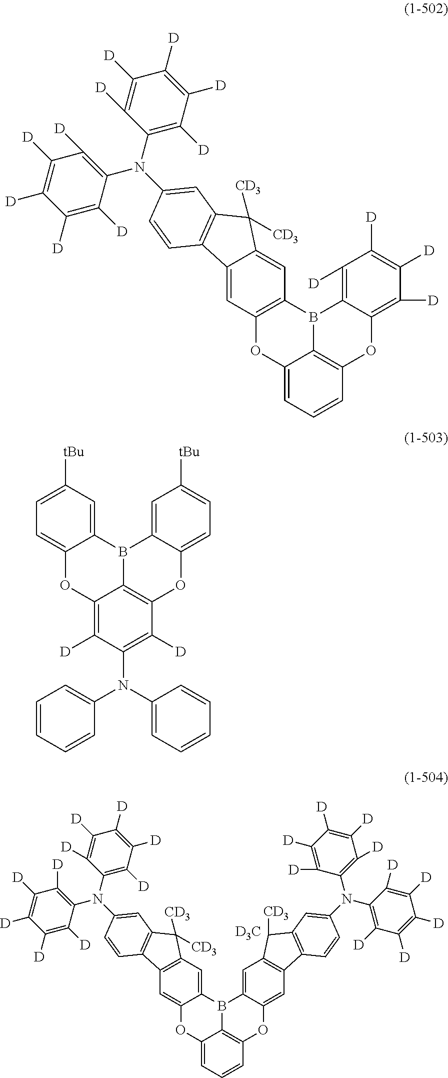

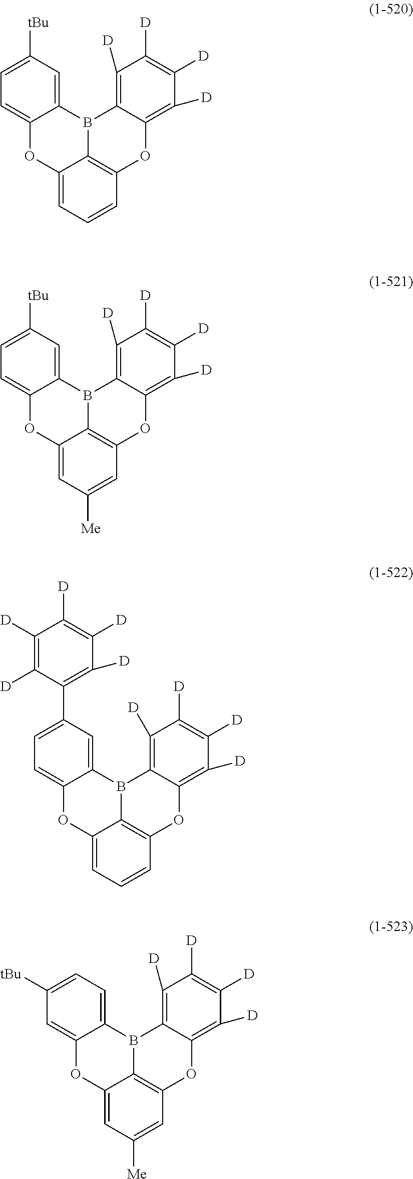 [SMILES: [2H]c1c([2H])c([2H])c2c(c1[2H])Oc1cccc3c1B2c1cc(C(C)(C)C)ccc1O3 ; [2H]c1c([2H])c([2H])c2c(c1[2H])Oc1cc(C)cc3c1B2c1cc(C(C)(C)C)ccc1O3 ; [2H]c1c([2H])c([2H])c(-c2ccc3c(c2)B2c4c(cccc4Oc4c([2H])c([2H])c([2H])c([2H])c42)O3)c([2H])c1[2H] ; [2H]c1c([2H])c([2H])c2c(c1[2H])Oc1cc(C)cc3c1B2c1ccc(C(C)(C)C)cc1O3]

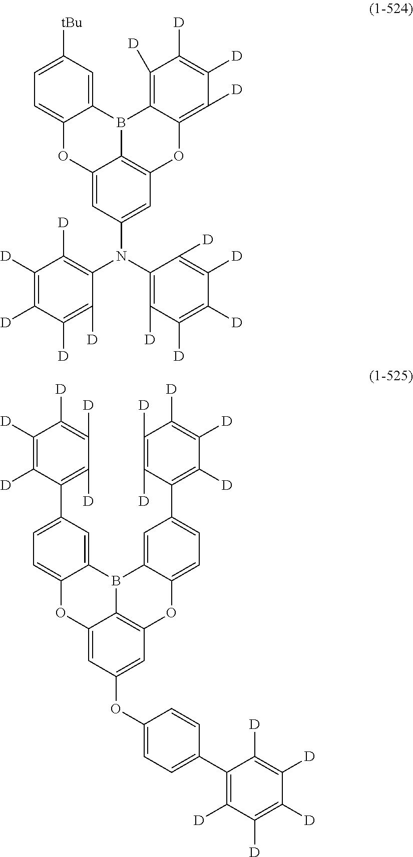

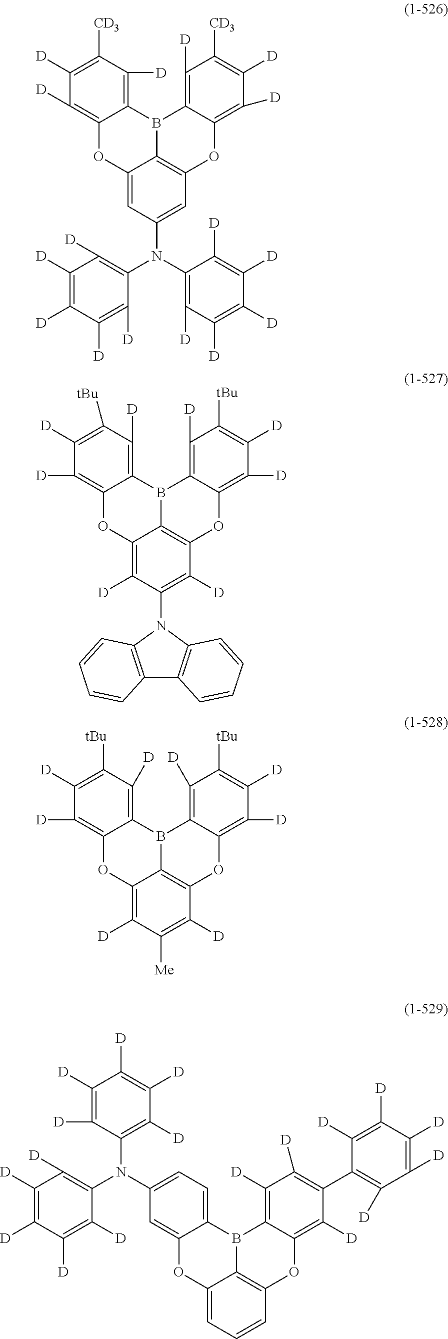

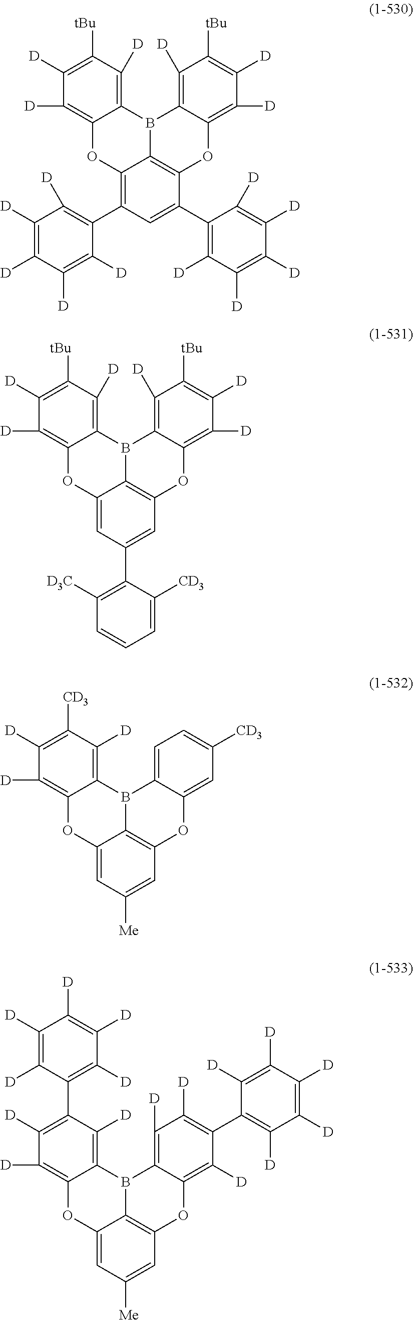

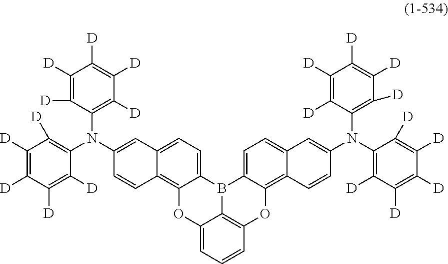 [SMILES: [2H]c1c([2H])c([2H])c(N(c2ccc3c4c(ccc3c2)B2c3ccc5cc(N(c6c([2H])c([2H])c([2H])c([2H])c6[2H])c6c([2H])c([2H])c([2H])c([2H])c6[2H])ccc5c3Oc3cccc(c32)O4)c2c([2H])c([2H])c([2H])c([2H])c2[2H])c([2H])c1[2H]]

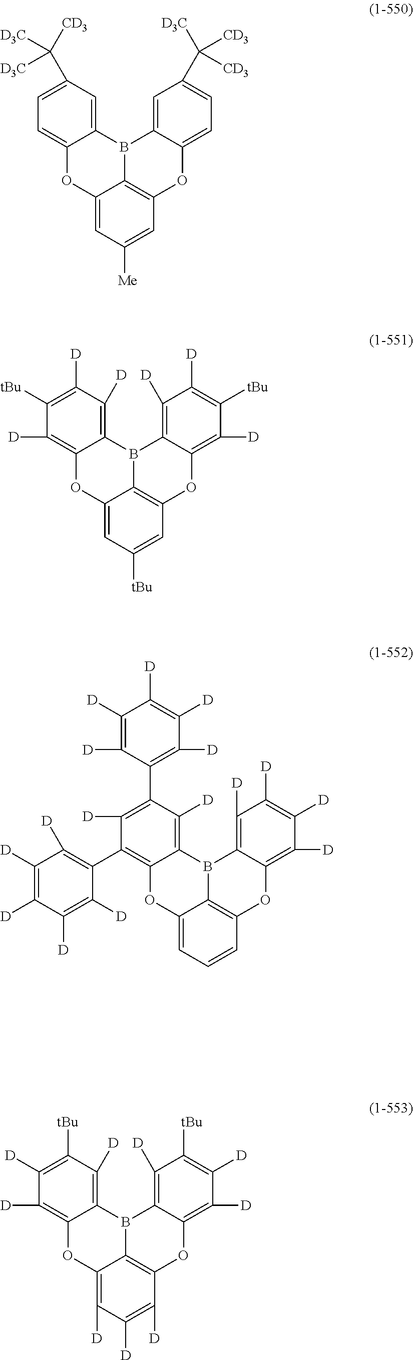

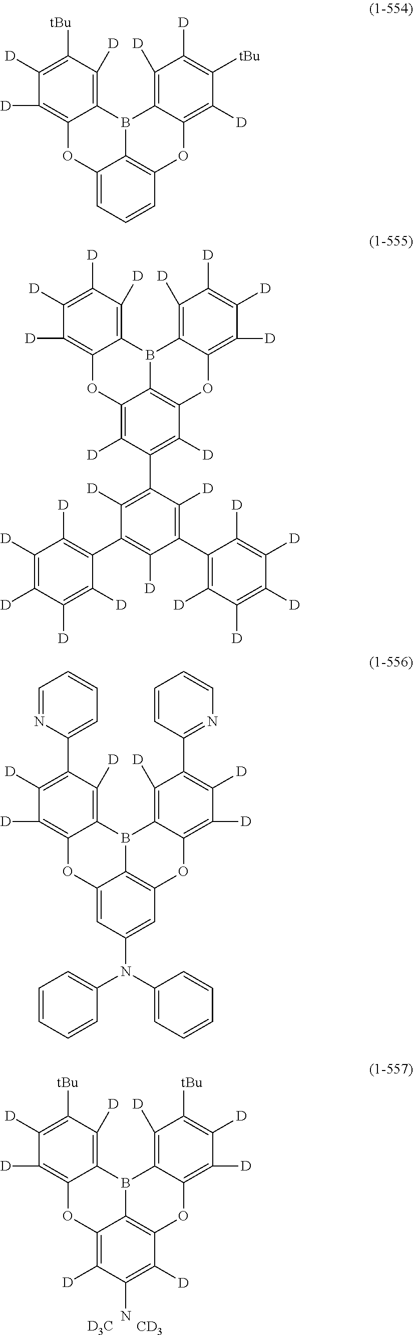

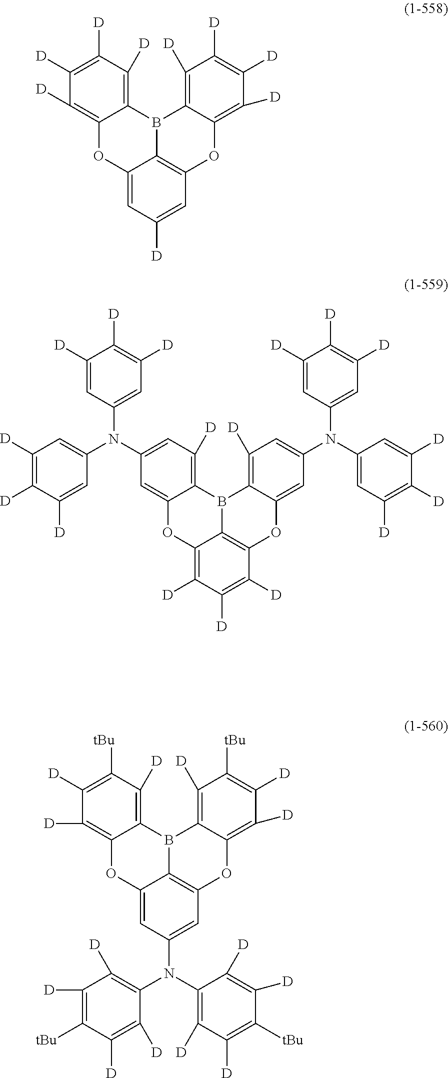 [SMILES: [2H]c1cc2c3c(c1)Oc1c([2H])c([2H])c([2H])c([2H])c1B3c1c([2H])c([2H])c([2H])c([2H])c1O2 ; [2H]c1cc(N(c2cc([2H])c([2H])c([2H])c2)c2cc([2H])c3c(c2)Oc2c([2H])c([2H])c([2H])c4c2B3c2c([2H])cc(N(c3cc([2H])c([2H])c([2H])c3)c3cc([2H])c([2H])c([2H])c3)cc2O4)cc([2H])c1[2H] ; [2H]c1c([2H])c(C(C)(C)C)c([2H])c2c1Oc1cc(N(c3c([2H])c([2H])c(C(C)(C)C)c([2H])c3[2H])c3c([2H])c([2H])c(C(C)(C)C)c([2H])c3[2H])cc3c1B2c1c([2H])c(C(C)(C)C)c([2H])c([2H])c1O3]

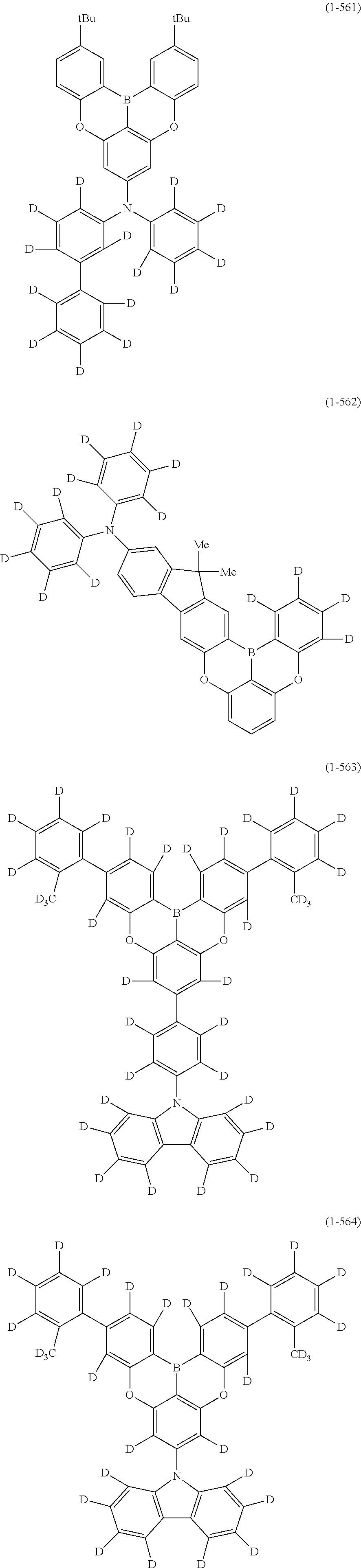

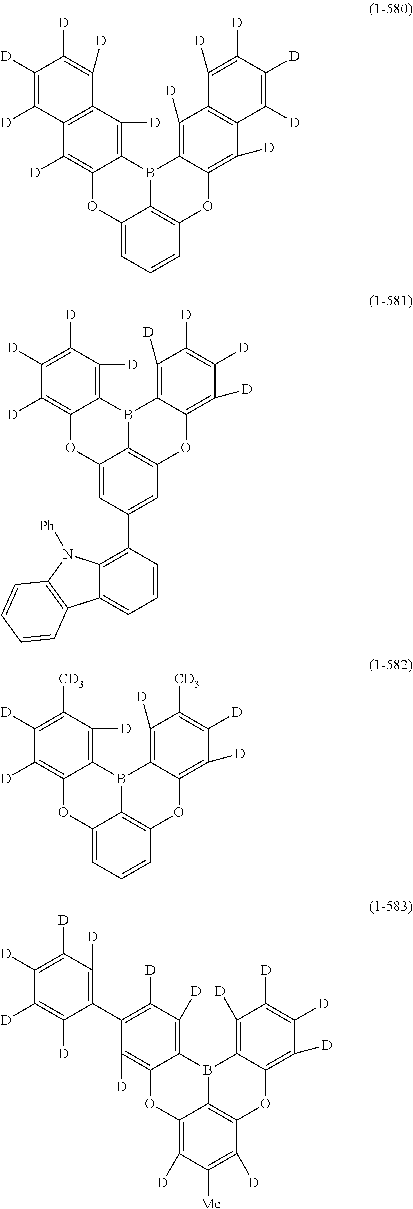

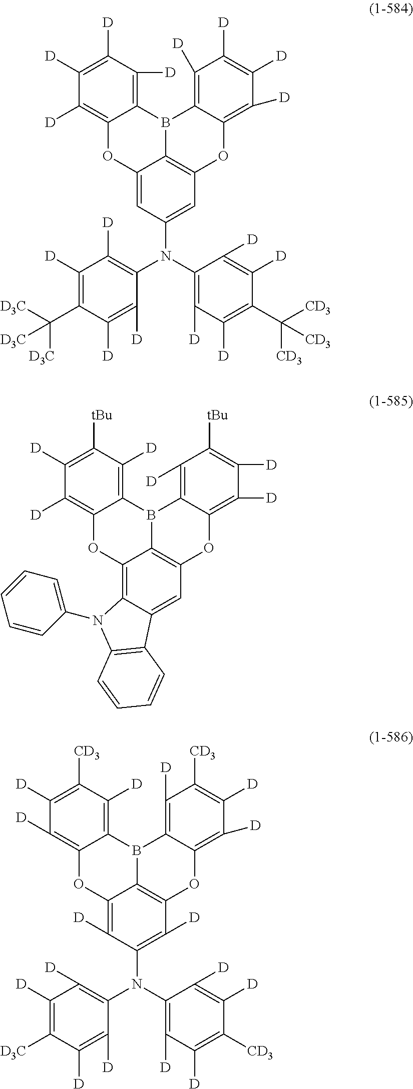

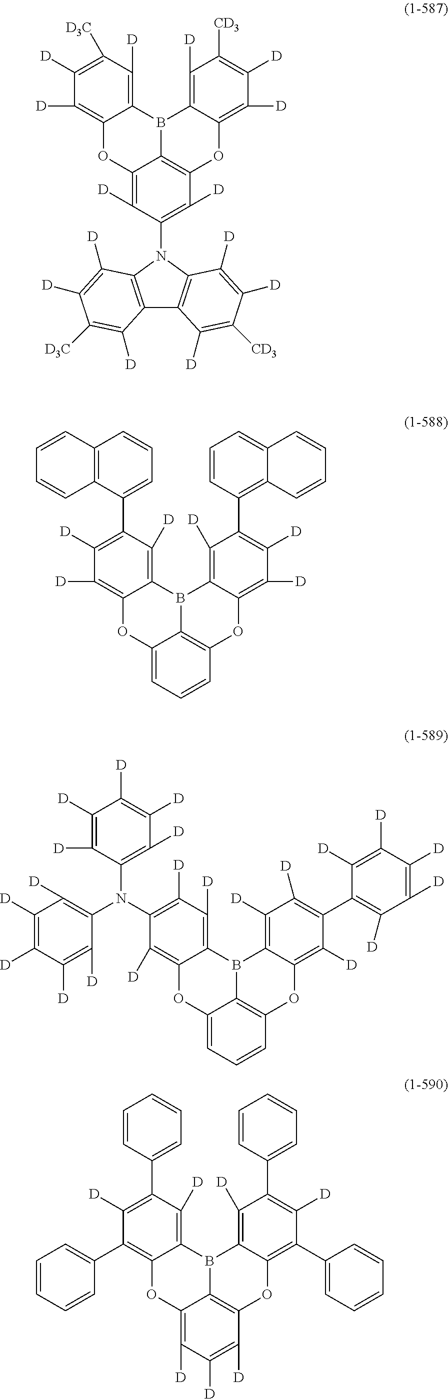

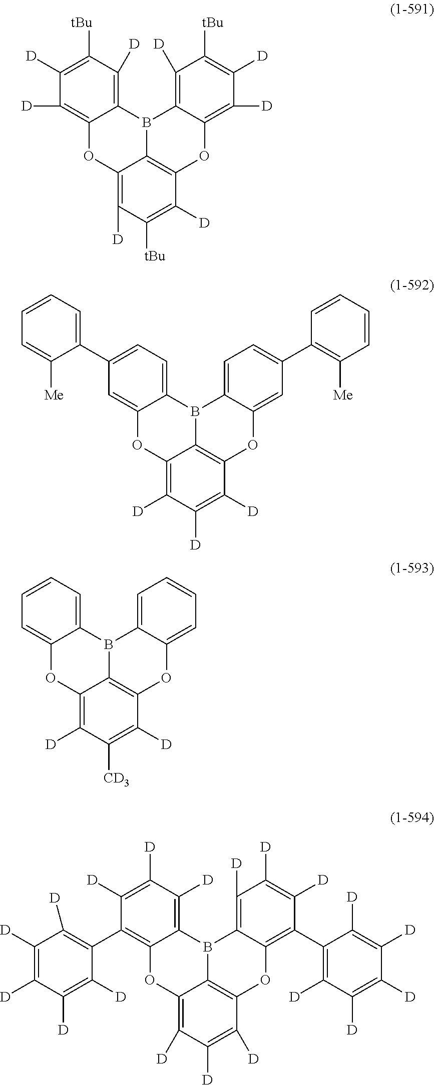

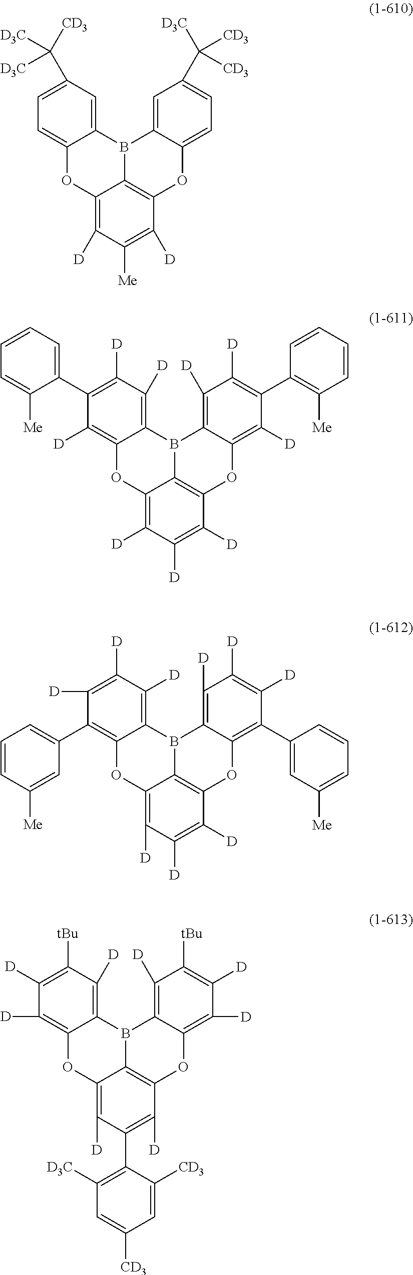

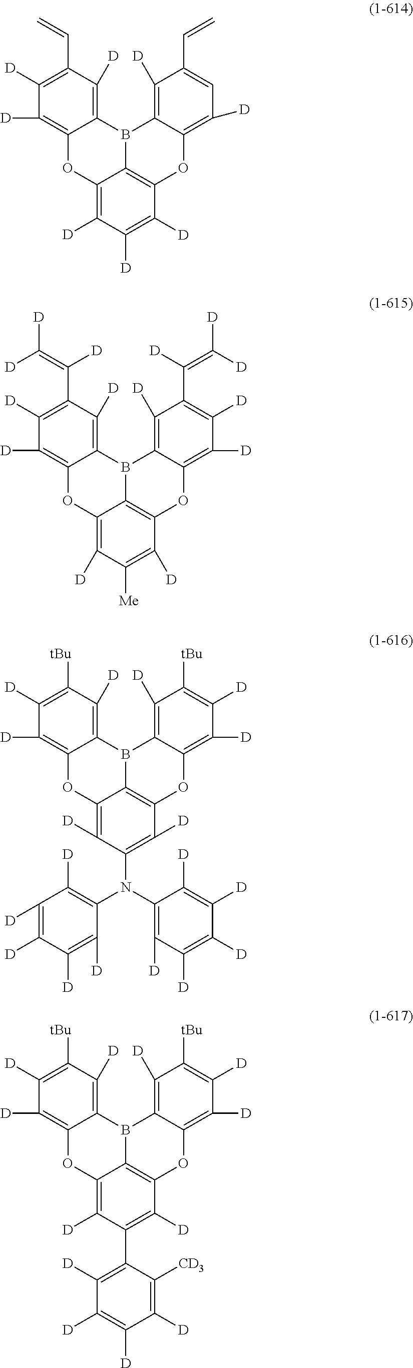

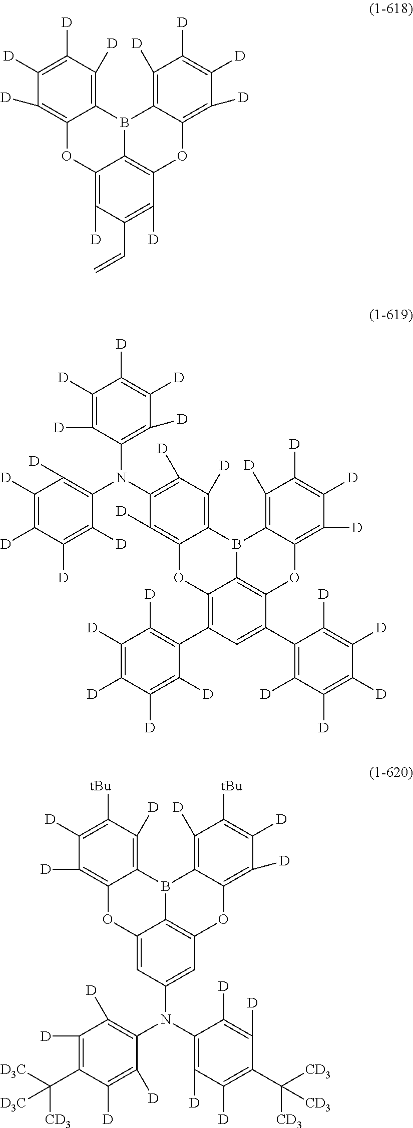

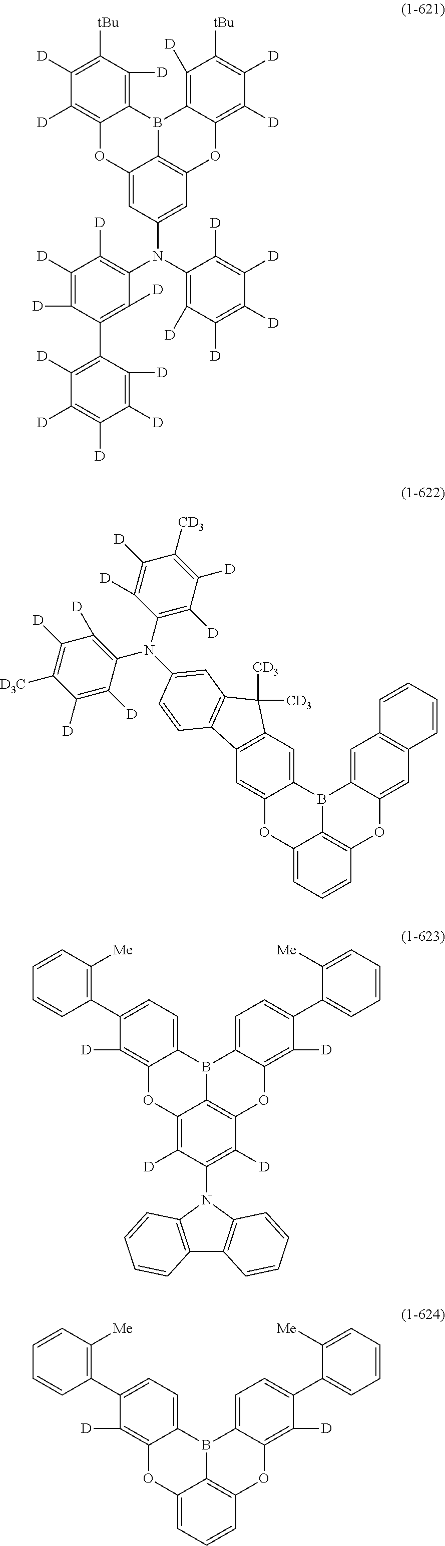

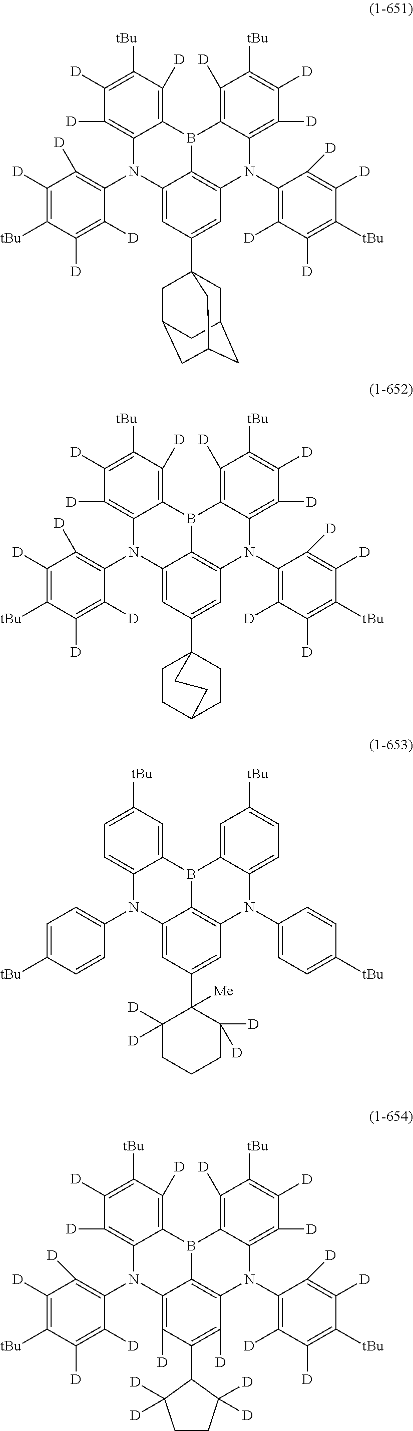

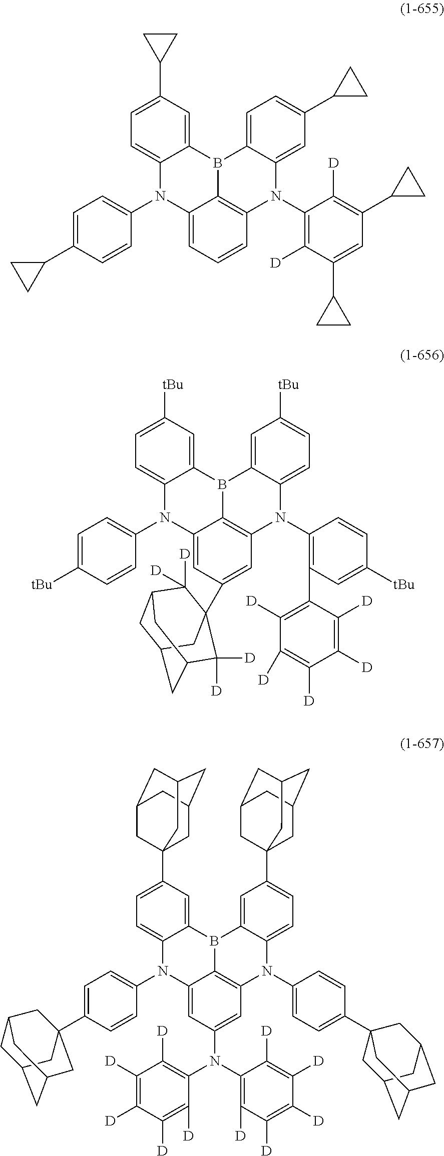 [SMILES: [2H]c1c(C2CC2)cc(C2CC2)c([2H])c1N1c2cc(C3CC3)ccc2B2c3cc(C4CC4)ccc3N(c3ccc(C4CC4)cc3)c3cccc1c32 ; [2H]c1c([2H])c([2H])c(-c2cc(C(C)(C)C)ccc2N2c3ccc(C(C)(C)C)cc3B3c4cc(C(C)(C)C)ccc4N(c4ccc(C(C)(C)C)cc4)c4cc(C56CC7CC(CC(C7)C5([2H])[2H])C6([2H])[2H])cc2c43)c([2H])c1[2H] ; [2H]c1c([2H])c([2H])c(N(c2cc3c4c(c2)N(c2ccc(C56CC7CC(CC(C7)C5)C6)cc2)c2ccc(C56CC7CC(CC(C7)C5)C6)cc2B4c2cc(C45CC6CC(CC(C6)C4)C5)ccc2N3c2ccc(C34CC5CC(CC(C5)C3)C4)cc2)c2c([2H])c([2H])c([2H])c([2H])c2[2H])c([2H])c1[2H]]

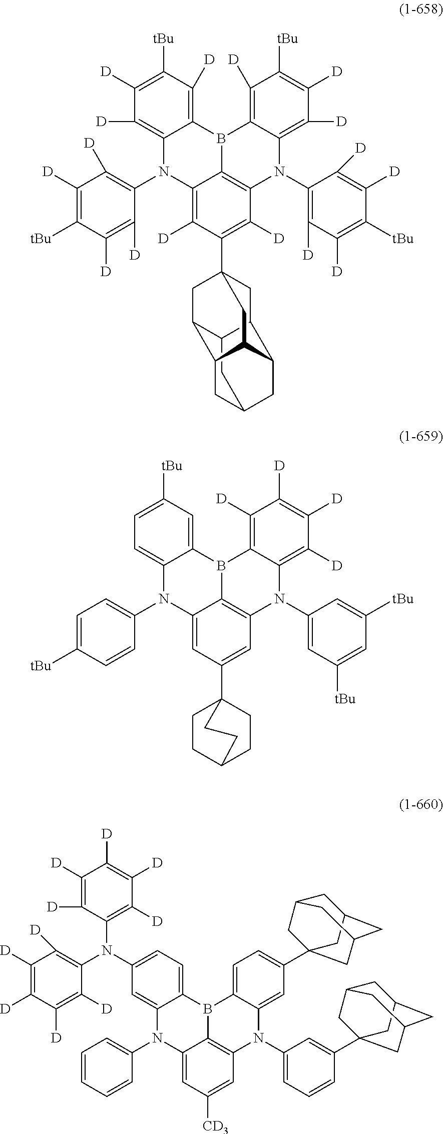

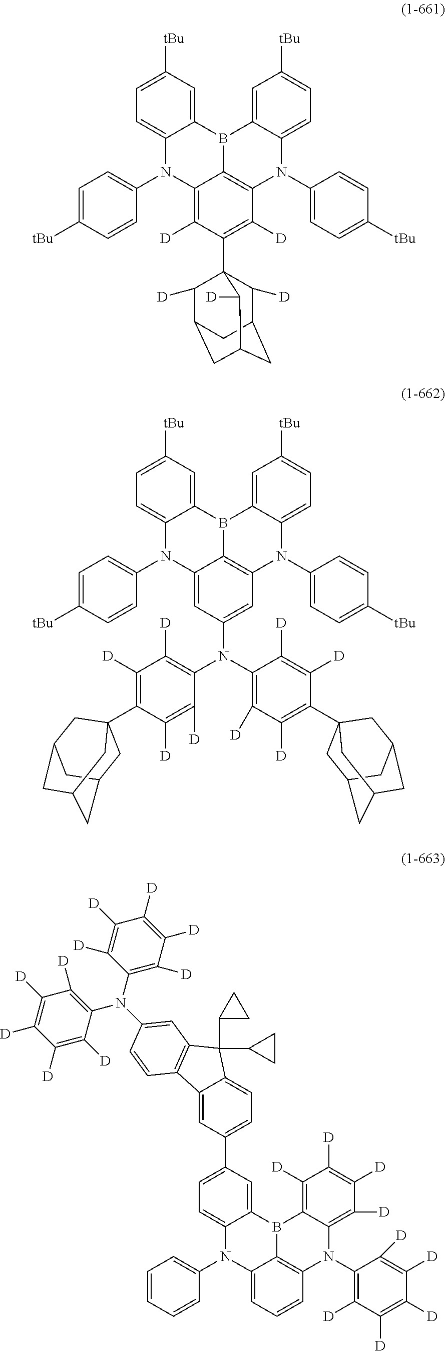

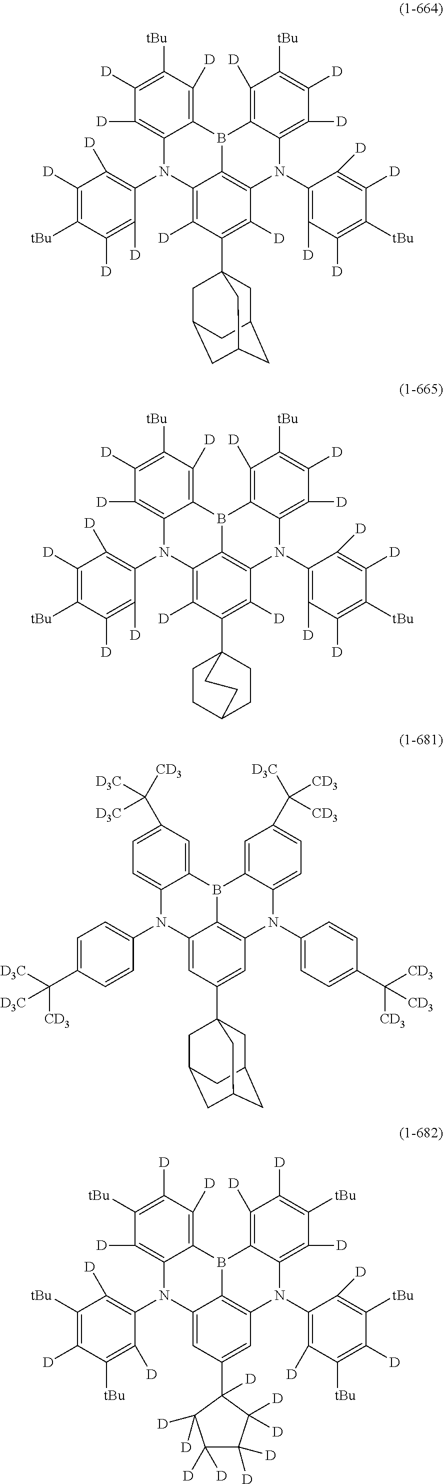

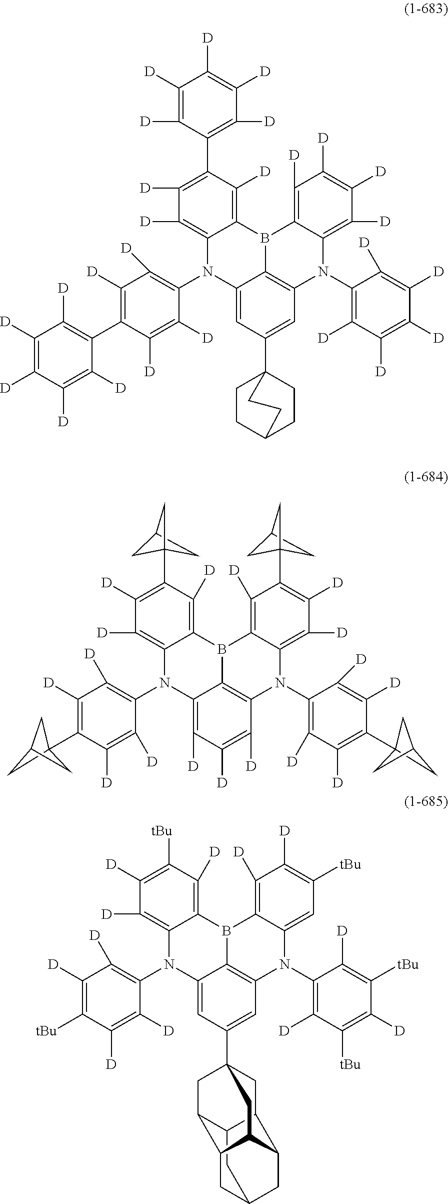

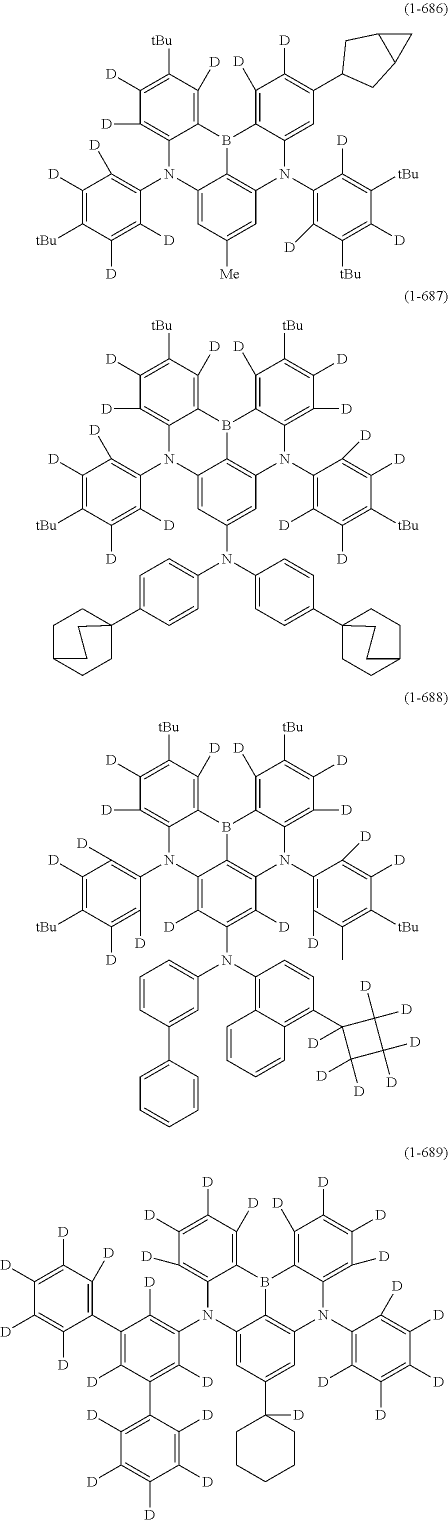

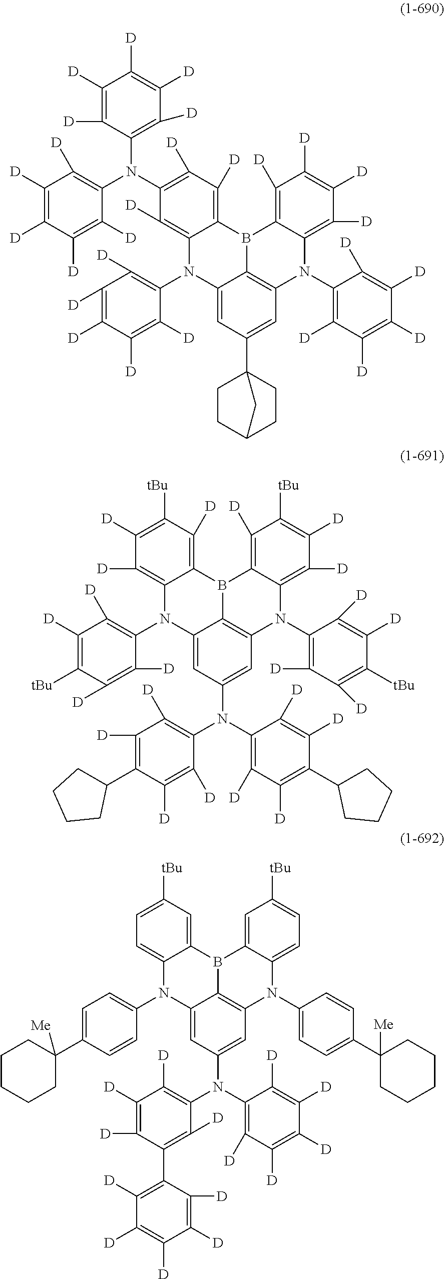

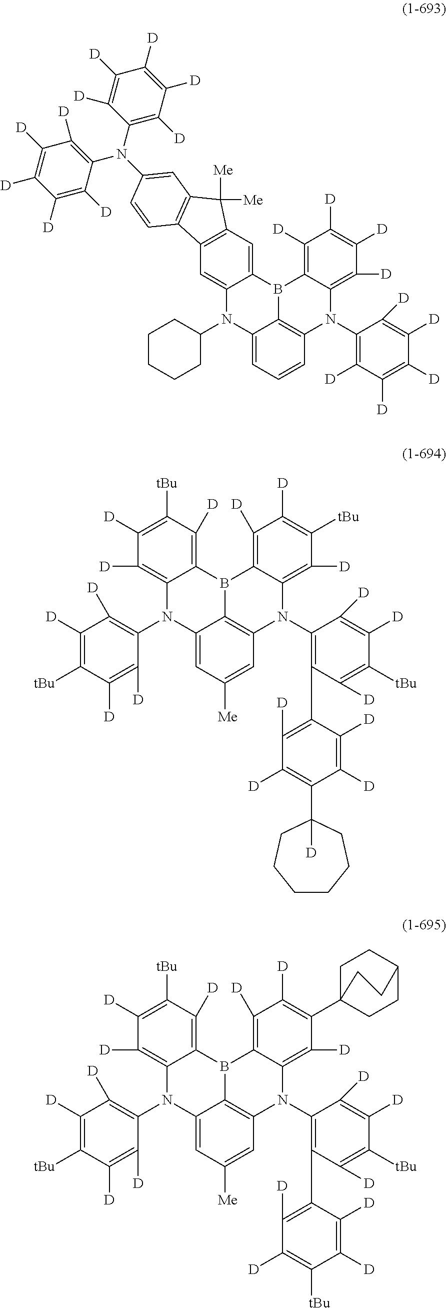

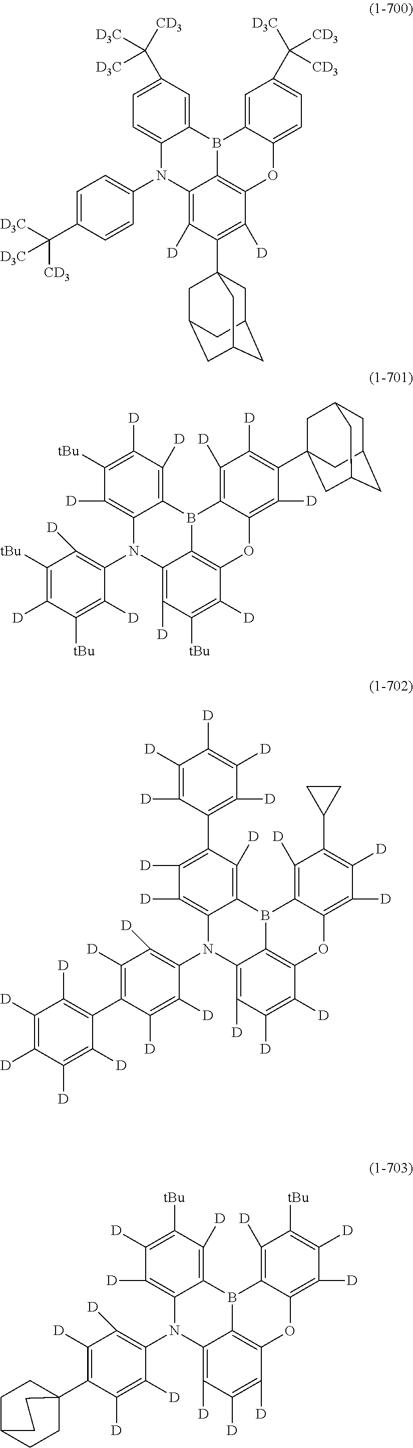

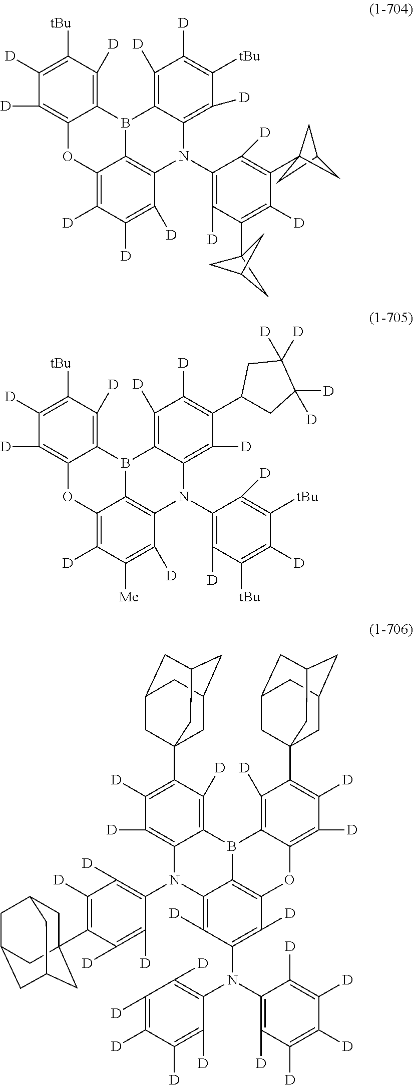

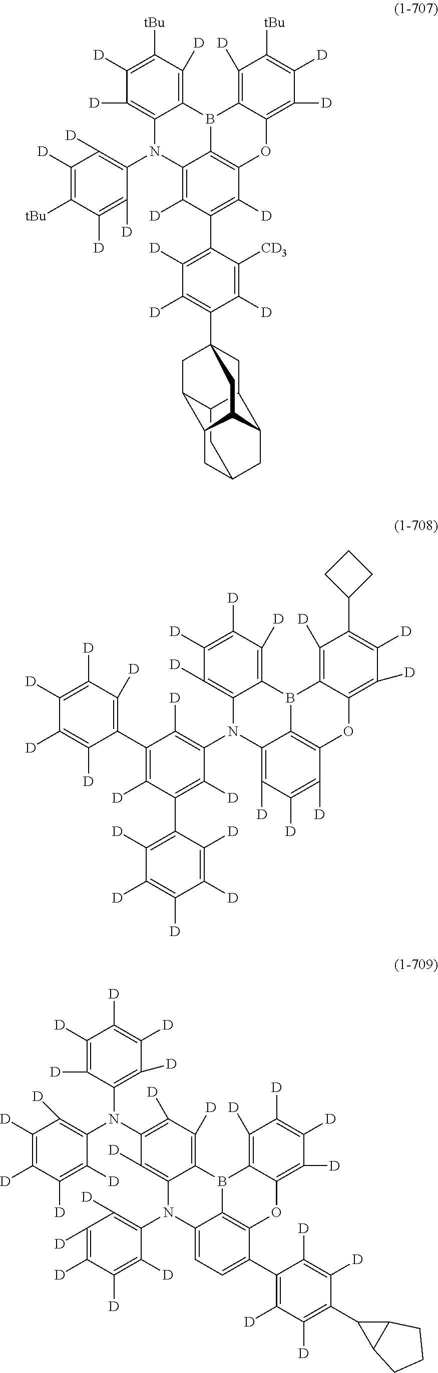

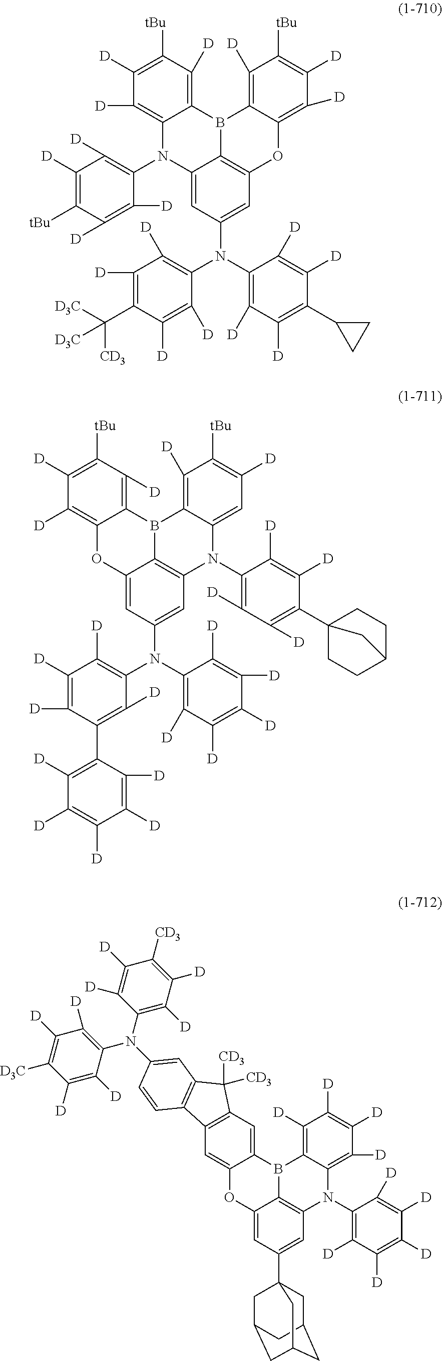

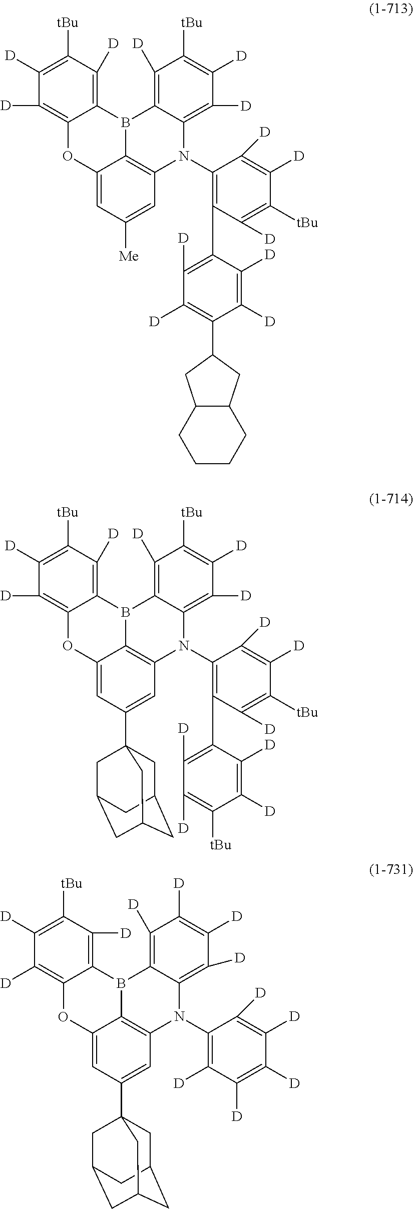

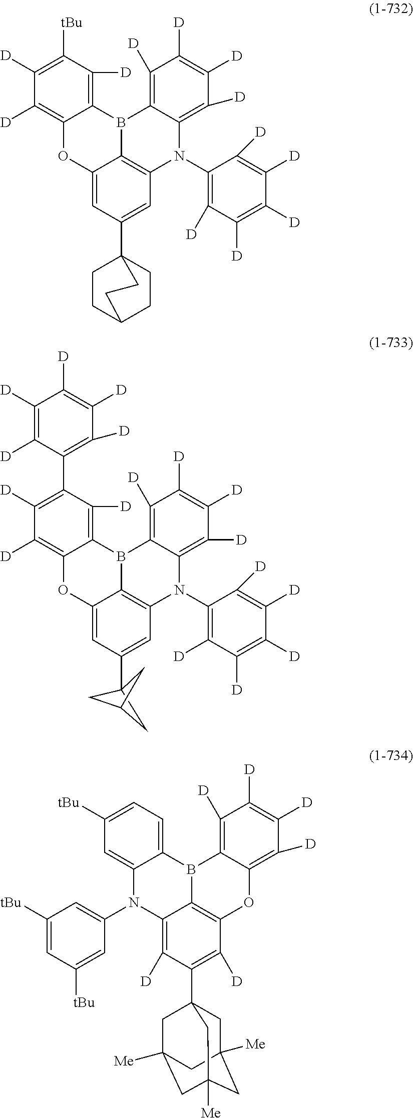 [SMILES: [2H]c1c([2H])c([2H])c(N2c3cc(C45CCC(CC4)CC5)cc4c3B(c3c([2H])c(C(C)(C)C)c([2H])c([2H])c3O4)c3c([2H])c([2H])c([2H])c([2H])c32)c([2H])c1[2H] ; [2H]c1c([2H])c([2H])c(-c2c([2H])c([2H])c3c(c2[2H])B2c4c(cc(C56CC(C5)C6)cc4N(c4c([2H])c([2H])c([2H])c([2H])c4[2H])c4c([2H])c([2H])c([2H])c([2H])c42)O3)c([2H])c1[2H] ; [2H]c1c([2H])c([2H])c2c(c1[2H])Oc1c([2H])c(C34CC5(C)CC(C)(CC(C)(C5)C3)C4)c([2H])c3c1B2c1ccc(C(C)(C)C)cc1N3c1cc(C(C)(C)C)cc(C(C)(C)C)c1]

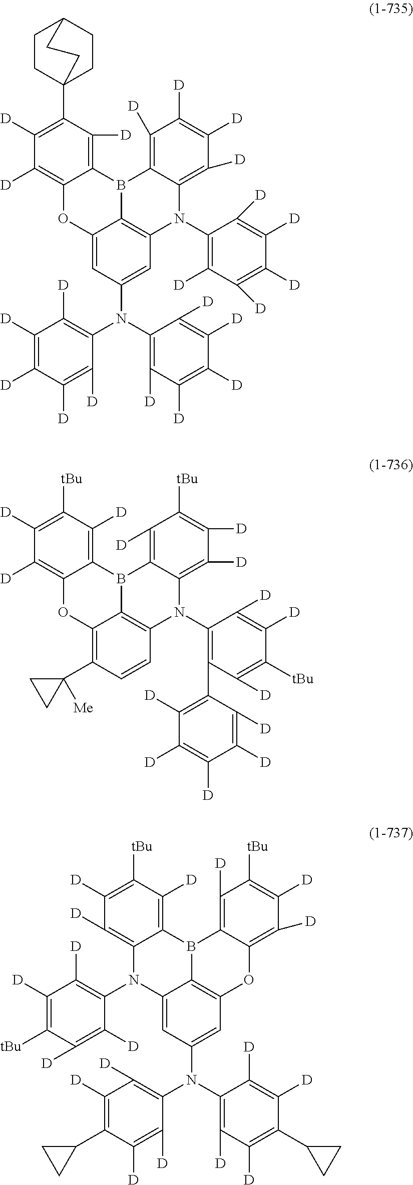

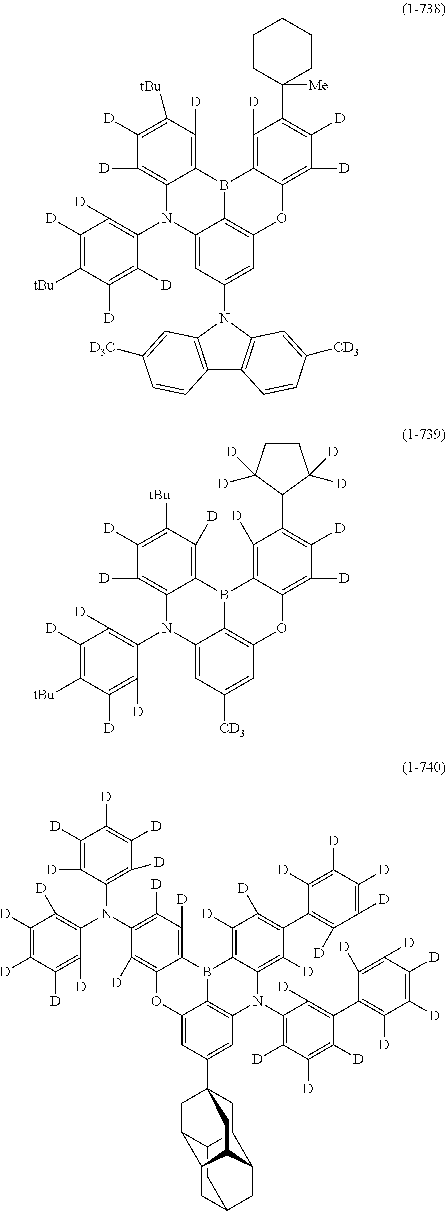

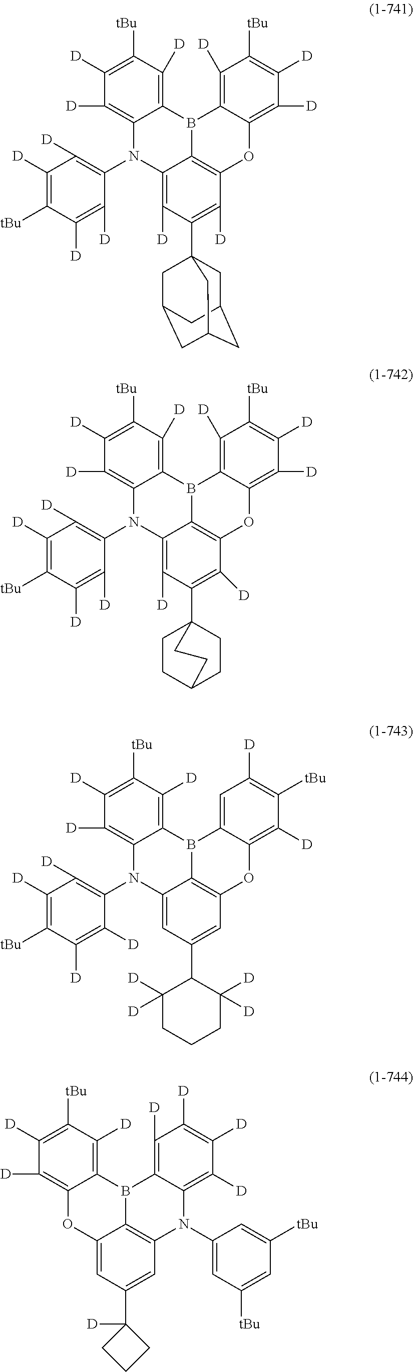

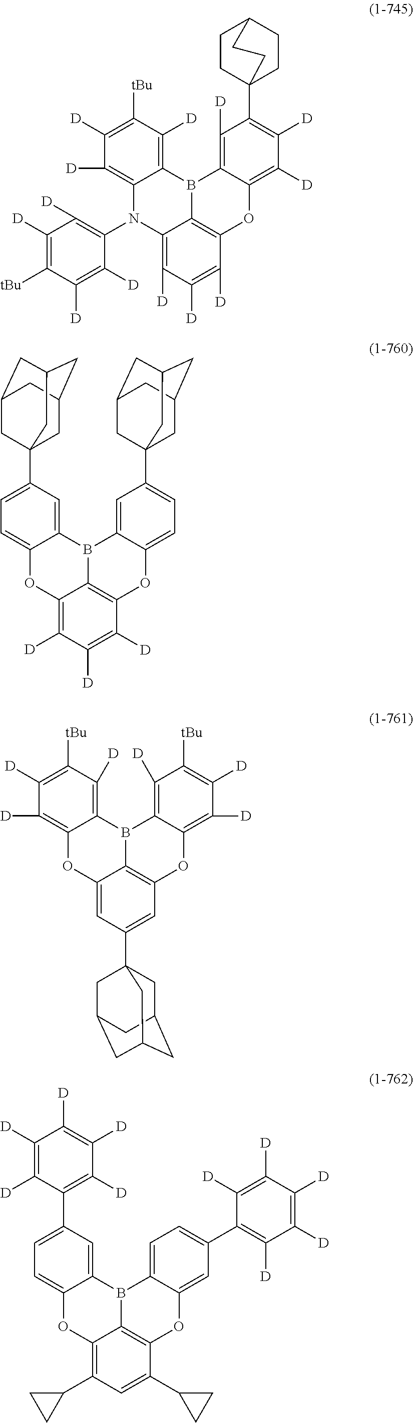

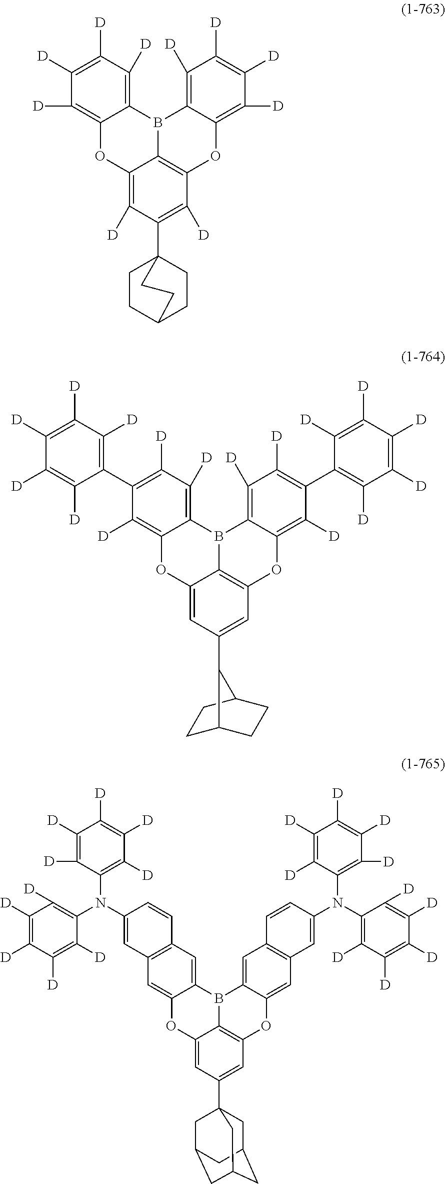 [SMILES: [2H]c1c([2H])c([2H])c2c(c1[2H])Oc1c([2H])c(C34CCC(CC3)CC4)c([2H])c3c1B2c1c([2H])c([2H])c([2H])c([2H])c1O3 ; [2H]c1c([2H])c([2H])c(-c2c([2H])c([2H])c3c(c2[2H])Oc2cc(C4C5CCC4CC5)cc4c2B3c2c([2H])c([2H])c(-c3c([2H])c([2H])c([2H])c([2H])c3[2H])c([2H])c2O4)c([2H])c1[2H] ; [2H]c1c([2H])c([2H])c(N(c2ccc3cc4c(cc3c2)Oc2cc(C35CC6CC(CC(C6)C3)C5)cc3c2B4c2cc4ccc(N(c5c([2H])c([2H])c([2H])c([2H])c5[2H])c5c([2H])c([2H])c([2H])c([2H])c5[2H])cc4cc2O3)c2c([2H])c([2H])c([2H])c([2H])c2[2H])c([2H])c1[2H]]

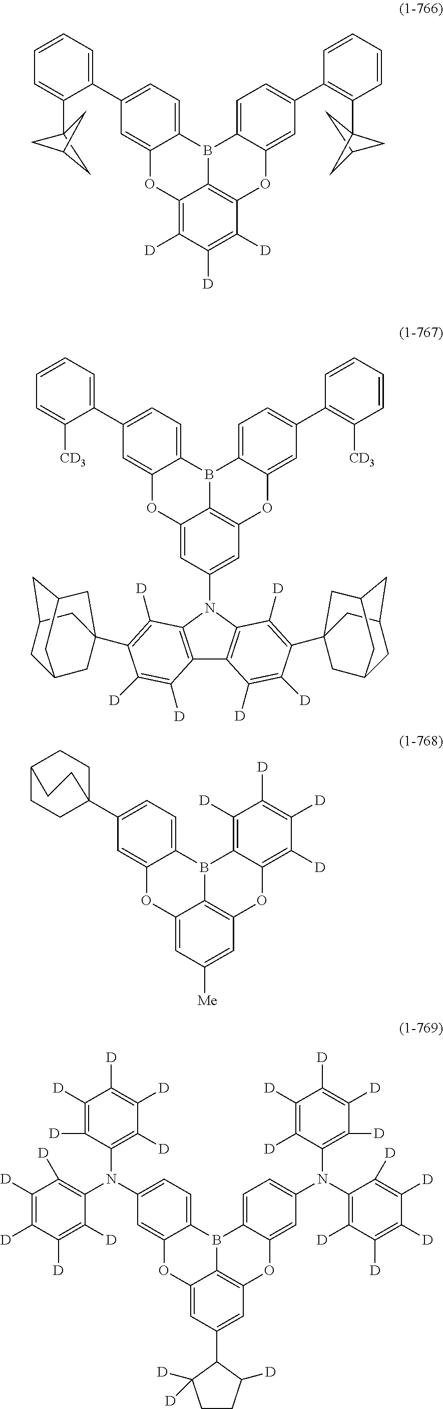

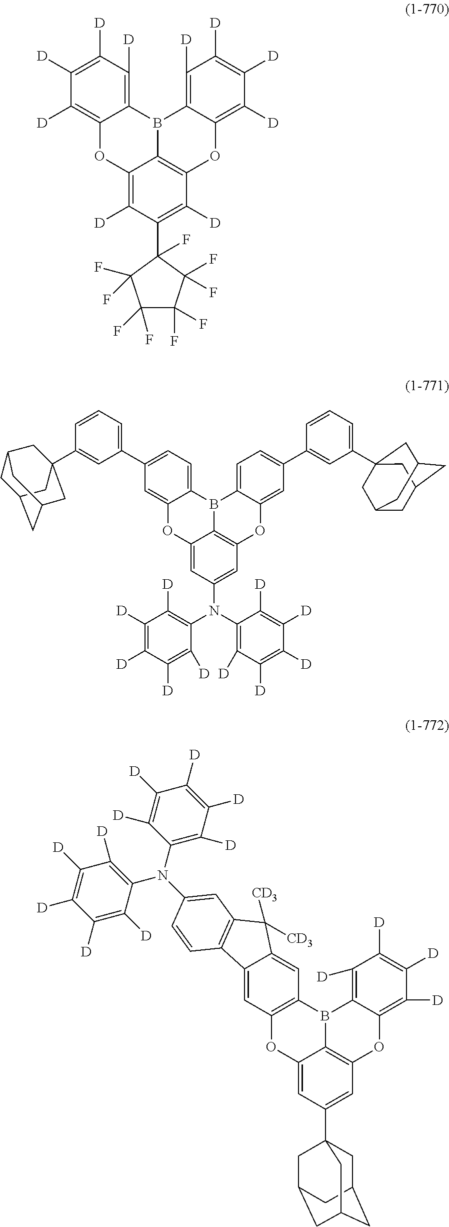

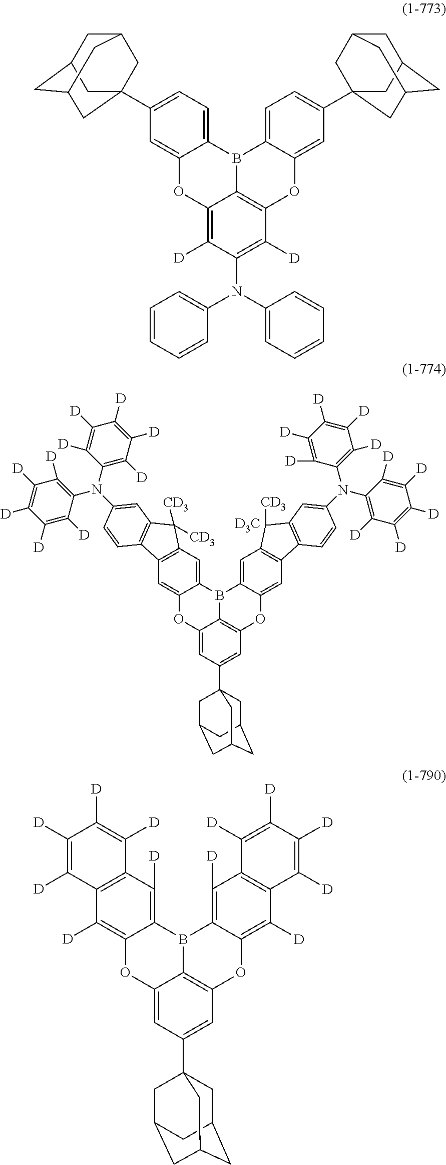

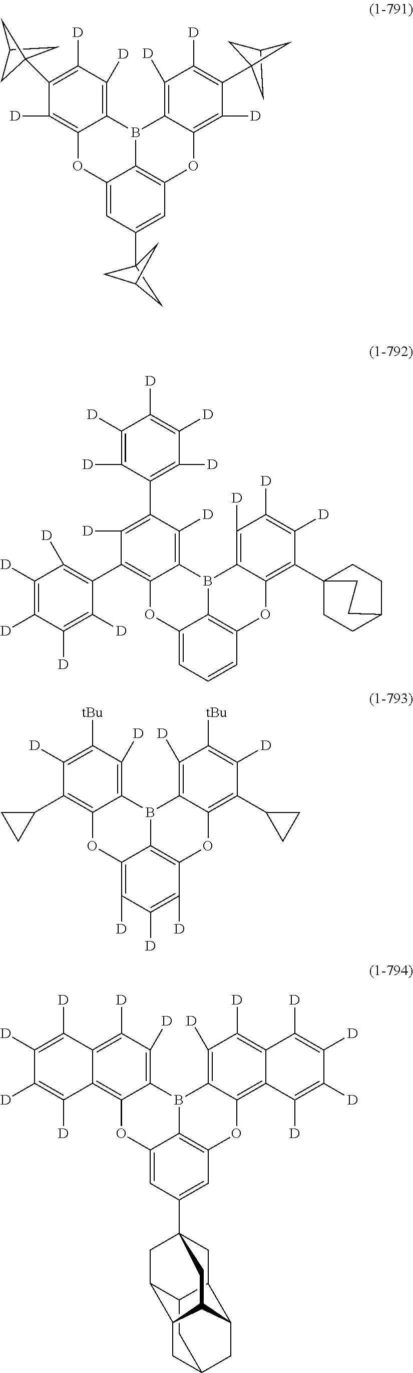

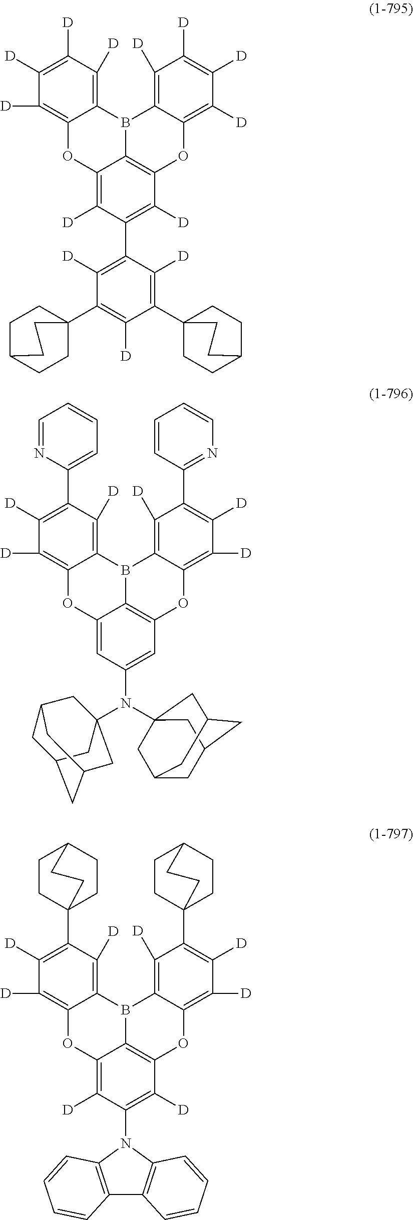

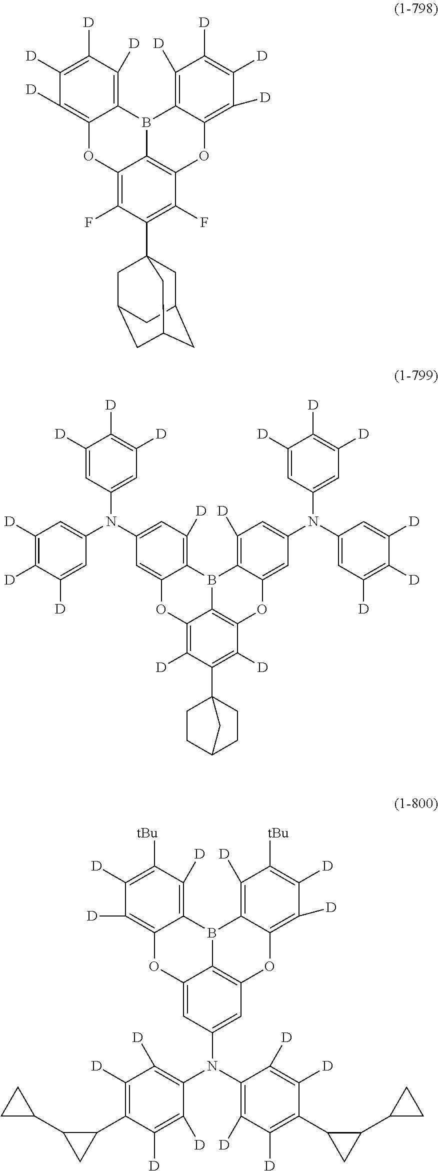 [SMILES: [2H]c1c([2H])c([2H])c2c(c1[2H])Oc1c(F)c(C34CC5CC(CC(C5)C3)C4)c(F)c3c1B2c1c([2H])c([2H])c([2H])c([2H])c1O3 ; [2H]c1cc(N(c2cc([2H])c([2H])c([2H])c2)c2cc([2H])c3c(c2)Oc2c([2H])c(C45CCC(CC4)C5)c([2H])c4c2B3c2c([2H])cc(N(c3cc([2H])c([2H])c([2H])c3)c3cc([2H])c([2H])c([2H])c3)cc2O4)cc([2H])c1[2H] ; [2H]c1c([2H])c(C(C)(C)C)c([2H])c2c1Oc1cc(N(c3c([2H])c([2H])c(C4CC4C4CC4)c([2H])c3[2H])c3c([2H])c([2H])c(C4CC4C4CC4)c([2H])c3[2H])cc3c1B2c1c([2H])c(C(C)(C)C)c([2H])c([2H])c1O3]

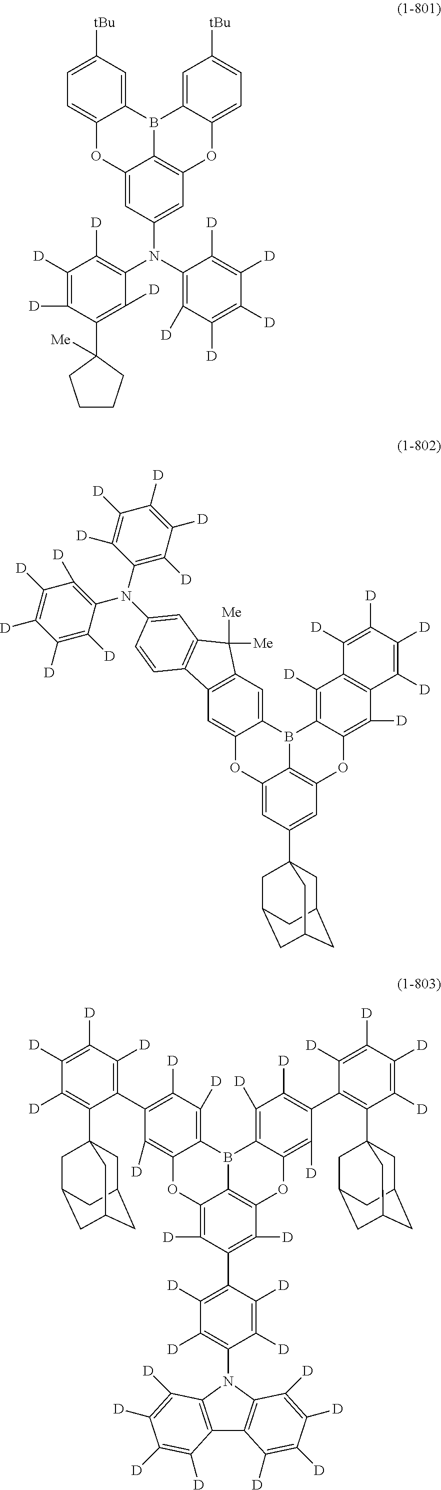

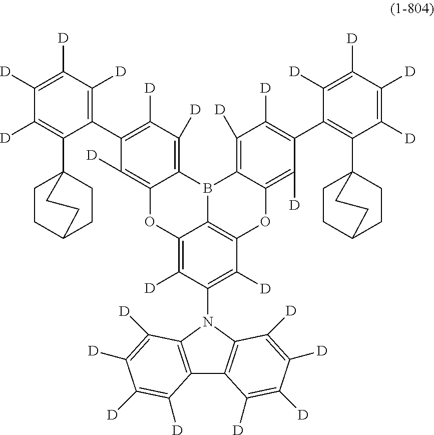 [SMILES: [2H]c1c([2H])c([2H])c(C23CCC(CC2)CC3)c(-c2c([2H])c([2H])c3c(c2[2H])Oc2c([2H])c(-n4c5c([2H])c([2H])c([2H])c([2H])c5c5c([2H])c([2H])c([2H])c([2H])c54)c([2H])c4c2B3c2c([2H])c([2H])c(-c3c([2H])c([2H])c([2H])c([2H])c3C35CCC(CC3)CC5)c([2H])c2O4)c1[2H]]

2. Method for Manufacturing Deuterium-Substituted Polycyclic Aromatic Compound and Multimer Thereof

In regard to the polycyclic aromatic compound represented by general formula (1) or (2) and a multimer thereof, basically, an intermediate is manufactured by first bonding the ring A (ring a), ring B (ring b), and ring C (ring c) with bonding groups (groups containing X¹ or X²) (first reaction), and then a final product can be manufactured by bonding the ring A (ring a), ring B (ring b), and ring C (ring c) with bonding groups (groups containing Y¹) (second reaction). In the first reaction, for example, in an etherification reaction, a general reaction such as a nucleophilic substitution reaction or an Ullmann reaction can be utilized, and in an amination reaction, a general reaction such as a Buchwald-Hartwig reaction can be utilized. Furthermore, in the second reaction, a Tandem Hetero-Friedel-Crafts reaction (continuous aromatic electrophilic substitution reaction, the same hereinafter) can be utilized. Furthermore, by using a deuterated raw material or adding a deuteration step somewhere in these reaction steps, the compound in which a desired position is deuterated according to an aspect of the present invention can be manufactured.

The second reaction is a reaction for introducing Y¹ that bonds the ring A (ring a), ring B (ring b), and ring C (ring c) as illustrated in the following scheme (1) or (2), and as an example, a case where Y¹ represents a boron atom, and X¹ and X² represent oxygen atoms is illustrated below. First, a hydrogen atom between X¹ and X² is ortho-metalated with n-butyllithium, sec-butyllithium, t-butyllithium, or the like. Subsequently, boron trichloride, boron tribromide, or the like is added thereto to perform lithium-boron metal exchange, and then a Brønsted base such as N,N-diisopropylethylamine is added thereto to induce a Tandem Bora-Friedel-Crafts reaction. Thus, a desired product can be obtained. In the second reaction, a Lewis acid such as aluminum trichloride may be added in order to accelerate the reaction. Incidentally, the definitions of the reference numerals in the structural formulas in the following schemes (1) and (2) and subsequent schemes (3) to (28) are the same as the definitions described above.

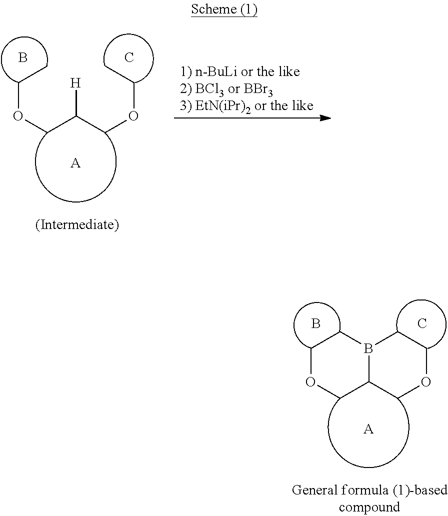

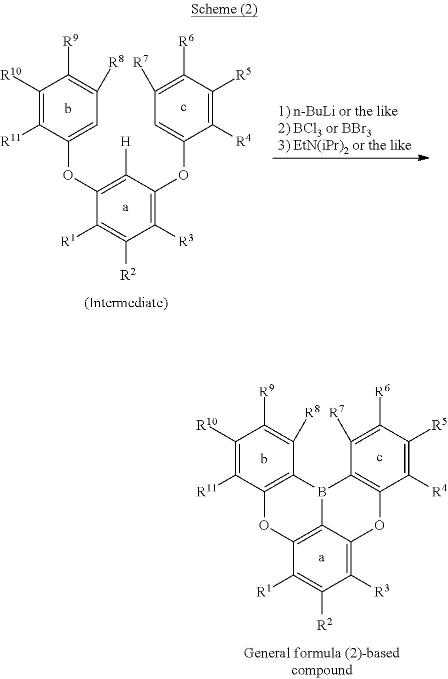

Incidentally, the scheme (1) or (2) mainly illustrates a method for manufacturing a polycyclic aromatic compound represented by general formula (1) or (2). However, a multimer thereof can be manufactured using an intermediate having a plurality of ring A's (ring a's), ring B's (ring b's) and ring C's (ring c's). Specifically, the manufacturing method will be described with the following schemes (3) to (5). In this case, a desired product can be obtained by increasing the amount of a reagent to be used, such as butyllithium, to a double amount or a triple amount.

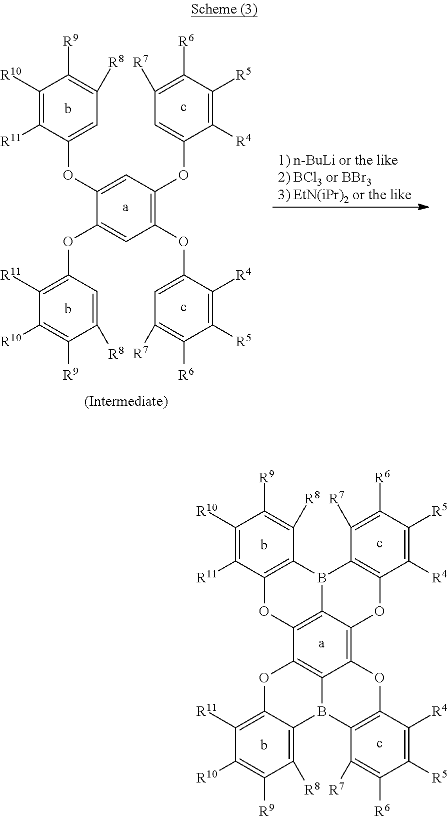

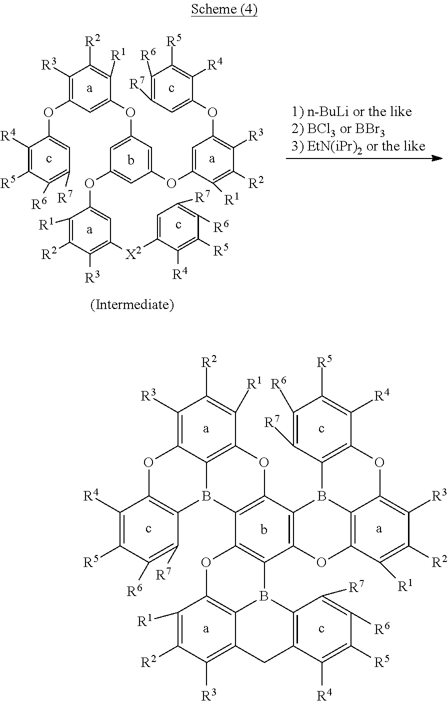

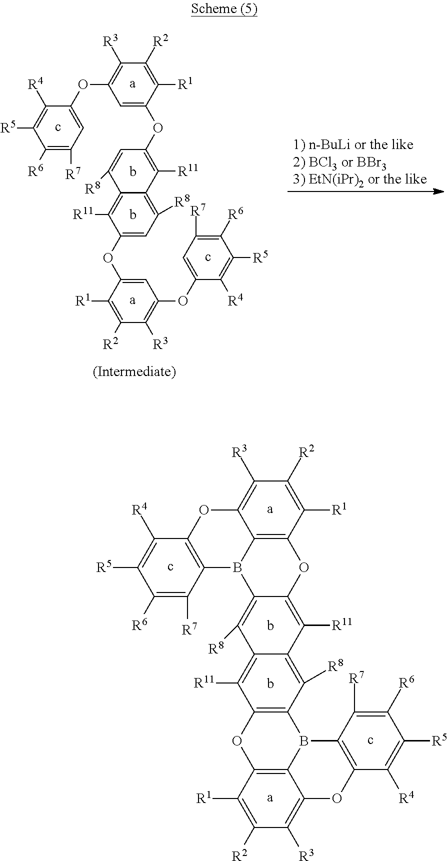

In the above schemes, a lithium atom is introduced into a desired position by ortho-metalation. However, a lithium atom can be introduced into a desired position also by introducing a bromine atom or the like into a position into which it is desired to introduce the lithium atom and performing halogen-metal exchange as in the following schemes (6) and (7).

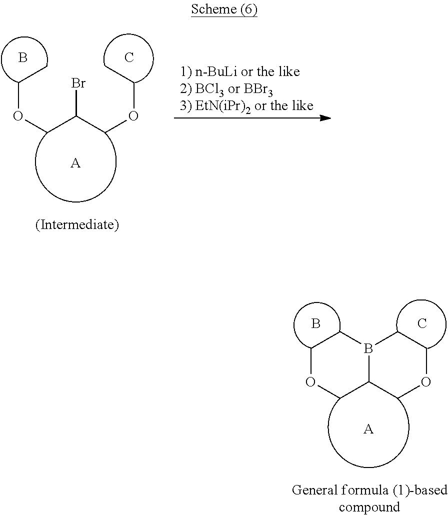

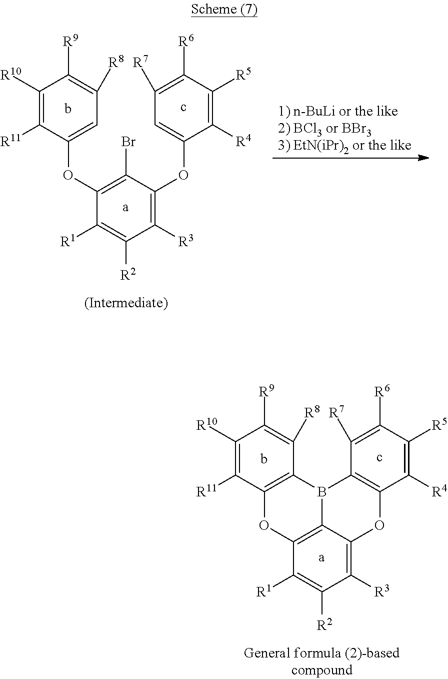

Furthermore, also in regard to the method for manufacturing a multimer described in scheme (3), a lithium atom can be introduced into a desired position also by introducing a halogen atom such as a bromine atom or a chlorine atom into a position into which it is desired to introduce the lithium atom and performing halogen-metal exchange as in the above schemes (6) and (7) (the following schemes (8), (9), and (10)).

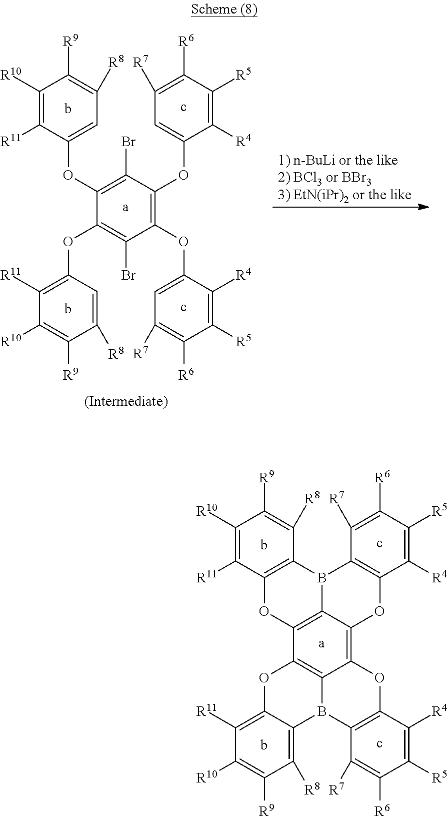

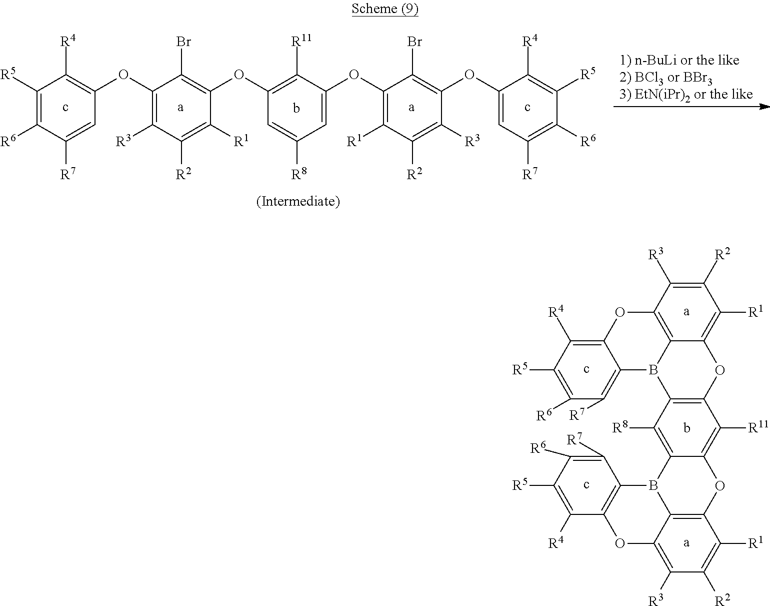

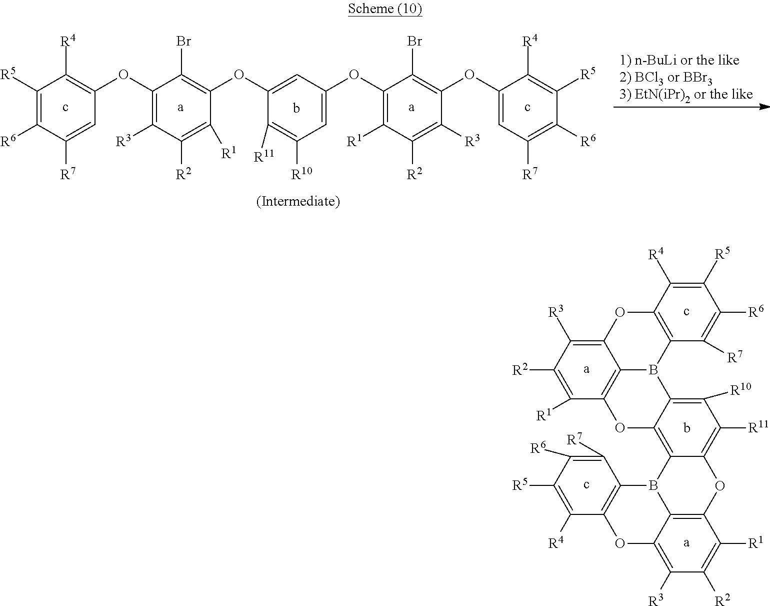

According to this method, a desired product can also be synthesized even in a case where ortho-metalation cannot be achieved due to an influence of a substituent, and therefore the method is useful.

By appropriately selecting the synthesis method described above and appropriately selecting a raw material to be used, a polycyclic aromatic compound in which a desired position is deuterated, a substituent is present at a desired position, Y¹ represents a boron atom, and X¹ and X² represent oxygen atoms, and a multimer thereof can be synthesized.

Next, as an example, a case where Y¹ represents a boron atom, and X¹ and X² represent nitrogen atoms is illustrated in the following schemes (11) and (12). As in the case where X¹ and X² represent oxygen atoms, a hydrogen atom between X¹ and X² is first ortho-metalated with n-butyllithium or the like. Subsequently, boron tribromide or the like is added thereto to induce lithium-boron metal exchange, and then a Brønsted base such as N,N-diisopropylethylamine is added thereto to induce a Tandem Bora-Friedel-Crafts reaction. Thus, a desired product can be obtained. Here, a Lewis acid such as aluminum trichloride may also be added in order to accelerate the reaction. Furthermore, by using a deuterated raw material or adding a deuteration step somewhere in these reaction steps, the compound in which a desired position is deuterated according to an aspect of the present invention can be manufactured.

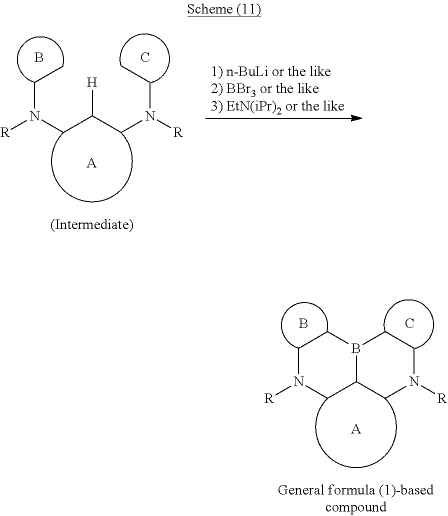

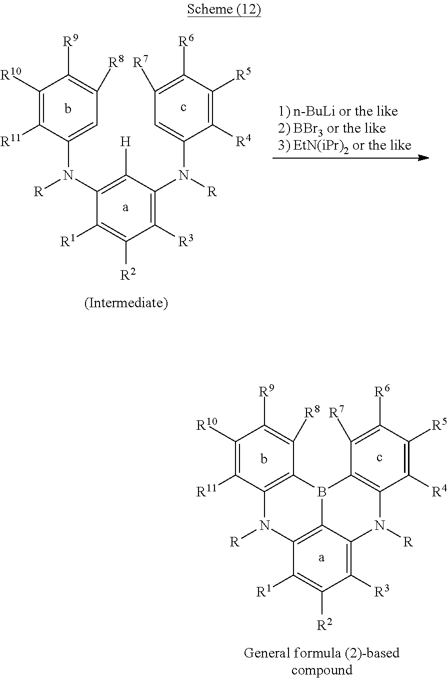

Furthermore, also for a multimer in which Y¹ represents a boron atom, and X¹ and X² represent nitrogen atoms, a lithium atom can be introduced into a desired position also by introducing a halogen atom such as a bromine atom or a chlorine atom into a position into which it is desired to introduce the lithium atom and performing halogen-metal exchange as in the above schemes (6) and (7) (the following schemes (13), (14), and (15)).

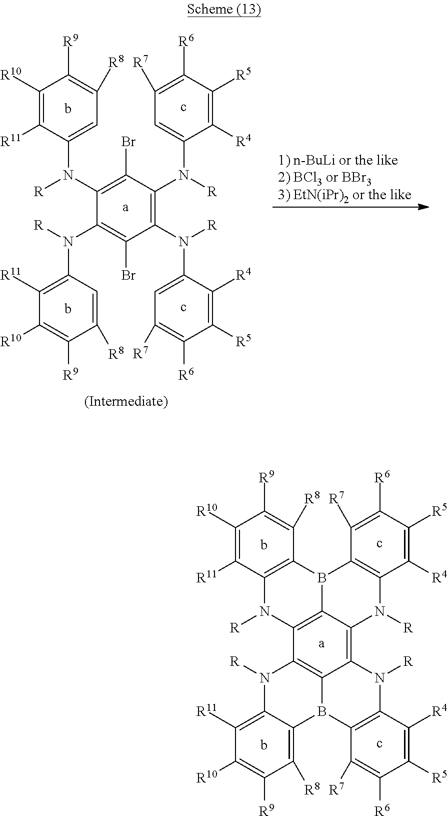

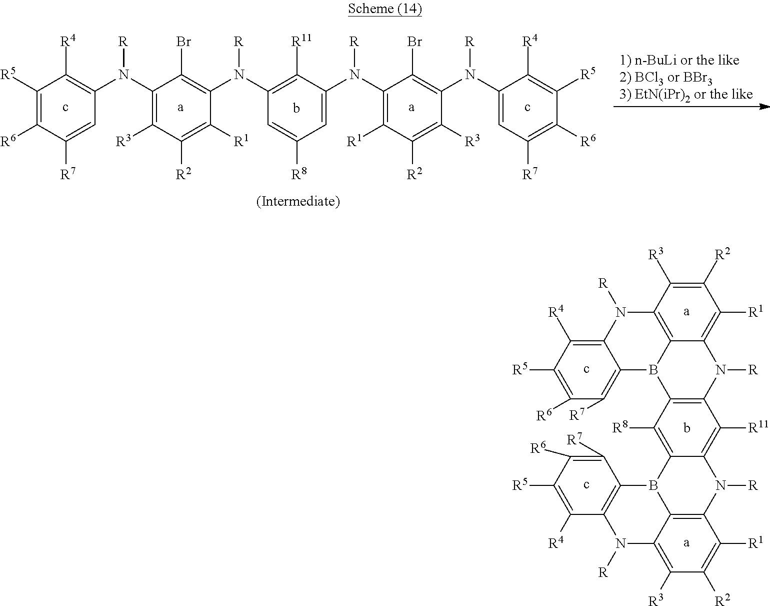

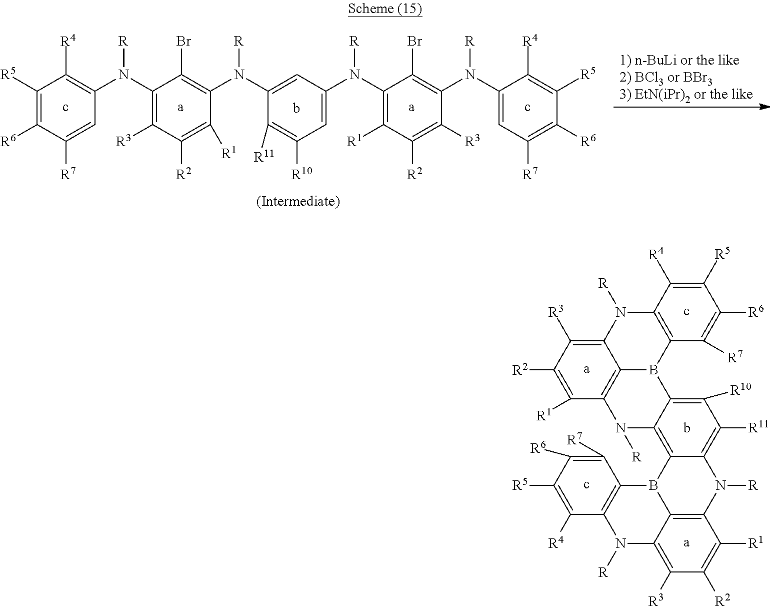

Next, as an example, a case where Y¹ represents phosphorus sulfide, phosphorus oxide, or a phosphorus atom, and X¹ and X² represent oxygen atoms is illustrated in the following schemes (16) to (19). As in the cases described above, a hydrogen atom between X¹ and X² is first ortho-metalated with n-butyllithium or the like. Subsequently, phosphorus trichloride and sulfur are added thereto in this order, and finally a Lewis acid such as aluminum trichloride and a Brønsted base such as N,N-diisopropylethylamine are added thereto to induce a Tandem Phospha-Friedel-Crafts reaction. Thus, a compound in which Y¹ represents phosphorus sulfide can be obtained. Furthermore, by treating the phosphorus sulfide compound thus obtained with m-chloroperbenzoic acid (m-CPBA), a compound in which Y¹ represents phosphorus oxide can be obtained, and by treating the phosphorus sulfide compound with triethylphosphine, a compound in which Y¹ represents a phosphorus atom can be obtained. Furthermore, by using a deuterated raw material or adding a deuteration step somewhere in these reaction steps, the compound in which a desired position is deuterated according to an aspect of the present invention can be manufactured.

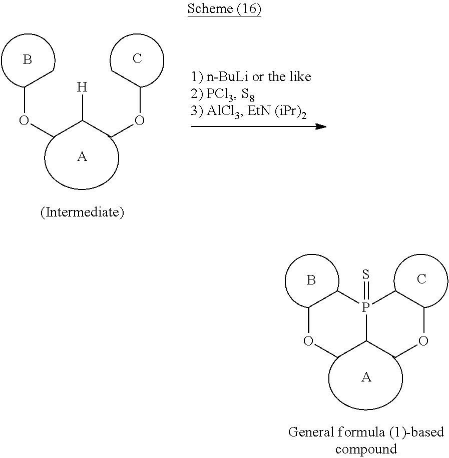

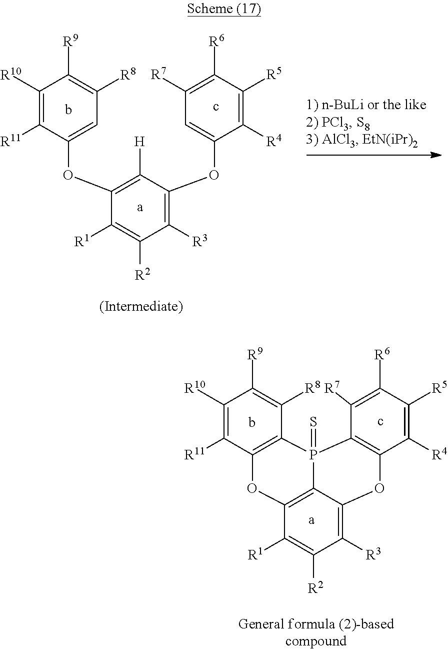

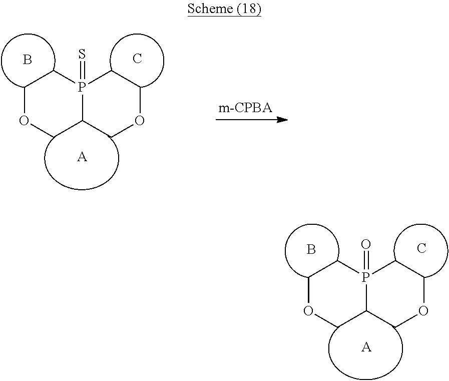

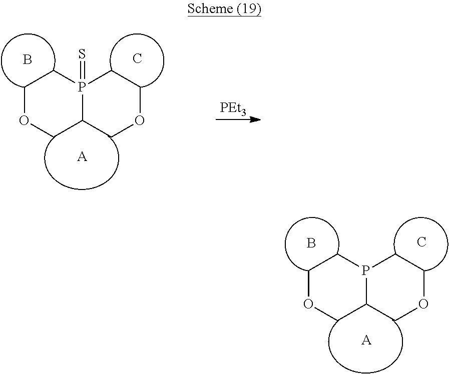

Furthermore, also for a multimer in a case where Y¹ represents phosphorus sulfide, and X¹ and X² represent oxygen atoms, a lithium atom can be introduced into a desired position also by introducing a halogen atom such as a bromine atom or a chlorine atom into a position into which it is desired to introduce the lithium atom and performing halogen-metal exchange as in the above schemes (6) and (7) (the following schemes (20), (21), and (22)). Furthermore, also for the thus formed multimer in which Y¹ represents phosphorus sulfide, and X¹ and X² represent oxygen atoms, as in the above schemes (18) and (19), by treating the multimer with m-chloroperbenzoic acid (m-CPBA), a compound in which Y¹ represents phosphorus oxide can be obtained, and by treating the multimer with triethylphosphine, a compound in which Y¹ represents a phosphorus atom can be obtained.

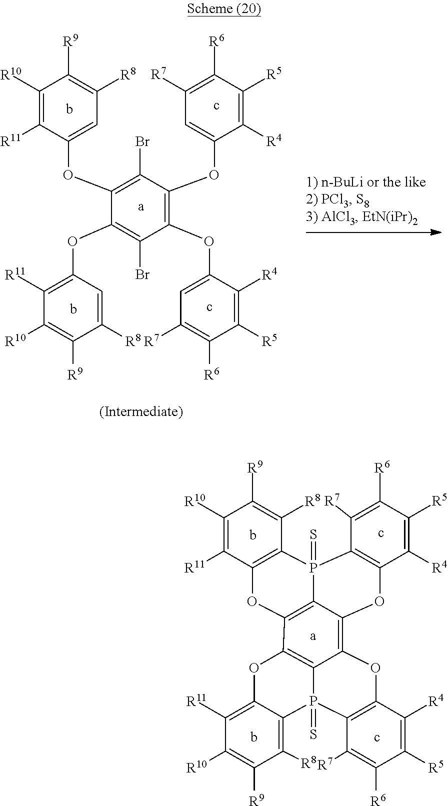

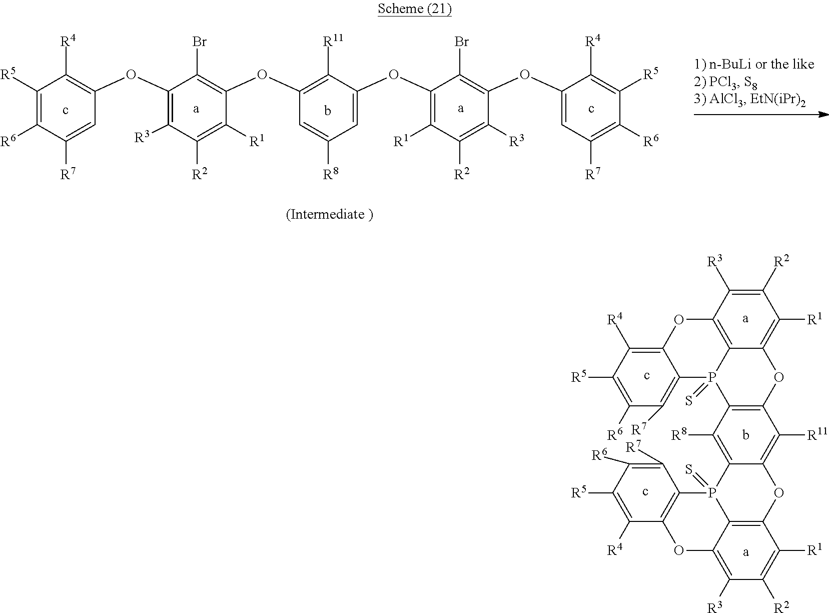

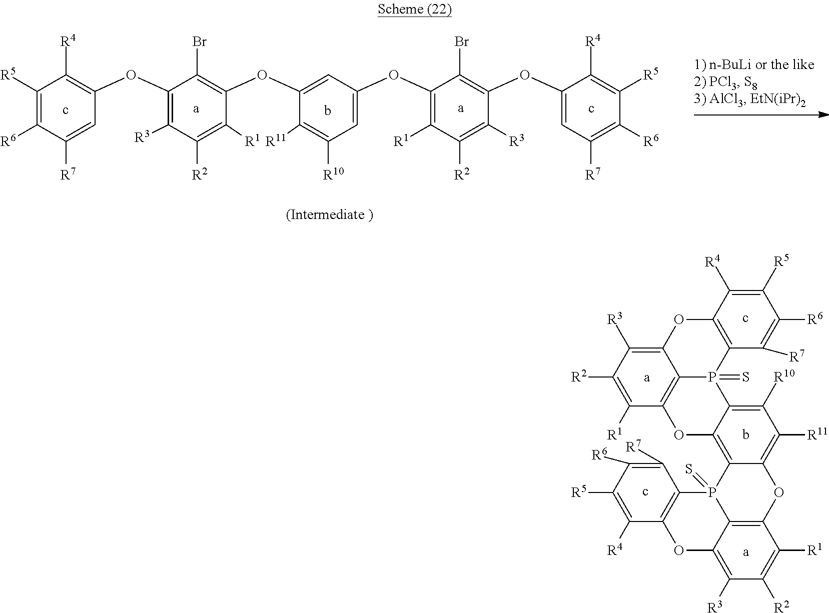

Here, an example in which Y¹ represents B, P, P═O, or P═S, and X¹ and X² each represent O or NR has been described. However, by changing the raw materials appropriately, a compound in which Y¹ represents Al, Ga, As, Si—R, or Ge—R, and X¹ and X² each represent S can also be synthesized.

Specific examples of a solvent used in the above reactions include t-butylbenzene and xylene.

Furthermore, in general formula (2), adjacent groups among the substituents R¹ to R¹¹ of the ring a, ring b, and ring c may be bonded to each other to form an aryl ring or a heteroaryl ring together with the ring a, ring b, or ring c, and at least one hydrogen atom in the ring thus formed may be substituted by an aryl or a heteroaryl. Therefore, in a polycyclic aromatic compound represented by general formula (2), a ring structure constituting the compound changes as represented by formulas (2-1) and (2-2) of the following schemes (23) and (24) according to a mutual bonding form of substituents in the ring a, ring b, and ring c. These compounds can be synthesized by applying synthesis methods illustrated in the above schemes (1) to (19) to intermediates illustrated in the following schemes (23) and (24). Furthermore, by using a deuterated raw material or adding a deuteration step somewhere in these reaction steps, the compound in which a desired position is deuterated according to an aspect of the present invention can be manufactured.

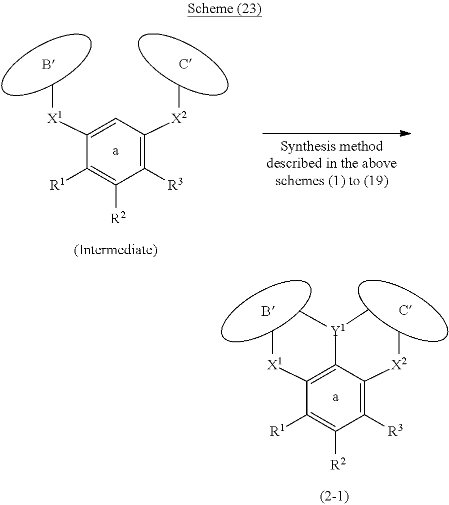

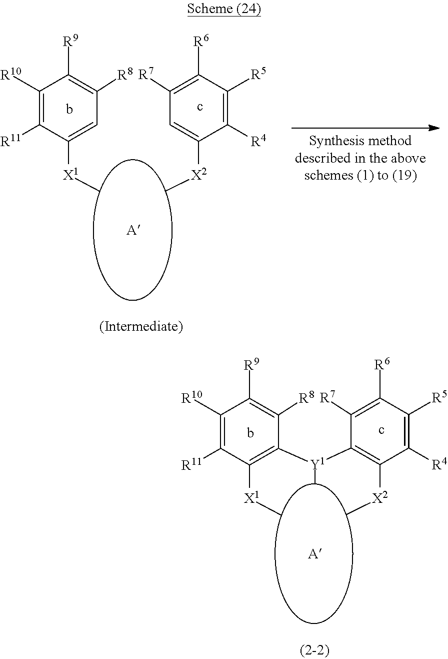

Ring A′, ring B′ and ring C′ in the above formulas (2-1) and (2-2) each represent an aryl ring or a heteroaryl ring formed by bonding adjacent groups among the substituents R¹ to R¹¹ together with the ring a, ring b, and ring c, respectively (may also be a fused ring obtained by fusing another ring structure to the ring a, ring b, or ring c). Incidentally, although not indicated in the formula, there is also a compound in which all of the ring a, ring b, and ring c have been changed to the ring A′, ring B′ and ring C′.

Furthermore, the provision that “R in the N—R is bonded to the ring a, ring b, and/or ring c via —O—, —S—, —C(—R)₂—, or a single bond” in general formulas (2) can be expressed as a compound having a ring structure represented by formula (2-3-1) of the following scheme (25), in which X¹ or X² is incorporated into the fused ring B′ or fused ring C′, or a compound having a ring structure represented by formula (2-3-2) or (2-3-3), in which X¹ or X² is incorporated into the fused ring A′. These compounds can be synthesized by applying the synthesis methods illustrated in the schemes (1) to (19) to the intermediate represented by the following scheme (25). Furthermore, by using a deuterated raw material or adding a deuteration step somewhere in these reaction steps, the compound in which a desired position is deuterated according to an aspect of the present invention can be manufactured.

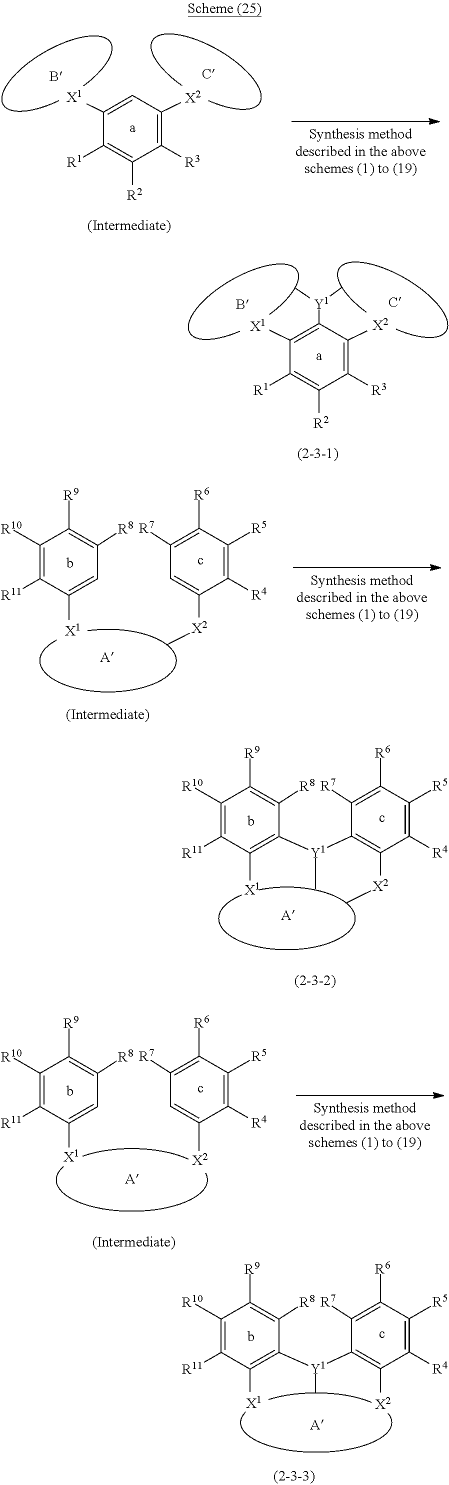

Furthermore, the synthesis methods of the above schemes (1) to (17) and (20) to (25) illustrate an example of performing a Tandem Hetero-Friedel-Crafts reaction by ortho-metalating a hydrogen atom (or a halogen atom) between X¹ and X² with butyllithium or the like before boron trichloride, boron tribromide, or the like is added. However, the reaction can also be advanced by adding boron trichloride, boron tribromide, or the like without performing ortho-metalation using buthyllithium or the like.

Furthermore, in a case where Y¹ represents a phosphorus-based group, as illustrated in the following scheme (26) or (27), a desired product can be obtained by ortho-metalating a hydrogen atom between X¹ and X² (O in the following formula) with n-butyllithium, sec-butyllithium, t-butyllithium, or the like, subsequently adding bisdiethylaminochlorophosphine thereto to perform lithium-phosphorus metal exchange, and then adding a Lewis acid such as aluminum trichloride thereto to induce a Tandem Phospha-Friedel-Crafts reaction. This reaction method is also described in WO 2010/104047 A (for example, page 27). Furthermore, by using a deuterated raw material or adding a deuteration step somewhere in these reaction steps, the compound in which a desired position is deuterated according to an aspect of the present invention can be manufactured.

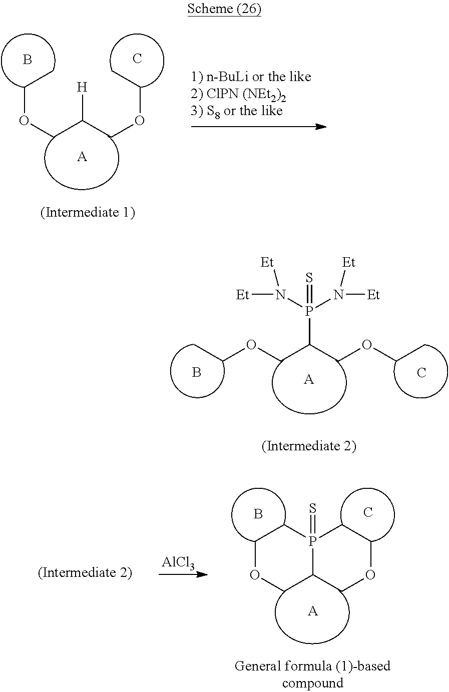

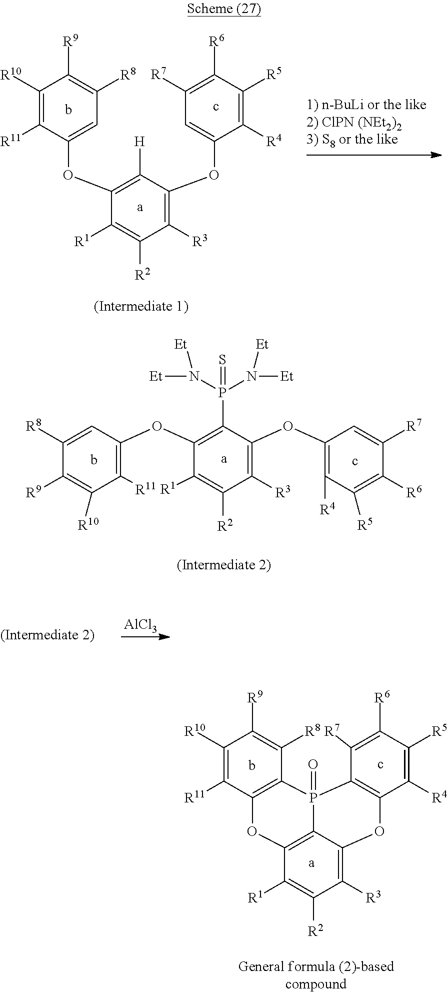

Incidentally, also in the above scheme (26) or (27), a multimer compound can be synthesized using an ortho-metalation reagent such as butyllithium in a molar amount twice or three time the molar amount of an intermediate. Furthermore, a metal atom can be introduced into a desired position by introducing a halogen atom such as a bromine atom or a chlorine atom in advance into a position into which it is desired to introduce a metal atom such as a lithium atom, and performing halogen-metal exchange.

In addition, regarding the polycyclic aromatic compound represented by general formula (2-A), as illustrated in the following scheme (28), a deuterated intermediate is synthesized and cyclized to synthesize a polycyclic aromatic compound in which a desired position is substituted by a deuterium atom. In scheme (28), X represents a halogen atom or a hydrogen atom, and the definitions of the other reference numerals are the same as the definitions of the reference numerals in general formula (2).

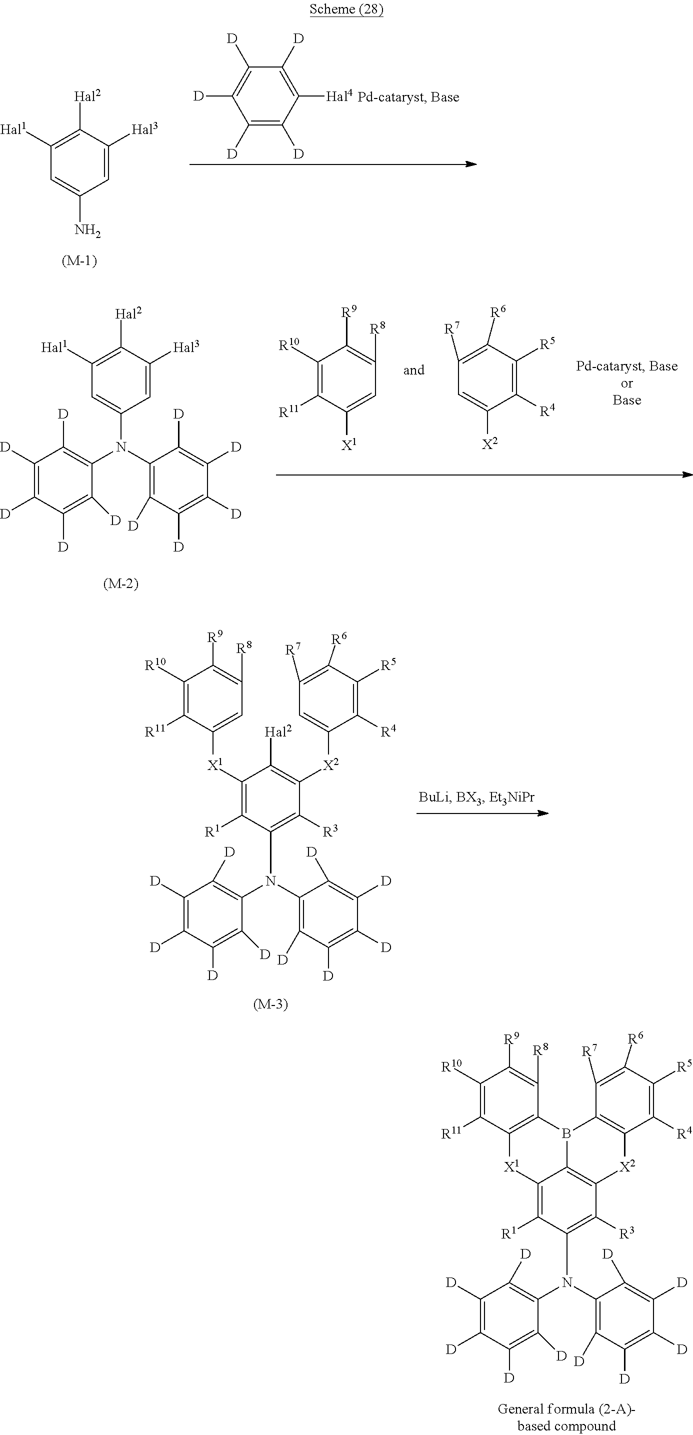

An intermediate before cyclization in scheme (28) can also be synthesized by a method illustrated in scheme (1) or the like. That is, an intermediate having a desired substituent can be synthesized by appropriately combining a Buchwald-Hartwig reaction, a Suzuki coupling reaction, an etherification reaction using a nucleophilic substitution reaction or an Ullmann reaction, and the like. In these reactions, a commercially available product can be used as a raw material serving as a deuterated precursor.

A compound of general formula (2-A) having a deuterated diphenylamino group can also be synthesized, for example, by the following method. That is, a deuterated diphenylamino group is introduced by an amination reaction such as a Buchwald-Hartwig reaction between commercially available d⁵-bromobenzene and trihalogenated aniline. Thereafter, the resulting product is induced to an intermediate (M-3) by an amination reaction such as a Buchwald-Hartwig reaction when X¹ and X² each represent N—R, or by an etherification using phenol when X¹ and X² each represent O. Thereafter, the resulting product is transmetalated by an action of a metalation reagent such as butyllithium, then caused to react with a boron halide such as boron tribromide, and then caused to react with a Brønsted base such as diethyl isopropylamine to cause a Tandem Bora-Friedel-Crafts reaction. Thus, the compound of formula (2-A) can be synthesized. These reactions can also be applied to other deuterated compounds.

Note that examples of an ortho-metalation reagent used in the above schemes (1) to (28) include an alkyllithium such as methyllithium, n-butyllithium, sec-butyllithium, or t-butyllithium; and an organic alkali compound such as lithium diisopropylamide, lithium tetramethylpiperidide, lithium hexamethyldisilazide, or potassium hexamethyldisilazide.

Incidentally, examples of a metal exchanging reagent for metal-Y¹ used in the above schemes (1) to (28) include a halide of Y¹ such as trifluoride of Y¹, trichloride of Y¹, tribromide of Y¹, or triiodide of Y¹; an aminated halide of Y¹ such as CIPN(NEt₂)₂; an alkoxylated product of Y¹; and an aryloxylated product of Y¹.

Incidentally, examples of the Brønsted base used for the above schemes (1) to (28) include N,N-diisopropylethylamine, triethylamine, 2,2,6,6-tetramethylpiperidine, 1,2,2,6,6-pentamethylpiperidine, N,N-dimethylaniline, N,N-dimethyltoluidine, 2,6-lutidine, sodium tetraphenylborate, potassium tetraphenylborate, triphenylborane, tetraphenylsilane, Ar₄BNa, Ar₄BK, Ar₃B, and Ar₄Si (Ar represents an aryl such as phenyl).

Examples of a Lewis acid used for the above schemes (1) to (28) include AlCl₃, AlBr₃, AlF₃, BF₃.OEt₂, BC1₃, BBr₃, GaCl₃, GaBr₃, InCl₃, InBr₃, In(OTf)₃, SnCl₄, SnBr₄, AgOTf, ScCl₃, Sc(OTf)₃, ZnCl₂, ZnBr₂, Zn(OTf)₂, MgCl₂, MgBr₂, Mg(OTf)₂, LiOTf, NaOTf, KOTf, Me₃SiOTf, Cu(OTf)₂, CuCl₂, YCl₃, Y(OTf)₃, TiCl₄, TiBr₄, ZrCl₄, ZrBr₄, FeCl₃, FeBr₃, CoCl₃, and CoBr₃.

In the above schemes (1) to (28), a Brønsted base or a Lewis acid may be used in order to accelerate the Tandem Hetero Friedel-Crafts reaction. However, in a case where a halide of Y¹ such as trifluoride of Y¹, trichloride of Y¹, tribromide of Y¹, or triiodide of Y¹ is used, an acid such as hydrogen fluoride, hydrogen chloride, hydrogen bromide, or hydrogen iodide is generated along with progress of an aromatic electrophilic substitution reaction. Therefore, it is effective to use a Brønsted base that captures an acid. Meanwhile, in a case where an aminated halide of Y¹ or an alkoxylation product of Y¹ is used, an amine or an alcohol is generated along with progress of the aromatic electrophilic substitution reaction. Therefore, in many cases, it is not necessary to use a Brønsted base. However, leaving ability of an amino group or an alkoxy group is low, and therefore it is effective to use a Lewis acid that promotes leaving of these groups.

Furthermore, the polycyclic aromatic compound or the multimer thereof according to an aspect of the present invention also includes a compound in which at least some of hydrogen atoms are substituted by cyanos or substituted by halogen atoms such as fluorine atoms or chlorine atoms. However, these compounds can be synthesized in a similar manner to the above using a raw material in which a desired position is cyanized, fluorinated, or chlorinated.

3. Organic Device

The deuterium-substituted polycyclic aromatic compound according to an aspect of the present invention can be used as a material for an organic device. Examples of the organic device include an organic electroluminescent element, an organic field effect transistor, and an organic thin film solar cell.

3-1. Organic Electroluminescent Element

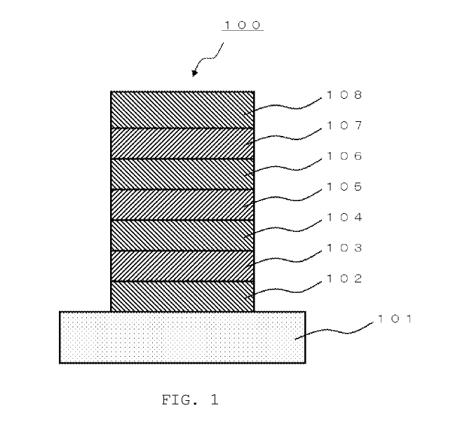

Hereinafter, an organic EL element according to the present embodiment will be described in detail based on the drawings. FIG. 1 is a schematic cross-sectional view illustrating the organic EL element according to the present embodiment.

<Structure of Organic Electroluminescent Element>

An organic EL element 100 illustrated in FIG. 1 includes a substrate 101, a positive electrode 102 provided on the substrate 101, a hole injection layer 103 provided on the positive electrode 102, a hole transport layer 104 provided on the hole injection layer 103, a light emitting layer 105 provided on the hole transport layer 104, an electron transport layer 106 provided on the light emitting layer 105, an electron injection layer 107 provided on the electron transport layer 106, and a negative electrode 108 provided on the electron injection layer 107.

Incidentally, the organic EL element 100 may be constituted, by reversing the manufacturing order, to include, for example, the substrate 101, the negative electrode 108 provided on the substrate 101, the electron injection layer 107 provided on the negative electrode 108, the electron transport layer 106 provided on the electron injection layer 107, the light emitting layer 105 provided on the electron transport layer 106, the hole transport layer 104 provided on the light emitting layer 105, the hole injection layer 103 provided on the hole transport layer 104, and the positive electrode 102 provided on the hole injection layer 103.

Not all of the above layers are essential. The configuration includes the positive electrode 102, the light emitting layer 105, and the negative electrode 108 as a minimum constituent unit, while the hole injection layer 103, the hole transport layer 104, the electron transport layer 106, and the electron injection layer 107 are optionally provided. Furthermore, each of the above layers may be formed of a single layer or a plurality of layers.

A form of layers constituting the organic EL element may be, in addition to the above structure form of “substrate/positive electrode/hole injection layer/hole transport layer/light emitting layer/electron transport layer/electron injection layer/negative electrode”, a structure form of “substrate/positive electrode/hole transport layer/light emitting layer/electron transport layer/electron injection layer/negative electrode”, “substrate/positive electrode/hole injection layer/light emitting layer/electron transport layer/electron injection layer/negative electrode”, “substrate/positive electrode/hole injection layer/hole transport layer/light emitting layer/electron injection layer/negative electrode”, “substrate/positive electrode/hole injection layer/hole transport layer/light emitting layer/electron transport layer/negative electrode”, “substrate/positive electrode/light emitting layer/electron transport layer/electron injection layer/negative electrode”, “substrate/positive electrode/hole transport layer/light emitting layer/electron injection layer/negative electrode”, “substrate/positive electrode/hole transport layer/light emitting layer/electron transport layer/negative electrode”, “substrate/positive electrode/hole injection layer/light emitting layer/electron injection layer/negative electrode”, “substrate/positive electrode/hole injection layer/light emitting layer/electron transport layer/negative electrode”, “substrate/positive electrode/light emitting layer/electron transport layer/negative electrode”, or “substrate/positive electrode/light emitting layer/electron injection layer/negative electrode”.

<Substrate in Organic Electroluminescent Element>

The substrate 101 serves as a support of the organic EL element 100, and usually, quartz, glass, metals, plastics, and the like are used therefor. The substrate 101 is formed into a plate shape, a film shape, or a sheet shape according to a purpose, and for example, a glass plate, a metal plate, a metal foil, a plastic film, and a plastic sheet are used. Among these examples, a glass plate and a plate made of a transparent synthetic resin such as polyester, polymethacrylate, polycarbonate, or polysulfone are preferable. For a glass substrate, soda lime glass, alkali-free glass, and the like are used. The thickness is only required to be a thickness sufficient for maintaining mechanical strength. Therefore, the thickness is only required to be 0.2 mm or more, for example. The upper limit value of the thickness is, for example, 2 mm or less, and preferably 1 mm or less. Regarding a material of glass, glass having fewer ions eluted from the glass is desirable, and therefore alkali-free glass is preferable. However, soda lime glass which has been subjected to barrier coating with SiO₂ or the like is also commercially available, and therefore this soda lime glass can be used. Furthermore, the substrate 101 may be provided with a gas barrier film such as a dense silicon oxide film on at least one surface in order to increase a gas barrier property. Particularly in a case of using a plate, a film, or a sheet made of a synthetic resin having a low gas barrier property as the substrate 101, a gas barrier film is preferably provided.

<Positive Electrode in Organic Electroluminescent Element>

The positive electrode 102 plays a role of injecting a hole into the light emitting layer 105. Incidentally, in a case where the hole injection layer 103 and/or the hole transport layer 104 are/is provided between the positive electrode 102 and the light emitting layer 105, a hole is injected into the light emitting layer 105 through these layers.

Examples of a material to form the positive electrode 102 include an inorganic compound and an organic compound. Examples of the inorganic compound include a metal (aluminum, gold, silver, nickel, palladium, chromium, and the like), a metal oxide (indium oxide, tin oxide, indium-tin oxide (ITO), indium-zinc oxide (IZO), and the like), a metal halide (copper iodide and the like), copper sulfide, carbon black, ITO glass, and Nesa glass. Examples of the organic compound include an electrically conductive polymer such as polythiophene such as poly(3-methylthiophene), polypyrrole, or polyaniline. In addition to these compounds, a material can be appropriately selected for use from materials used as a positive electrode of an organic EL element.

A resistance of a transparent electrode is not limited as long as a sufficient current can be supplied to light emission of a luminescent element. However, low resistance is desirable from a viewpoint of consumption power of the luminescent element. For example, an ITO substrate having a resistance of 300Ω/□ or less functions as an element electrode. However, a substrate having a resistance of about 10Ω/□ can be also supplied at present, and therefore it is particularly desirable to use a low resistance product having a resistance of, for example, 100 to 5Ω/□, preferably 50 to 5Ω/□. The thickness of an ITO can be arbitrarily selected according to a resistance value, but an ITO having a thickness of 50 to 300 nm is often used.

<Hole Injection Layer and Hole Transport Layer in Organic Electroluminescent Element>

The hole injection layer 103 plays a role of efficiently injecting a hole that migrates from the positive electrode 102 into the light emitting layer 105 or the hole transport layer 104. The hole transport layer 104 plays a role of efficiently transporting a hole injected from the positive electrode 102 or a hole injected from the positive electrode 102 through the hole injection layer 103 to the light emitting layer 105. The hole injection layer 103 and the hole transport layer 104 are each formed by laminating and mixing one or more kinds of hole injection/transport materials, or by a mixture of a hole injection/transport material and a polymer binder. Furthermore, a layer may be formed by adding an inorganic salt such as iron(III) chloride to the hole injection/transport materials.

A hole injecting/transporting substance needs to efficiently inject/transport a hole from a positive electrode between electrodes to which an electric field is applied, and preferably has high hole injection efficiency and transports an injected hole efficiently. For this purpose, a substance which has low ionization potential, large hole mobility, and excellent stability, and in which impurities that serve as traps are not easily generated at the time of manufacturing and at the time of use, is preferable.

As a material to form the hole injection layer 103 and the hole transport layer 104, any compound can be selected for use among compounds that have been conventionally used as charge transporting materials for holes, p-type semiconductors, and known compounds used in a hole injection layer and a hole transport layer of an organic EL element. Specific examples thereof include a heterocyclic compound including a carbazole derivative (N-phenylcarbazole, polyvinylcarbazole, and the like), a biscarbazole derivative such as bis(N-arylcarbazole) or bis(N-alkylcarbazole), a triarylamine derivative (a polymer having an aromatic tertiary amino in a main chain or a side chain, 1,1-bis(4-di-p-tolylaminophenyl)cyclohexane, N,N′-diphenyl-N,N′-di(3-methylphenyl)-4,4′-diaminobiphenyl, N,N′-diphenyl-N,N′-dinaphthyl-4,4′-diaminobiphenyl, N,N′-diphenyl-N,N′-di(3-methylphenyl)-4,4′-diphenyl-1,1′-diamine, N,N′-dinaphthyl-N,N′-diphenyl-4,4′-dphenyl-1,1′-diamine, N⁴,N⁴′-diphenyl-N⁴,N⁴′-bis(9-phenyl-9H-carbazol-3-yl)-[1,1′-biphenyl]-4,4′-diamine, N⁴,N⁴,N⁴′,N⁴′-tetra[1,1′-biphenyl]-4-yl)-[1,1′-biphenyl]-4,4′-diamine, a triphenylamine derivative such as 4,4′,4″-tris(3-methylphenyl(phenyl)amino)triphenylamine, a starburst amine derivative, and the like), a stilbene derivative, a phthalocyanine derivative (non-metal, copper phthalocyanine, and the like), a pyrazoline derivative, a hydrazone-based compound, a benzofuran derivative, a thiophene derivative, an oxadiazole derivative, a quinoxaline derivative (for example, 1,4,5,8,9,12-hexaazatriphenylene-2,3,6,7,10,11-hexacarbonitrile, and the like), and a porphyrin derivative, and a polysilane. Among the polymer-based materials, a polycarbonate, a styrene derivative, a polyvinylcarbazole, a polysilane, and the like having the above monomers in side chains are preferable. However, there is no particular limitation as long as a compound can form a thin film required for manufacturing a luminescent element, can inject a hole from a positive electrode, and can further transport a hole.

Furthermore, it is also known that electroconductivity of an organic semiconductor is strongly affected by doping into the organic semiconductor. Such an organic semiconductor matrix substance is formed of a compound having a good electron-donating property, or a compound having a good electron-accepting property. For doping with an electron-donating substance, a strong electron acceptor such as tetracyanoquinonedimethane (TCNQ) or 2,3,5,6-tetrafluorotetracyano-1,4-benzoquinonedimethane (F4TCNQ) is known (see, for example, “M. Pfeiffer, A. Beyer, T. Fritz, K. Leo, Appl. Phys. Lett., 73(22), 3202-3204 (1998)” and “J. Blochwitz, M. Pheiffer, T. Fritz, K. Leo, Appl. Phys. Lett., 73(6), 729-731 (1998)”). These compounds generate a so-called hole by an electron transfer process in an electron-donating type base substance (hole transporting substance). Electroconductivity of the base substance depends on the number and mobility of the holes fairly significantly. Known examples of a matrix substance having a hole transporting characteristic include a benzidine derivative (TPD and the like), a starburst amine derivative (TDATA and the like), and a specific metal phthalocyanine (particularly, zinc phthalocyanine (ZnPc) and the like) (JP 2005-167175 A).

<Light Emitting Layer in Organic Electroluminescent Element>

The light emitting layer 105 emits light by recombining a hole injected from the positive electrode 102 and an electron injected from the negative electrode 108 between electrodes to which an electric field is applied. A material to form the light emitting layer 105 is only required to be a compound which is excited by recombination between a hole and an electron and emits light (luminescent compound), and is preferably a compound which can form a stable thin film shape, and exhibits strong light emission (fluorescence) efficiency in a solid state. In the present invention, as a material for a light emitting layer, a host material and, for example, a polycyclic aromatic compound represented by the above general formula (1) as a dopant material can be used.

The light emitting layer may be formed of a single layer or a plurality of layers, and each layer is formed of a material for a light emitting layer (a host material and a dopant material). Each of the host material and the dopant material may be formed of a single kind, or a combination of a plurality of kinds. The dopant material may be included in the host material wholly or partially. Regarding a doping method, doping can be performed by a co-deposition method with a host material, or alternatively, a dopant material may be mixed in advance with a host material, and then vapor deposition may be carried out simultaneously.

The amount of use of the host material depends on the kind of the host material, and may be determined according to a characteristic of the host material. The reference of the amount of use of the host material is preferably from 50 to 99.999% by weight, more preferably from 80 to 99.95% by weight, and still more preferably from 90 to 99.9% by weight with respect to the total amount of a material for a light emitting layer.

The amount of use of the dopant material depends on the kind of the dopant material, and may be determined according to a characteristic of the dopant material. The reference of the amount of use of the dopant is preferably from 0.001 to 50% by weight, more preferably from 0.05 to 20% by weight, and still more preferably from 0.1 to 10% by weight with respect to the total amount of a material for a light emitting layer. The amount of use within the above range is preferable, for example, from a viewpoint of being able to prevent a concentration quenching phenomenon.

Examples of the host material include a fused ring derivative of anthracene, pyrene, dibenzochrysene, fluorene, or the like conventionally known as a luminous body, a bisstyryl derivative such as a bisstyrylanthracene derivative or a distyrylbenzene derivative, a tetraphenylbutadiene derivative, and a cyclopentadiene derivative. Particularly, an anthracene-based compound, a fluorene-based compound, and a dibenzochrysene-based compound are preferable.

<Anthracene-Based Compound>

The anthracene-based compound as a host is, for example, a compound represented by the following general formula (3).

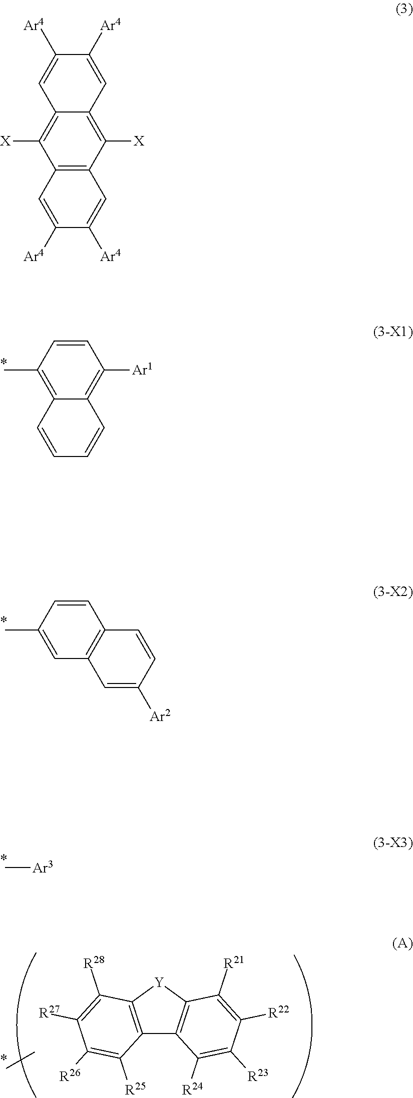

In general formula (3), X's each independently represent a group represented by the above formula (3-X1), (3-X2), or (3-X3), and the group represented by the formula (3-X1), (3-X2), or (3-X3) is bonded to the anthracene ring of formula (3) at the symbol *. Preferably, the two X's do not simultaneously represent a group represented by formula (3-X3). More preferably, the two X's do not simultaneously represent a group represented by formula (3-X2).

The naphthylene moiety in formula (3-X1) and formula (3-X2) may be fused with one benzene ring. A structure fused in this way is as follows.

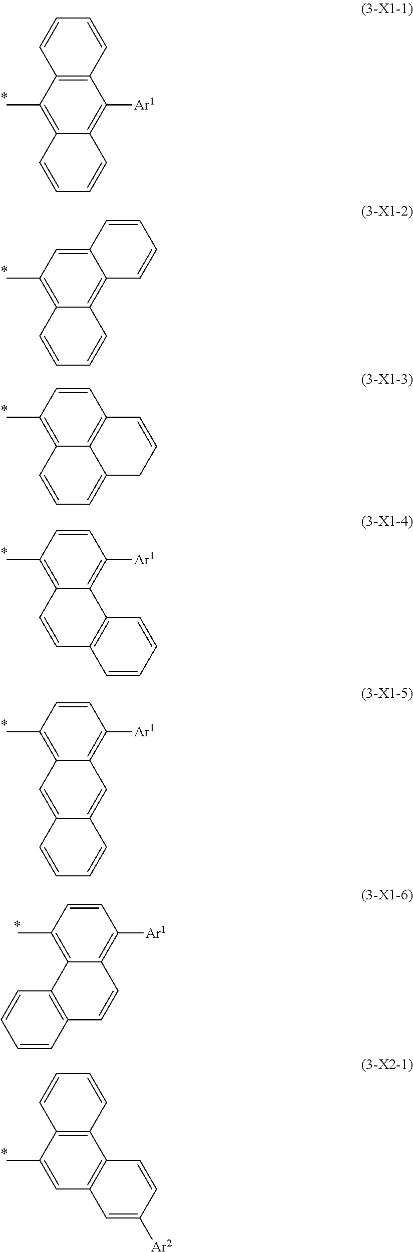

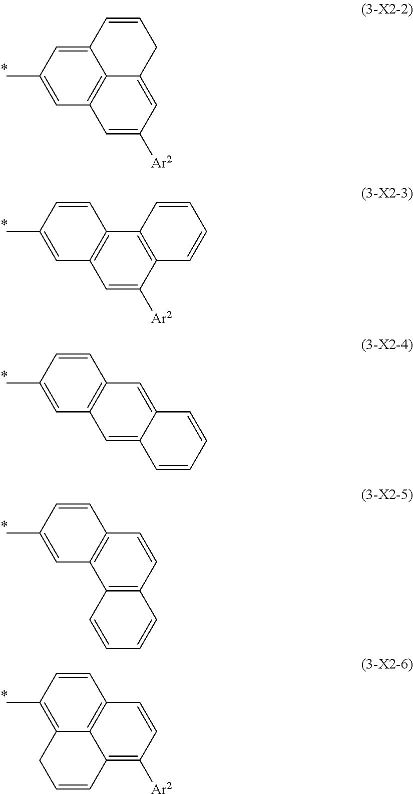

Ar¹ and Are each independently represent a hydrogen atom, phenyl, biphenylyl, terphenylyl, quaterphenylyl, naphthyl, phenanthryl, fluorenyl, benzofluorenyl, chrysenyl, triphenylenyl, pyrenylyl, or a group represented by the above formula (A) (including a carbazolyl group, a benzocarbazolyl group, and a phenyl-substituted carbazolyl group). Incidentally, in a case where Ar¹ or Are is a group represented by formula (A), the group represented by formula (A) is bonded to a naphthalene ring in formula (3-X1) or (3-X2) at the symbol *.

Ar³ represents phenyl, biphenylyl, terphenylyl, quaterphenylyl, naphthyl, phenanthryl, fluorenyl, benzofluorenyl, chrysenyl, triphenylenyl, pyrenylyl, or a group represented by the above formula (A) (including a carbazolyl group, a benzocarbazolyl group, and a phenyl-substituted carbazolyl group). Incidentally, in a case where Ar³ is a group represented by formula (A), the group represented by formula (A) is bonded to a single bond represented by the straight line in formula (3-X3) at the symbol *. That is, the anthracene ring of formula (3) and the group represented by formula (A) are directly bonded to each other.

Furthermore, Ar³ may have a substituent, and at least one hydrogen atom in Ar³ may be further substituted by phenyl, biphenylyl, terphenylyl, naphthyl, phenanthryl, fluorenyl, chrysenyl, triphenylenyl, pyrenylyl, or a group represented by the above formula (A) (including a carbazolyl group and a phenyl-substituted carbazolyl group). Incidentally, in a case where the substituent included in Ar³ is a group represented by formula (A), the group represented by formula (A) is bonded to Ar³ in formula (3-X3) at the symbol *.

Ar⁴'s each independently represent a hydrogen atom, phenyl, biphenylyl, terphenylyl, naphthyl, or a silyl substituted by an alkyl having 1 to 4 carbon atoms (methyl, ethyl, t-butyl, and the like).

Furthermore, a hydrogen atom in a chemical structure of the anthracene-based compound represented by general formula (3) may be substituted by a group represented by the above formula (A). In a case where the hydrogen atom is substituted by the group represented by formula (A), the group represented by formula (A) is substituted by at least one hydrogen atom in the compound represented by formula (3) at the symbol *.

In the above formula (A), Y represents —O—, —S—, or >N—R²⁹, R²¹ to R²⁸ each independently represent a hydrogen atom, an optionally substituted alkyl, an optionally substituted cycloalkyl an optionally substituted aryl, an optionally substituted heteroaryl, an optionally substituted alkoxy, an optionally substituted aryloxy, an optionally substituted arylthio, a trialkylsilyl, a tricycloalkylsilyl, an optionally substituted amino, a halogen atom, hydroxy, or cyano, adjacent groups among R²¹ to R²⁸ may be bonded to each other to form a hydrocarbon ring, an aryl ring, or a heteroaryl ring, and R²⁹ represents a hydrogen atom or an optionally substituted aryl.

Adjacent groups among R²¹ to R²⁸ may be bonded to each other to form a hydrocarbon ring, an aryl ring, or a heteroaryl ring. Examples of a case of not forming a ring include a group represented by the following formula (A-1). Examples of a case of forming a ring include groups represented by the following formulas (A-2) to (A-14). Note that at least one hydrogen atom in a group represented by any one of formulas (A-1) to (A-14) may be substituted by an alkyl, a cycloalkyl, an aryl, a heteroaryl, an alkoxy, an aryloxy, an arylthio, a trialkylsilyl, a tricycloalkylsilyl, a diaryl-substituted amino, a diheteroaryl-substituted amino, an arylheteroaryl-substituted amino, a halogen atom, hydroxy, or cyano.

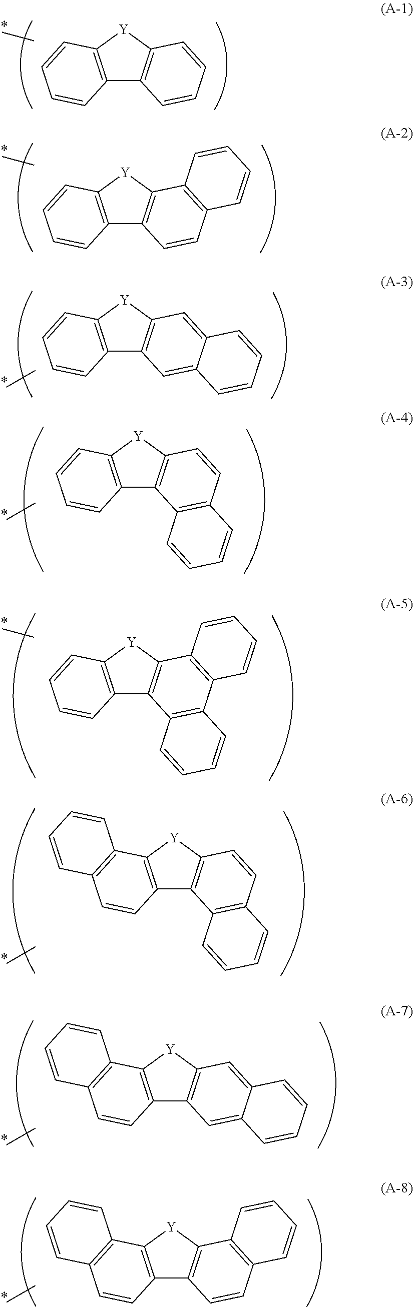

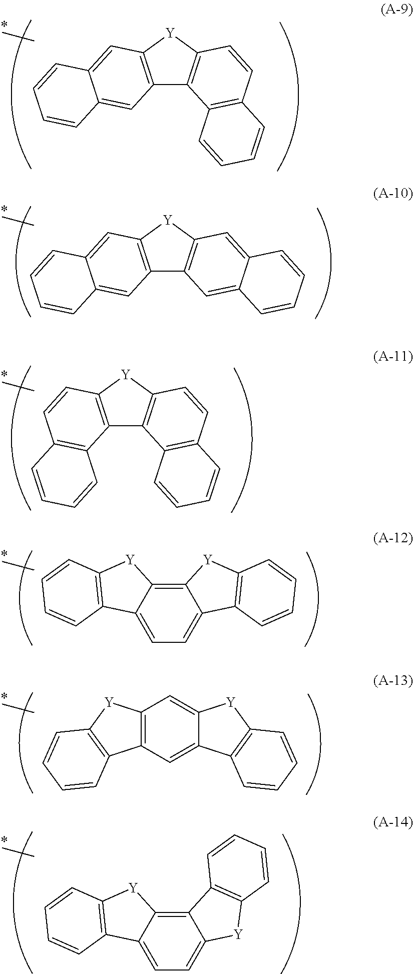

Furthermore, all or a part of the hydrogen atoms in the chemical structure of an anthracene-based compound represented by general formula (3) may be deuterium atoms.

<Fluorene-Based Compound>

Basically, a compound represented by general formula (4) functions as a host.

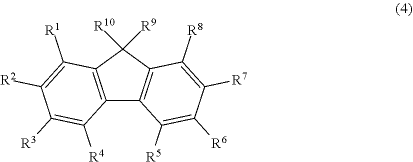

In the above formula (4),

R¹ to R¹⁰ each independently represent a hydrogen atom, an aryl, a heteroaryl (the heteroaryl may be bonded to a fluorene skeleton in the above formula (4) via a linking group), a diarylamino, a diheteroarylamino, an arylheteroarylamino, an alkyl, a cycloalkyl, an alkenyl, an alkoxy, or an aryloxy, in which at least one hydrogen atom may be substituted by an aryl, a heteroaryl, an alkyl, or a cycloalkyl,

R¹ and R², R² and R³, R³ and R⁴, R⁵ and R⁶, R⁶ and R⁷, R⁷ and R⁸, and R⁹ and R¹⁰ may be each independently bonded to each other to form a fused ring or a spiro ring, at least one hydrogen atom in the ring thus formed may be substituted by an aryl, a heteroaryl (the heteroaryl may be bonded to the ring thus formed via a linking group), a diarylamino, a diheteroarylamino, an arylheteroarylamino, an alkyl, a cycloalkyl, an alkenyl, an alkoxy, or an aryloxy, in which at least one hydrogen atom in these may be substituted by an aryl, a heteroaryl, an alkyl, or a cycloalkyl, and

at least one hydrogen atom in the compound represented by formula (4) may be substituted by a halogen atom, cyano, or a deuterium atom.

For the details of each group in the definition of the above formula (4), the above description for the polycyclic aromatic compound of formula (1) can be cited.

Examples of the alkenyl in R¹ to R¹⁰ include an alkenyl having 2 to 30 carbon atoms. An alkenyl having 2 to 20 carbon atoms is preferable, an alkenyl having 2 to 10 carbon atoms is more preferable, an alkenyl having 2 to 6 carbon atom is still more preferable, and an alkenyl having 2 to 4 carbon atoms is particularly preferable. The alkenyl is preferably vinyl, 1-propenyl, 2-propenyl, 1-butenyl, 2-butenyl, 3-butenyl, 1-pentenyl, 2-pentenyl, 3-pentenyl, 4-pentenyl, 1-hexenyl, 2-hexenyl, 3-hexenyl, 4-hexenyl, or 5-hexenyl.

Note that specific examples of the heteroaryl include a monovalent group having a structure represented by the following formula (4-Ar1), (4-Ar2), (4-Ar3), (4-Ar4), or (4-Ar5).

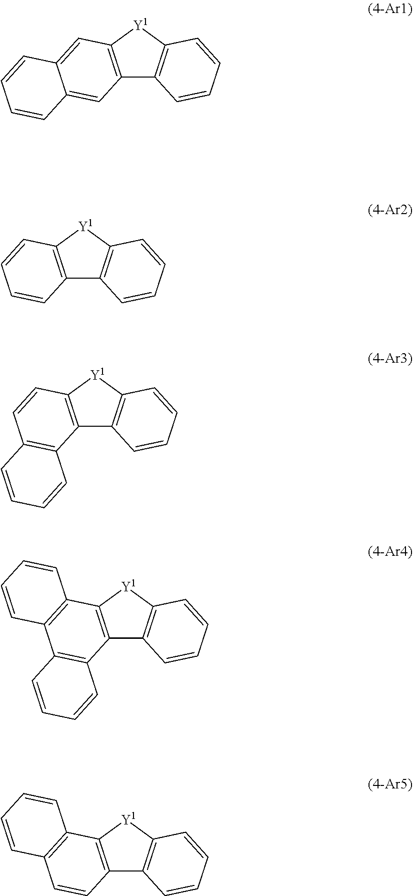

In formulas (4-Ar1) to (4-Ar5), Y¹'s each independently represent O, S, or N—R, while R represents phenyl, biphenylyl, naphthyl, anthracenyl, or a hydrogen atom, and at least one hydrogen atom in the structures of the above formulas (4-Ar1) to (4-Ar5) may be substituted by phenyl, biphenylyl, naphthyl, anthracenyl, phenanthrenyl, methyl, ethyl, propyl, or butyl.

These heteroaryls may be bonded to the fluorene skeleton in the above formula (4) via a linking group. That is, the fluorene skeleton in formula (4) and the above heteroaryl may be bound not only directly but also via a linking group therebetween. Examples of the linking group include phenylene, biphenylene, naphthylene, anthracenylene, methylene, ethylene, —OCH₂CH₂—, —CH₂CH₂O—, and —OCH₂CH₂O—.

Furthermore, R¹ and R², R² and R³, R³ and R⁴, R⁵ and R⁶, R⁶ and R⁷, or R⁷ and R⁸ in formula (4) may be each independently bonded to each other to form a fused ring, and R⁹ and R¹⁰ may be bonded to each other to form a spiro ring. The fused ring formed by R¹ to R⁸ is a ring fused to the benzene ring in formula (4), and is an aliphatic ring or an aromatic ring. The fused ring is preferably an aromatic ring, and examples of the structure thereof including the benzene ring in formula (4) include a naphthalene ring and a phenanthrene ring. The spiro ring formed by R⁹ and R¹⁰ is a ring spiro-bonded to the 5-membered ring in formula (4), and is an aliphatic ring or an aromatic ring. The spiro ring is preferably an aromatic ring, and examples thereof include a fluorene ring.

The compound represented by general formula (4) is preferably a compound represented by the following formula (4-1), (4-2), or (4-3). The compound represented by formula (4-1) is a compound in which a benzene ring formed by bonding between R¹ and R² in general formula (4) is fused. The compound represented by formula (4-2) is a compound in which a benzene ring formed by bonding between R³ and R⁴ in general formula (4) is fused. The compound represented by formula (4-3) is a compound in which any two of R¹ to R⁸ in general formula (4) are not bonded to each other.

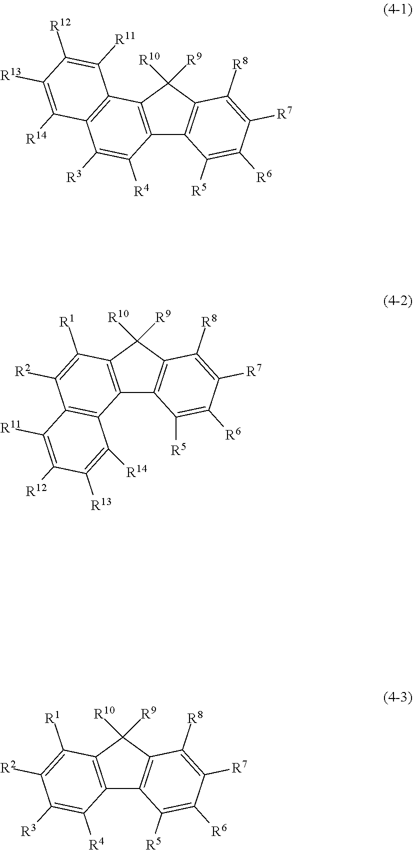

The definitions of R¹ to R¹⁰ in formulas (4-1), (4-2), and (4-3) are the same as those of the corresponding R¹ to R¹⁰ in formula (4). The definitions of R¹¹ to R¹⁴ in formulas (4-1) and (4-2) are the same as those of R¹ to R¹⁰ in formula (4).

The compound represented by general formula (4) is more preferably a compound represented by the following formula (4-1A), (4-2A), or (4-3A), which is a compound in which R⁹ and R¹⁰ are bonded to each other to form a spiro-fluorene ring in formula (4-1), (4-2), or (4-3).

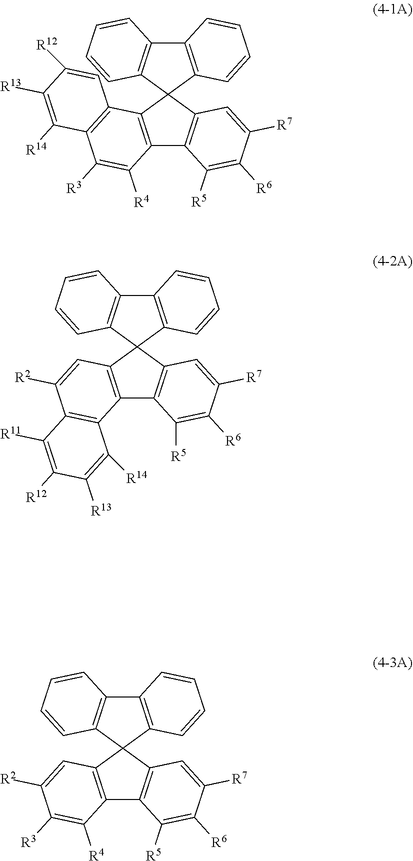

The definitions of R² to R⁷ in formulas (4-1A), (4-2A), and (4-3A) are the same as those of the corresponding R² to R⁷ in formulas (4-1), (4-2), and (4-3). The definitions of R¹¹ to R¹⁴ in formulas (4-1A) and (4-2A) are the same as those of R¹¹ to R¹⁴ in formulas (4-1) and (4-2).

Furthermore, all or a part of hydrogen atoms in the compound represented by formula (4) may be substituted by halogen atoms, cyanos, or deuterium atoms.

<Dibenzochrysene-Based Compound>

A dibenzochrysene-based compound as a host is, for example, a compound represented by the following general formula (5).

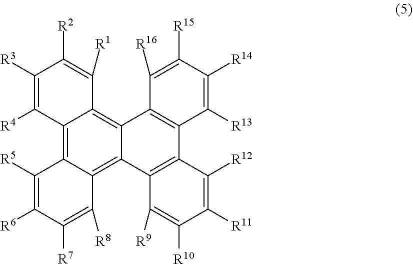

In the above formula (5),

R¹ to R¹⁶ each independently represent a hydrogen atom, an aryl, a heteroaryl (the heteroaryl may be bonded to a dibenzochrysene skeleton in the above formula (5) via a linking group), a diarylamino, a diheteroarylamino, an arylheteroarylamino, an alkyl, a cycloalkyl, an alkenyl, an alkoxy, or an aryloxy, in which at least one hydrogen atom may be substituted by an aryl, a heteroaryl, an alkyl, or a cycloalkyl,

adjacent groups among R¹ to R¹⁶ may be bonded to each other to form a fused ring, at least one hydrogen atom in the ring thus formed may be substituted by an aryl, a heteroaryl (the heteroaryl may be bonded to the ring thus formed via a linking group), a diarylamino, a diheteroarylamino, an arylheteroarylamino, an alkyl, a cycloalkyl, an alkenyl, an alkoxy, or an aryloxy, in which

at least one hydrogen atom in these may be substituted by an aryl, a heteroaryl, an alkyl, or a cycloalkyl, and at least one hydrogen atom in the compound represented by formula (5) may be substituted by a halogen atom, cyano, or a deuterium atom.

For the details of each group in the definition of the above formula (5), the above description for the polycyclic aromatic compound of formula (1) can be cited.

Examples of the alkenyl in the definition of the above formula (5) include an alkenyl having 2 to 30 carbon atoms. An alkenyl having 2 to 20 carbon atoms is preferable, an alkenyl having 2 to 10 carbon atoms is more preferable, an alkenyl having 2 to 6 carbon atom is still more preferable, and an alkenyl having 2 to 4 carbon atoms is particularly preferable. The alkenyl is preferably vinyl, 1-propenyl, 2-propenyl, 1-butenyl, 2-butenyl, 3-butenyl, 1-pentenyl, 2-pentenyl, 3-pentenyl, 4-pentenyl, 1-hexenyl, 2-hexenyl, 3-hexenyl, 4-hexenyl, or 5-hexenyl.

Note that specific examples of the heteroaryl include a monovalent group having a structure represented by the following formula (5-Ar1), (5-Ar2), (5-Ar3), (5-Ar4), or (5-Ar5).

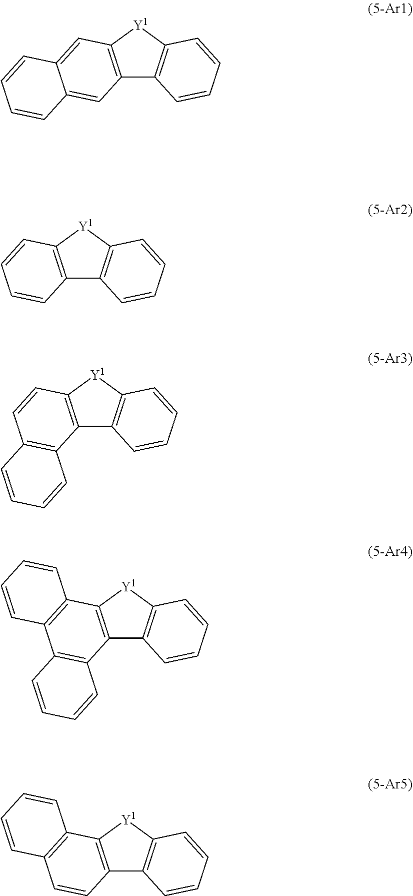

In formulas (5-Ar1) to (5-Ar5), Y¹'s each independently represent O, S, or N—R, while R represents phenyl, biphenylyl, naphthyl, anthracenyl, or a hydrogen atom, and at least one hydrogen atom in the structures of the above formulas (5-Ar1) to (5-Ar5) may be substituted by phenyl, biphenylyl, naphthyl, anthracenyl, phenanthrenyl, methyl, ethyl, propyl, or butyl.

These heteroaryls may be bonded to the dibenzochrysene skeleton in the above formula (5) via a linking group. That is, the dibenzochrysene skeleton in formula (5) and the above heteroaryl may be bound not only directly but also via a linking group therebetween. Examples of the linking group include phenylene, biphenylene, naphthylene, anthracenylene, methylene, ethylene, —OCH₂CH₂—, —CH₂CH₂O—, and —OCH₂CH₂O—.

The compound represented by general formula (5) is preferably a compound in which R¹, R⁴, R⁵, R⁸, R⁹, R¹², R¹³, and R¹⁶ represent hydrogen atoms. In this case, R², R³, R⁶, R⁷, R¹⁰, R¹¹, R¹⁴, and R¹⁵ in formula (5) preferably each independently represent a hydrogen atom, phenyl, biphenylyl, naphthyl, anthracenyl, phenanthrenyl, a monovalent group having a structure of the above formula (5-Ar1), (5-Ar2), (5-Ar3), (5-Ar4), or (5-Ar5) (the monovalent group having the structure may be bonded to the dibenzochrysene skeleton in the above formula (5) via phenylene, biphenylene, naphthylene, anthracenylene, methylene, ethylene, —OCH₂CH₂—, —CH₂CH₂O—, or —OCH₂CH₂O—), methyl, ethyl, propyl, or butyl.

The compound represented by general formula (5) is more preferably a compound in which R¹, R², R⁴, R⁵, R⁷, R⁸, R⁹, R¹⁰, R¹², R¹³, R¹⁵, and R¹⁶ represent hydrogen atoms. In this case, at least one (preferably one or two, more preferably one) of R³, R⁶, R¹¹, and R¹⁴ in formula (5) represents a monovalent group having a structure of the above formula (5-Ar1), (5-Ar2), (5-Ar3), (5-Ar4), or (5-Ar5) via a single bond, phenylene, biphenylene, naphthylene, anthracenylene, methylene, ethylene, —OCH₂CH₂—, —CH₂CH₂O—, or —OCH₂CH₂O—,

the groups other than the above at least one (that is, groups at positions other than the position substituted by a monovalent group having the above structure) each represent a hydrogen atom, phenyl, biphenylyl, naphthyl, anthracenyl, methyl, ethyl, propyl, or butyl, in which at least one hydrogen atom may be substituted by phenyl, biphenylyl, naphthyl, anthracenyl, methyl, ethyl, propyl, or butyl.

Furthermore, in a case where a monovalent group having the structure represented by any one of the above formulas (5-Ar1) to the formula (5-Ar5) is selected as R², R³, R⁶, R⁷, R¹⁰, R¹¹, R¹⁴, or R¹⁵ in formula (5), at least one hydrogen atom in the structure may be bonded to any one of R¹ to R¹⁶ in formula (5) to form a single bond.

<Electron Injection Layer and Electron Transport Layer in Organic Electroluminescent Element>

The electron injection layer 107 plays a role of efficiently injecting an electron migrating from the negative electrode 108 into the light emitting layer 105 or the electron transport layer 106. The electron transport layer 106 plays a role of efficiently transporting an electron injected from the negative electrode 108, or an electron injected from the negative electrode 108 through the electron injection layer 107 to the light emitting layer 105. The electron transport layer 106 and the electron injection layer 107 are each formed by laminating and mixing one or more kinds of electron transport/injection materials, or by a mixture of an electron transport/injection material and a polymeric binder.

An electron injection/transport layer is a layer that manages injection of an electron from a negative electrode and transport of an electron, and is preferably a layer that has high electron injection efficiency and can efficiently transport an injected electron. For this purpose, a substance which has high electron affinity, large electron mobility, and excellent stability, and in which impurities that serve as traps are not easily generated at the time of manufacturing and at the time of use, is preferable. However, when a transport balance between a hole and an electron is considered, in a case where the electron injection/transport layer mainly plays a role of efficiently preventing a hole coming from a positive electrode from flowing toward a negative electrode side without being recombined, even if electron transporting ability is not so high, an effect of enhancing luminous efficiency is equal to that of a material having high electron transporting ability. Therefore, the electron injection/transport layer according to the present embodiment may also include a function of a layer that can efficiently prevent migration of a hole.

A material (electron transport material) for forming the electron transport layer 106 or the electron injection layer 107 can be arbitrarily selected for use from compounds conventionally used as electron transfer compounds in a photoconductive material, and known compounds that are used in an electron injection layer and an electron transport layer of an organic EL element.

A material used in an electron transport layer or an electron injection layer preferably includes at least one selected from a compound formed of an aromatic ring or a heteroaromatic ring including one or more kinds of atoms selected from carbon, hydrogen, oxygen, sulfur, silicon, and phosphorus atoms, a pyrrole derivative and a fused ring derivative thereof, and a metal complex having an electron-accepting nitrogen atom. Specific examples of the material include a fused ring-based aromatic ring derivative of naphthalene, anthracene, or the like, a styryl-based aromatic ring derivative represented by 4,4′-bis(diphenylethenyl)biphenyl, a perinone derivative, a coumarin derivative, a naphthalimide derivative, a quinone derivative such as anthraquinone or diphenoquinone, a phosphorus oxide derivative, a carbazole derivative, and an indole derivative. Examples of the metal complex having an electron-accepting nitrogen atom include a hydroxyazole complex such as a hydroxyphenyloxazole complex, an azomethine complex, a tropolone metal complex, a flavonol metal complex, and a benzoquinoline metal complex. These materials are used singly, but may also be used in a mixture with other materials.

Furthermore, specific examples of other electron transfer compounds include a pyridine derivative, a naphthalene derivative, an anthracene derivative, a phenanthroline derivative, a perinone derivative, a coumarin derivative, a naphthalimide derivative, an anthraquinone derivative, a diphenoquinone derivative, a diphenylquinone derivative, a perylene derivative, an oxadiazole derivative (1,3-bis[(4-t-butylphenyl)-1,3,4-oxadiazolyl]phenylene and the like), a thiophene derivative, a triazole derivative (N-naphthyl-2,5-diphenyl-1,3,4-triazole and the like), a thiadiazole derivative, a metal complex of an oxine derivative, a quinolinol-based metal complex, a quinoxaline derivative, a polymer of a quinoxaline derivative, a benzazole compound, a gallium complex, a pyrazole derivative, a perfluorinated phenylene derivative, a triazine derivative, a pyrazine derivative, a benzoquinoline derivative (2,2′-bis(benzo[h]quinolin-2-yl)-9,9′-spirobifluorene and the like), an imidazopyridine derivative, a borane derivative, a benzimidazole derivative (tris(N-phenylbenzimidazol-2-yl)benzene and the like), a benzoxazole derivative, a benzothiazole derivative, a quinoline derivative, an oligopyridine derivative such as terpyridine, a bipyridine derivative, a terpyridine derivative (1,3-bis(4′-(2,2′:6′2″-terpyridinyl))benzene and the like), a naphthyridine derivative (bis(1-naphthyl)-4-(1,8-naphthyridin-2-yl)phenylphosphine oxide and the like), an aldazine derivative, a carbazole derivative, an indole derivative, a phosphorus oxide derivative, and a bisstyryl derivative.

Furthermore, a metal complex having an electron-accepting nitrogen atom can also be used, and examples thereof include a quinolinol-based metal complex, a hydroxyazole complex such as a hydroxyphenyloxazole complex, an azomethine complex, a tropolone-metal complex, a flavonol-metal complex, and a benzoquinoline-metal complex.

The materials described above are used singly, but may also be used in a mixture with other materials.

Among the above materials, a borane derivative, a pyridine derivative, a fluoranthene derivative, a BO-based derivative, an anthracene derivative, a benzofluorene derivative, a phosphine oxide derivative, a pyrimidine derivative, a carbazole derivative, a triazine derivative, a benzimidazole derivative, a phenanthroline derivative, and a quinolinol-based metal complex are preferable.

<Borane Derivative>

The borane derivative is, for example, a compound represented by the following general formula (ETM-1), and specifically disclosed in JP 2007-27587 A.

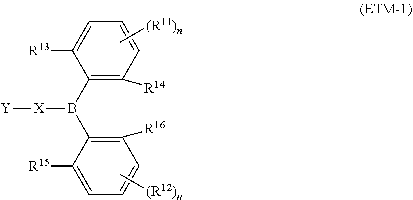

In the above formula (ETM-1), R¹¹ and R¹² each independently represent at least one of a hydrogen atom, an alkyl, a cycloalkyl, an optionally substituted aryl, a substituted silyl, an optionally substituted nitrogen-containing heterocyclic ring, and cyano, R¹³ to R¹⁶ each independently represent an optionally substituted alkyl, an optionally substituted cycloalkyl or an optionally substituted aryl, X represents an optionally substituted arylene, Y represents an optionally substituted aryl having 16 or fewer carbon atoms, a substituted boryl, or an optionally substituted carbazolyl, and n's each independently represent an integer of 0 to 3. Furthermore, examples of a substituent in a case of being “optionally substituted” or “substituted” include an aryl, a heteroaryl, an alkyl, and a cycloalkyl.

Among compounds represented by the above general formula (ETM-1), a compound represented by the following general formula (ETM-1-1) and a compound represented by the following general formula (ETM-1-2) are preferable.

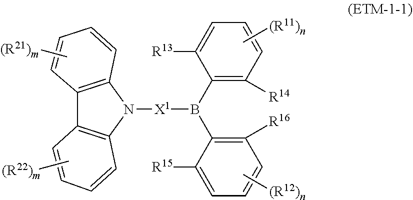

In formula (ETM-1-1), R¹¹ and R¹² each independently represent at least one of a hydrogen atom, an alkyl, a cycloalkyl, an optionally substituted aryl, a substituted silyl, an optionally substituted nitrogen-containing heterocyclic ring, and cyano, R¹³ to R¹⁶ each independently represent an optionally substituted alkyl, an optionally substituted cycloalkyl or an optionally substituted aryl, R²¹ and R²² each independently represent at least one of a hydrogen atom, an alkyl, a cycloalkyl, an optionally substituted aryl, a substituted silyl, an optionally substituted nitrogen-containing heterocyclic ring, and cyano, X¹ represents an optionally substituted arylene having 20 or fewer carbon atoms, n's each independently represent an integer of 0 to 3, and m's each independently represent an integer of 0 to 4. Furthermore, examples of a substituent in a case of being “optionally substituted” or “substituted” include an aryl, a heteroaryl, an alkyl, and a cycloalkyl.

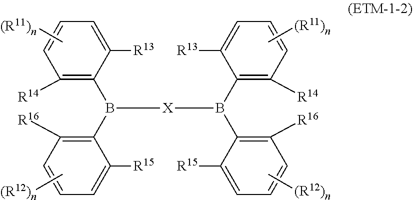

In formula (ETM-1-2), R¹¹ and R¹² each independently represent at least one of a hydrogen atom, an alkyl, a cycloalkyl, an optionally substituted aryl, a substituted silyl, an optionally substituted nitrogen-containing heterocyclic ring, and cyano, R¹³ to R¹⁶ each independently represent an optionally substituted alkyl, an optionally substituted cycloalkyl or an optionally substituted aryl, X¹ represents an optionally substituted arylene having 20 or fewer carbon atoms, and n's each independently represent an integer of 0 to 3. Furthermore, examples of a substituent in a case of being “optionally substituted” or “substituted” include an aryl, a heteroaryl, an alkyl, and a cycloalkyl.

Specific examples of X¹ include divalent groups represented by the following formulas (X-1) to (X-9).

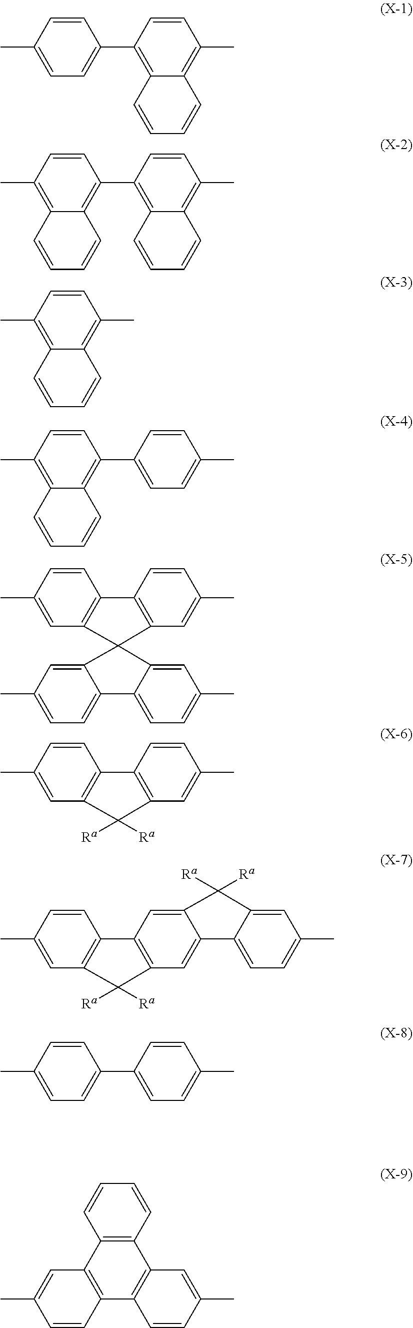

(In each formula, R^{a}'s each independently represent an alkyl group, a cycloalkyl group or an optionally substituted phenyl group.)

Specific examples of this borane derivative include the following compounds.

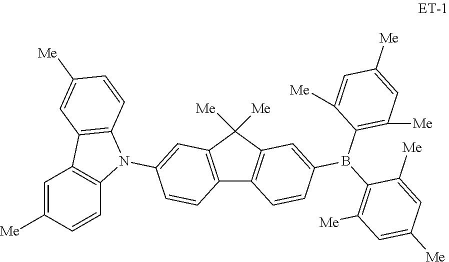 [SMILES: Cc1cc(C)c(B(c2ccc3c(c2)C(C)(C)c2cc(-n4c5ccc(C)cc5c5cc(C)ccc54)ccc2-3)c2c(C)cc(C)cc2C)c(C)c1]

This borane derivative can be manufactured using known raw materials and known synthesis methods.

<Pyridine Derivative>

A pyridine derivative is, for example, a compound represented by the following formula (ETM-2), and preferably a compound represented by formula (ETM-2-1) or (ETM-2-2).

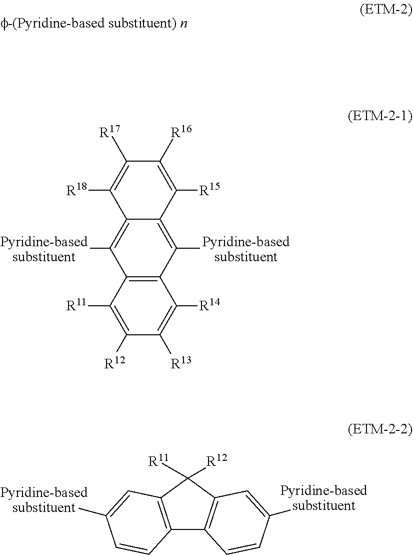

φ represents an n-valent aryl ring (preferably, an n-valent benzene ring, naphthalene ring, anthracene ring, fluorene ring, benzofluorene ring, phenalene ring, phenanthrene ring, or triphenylene ring), and n represents an integer of 1 to 4.

In the above formula (ETM-2-1), R¹¹ to R¹⁸ each independently represent a hydrogen atom, an alkyl (preferably, an alkyl having 1 to 24 carbon atoms), a cycloalkyl (preferably, a cycloalkyl having 3 to 12 carbon atoms), or an aryl (preferably, an aryl having 6 to 30 carbon atoms).

In the above formula (ETM-2-2), R¹¹ and R¹² each independently represent a hydrogen atom, an alkyl (preferably, an alkyl having 1 to 24 carbon atoms), a cycloalkyl (preferably, a cycloalkyl having 3 to 12 carbon atoms), or an aryl (preferably, an aryl having 6 to 30 carbon atoms), and R¹¹ and R¹² may be bonded to each other to form a ring.

In each formula, the “pyridine-based substituent” is any one of the following formulas (Py-1) to (Py-15), and the pyridine-based substituents may be each independently substituted by an alkyl having 1 to 4 carbon atoms. Furthermore, the pyridine-based substituent may be bonded to φ, an anthracene ring, or a fluorene ring in each formula via a phenylene group or a naphthylene group.

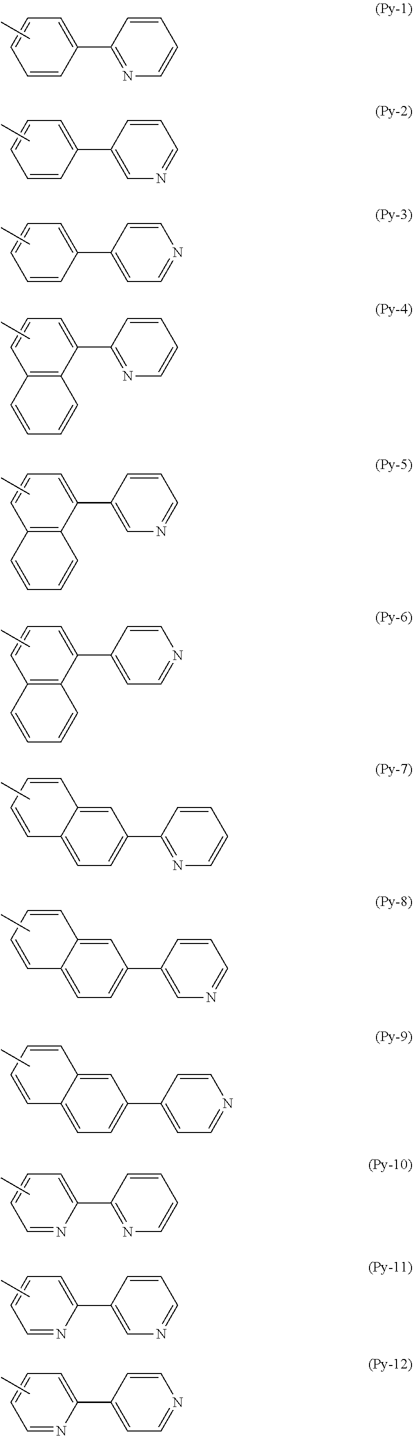

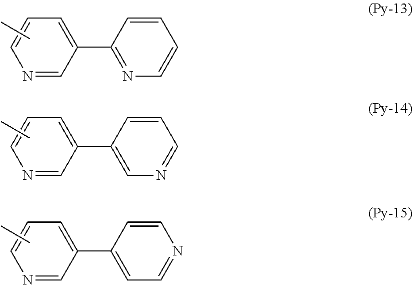

The pyridine-based substituent is any one of the above-formulas (Py-1) to (Py-15). However, among these formulas, the pyridine-based substituent is preferably any one of the following formulas (Py-21) to (Py-44).

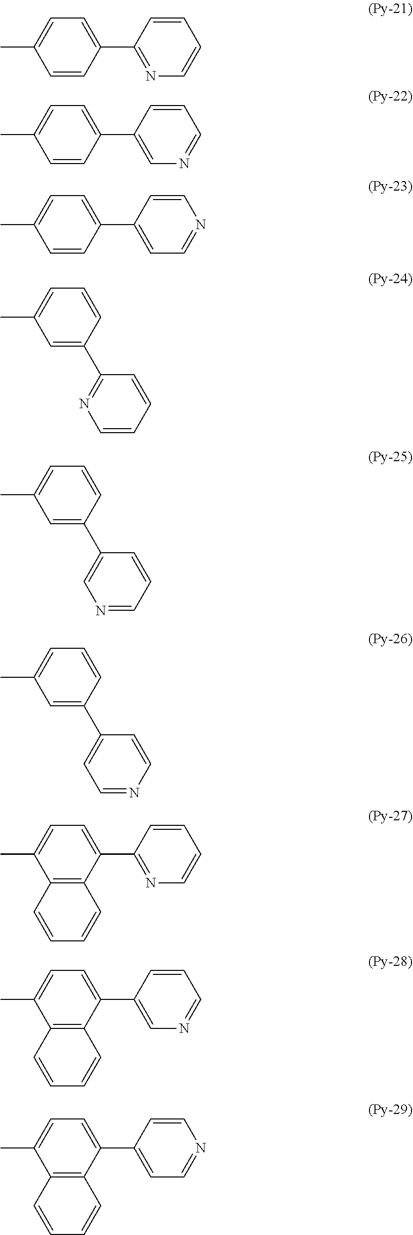

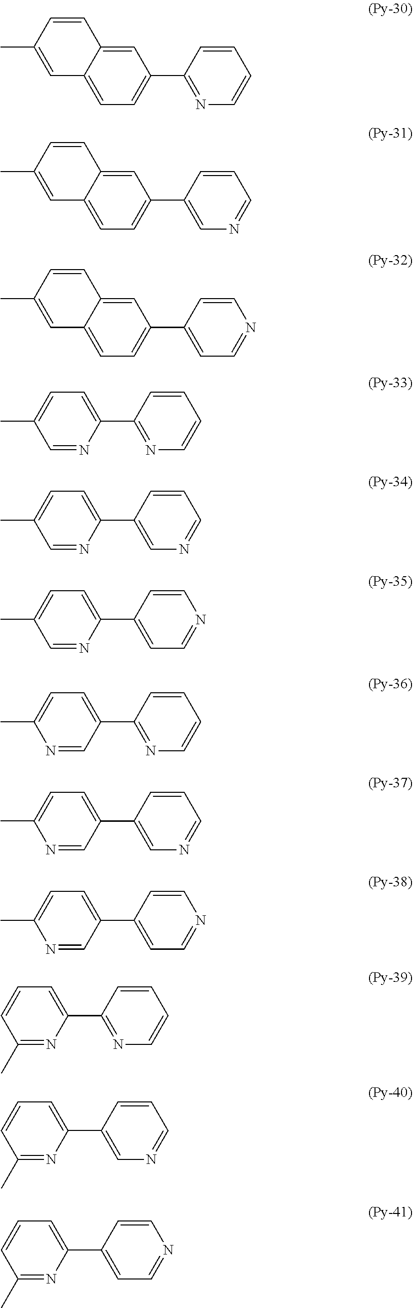

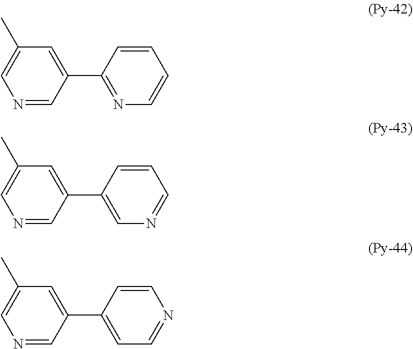

At least one hydrogen atom in each pyridine derivative may be substituted by a deuterium atom. Furthermore, one of the two “pyridine-based substituents” in the above formulas (ETM-2-1) and (ETM-2-2) may be substituted by an aryl.

The “alkyl” in R¹¹ to R¹⁸ may be either linear or branched, and examples thereof include a linear alkyl having 1 to 24 carbon atoms and a branched alkyl having 3 to 24 carbon atoms. A preferable “alkyl” is an alkyl having 1 to 18 carbon atoms (branched alkyl having 3 to 18 carbon atoms). A more preferable “alkyl” is an alkyl having 1 to 12 carbons (branched alkyl having 3 to 12 carbons). A still more preferable “alkyl” is an alkyl having 1 to 6 carbon atoms (branched alkyl having 3 to 6 carbon atoms). A particularly preferable “alkyl” is an alkyl having 1 to 4 carbon atoms (branched alkyl having 3 to 4 carbon atoms).

Specific examples of the “alkyl” include methyl, ethyl, n-propyl, isopropyl, n-butyl, isobutyl, s-butyl, t-butyl, n-pentyl, isopentyl, neopentyl, t-pentyl, n-hexyl, 1-methylpentyl, 4-methyl-2-pentyl, 3,3-dimethylbutyl, 2-ethylbutyl, n-heptyl, 1-methylhexyl, n-octyl, t-octyl, 1-methylheptyl, 2-ethylhexyl, 2-propylpentyl, n-nonyl, 2,2-dimethylheptyl, 2,6-dimethyl-4-heptyl, 3,5,5-trimethylhexyl, n-decyl, n-undecyl, 1-methyldecyl, n-dodecyl, n-tridecyl, 1-hexylheptyl, n-tetradecyl, n-pentadecyl, n-hexadecyl, n-heptadecyl, n-octadecyl, and n-eicosyl.

As the alkyl having 1 to 4 carbon atoms by which the pyridine-based substituent is substituted, the above description of the alkyl can be cited.

Examples of the “cycloalkyl” in R¹¹ to R¹⁸ include a cycloalkyl having 3 to 12 carbon atoms. A preferable “cycloalkyl” is a cycloalkyl having 3 to 10 carbons. A more preferable “cycloalkyl” is a cycloalkyl having 3 to 8 carbon atoms. A still more preferable “cycloalkyl” is a cycloalkyl having 3 to 6 carbon atoms.

Specific examples of the “cycloalkyl” include cyclopropyl, cyclobutyl, cyclopentyl, cyclohexyl, methylcyclopentyl, cycloheptyl, methylcyclohexyl, cyclooctyl, and dimethylcyclohexyl.

As the cycloalkyl having 5 to 10 carbon atoms by which the pyridine-based substituent is substituted, the above description of the cycloalkyl can be cited.

As the “aryl” in R¹¹ to R¹⁸, a preferable aryl is an aryl having 6 to 30 carbon atoms, a more preferable aryl is an aryl having 6 to 18 carbon atoms, a still more preferable aryl is an aryl having 6 to 14 carbon atoms, and a particularly preferable aryl is an aryl having 6 to 12 carbon atoms.

Specific examples of the “aryl having 6 to 30 carbon atoms” include phenyl which is a monocyclic aryl; (1-,2-) naphthyl which is a fused bicyclic aryl; acenaphthylene-(1-,3-,4-,5-)yl, a fluorene-(1-,2-,3-,4-,9-)yl, phenalene-(1-, 2-)yl, and (1-,2-,3-,4-,9-)phenanthryl which are fused tricyclic aryls; triphenylene-(1-, 2-)yl, pyrene-(1-,2-, 4-)yl, and naphthacene-(1-, 2-, 5-)yl which are fused tetracyclic aryls; and perylene-(1-,2-,3-)yl and pentacene-(1-, 2-, 5-, 6-)yl which are fused pentacyclic aryls.

Preferable examples of the “aryl having 6 to 30 carbon atoms” include a phenyl, a naphthyl, a phenanthryl, a chrysenyl, and a triphenylenyl. More preferable examples thereof include a phenyl, a 1-naphthyl, a 2-naphthyl, and a phenanthryl. Particularly preferable examples thereof include a phenyl, a 1-naphthyl, and a 2-naphthyl.

R¹¹ and R¹² in the above formula (ETM-2-2) may be bonded to each other to form a ring. As a result, cyclobutane, cyclopentane, cyclopentene, cyclopentadiene, cyclohexane, fluorene, indene, or the like may be spiro-bonded to a 5-membered ring of a fluorene skeleton.

Specific examples of this pyridine derivative include the following compounds.

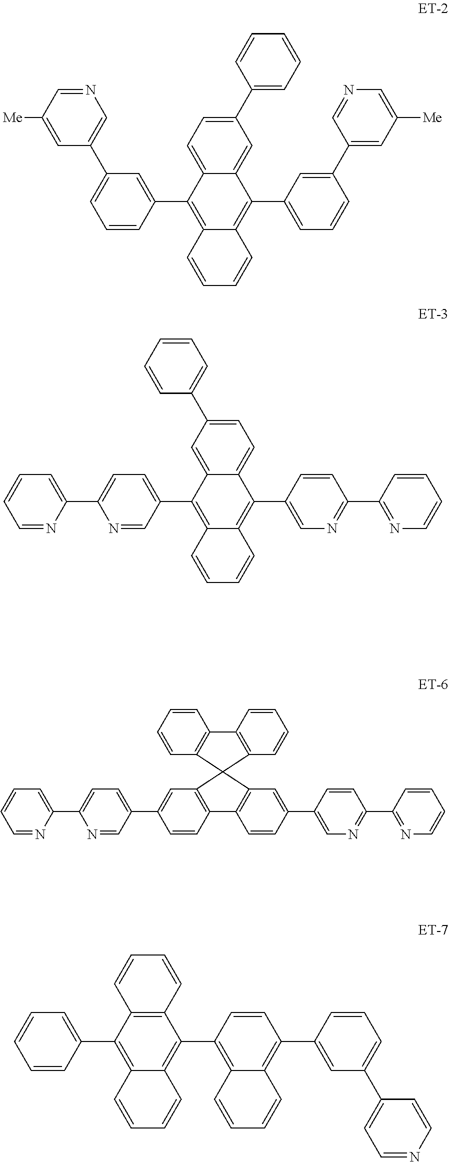 [SMILES: Cc1cncc(-c2cccc(-c3c4ccccc4c(-c4cccc(-c5cncc(C)c5)c4)c4cc(-c5ccccc5)ccc34)c2)c1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc(-c3ccc4c(c3)C3(c5ccccc5-c5ccccc53)c3cc(-c5ccc(-c6ccccn6)nc5)ccc3-4)cn2)nc1 ; c1ccc(-c2c3ccccc3c(-c3ccc(-c4cccc(-c5ccncc5)c4)c4ccccc34)c3ccccc23)cc1]

This pyridine derivative can be manufactured using known raw materials and known synthesis methods.

<Fluoranthene Derivative>

The fluoranthene derivative is, for example, a compound represented by the following general formula (ETM-3), and specifically disclosed in WO 2010/134352 A.

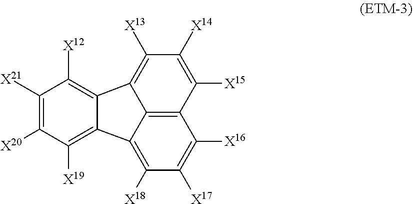

In the above formula (ETM-3), X¹² to X²¹ each represent a hydrogen atom, a halogen atom, a linear, branched or cyclic alkyl, a linear, branched or cyclic alkoxy, a substituted or unsubstituted aryl, or a substituted or unsubstituted heteroaryl. Examples of a substituent in a case of being substituted include an aryl, a heteroaryl, an alkyl, and a cycloalkyl.

Specific examples of this fluoranthene derivative include the following compounds.

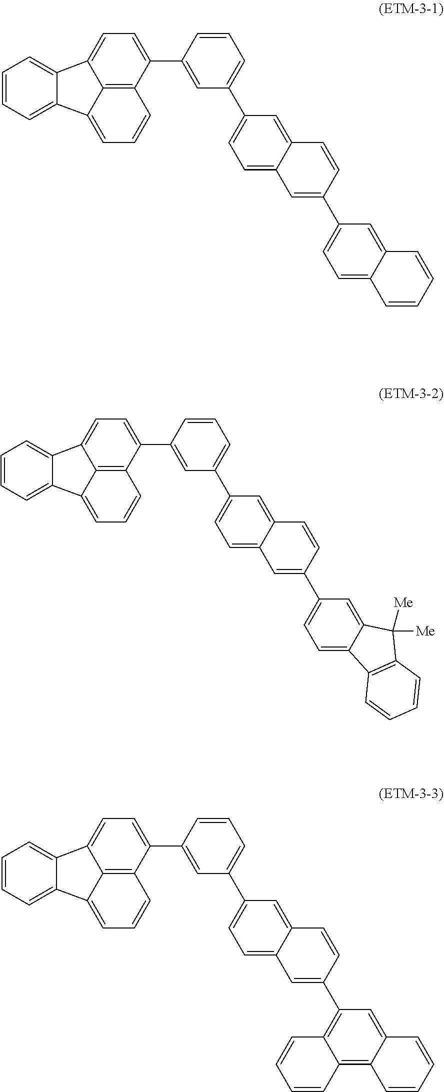

<BO-Based Derivative>

The BO-based derivative is, for example, a polycyclic aromatic compound represented by the following formula (ETM-4) or a polycyclic aromatic compound multimer having a plurality of structures represented by the following formula (ETM-4).

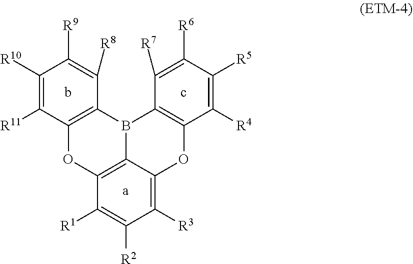

R¹ to R¹¹ each independently represent a hydrogen atom, an aryl, a heteroaryl, a diarylamino, a diheteroarylamino, an arylheteroarylamino, an alkyl, a cycloalkyl, an alkoxy, or an aryloxy, while at least one hydrogen atom in these may be substituted by an aryl, a heteroaryl, an alkyl, or a cycloalkyl.

Furthermore, adjacent groups among R¹ to R¹¹ may be bonded to each other to form an aryl ring or a heteroaryl ring together with the ring a, ring b, or ring c, and at least one hydrogen atom in the ring thus formed may be substituted by an aryl, a heteroaryl, a diarylamino, a diheteroarylamino, an arylheteroarylamino, an alkyl, a cycloalkyl, an alkoxy, or an aryloxy, while at least one hydrogen atom in these may be substituted by an aryl, a heteroaryl, an alkyl, or a cycloalkyl.

Furthermore, at least one hydrogen atom in a compound or structure represented by formula (ETM-4) may be substituted by a halogen atom or a deuterium atom.

For description of a substituent in formula (ETM-4) and a form of ring formation, the description of the polycyclic aromatic compound represented by the above general formula (1) can be cited.

Specific examples of this BO-based derivative include the following compounds.

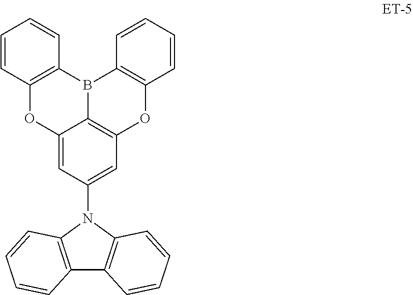 [SMILES: c1ccc2c(c1)Oc1cc(-n3c4ccccc4c4ccccc43)cc3c1B2c1ccccc1O3]

This BO-based derivative can be manufactured using known raw materials and known synthesis methods.

<Anthracene Derivative>

One of the anthracene derivatives is, for example, a compound represented by the following formula (ETM-5-1).

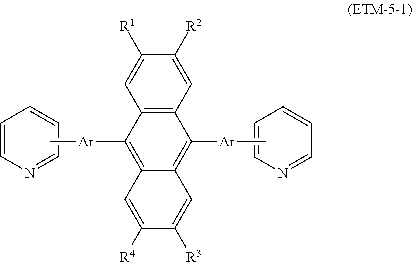

Ar's each independently represent a divalent benzene or naphthalene, R¹ to R⁴ each independently represent a hydrogen atom, an alkyl having 1 to 6 carbon atoms, a cycloalkyl having 3 to 6 carbon atoms, or an aryl having 6 to 20 carbon atoms.

Ar's can be each independently selected from a divalent benzene and naphthalene appropriately. Two Ar's may be different from or the same as each other, but are preferably the same from a viewpoint of easiness of synthesis of an anthracene derivative. Ar is bonded to pyridine to form “a moiety formed of Ar and pyridine”. For example, this moiety is bonded to anthracene as a group represented by any one of the following formulas (Py-1) to (Py-12).

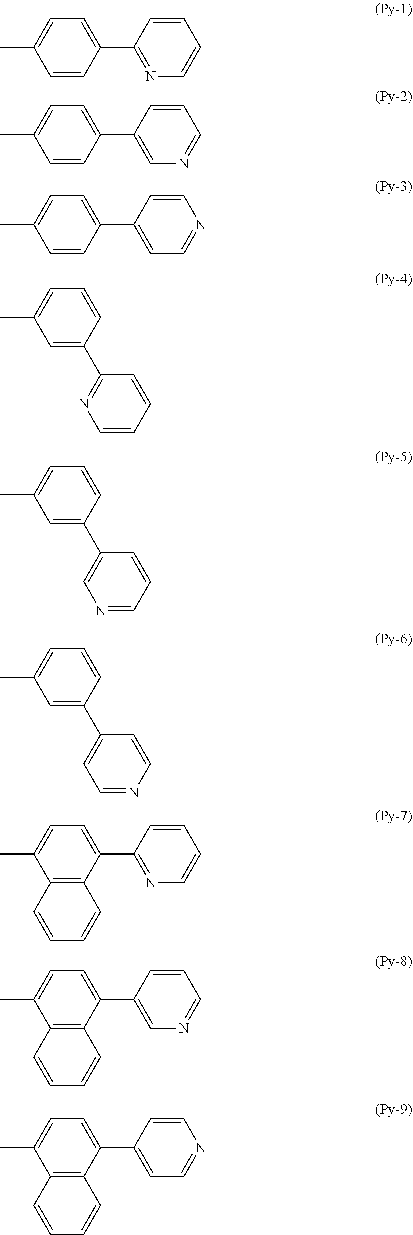

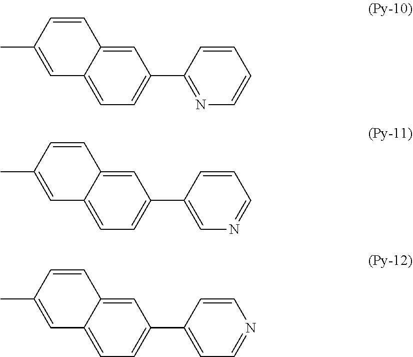

Among these groups, a group represented by any one of the above formulas (Py-1) to (Py-9) is preferable, and a group represented by any one of the above formulas (Py-1) to (Py-6) is more preferable. Two “moieties formed of Ar and pyridine” bonded to anthracene may have the same structure as or different structures from each other, but preferably have the same structure from a viewpoint of easiness of synthesis of an anthracene derivative. However, two “moieties formed of Ar and pyridine” preferably have the same structure or different structures from a viewpoint of element characteristics.

The alkyl having 1 to 6 carbon atoms in R¹ to R⁴ may be either linear or branched. That is, the alkyl having 1 to 6 carbon atoms is a linear alkyl having 1 to 6 carbon atoms or a branched alkyl having 3 to 6 carbon atoms. More preferably, the alkyl having 1 to 6 carbon atoms is an alkyl having 1 to 4 carbon atoms (branched alkyl having 3 to 4 carbon atoms). Specific examples thereof include methyl, ethyl, n-propyl, isopropyl, n-butyl, isobutyl, s-butyl, t-butyl, n-pentyl, isopentyl, neopentyl, t-pentyl, n-hexyl, 1-methylpentyl, 4-methyl-2-pentyl, 3,3-dimethylbutyl, and 2-ethylbutyl. Methyl, ethyl, n-propyl, isopropyl, n-butyl, isobutyl, s-butyl, and t-butyl are preferable. Methyl, ethyl, and t-butyl are more preferable.

Specific examples of the cycloalkyl having 3 to 6 carbon atoms in R¹ to R⁴ include cyclopropyl, cyclobutyl, cyclopentyl, cyclohexyl, methylcyclopentyl, cycloheptyl, methylcyclohexyl, cyclooctyl, and dimethylcyclohexyl.

For the aryl having 6 to 20 carbon atoms in R¹ to R⁴, an aryl having 6 to 16 carbon atoms is preferable, an aryl having 6 to 12 carbon atoms is more preferable, and an aryl having 6 to 10 carbon atoms is particularly preferable.

Specific examples of the “aryl having 6 to 20 carbon atoms” include phenyl, (o-, m-, p-) tolyl, (2,3-, 2,4-, 2,5-, 2,6-, 3,4-, 3,5-) xylyl, mesityl (2,4,6-trimethylphenyl), and (o-, m-, p-)cumenyl which are monocyclic aryls; (2-, 3-, 4-)biphenylyl which is a bicyclic aryl; (1-, 2-)naphthyl which is a fused bicyclic aryl; terphenylyl (m-terphenyl-2′-yl, m-terphenyl-4′-yl, m-terphenyl-5′-yl, o-terphenyl-3′-yl, o-terphenyl-4′-yl, p-terphenyl-2′-yl, m-terphenyl-2-yl, m-terphenyl-3-yl, m-terphenyl-4-yl, o-terphenyl-2-yl, o-terphenyl-3-yl, o-terphenyl-4-yl, p-terphenyl-2-yl, p-terphenyl-3-yl, p-terphenyl-4-yl) which is a tricyclic aryl; anthracene-(1-, 2-, 9-)yl, acenaphthylene-(1-, 3-, 4-, 5-)yl, fluorene-(1-, 2-, 3-, 4-, 9-)yl, phenalene-(1-, 2-)yl, and (1-, 2-, 3-, 4-, 9-)phenanthryl which are fused tricyclic aryls; triphenylene-(1-, 2-)yl, pyrene-(1-, 2-, 4-)yl, and tetracene-(1-, 2-, 5-)yl which are fused tetracyclic aryls; and perylene-(1-, 2-, 3-)yl which is a fused pentacyclic aryl.

The “aryl having 6 to 20 carbon atoms” is preferably a phenyl, a biphenylyl, a terphenylyl, or a naphthyl, more preferably a phenyl, a biphenylyl, a 1-naphthyl, a 2-naphthyl, or an m-terphenyl-5′-yl, still more preferably a phenyl, a biphenylyl, a 1-naphthyl, or a 2-naphthyl, and most preferably a phenyl.

One of the anthracene derivatives is, for example, a compound represented by the following formula (ETM-5-2).

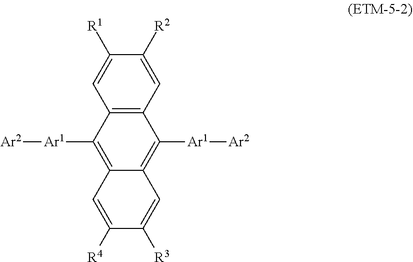

Ar¹'s each independently represent a single bond, a divalent benzene, naphthalene, anthracene, fluorene, or phenalene.

Ar²'s each independently represent an aryl having 6 to 20 carbon atoms. The same description as the “aryl having 6 to 20 carbon atoms” in the above formula (ETM-5-1) can be cited. An aryl having 6 to 16 carbon atoms is preferable, an aryl having 6 to 12 carbon atoms is more preferable, and an aryl having 6 to 10 carbon atoms is particularly preferable. Specific examples thereof include phenyl, biphenylyl, naphthyl, terphenylyl, anthracenyl, acenaphthylenyl, fluorenyl, phenalenyl, phenanthryl, triphenylenyl, pyrenyl, tetracenyl, and perylenyl.

R¹ to R⁴ each independently represent a hydrogen atom, an alkyl having 1 to 6 carbon atoms, a cycloalkyl having 3 to 6 carbon atoms, or an aryl having 6 to 20 carbon atoms. The same description as in the above formula (ETM-5-1) can be cited.

Specific examples of these anthracene derivatives include the following compounds.

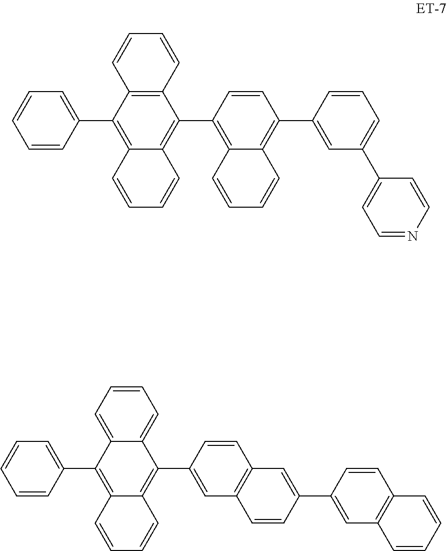

These anthracene derivatives can be manufactured using known raw materials and known synthesis methods.

<Benzofluorene Derivative>

The benzofluorene derivative is, for example, a compound represented by the following formula (ETM-6).

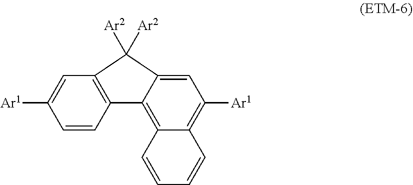

Ar¹'s each independently represent an aryl having 6 to 20 carbon atoms. The same description as the “aryl having 6 to 20 carbon atoms” in the above formula (ETM-5-1) can be cited. An aryl having 6 to 16 carbon atoms is preferable, an aryl having 6 to 12 carbon atoms is more preferable, and an aryl having 6 to 10 carbon atoms is particularly preferable. Specific examples thereof include phenyl, biphenylyl, naphthyl, terphenylyl, anthracenyl, acenaphthylenyl, fluorenyl, phenalenyl, phenanthryl, triphenylenyl, pyrenyl, tetracenyl, and perylenyl.

Ar²'s each independently represent a hydrogen atom, an alkyl (preferably, an alkyl having 1 to 24 carbon atoms), a cycloalkyl (preferably, a cycloalkyl having 3 to 12 carbon atoms), or an aryl (preferably, an aryl having 6 to 30 carbon atoms), and two Ar²'s may be bonded to each other to form a ring.

The “alkyl” in Ar² may be either linear or branched, and examples thereof include a linear alkyl having 1 to 24 carbon atoms and a branched alkyl having 3 to 24 carbon atoms. A preferable “alkyl” is an alkyl having 1 to 18 carbon atoms (branched alkyl having 3 to 18 carbon atoms). A more preferable “alkyl” is an alkyl having 1 to 12 carbons (branched alkyl having 3 to 12 carbons). A still more preferable “alkyl” is an alkyl having 1 to 6 carbon atoms (branched alkyl having 3 to 6 carbon atoms). A particularly preferable “alkyl” is an alkyl having 1 to 4 carbon atoms (branched alkyl having 3 to 4 carbon atoms). Specific examples of the “alkyl” include methyl, ethyl, n-propyl, isopropyl, n-butyl, isobutyl, s-butyl, t-butyl, n-pentyl, isopentyl, neopentyl, t-pentyl, n-hexyl, 1-methylpentyl, 4-methyl-2-pentyl, 3,3-dimethylbutyl, 2-ethylbutyl, n-heptyl, and 1-methylhexyl.

Examples of the “cycloalkyl” in Ar² include a cycloalkyl having 3 to 12 carbon atoms. A preferable “cycloalkyl” is a cycloalkyl having 3 to 10 carbons. A more preferable “cycloalkyl” is a cycloalkyl having 3 to 8 carbon atoms. A still more preferable “cycloalkyl” is a cycloalkyl having 3 to 6 carbon atoms. Specific examples of the “cycloalkyl” include cyclopropyl, cyclobutyl, cyclopentyl, cyclohexyl, methylcyclopentyl, cycloheptyl, methylcyclohexyl, cyclooctyl, and dimethylcyclohexyl.

As the “aryl” in Are, a preferable aryl is an aryl having 6 to 30 carbon atoms, a more preferable aryl is an aryl having 6 to 18 carbon atoms, a still more preferable aryl is an aryl having 6 to 14 carbon atoms, and a particularly preferable aryl is an aryl having 6 to 12 carbon atoms.

Specific examples of the “aryl having 6 to 30 carbon atoms” include phenyl, naphthyl, acenaphthylenyl, fluorenyl, phenalenyl, phenanthryl, triphenylenyl, pyrenyl, naphthacenyl, perylenyl, and pentacenyl.

Two Ar²'s may be bonded to each other to form a ring. As a result, cyclobutane, cyclopentane, cyclopentene, cyclopentadiene, cyclohexane, fluorene, indene, or the like may be spiro-bonded to a 5-membered ring of a fluorene skeleton.

Specific examples of this benzofluorene derivative include the following compounds.

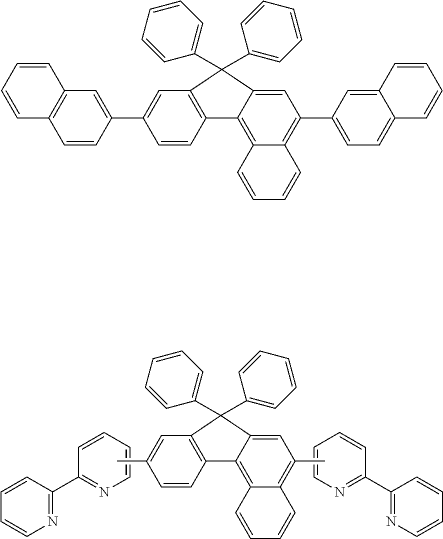

This benzofluorene derivative can be manufactured using known raw materials and known synthesis methods.

<Phosphine Oxide Derivative>

The phosphine oxide derivative is, for example, a compound represented by the following formula (ETM-7-1). Details are also described in WO 2013/079217 A.

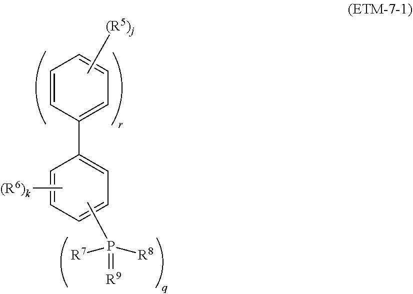

R⁵ represents a substituted or unsubstituted alkyl having 1 to 20 carbon atoms, cycloalkyl having 3 to 20 carbon atoms, an aryl having 6 to 20 carbon atoms, or a heteroaryl having 5 to 20 carbon atoms, R⁶ represents CN, a substituted or unsubstituted alkyl having 1 to 20 carbons, cycloalkyl having 3 to 20 carbon atoms, a heteroalkyl having 1 to 20 carbons, an aryl having 6 to 20 carbons, a heteroaryl having 5 to 20 carbons, an alkoxy having 1 to 20 carbons, or an aryloxy having 6 to 20 carbon atoms, R⁷ and R⁸ each independently represent a substituted or unsubstituted aryl having 6 to 20 carbon atoms or a heteroaryl having 5 to 20 carbon atoms, R⁹ represents an oxygen atom or a sulfur atom, j represents 0 or 1, k represents 0 or 1, r represents an integer of 0 to 4, and q represents an integer of 1 to 3.

Examples of a substituent in a case of being substituted include an aryl, a heteroaryl, an alkyl, and a cycloalkyl.

The phosphine oxide derivative may be, for example, a compound represented by the following formula (ETM-7-2).

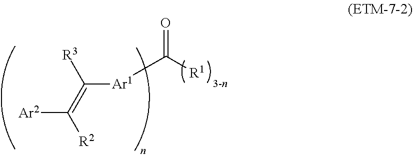

R¹ to R³ may be the same as or different from each other and are selected from a hydrogen atom, an alkyl group, a cycloalkyl group, an aralkyl group, an alkenyl group, a cycloalkenyl group, an alkynyl group, an alkoxy group, an alkylthio group, a cycloalkylthio group, an aryl ether group, an aryl thioether group, an aryl group, a heterocyclic group, a halogen atom, cyano group, an aldehyde group, a carbonyl group, a carboxyl group, an amino group, a nitro group, a silyl group, and a fused ring formed with an adjacent substituent.

Ar¹'s may be the same as or different from each other, and represents an arylene group or a heteroarylene group. Ar²'s may be the same as or different from each other, and represents an aryl group or a heteroaryl group. However, at least one of Ar¹ and Are has a substituent or forms a fused ring with an adjacent substituent. n represents an integer of 0 to 3. When n is 0, no unsaturated structure portion is present. When n is 3, R¹ is not present.

Among these substituents, the alkyl group represents a saturated aliphatic hydrocarbon group such as a methyl group, an ethyl group, a propyl group, or a butyl group. This saturated aliphatic hydrocarbon group may be unsubstituted or substituted. The substituent in a case of being substituted is not particularly limited, and examples thereof include an alkyl group, an aryl group, and a heterocyclic group, and this point is also common to the following description. Furthermore, the number of carbon atoms in the alkyl group is not particularly limited, but is usually in a range of 1 to 20 from a viewpoint of availability and cost.

Furthermore, the cycloalkyl group represents a saturated alicyclic hydrocarbon group such as cyclopropyl, cyclohexyl, norbornyl, or adamantyl. This saturated alicyclic hydrocarbon group may be unsubstituted or substituted. The carbon number of the alkyl group moiety is not particularly limited, but is usually in a range of 3 to 20.

Furthermore, the aralkyl group represents an aromatic hydrocarbon group via an aliphatic hydrocarbon, such as a benzyl group or a phenylethyl group. Both the aliphatic hydrocarbon and the aromatic hydrocarbon may be unsubstituted or substituted. The carbon number of the aliphatic moiety is not particularly limited, but is usually in a range of 1 to 20.

Furthermore, the alkenyl group represents an unsaturated aliphatic hydrocarbon group containing a double bond, such as a vinyl group, an allyl group, or a butadienyl group. This unsaturated aliphatic hydrocarbon group may be unsubstituted or substituted. The carbon number of the alkenyl group is not particularly limited, but is usually in a range of 2 to 20.

Furthermore, the cycloalkenyl group represents an unsaturated alicyclic hydrocarbon group containing a double bond, such as a cyclopentenyl group, a cyclopentadienyl group, or a cyclohexene group. This unsaturated alicyclic hydrocarbon group may be unsubstituted or substituted.

Furthermore, the alkynyl group represents an unsaturated aliphatic hydrocarbon group containing a triple bond, such as an acetylenyl group. This unsaturated aliphatic hydrocarbon group may be unsubstituted or substituted. The carbon number of the alkynyl group is not particularly limited, but is usually in a range of 2 to 20.

Furthermore, the alkoxy group represents an aliphatic hydrocarbon group via an ether bond, such as a methoxy group. The aliphatic hydrocarbon group may be unsubstituted or substituted. The carbon number of the alkoxy group is not particularly limited, but is usually in a range of 1 to 20.

Furthermore, the alkylthio group is a group in which an oxygen atom of an ether bond of an alkoxy group is substituted by a sulfur atom.

Furthermore, the cycloalkylthio group is a group in which an oxygen atom of an ether bond of a cycloalkoxy group is substituted by a sulfur atom.

Furthermore, the aryl ether group represents an aromatic hydrocarbon group via an ether bond, such as a phenoxy group. The aromatic hydrocarbon group may be unsubstituted or substituted. The carbon number of the aryl ether group is not particularly limited, but is usually in a range of 6 to 40.

Furthermore, the aryl thioether group is a group in which an oxygen atom of an ether bond of an aryl ether group is substituted by a sulfur atom.

Furthermore, the aryl group represents an aromatic hydrocarbon group such as a phenyl group, a naphthyl group, a biphenyl group, a phenanthryl group, a terphenyl group, or a pyrenyl group. The aryl group may be unsubstituted or substituted. The carbon number of the aryl group is not particularly limited, but is usually in a range of 6 to 40.

Furthermore, the heterocyclic group represents a cyclic structural group having an atom other than a carbon atom, such as a furanyl group, a thiophenyl group, an oxazolyl group, a pyridyl group, a quinolinyl group, or a carbazolyl group. This cyclic structural group may be unsubstituted or substituted. The carbon number of the heterocyclic group is not particularly limited, but is usually in a range of 2 to 30.

Halogen refers to fluorine, chlorine, bromine, and iodine.

The aldehyde group, the carbonyl group, and the amino group can include a group substituted by an aliphatic hydrocarbon, an alicyclic hydrocarbon, an aromatic hydrocarbon, a heterocyclic ring, or the like.

Furthermore, the aliphatic hydrocarbon, the alicyclic hydrocarbon, the aromatic hydrocarbon, and the heterocyclic ring may be unsubstituted or substituted.

The silyl group represents, for example, a silicon compound group such as a trimethylsilyl group. This silicon compound group may be unsubstituted or substituted. The number of carbon atoms of the silyl group is not particularly limited, but is usually in a range of 3 to 20. Furthermore, the number of silicon atoms is usually 1 to 6.

The fused ring formed with an adjacent substituent is, for example, a conjugated or unconjugated fused ring formed between Ar¹ and R², Ar¹ and R³, Ar² and R², Ar² and R³, R² and R³, or Ar¹ and Ar². Here, when n is 1, two R¹'s may form a conjugated or unconjugated fused ring. These fused rings may contain a nitrogen atom, an oxygen atom, or a sulfur atom in the ring structure, or may be fused with another ring.

Specific examples of this phosphine oxide derivative include the following compounds.

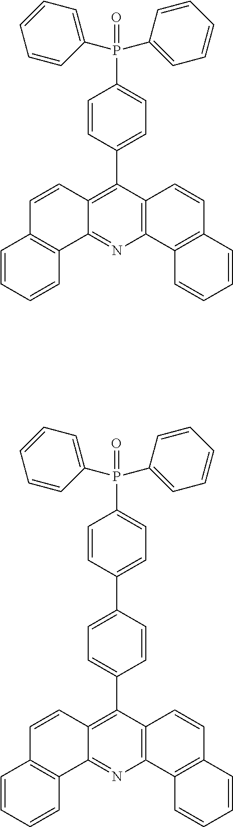 [SMILES: O=P(c1ccccc1)(c1ccccc1)c1ccc(-c2c3ccc4ccccc4c3nc3c2ccc2ccccc23)cc1 ; O=P(c1ccccc1)(c1ccccc1)c1ccc(-c2ccc(-c3c4ccc5ccccc5c4nc4c3ccc3ccccc34)cc2)cc1]

This phosphine oxide derivative can be manufactured using known raw materials and known synthesis methods.

<Pyrimidine Derivative>

The pyrimidine derivative is, for example, a compound represented by the following formula (ETM-8), and preferably a compound represented by the following formula (ETM-8-1). Details are also described in WO 2011/021689 A.

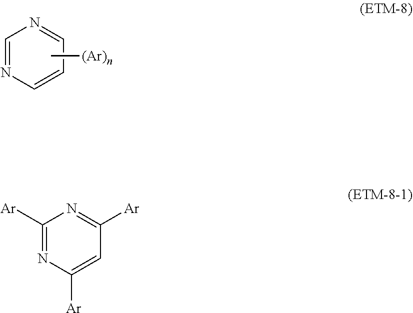

Ar's each independently represent an optionally substituted aryl or an optionally substituted heteroaryl. n represents an integer of 1 to 4, preferably an integer of 1 to 3, and more preferably 2 or 3.

Examples of the “aryl” as the “optionally substituted aryl” include an aryl having 6 to 30 carbon atoms. An aryl having 6 to 24 carbon atoms is preferable, an aryl having 6 to 20 carbon atoms is more preferable, and an aryl having 6 to 12 carbon atoms is still more preferable.

Specific examples of the “aryl” include phenyl which is a monocyclic aryl; (2-, 3-, 4-)biphenylyl which is a bicyclic aryl; (1-, 2-)naphthyl which is a fused bicyclic aryl; terphenylyl (m-terphenyl-2′-yl, m-terphenyl-4′-yl, m-terphenyl-5′-yl, o-terphenyl-3′-yl, o-terphenyl-4′-yl, p-terphenyl-2′-yl, m-terphenyl-2-yl, m-terphenyl-3-yl, m-terphenyl-4-yl, o-terphenyl-2-yl, o-terphenyl-3-yl, o-terphenyl-4-yl, p-terphenyl-2-yl, p-terphenyl-3-yl, p-terphenyl-4-yl) which is a tricyclic aryl; acenaphthylene-(1-, 3-, 4-, 5-)yl, fluorene-(1-, 2-, 3-, 4-, 9-)yl, phenalene-(1-, 2-)yl, and (1-, 2-, 3-, 4-, 9-)phenanthryl which are fused tricyclic aryls; quaterphenylyl-(5′-phenyl-m-terphenyl-2-yl, 5′-phenyl-m-terphenyl-3-yl, 5′-phenyl-m-terphenyl-4-yl, m-quaterphenylyl) which is a tetracyclic aryl; triphenylene-(1-, 2-)yl, pyrene-(1-, 2-, 4-)yl, and naphthacene-(1-, 2-, 5-)yl which are fused tetracyclic aryls; and perylene-(1-, 2-, 3-)yl and pentacene-(1-, 2-, 5-, 6-)yl which are fused pentacyclic aryls.

Examples of the “heteroaryl” as the “optionally substituted heteroaryl” include a heteroaryl having 2 to 30 carbon atoms. A heteroaryl having 2 to 25 carbon atoms is preferable, a heteroaryl having 2 to 20 carbon atoms is more preferable, a heteroaryl having 2 to 15 carbon atoms is still more preferable, and a heteroaryl having 2 to 10 carbon atoms is particularly preferable. Furthermore, examples of the “heteroaryl” include a heterocyclic ring containing 1 to 5 heteroatoms selected from an oxygen atom, a sulfur atom, and a nitrogen atom in addition to a carbon atom as a ring-constituting atom.

Specific examples of the “heteroaryl” include furyl, thienyl, pyrrolyl, oxazolyl, isoxazolyl, thiazolyl, isothiazolyl, imidazolyl, pyrazolyl, oxadiazolyl, furazanyl, thiadiazolyl, triazolyl, tetrazolyl, pyridyl, pyrimidinyl, pyridazinyl, pyrazinyl, triazinyl, benzofuranyl, isobenzofuranyl, benzo[b]thienyl, indolyl, isoindolyl, 1H-indazolyl, benzoimidazolyl, benzoxazolyl, benzothiazolyl, 1H-benzotriazolyl, quinolyl, isoquinolyl, cinnolyl, quinazolyl, quinoxalinyl, phthalazinyl, naphthyridinyl, purinyl, pteridinyl, carbazolyl, acridinyl, phenoxazinyl, phenothiazinyl, phenazinyl, phenoxathiinyl, thianthrenyl, and indolizinyl.

Furthermore, the above aryl and heteroaryl may be substituted, and may be each substituted by, for example, the above aryl or heteroaryl.

Specific examples of this pyrimidine derivative include the following compounds.

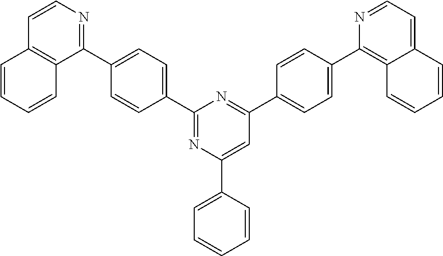 [SMILES: c1ccc(-c2cc(-c3ccc(-c4nccc5ccccc45)cc3)nc(-c3ccc(-c4nccc5ccccc45)cc3)n2)cc1]

This pyrimidine derivative can be manufactured using known raw materials and known synthesis methods.

<Carbazole Derivative>

The carbazole derivative is, for example, a compound represented by the following formula (ETM-9), or a multimer obtained by bonding a plurality of the compounds with a single bond or the like. Details are described in US 2014/0197386 A.

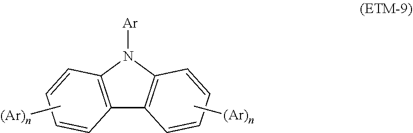

Ar's each independently represent an optionally substituted aryl or an optionally substituted heteroaryl. n represents an integer of 0 to 4, preferably an integer of 0 to 3, and more preferably 0 or 1.

Examples of the “aryl” as the “optionally substituted aryl” include an aryl having 6 to 30 carbon atoms. An aryl having 6 to 24 carbon atoms is preferable, an aryl having 6 to 20 carbon atoms is more preferable, and an aryl having 6 to 12 carbon atoms is still more preferable.

Specific examples of the “aryl” include phenyl which is a monocyclic aryl; (2-, 3-, 4-)biphenylyl which is a bicyclic aryl; (1-, 2-)naphthyl which is a fused bicyclic aryl; terphenylyl (m-terphenyl-2′-yl, m-terphenyl-4′-yl, m-terphenyl-5′-yl, o-terphenyl-3′-yl, o-terphenyl-4′-yl, p-terphenyl-2′-yl, m-terphenyl-2-yl, m-terphenyl-3-yl, m-terphenyl-4-yl, o-terphenyl-2-yl, o-terphenyl-3-yl, o-terphenyl-4-yl, p-terphenyl-2-yl, p-terphenyl-3-yl, p-terphenyl-4-yl) which is a tricyclic aryl; acenaphthylene-(1-, 3-, 4-, 5-)yl, fluorene-(1-, 2-, 3-, 4-, 9-)yl, phenalene-(1-, 2-)yl, and (1-, 2-, 3-, 4-, 9-)phenanthryl which are fused tricyclic aryls; quaterphenylyl-(5′-phenyl-m-terphenyl-2-yl, 5′-phenyl-m-terphenyl-3-yl, 5′-phenyl-m-terphenyl-4-yl, m-quaterphenylyl) which is a tetracyclic aryl; triphenylene-(1-, 2-)yl, pyrene-(1-, 2-, 4-)yl, and naphthacene-(1-, 2-, 5-)yl which are fused tetracyclic aryls; and perylene-(1-, 2-, 3-)yl and pentacene-(1-, 2-, 5-, 6-)yl which are fused pentacyclic aryls.

Examples of the “heteroaryl” as the “optionally substituted heteroaryl” include a heteroaryl having 2 to 30 carbon atoms. A heteroaryl having 2 to 25 carbon atoms is preferable, a heteroaryl having 2 to 20 carbon atoms is more preferable, a heteroaryl having 2 to 15 carbon atoms is still more preferable, and a heteroaryl having 2 to 10 carbon atoms is particularly preferable. Furthermore, examples of the “heteroaryl” include a heterocyclic ring containing 1 to 5 heteroatoms selected from an oxygen atom, a sulfur atom, and a nitrogen atom in addition to a carbon atom as a ring-constituting atom.

Specific examples of the “heteroaryl” include furyl, thienyl, pyrrolyl, oxazolyl, isoxazolyl, thiazolyl, isothiazolyl, imidazolyl, pyrazolyl, oxadiazolyl, furazanyl, thiadiazolyl, triazolyl, tetrazolyl, pyridyl, pyrimidinyl, pyridazinyl, pyrazinyl, triazinyl, benzofuranyl, isobenzofuranyl, benzo[b]thienyl, indolyl, isoindolyl, 1H-indazolyl, benzoimidazolyl, benzoxazolyl, benzothiazolyl, 1H-benzotriazolyl, quinolyl, isoquinolyl, cinnolyl, quinazolyl, quinoxalinyl, phthalazinyl, naphthyridinyl, purinyl, pteridinyl, carbazolyl, acridinyl, phenoxazinyl, phenothiazinyl, phenazinyl, phenoxathiinyl, thianthrenyl, and indolizinyl.

Furthermore, the above aryl and heteroaryl may be substituted, and may be each substituted by, for example, the above aryl or heteroaryl.

The carbazole derivative may be a multimer obtained by bonding a plurality of compounds represented by the above formula (ETM-9) with a single bond or the like. In this case, the compounds may be bonded with an aryl ring (preferably, a polyvalent benzene ring, naphthalene ring, anthracene ring, fluorene ring, benzofluorene ring, phenalene ring, phenanthrene ring or triphenylene ring) in addition to a single bond.

Specific examples of this carbazole derivative include the following compounds.

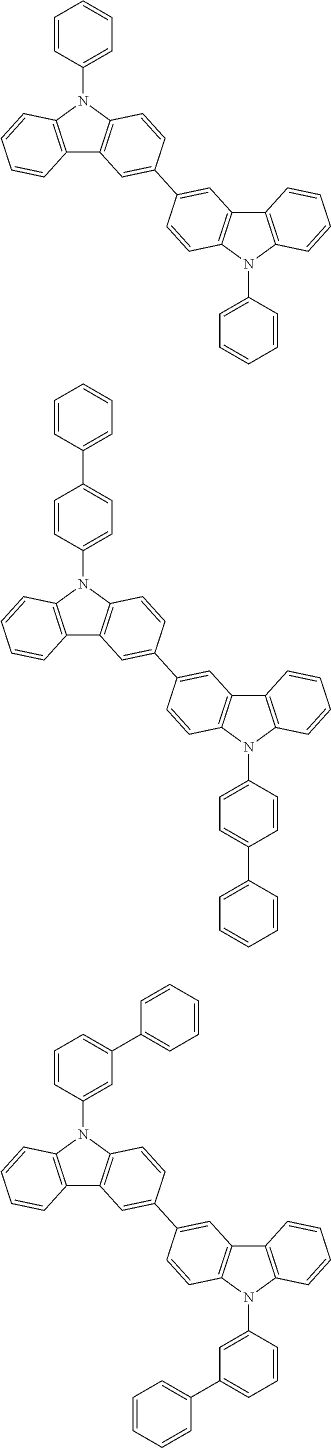 [SMILES: c1ccc(-n2c3ccccc3c3cc(-c4ccc5c(c4)c4ccccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1]

This carbazole derivative can be manufactured using known raw materials and known synthesis methods.

<Triazine Derivative>

The triazine derivative is, for example, a compound represented by the following formula (ETM-10), and preferably a compound represented by the following formula (ETM-10-1). Details are described in US 2011/0156013 A.

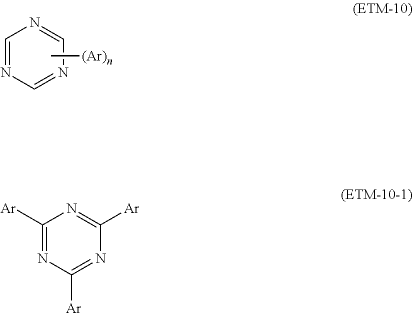

Ar's each independently represent an optionally substituted aryl or an optionally substituted heteroaryl. n represents an integer of 1 to 3, preferably 2 or 3.

Examples of the “aryl” as the “optionally substituted aryl” include an aryl having 6 to 30 carbon atoms. An aryl having 6 to 24 carbon atoms is preferable, an aryl having 6 to 20 carbon atoms is more preferable, and an aryl having 6 to 12 carbon atoms is still more preferable.

Specific examples of the “aryl” include phenyl which is a monocyclic aryl; (2-, 3-, 4-)biphenylyl which is a bicyclic aryl; (1-, 2-)naphthyl which is a fused bicyclic aryl; terphenylyl (m-terphenyl-2′-yl, m-terphenyl-4′-yl, m-terphenyl-5′-yl, o-terphenyl-3′-yl, o-terphenyl-4′-yl, p-terphenyl-2′-yl, m-terphenyl-2-yl, m-terphenyl-3-yl, m-terphenyl-4-yl, o-terphenyl-2-yl, o-terphenyl-3-yl, o-terphenyl-4-yl, p-terphenyl-2-yl, p-terphenyl-3-yl, p-terphenyl-4-yl) which is a tricyclic aryl; acenaphthylene-(1-, 3-, 4-, 5-)yl, fluorene-(1-, 2-, 3-, 4-, 9-)yl, phenalene-(1-, 2-)yl, and (1-, 2-, 3-, 4-, 9-)phenanthryl which are fused tricyclic aryls; quaterphenylyl-(5′-phenyl-m-terphenyl-2-yl, 5′-phenyl-m-terphenyl-3-yl, 5′-phenyl-m-terphenyl-4-yl, m-quaterphenylyl) which is a tetracyclic aryl; triphenylene-(1-, 2-)yl, pyrene-(1-, 2-, 4-)yl, and naphthacene-(1-, 2-, 5-)yl which are fused tetracyclic aryls; and perylene-(1-, 2-, 3-)yl and pentacene-(1-, 2-, 5-, 6-)yl which are fused pentacyclic aryls.

Examples of the “heteroaryl” as the “optionally substituted heteroaryl” include a heteroaryl having 2 to 30 carbon atoms. A heteroaryl having 2 to 25 carbon atoms is preferable, a heteroaryl having 2 to 20 carbon atoms is more preferable, a heteroaryl having 2 to 15 carbon atoms is still more preferable, and a heteroaryl having 2 to 10 carbon atoms is particularly preferable. Furthermore, examples of the “heteroaryl” include a heterocyclic ring containing 1 to 5 heteroatoms selected from an oxygen atom, a sulfur atom, and a nitrogen atom in addition to a carbon atom as a ring-constituting atom.

Specific examples of the “heteroaryl” include furyl, thienyl, pyrrolyl, oxazolyl, isoxazolyl, thiazolyl, isothiazolyl, imidazolyl, pyrazolyl, oxadiazolyl, furazanyl, thiadiazolyl, triazolyl, tetrazolyl, pyridyl, pyrimidinyl, pyridazinyl, pyrazinyl, triazinyl, benzofuranyl, isobenzofuranyl, benzo[b]thienyl, indolyl, isoindolyl, 1H-indazolyl, benzoimidazolyl, benzoxazolyl, benzothiazolyl, 1H-benzotriazolyl, quinolyl, isoquinolyl, cinnolyl, quinazolyl, quinoxalinyl, phthalazinyl, naphthyridinyl, purinyl, pteridinyl, carbazolyl, acridinyl, phenoxazinyl, phenothiazinyl, phenazinyl, phenoxathiinyl, thianthrenyl, and indolizinyl.

Furthermore, the above aryl and heteroaryl may be substituted, and may be each substituted by, for example, the above aryl or heteroaryl.

Specific examples of this triazine derivative include the following compounds.

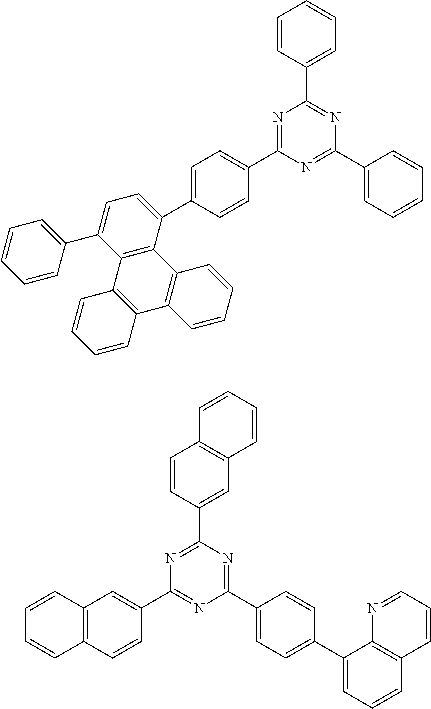 [SMILES: c1ccc(-c2nc(-c3ccccc3)nc(-c3ccc(-c4ccc(-c5ccccc5)c5c6ccccc6c6ccccc6c45)cc3)n2)cc1 ; c1ccc2cc(-c3nc(-c4ccc(-c5cccc6cccnc56)cc4)nc(-c4ccc5ccccc5c4)n3)ccc2c1]

This triazine derivative can be manufactured using known raw materials and known synthesis methods.

<Benzimidazole Derivative>

The benzimidazole derivative is, for example, a compound represented by the following formula (ETM-11).

ϕ-(Benzimidazole-based substituent) n (ETM-1)[0325]

φ represents an n-valent aryl ring (preferably, an n-valent benzene ring, naphthalene ring, anthracene ring, fluorene ring, benzofluorene ring, phenalene ring, phenanthrene ring, or triphenylene ring), and n represents an integer of 1 to 4. A “benzimidazole-based substituent” is a substituent in which the pyridyl group in the “pyridine-based substituent” in the formulas (ETM-2), (ETM-2-1), and (ETM-2-2) is substituted by a benzimidazole group, and at least one hydrogen atom in the benzimidazole derivative may be substituted by a deuterium atom.

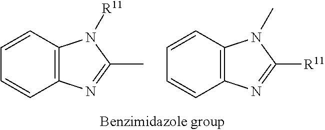

R¹¹ in the above benzimidazole represents a hydrogen atom, an alkyl having 1 to 24 carbon atoms, a cycloalkyl having 3 to 12 carbon atoms, or an aryl having 6 to 30 carbon atoms. The description of R¹¹ in the above formulas (ETM-2-1), and (ETM-2-2) can be cited.

Moreover, φ is preferably an anthracene ring or a fluorene ring. For the structure in this case, the description for the above formula (ETM-2-1) or (ETM-2-2) can be cited. For R¹¹ to R¹⁸ in each formula, the description for the above formula (ETM-2-1) or (ETM-2-2) can be cited. Furthermore, in the above formula (ETM-2-1) or (ETM-2-2), a form in which two pyridine-based substituents are bonded has been described. However, when these substituents are substituted by benzimidazole-based substituents, both the pyridine-based substituents may be substituted by benzimidazole-based substituents (that is, n=2), or one of the pyridine-based substituents may be substituted by a benzimidazole-based substituent and the other pyridine-based substituent may be substituted by any one of R¹¹ to R¹⁸ (that is, n=1). Moreover, for example, at least one of R¹¹ to R¹⁸ in the above formula (ETM-2-1) may be substituted by a benzimidazole-based substituent and the “pyridine-based substituent” may be substituted by any one of R¹¹ to R¹⁸.

Specific examples of this benzimidazole derivative include 1-phenyl-2-(4-(10-phenylanthracen-9-yl)phenyl)-1H-benzo[d]imidazole, 2-(4-(10-(naphthalen-2-yl)anthracen-9-yl)phenyl)-1-phenyl-1H-benzo[d]imidazole, 2-(3-(10-(naphthalen-2-yl)anthracen-9-yl)phenyl)-1-phenyl-1H-benzo[d]imidazole, 5-(10-(naphthlen-2-yl)anthracen-9-yl)-1,2-diphenyl-1H-benzo[d]imidazole, 1-(4-(10-(naphthalen-2-yl)anthracen-9-yl)phenyl)-2-phenyl-1H-benzo[d]imidazole, 2-(4-(9,10-di(naphthalen-2-yl)anthracen-2-yl)phenyl)-1-phenyl-1H-benzo[d]imidazole, 1-(4-(9,10-di(naphthalen-2-yl)anthracen-2-yl)phenyl)-2-phenyl-1H-benzo[d]imidazole, and 5-(9,10-di(naphthalen-2-yl)anthracen-2-yl)-1,2-diphenyl-1H-benzo[d]imidazole.

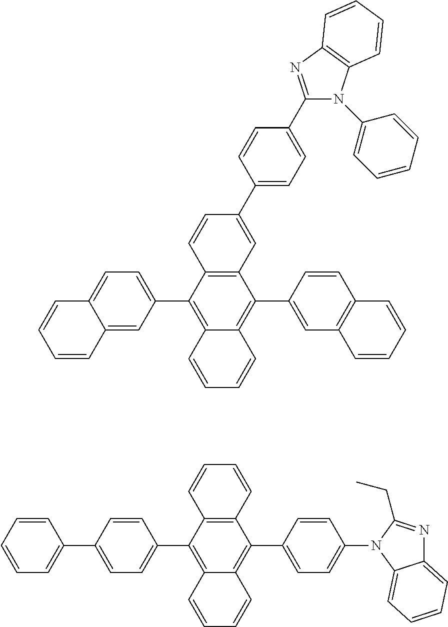 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; CCc1nc2ccccc2n1-c1ccc(-c2c3ccccc3c(-c3ccc(-c4ccccc4)cc3)c3ccccc23)cc1]

This benzimidazole derivative can be manufactured using known raw materials and known synthesis methods.

<Phenanthroline Derivative>

The phenanthroline derivative is, for example, a compound represented by the following formula (ETM-12) or (ETM-12-1). Details are described in WO 2006/021982 A.

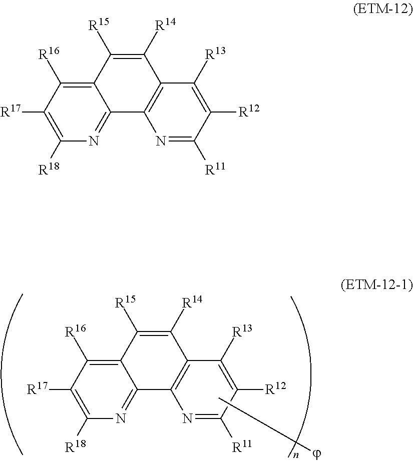

φ represents an n-valent aryl ring (preferably, an n-valent benzene ring, naphthalene ring, anthracene ring, fluorene ring, benzofluorene ring, phenalene ring, phenanthrene ring, or triphenylene ring), and n represents an integer of 1 to 4.

In each formula, R¹¹ to R¹⁸ each independently represent a hydrogen atom, an alkyl (preferably, an alkyl having 1 to 24 carbon atoms), a cycloalkyl (preferably, a cycloalkyl having 3 to 12 carbon atoms), or an aryl (preferably, an aryl having 6 to 30 carbon atoms). Furthermore, in the above formula (ETM-12-1), any one of R¹¹ to R¹⁸ is bonded to φ which is an aryl ring.

At least one hydrogen atom in each phenanthroline derivative may be substituted by a deuterium atom.

For the alkyl, cycloalkyl, and aryl in R¹¹ to R¹⁸, the description of R¹¹ to R¹⁸ in the above formula (ETM-2) can be cited. Furthermore, in addition to the above examples, examples of the φ include those having the following structural formulas. Note that R's in the following structural formulas each independently represent a hydrogen atom, methyl, ethyl, isopropyl, cyclohexyl, phenyl, 1-naphthyl, 2-naphthyl, biphenylyl, or terphenylyl.

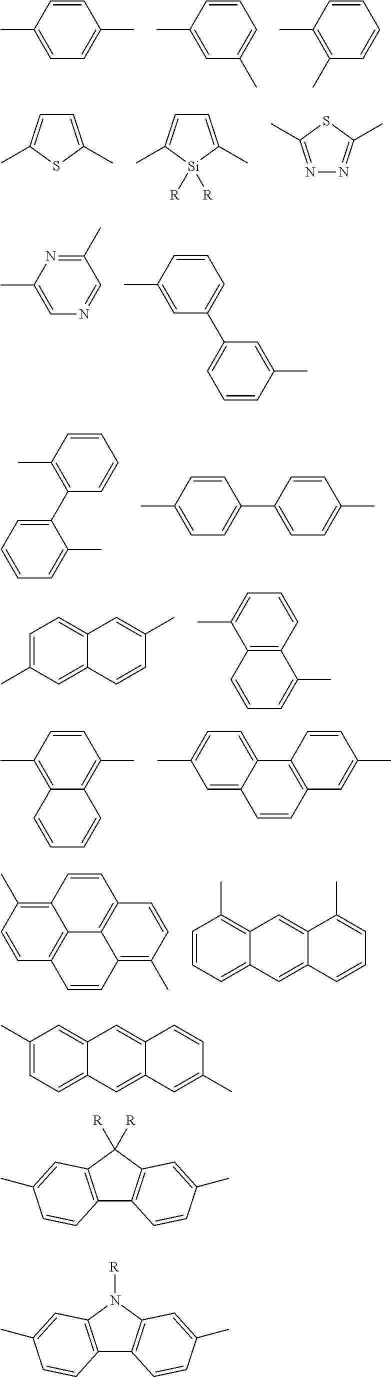

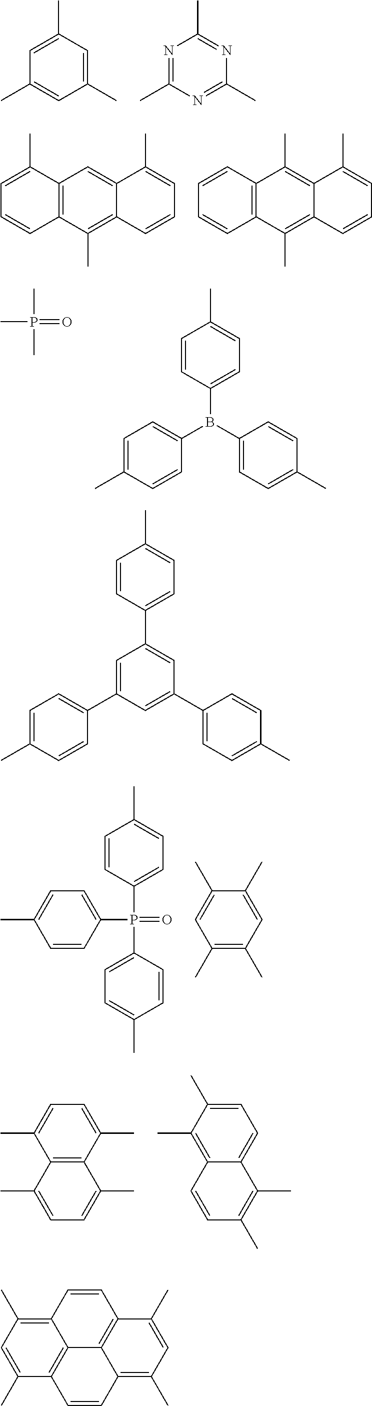

Specific examples of this phenanthroline derivative include 4,7-diphenyl-1,10-phenanthroline, 2,9-dimethyl-4,7-diphenyl-1,10-phenanthroline, 9,10-di(1,10-phenanthrolin-2-yl)anthracene, 2,6-di(1,10-phenanthrolin-5-yl)pyridine, 1,3,5-tri(1,10-phenanthrolin-5-yl)benzene, 9,9′-difluoro-bis(1,10-phenanthrolin-5-yl), bathocuproine, 1,3-bis(2-phenyl-1,10-phenanthrolin-9-yl) benzene, and a compound represented by the following structural formula.

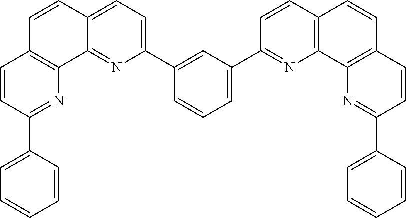 [SMILES: c1ccc(-c2ccc3ccc4ccc(-c5cccc(-c6ccc7ccc8ccc(-c9ccccc9)nc8c7n6)c5)nc4c3n2)cc1]

This phenanthroline derivative can be manufactured using known raw materials and known synthesis methods.

<Quinolinol-Based Metal Complex>

The quinolinol-based metal complex is, for example, a compound represented by the following general formula (ETM-13).

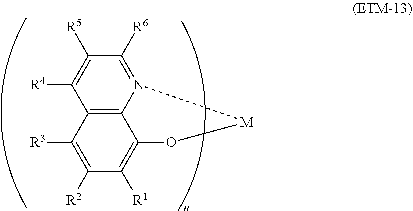

In the formula, R¹ to R⁶ each independently represent a hydrogen atom, a fluorine atom, an alkyl, a cycloalkyl, an aralkyl, an alkenyl, cyano, an alkoxy, or an aryl, M represents Li, Al, Ga, Be, or Zn, and n represents an integer of 1 to 3.

Specific examples of the quinolinol-based metal complex include 8-quinolinol lithium, tris(8-quinolinolato) aluminum, tris(4-methyl-8-quinolinolato) aluminum, tris(5-methyl-8-quinolinolato) aluminum, tris(3,4-dimethyl-8-quinolinolato) aluminum, tris(4,5-dimethyl-8-quinolinolato) aluminum, tris(4,6-dimethyl-8-quinolinolato) aluminum, bis(2-methyl-8-quinolinolato) (phenolato) aluminum, bis(2-methyl-8-quinolinolato) (2-methylphenolato) aluminum, bis(2-methyl-8-quinolinolato) (3-methylphenolato) aluminum, bis(2-methyl-8-quinolinolato) (4-methylphenolato) aluminum, bis(2-methyl-8-quinolinolato) (2-phenylphenolato) aluminum, bis(2-methyl-8-quinolinolato) (3-phenylphenolato) aluminum, bis(2-methyl-8-quinolinolato) (4-phenylphenolato) aluminum, bis(2-methyl-8-quinolinolato) (2,3-dimethylphenolato) aluminum, bis(2-methyl-8-quinolinolato) (2,6-dimethylphenolato) aluminum, bis(2-methyl-8-quinolinolato) (3,4-dimethylphenolato) aluminum, bis(2-methyl-8-quinolinolato) (3,5-dimethylphenolato) aluminum, bis(2-methyl-8-quinolinolato) (3,5-di-t-butylphenolato) aluminum, bis(2-methyl-8-quinolinolato) (2,6-diphenylphenolato) aluminum, bis(2-methyl-8-quinolinolato) (2,4,6-triphenylphenolato) aluminum, bis(2-methyl-8-quinolinolato) (2,4,6-trimethylphenolato) aluminum, bis(2-methyl-8-quinolinolato) (2,4,5,6-tetramethylphenolato) aluminum, bis(2-methyl-8-quinolinolato) (1-naphtholato) aluminum, bis(2-methyl-8-quinolinolato) (2-naphtholato) aluminum, bis(2,4-dimethyl-8-quinolinolato) (2-phenylphenolato) aluminum, bis(2,4-dimethyl-8-quinolinolato) (3-phenylphenolato) aluminum, bis(2,4-dimethyl-8-quinolinolato) (4-phenylphenolato) aluminum, bis(2,4-dimethyl-8-quinolinolato) (3,5-dimethylphenolato) aluminum, bis(2,4-dimethyl-8-quinolinolato) (3,5-di-t-butylphenolato) aluminum, bis(2-methyl-8-quinolinolato) aluminum-p-oxo-bis(2-methyl-8-quinolinolato) aluminum, bis(2,4-dimethyl-8-quinolinolato) aluminum-p-oxo-bis(2,4-dimethyl-8-quinolinolato) aluminum, bis(2-methyl-4-ethyl-8-quinolinolato) aluminum-p-oxo-bis(2-methyl-4-ethyl-8-quinolinolato) aluminum, bis(2-methyl-4-methoxy-8-quinolinolato) aluminum-p-oxo-bis(2-methyl-4-methoxy-8-quinolinolato) aluminum, bis(2-methyl-5-cyano-8-quinolinolato) aluminum-p-oxo-bis(2-methyl-5-cyano-8-quinolinolato) aluminum, bis(2-methyl-5-trifluoromethyl-8-quinolinolato) aluminum-p-oxo-bis(2-methyl-5-trifluoromethyl-8-quinolinolato) aluminum, and bis(10-hydroxybenzo[h]quinoline) beryllium.

This quinolinol-based metal complex can be manufactured using known raw materials and known synthesis methods.

<Thiazole Derivative and Benzothiazole Derivative>

The thiazole derivative is, for example, a compound represented by the following formula (ETM-14-1).

ϕ-(Thiazole-based substituent) n (ETM-14-1)

The benzothiazole derivative is, for example, a compound represented by the following formula (ETM-14-2).

ϕ-(Benzothiazole-based substituent) n (ETM-14-2)

φ in each formula represents an n-valent aryl ring (preferably, an n-valent benzene ring, naphthalene ring, anthracene ring, fluorene ring, benzofluorene ring, phenalene ring, phenanthrene ring, or triphenylene ring), and n represents an integer of 1 to 4. A “thiazole-based substituent” or a “benzothiazole-based substituent” is a substituent in which the pyridyl group in the “pyridine-based substituent” in the formulas (ETM-2), (ETM-2-1), and (ETM-2-2) is substituted by the following thiazole group or benzothiazole group, and at least one hydrogen atom in the thiazole derivative and the benzothiazole derivative may be substituted by a deuterium atom.

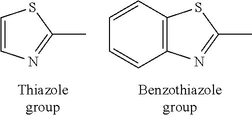

Moreover, φ is preferably an anthracene ring or a fluorene ring. For the structure in this case, the description for the above formula (ETM-2-1) or (ETM-2-2) can be cited. For R¹¹ to R¹⁸ in each formula, the description for the above formula (ETM-2-1) or (ETM-2-2) can be cited. Furthermore, in the above formula (ETM-2-1) or (ETM-2-2), a form in which two pyridine-based substituents are bonded has been described. However, when these substituents are substituted by thiazole-based substituents (or benzothiazole-based substituents), both the pyridine-based substituents may be substituted by thiazole-based substituents (or benzothiazole-based substituents) (that is, n=2), or one of the pyridine-based substituents may be substituted by a thiazole-based substituent (or benzothiazole-based substituent) and the other pyridine-based substituent may be substituted by any one of R¹¹ to R¹⁸ (that is, n=1). Moreover, for example, at least one of R¹¹ to R¹⁸ in the above formula (ETM-2-1) may be substituted by a thiazole-based substituent (or benzothiazole-based substituent) and the “pyridine-based substituent” may be substituted by any one of R¹¹ to R¹⁸.

These thiazole derivatives or benzothiazole derivatives can be manufactured using known raw materials and known synthesis methods.

An electron transport layer or an electron injection layer may further contain a substance that can reduce a material to form an electron transport layer or an electron injection layer. As this reducing substance, various substances are used as long as having reducibility to a certain extent. For example, at least one selected from the group consisting of an alkali metal, an alkaline earth metal, a rare earth metal, an oxide of an alkali metal, a halide of an alkali metal, an oxide of an alkaline earth metal, a halide of an alkaline earth metal, an oxide of a rare earth metal, a halide of a rare earth metal, an organic complex of an alkali metal, an organic complex of an alkaline earth metal, and an organic complex of a rare earth metal, can be suitably used.

Preferable examples of the reducing substance include an alkali metal such as Na (work function 2.36 eV), K (work function 2.28 eV), Rb (work function 2.16 eV), or Cs (work function 1.95 eV); and an alkaline earth metal such as Ca (work function 2.9 eV), Sr (work function 2.0 to 2.5 eV), or Ba (work function 2.52 eV). A substance having a work function of 2.9 eV or less is particularly preferable. Among these substances, an alkali metal such as K, Rb, or Cs is a more preferable reducing substance, Rb or Cs is a still more preferable reducing substance, and Cs is the most preferable reducing substance. These alkali metals have particularly high reducing ability, and can enhance emission luminance of an organic EL element or can lengthen a lifetime thereof by adding the alkali metals in a relatively small amount to a material to form an electron transport layer or an electron injection layer. Furthermore, as the reducing substance having a work function of 2.9 eV or less, a combination of two or more kinds of these alkali metals is also preferable, and particularly, a combination including Cs, for example, a combination of Cs with Na, a combination of Cs with K, a combination of Cs with Rb, or a combination of Cs with Na and K, is preferable. By inclusion of Cs, reducing ability can be efficiently exhibited, and emission luminance of an organic EL element is enhanced, or a lifetime thereof is lengthened by adding Cs to a material to form an electron transport layer or an electron injection layer.

<Negative Electrode in Organic Electroluminescent Element>

The negative electrode 108 plays a role of injecting an electron to the light emitting layer 105 through the electron injection layer 107 and the electron transport layer 106.

A material to form the negative electrode 108 is not particularly limited as long as being a substance capable of efficiently injecting an electron to an organic layer. However, a material similar to a material to form the positive electrode 102 can be used. Among these materials, a metal such as tin, indium, calcium, aluminum, silver, copper, nickel, chromium, gold, platinum, iron, zinc, lithium, sodium, potassium, cesium, or magnesium, and an alloy thereof (a magnesium-silver alloy, a magnesium-indium alloy, an aluminum-lithium alloy such as lithium fluoride/aluminum, or the like) are preferable. In order to enhance element characteristics by increasing electron injection efficiency, lithium, sodium, potassium, cesium, calcium, magnesium, or an alloy containing these low work function-metals is effective. However, many of these low work function-metals are generally unstable in air. In order to ameliorate this problem, for example, a method for using an electrode having high stability obtained by doping an organic layer with a trace amount of lithium, cesium, or magnesium is known. Other examples of a dopant that can be used include an inorganic salt such as lithium fluoride, cesium fluoride, lithium oxide, or cesium oxide. However, the dopant is not limited thereto.

Furthermore, in order to protect an electrode, a metal such as platinum, gold, silver, copper, iron, tin, aluminum, or indium, an alloy using these metals, an inorganic substance such as silica, titania, or silicon nitride, polyvinyl alcohol, vinyl chloride, a hydrocarbon-based polymer compound, or the like may be laminated as a preferable example. These method for manufacturing an electrode are not particularly limited as long as being capable of conduction, such as resistance heating, electron beam deposition, sputtering, ion plating, or coating.

<Binder that May be Used in Each Layer>

The materials used in the above-described hole injection layer, hole transport layer, light emitting layer, electron transport layer, and electron injection layer can form each layer by being used singly. However, it is also possible to use the materials by dispersing the materials in a solvent-soluble resin such as polyvinyl chloride, polycarbonate, polystyrene, poly(N-vinylcarbazole), polymethyl methacrylate, polybutyl methacrylate, polyester, polysulfone, polyphenylene oxide, polybutadiene, a hydrocarbon resin, a ketone resin, a phenoxy resin, polyamide, ethyl cellulose, a vinyl acetate resin, an ABS resin, or a polyurethane resin; or a curable resin such as a phenolic resin, a xylene resin, a petroleum resin, a urea resin, a melamine resin, an unsaturated polyester resin, an alkyd resin, an epoxy resin, or a silicone resin.

<Method for Manufacturing Organic Electroluminescent Element>

Each layer constituting an organic EL element can be formed by forming thin films of the materials to constitute each layer by methods such as a vapor deposition method, resistance heating deposition, electron beam deposition, sputtering, a molecular lamination method, a printing method, a spin coating method, a casting method, and a coating method. The film thickness of each layer thus formed is not particularly limited, and can be appropriately set according to a property of a material, but is usually within a range of 2 nm to 5000 nm. The film thickness can be usually measured using a crystal oscillation type film thickness analyzer or the like. In a case of forming a thin film using a vapor deposition method, deposition conditions depend on the kind of a material, an intended crystal structure and association structure of the film, and the like. It is preferable to appropriately set the vapor deposition conditions generally in ranges of a boat heating temperature of +50 to +400° C., a degree of vacuum of 10⁻⁶ to 10⁻³ Pa, a vapor deposition rate of 0.01 to 50 nm/sec, a substrate temperature of −150 to +300° C., and a film thickness of 2 nm to 5 μm.

Next, as an example of a method for manufacturing an organic EL element, a method for manufacturing an organic EL element formed of positive electrode/hole injection layer/hole transport layer/light emitting layer including a host material and a dopant material/electron transport layer/electron injection layer/negative electrode will be described. A thin film of a positive electrode material is formed on an appropriate substrate by a vapor deposition method or the like to manufacture a positive electrode, and then thin films of a hole injection layer and a hole transport layer are formed on this positive electrode. A thin film is formed thereon by co-depositing a host material and a dopant material to obtain a light emitting layer. An electron transport layer and an electron injection layer are formed on this light emitting layer, and a thin film formed of a substance for a negative electrode is formed by a vapor deposition method or the like to obtain a negative electrode. An intended organic EL element is thereby obtained. Incidentally, in manufacturing the above organic EL element, it is also possible to manufacture the organic EL element by reversing the manufacturing order, that is, in order of a negative electrode, an electron injection layer, an electron transport layer, a light emitting layer, a hole transport layer, a hole injection layer, and a positive electrode.

In a case where a direct current voltage is applied to the organic EL element thus obtained, it is only required to apply the voltage by assuming a positive electrode as a positive polarity and assuming a negative electrode as a negative polarity. By applying a voltage of about 2 to 40 V, light emission can be observed from a transparent or semitransparent electrode side (the positive electrode or the negative electrode, or both the electrodes). Furthermore, this organic EL element also emits light even in a case where a pulse current or an alternating current is applied. Note that a waveform of an alternating current applied may be any waveform.

<Application Examples of Organic Electroluminescent Element>

Furthermore, the present invention can also be applied to a display apparatus including an organic EL element, a lighting apparatus including an organic EL element, or the like.

The display apparatus or lighting apparatus including an organic EL element can be manufactured by a known method such as connecting the organic EL element according to the present embodiment to a known driving apparatus, and can be driven by appropriately using a known driving method such as direct driving, pulse driving, or alternating driving.

Examples of the display apparatus include panel displays such as color flat panel displays; and flexible displays such as flexible organic electroluminescent (EL) displays (see, for example, JP 10-335066 A, JP 2003-321546 A, JP 2004-281086 A, and the like). Furthermore, examples of a display method of the display include a matrix method and/or a segment method. Note that the matrix display and the segment display may co-exist in the same panel.

In the matrix, pixels for display are arranged two-dimensionally as in a lattice form or a mosaic form, and characters or images are displayed by an assembly of pixels. The shape or size of a pixel depends on intended use. For example, for display of images and characters of a personal computer, a monitor, or a television, square pixels each having a size of 300 μm or less on each side are usually used. Furthermore, in a case of a large-sized display such as a display panel, pixels having a size in the order of millimeters on each side are used. In a case of monochromic display, it is only required to arrange pixels of the same color. However, in a case of color display, display is performed by arranging pixels of red, green and blue. In this case, typically, delta type display and stripe type display are available. For this matrix driving method, either a line sequential driving method or an active matrix method may be employed. The line sequential driving method has an advantage of having a simpler structure. However, in consideration of operation characteristics, the active matrix method may be superior. Therefore, it is necessary to use the line sequential driving method or the active matrix method properly according to intended use.

In the segment method (type), a pattern is formed so as to display predetermined information, and a determined region emits light. Examples of the segment method include display of time or temperature in a digital clock or a digital thermometer, display of a state of operation in an audio instrument or an electromagnetic cooker, and panel display in an automobile.

Examples of the lighting apparatus include a lighting apparatuses for indoor lighting or the like, and a backlight of a liquid crystal display apparatus (see, for example, JP 2003-257621 A, JP 2003-277741 A, and JP 2004-119211 A). The backlight is mainly used for enhancing visibility of a display apparatus that is not self-luminous, and is used in a liquid crystal display apparatus, a timepiece, an audio apparatus, an automotive panel, a display plate, a sign, and the like. Particularly, in a backlight for use in a liquid crystal display apparatus, among the liquid crystal display apparatuses, for use in a personal computer in which thickness reduction has been a problem to be solved, in consideration of difficulty in thickness reduction because a conventional type backlight is formed from a fluorescent lamp or a light guide plate, a backlight using the luminescent element according to the present embodiment is characterized by its thinness and lightweightness.

3-2. Other Organic Devices

The polycyclic aromatic compound according to an aspect of the present invention can be used for manufacturing an organic field effect transistor, an organic thin film solar cell, or the like, in addition to the organic electroluminescent element described above.

The organic field effect transistor is a transistor that controls a current by means of an electric field generated by voltage input, and is provided with a source electrode, a drain electrode, and a gate electrode. When a voltage is applied to the gate electrode, an electric field is generated, and the organic field effect transistor can control a current by arbitrarily damming a flow of electrons (or holes) that flow between the source electrode and the drain electrode. The field effect transistor can be easily miniaturized compared with a simple transistor (bipolar transistor), and is often used as an element constituting an integrated circuit or the like.

The structure of the organic field effect transistor is usually as follows. That is, a source electrode and a drain electrode are provided in contact with an organic semiconductor active layer formed using the polycyclic aromatic compound according to an aspect of the present invention, and it is only required that a gate electrode is further provided so as to interpose an insulating layer (dielectric layer) in contact with the organic semiconductor active layer. Examples of the element structure include the following structures.

(1) Substrate/gate electrode/insulator layer/source electrode and drain electrode/organic semiconductor active layer
(2) Substrate/gate electrode/insulator layer/organic semiconductor active layer/source electrode and drain electrode
(3) Substrate/organic semiconductor active layer/source electrode and drain electrode/insulator layer/gate electrode
(4) Substrate/source electrode and drain electrode/organic semiconductor active layer/insulator layer/gate electrode

An organic field effect transistor thus constituted can be applied as a pixel driving switching element of an active matrix driving type liquid crystal display or an organic electroluminescent display, or the like.

An organic thin film solar cell has a structure in which a positive electrode such as ITO, a hole transport layer, a photoelectric conversion layer, an electron transport layer, and a negative electrode are laminated on a transparent substrate of glass or the like. The photoelectric conversion layer has a p-type semiconductor layer on the positive electrode side, and has an n-type semiconductor layer on the negative electrode side. The polycyclic aromatic compound according to an aspect of the present invention can be used as a material for a hole transport layer, a p-type semiconductor layer, an n-type semiconductor layer, or an electron transport layer, depending on physical properties thereof. The polycyclic aromatic compound according to an aspect of the present invention can function as a hole transport material or an electron transport material in an organic thin film solar cell. The organic thin film solar cell may appropriately include a hole blocking layer, an electron blocking layer, an electron injection layer, a hole injection layer, a smoothing layer, and the like, in addition to the members described above. For the organic thin film solar cell, known materials used for an organic thin film solar cell can be appropriately selected and used in combination.

### EXAMPLES

Hereinafter, the present invention will be described more specifically by way of Examples, but the present invention is not limited thereto. First, a synthesis example of a polycyclic aromatic compound will be described below.

### Synthesis Example (1): Synthesis of Compound (1-22)

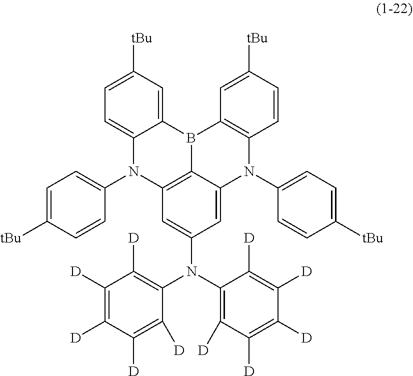 [SMILES: [2H]c1c([2H])c([2H])c(N(c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)c2c([2H])c([2H])c([2H])c([2H])c2[2H])c([2H])c1[2H]]

Under an atmosphere of nitrogen, 3,4,5-trichloroaniline (12.0 g), d⁵-bromobenzene (30.0 g), dichlorobis[(di-t-butyl (4-dimethylaminophenyl) phosphino) palladium (Pd-132, 0.43 g) as a palladium catalyst, sodium-t-butoxide (NaOtBu, 14.7 g), and xylene (200 ml) were put in a flask and heated at 120° C. for three hours. After a reaction, water and ethyl acetate were added to the reaction solution, followed by stirring. Thereafter, the organic layer was separated and washed with water. Thereafter, the organic layer was concentrated to obtain a crude product. The crude product was purified with a silica gel short pass column (eluent: toluene/heptane=1/1 (volume ratio)) to obtain intermediate (I-A) (15.0 g).

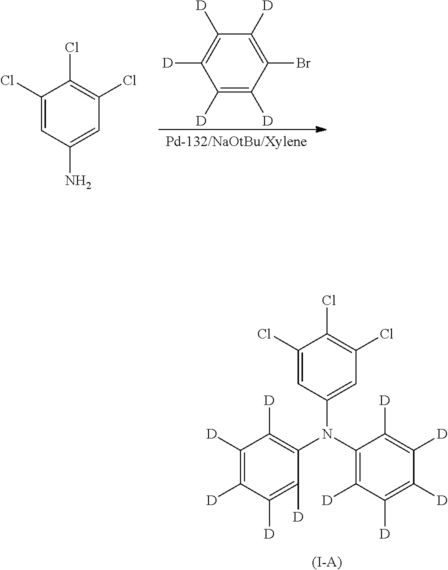

Under an atmosphere of nitrogen, intermediate (I-A) (15.0 g), bis(4-t-butylphenyl) amine (25.9 g), bis(dibenzylideneacetone) palladium (0.48 g), 2-dicyclohexylphosphino-2′,6′-dimethoxybiphenyl (SPhos, 0.86 g), sodium-t-butoxide (10.0 g), and xylene (130 ml) were put in a flask and heated at 100° C. for one hour. After a reaction, water and toluene were added to the reaction solution, followed by stirring. Thereafter, the organic layer was separated and washed with water. Thereafter, the organic layer was concentrated to obtain a crude product. The crude product was purified with a silica gel short pass column (eluent: toluene) to obtain intermediate (I-B) (23.0 g).

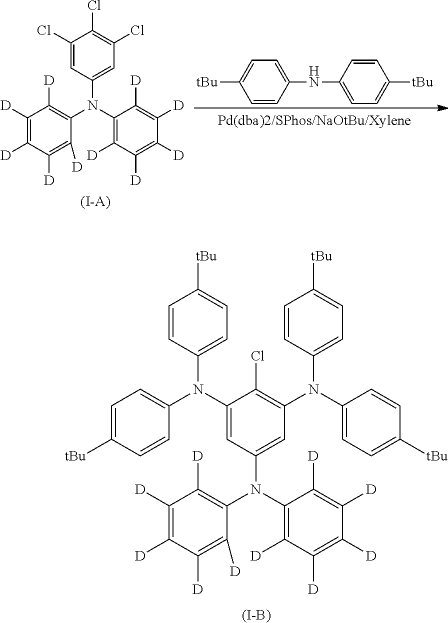

Under an atmosphere of nitrogen, a 1.62 M tert-butyllithium pentane solution (33.5 ml) was put in a flask containing intermediate (I-B) (23.0 g) and tert-butylbenzene (250 ml) at 0° C. After completion of dropwise addition, the temperature of the mixture was increased to 60° C., the mixture was stirred for one hour, and then components having boiling points lower than that of tert-butylbenzene were distilled off under reduced pressure. The residue was cooled to −50° C., boron tribromide (13.6 g) was added thereto, the temperature of the mixture was raised to room temperature, and the mixture was stirred for 0.5 hours. Thereafter, the mixture was cooled again to 0° C., N,N-diisopropylethylamine (7.0 g) was added thereto, and the mixture was stirred at room temperature until heat generation was settled. Subsequently, the temperature of the mixture was raised to 100° C., and the mixture was heated and stirred for one hour. The reaction liquid was cooled to room temperature, an aqueous solution of sodium acetate that had been cooled in an ice bath and then ethyl acetate were added thereto, and the mixture was partitioned. The organic layer was concentrated, and then purified with a silica gel short pass column (eluent: heated chlorobenzene). The obtained crude product was washed with refluxed heptane and refluxed ethyl acetate, and then was further reprecipitated from chlorobenzene. Thus, compound (1-22) was obtained (12.9 g).

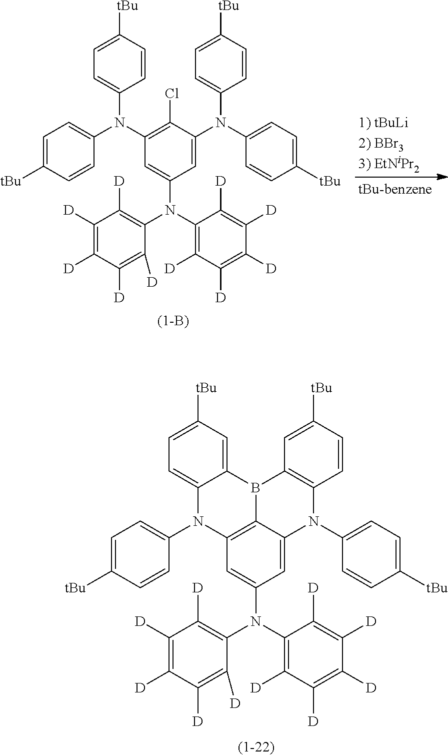

The structure of the compound thus obtained was identified by an NMR analysis.

¹H-NMR (CDCl₃): δ=1.3 (s, 18H), 1.5 (s, 18H), 5.6 (s, 2H), 6.8 (d, 2H), 7.1 (m, 4H), 7.4 to 7.5 (m, 6H), 9.0 (d, 2H).

### Synthesis Example (2): Synthesis of Compound (1-102)

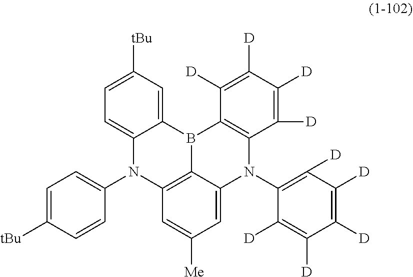 [SMILES: [2H]c1c([2H])c([2H])c(N2c3cc(C)cc4c3B(c3cc(C(C)(C)C)ccc3N4c3ccc(C(C)(C)C)cc3)c3c([2H])c([2H])c([2H])c([2H])c32)c([2H])c1[2H]]

Under an atmosphere of nitrogen, d⁵-aniline (5.0 g), d⁵-bromobenzene (8.25 g), Pd-132 (0.36 g) as a palladium catalyst, NaOtBu (7.1 g), and xylene (100 ml) were put in a flask and heated at 120° C. for 1.5 hours. After a reaction, water and ethyl acetate were added to the reaction solution, followed by stirring. Thereafter, the organic layer was separated and washed with water. Thereafter, the organic layer was concentrated to obtain a crude product. The crude product was purified with a silica gel short pass column (eluent: toluene/heptane=1/1 (volume ratio)) to obtain intermediate (I-C) (8.1 g).

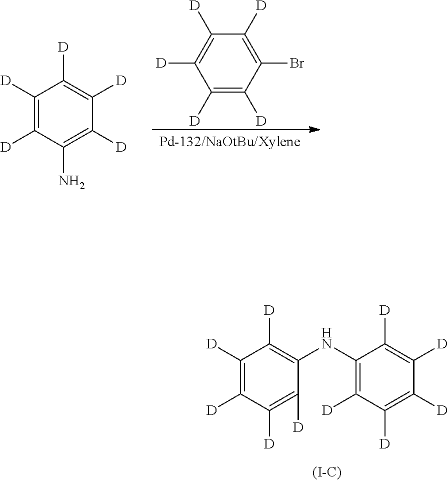

Under an atmosphere of nitrogen, intermediate (I-C) (8.0 g), intermediate (I-D) (20.6 g), Pd-132 (0.31 g) as a palladium catalyst, NaOtBu (6.4 g), and xylene (100 ml) were put in a flask and heated at 120° C. for one hour. After a reaction, water and ethyl acetate were added to the reaction solution, followed by stirring. Thereafter, the organic layer was separated and washed with water. Thereafter, the organic layer was concentrated to obtain a crude product. The crude product was purified with a silica gel short pass column (eluent: toluene/heptane=1/1 (volume ratio)) to obtain intermediate (I-E) (20.2 g).

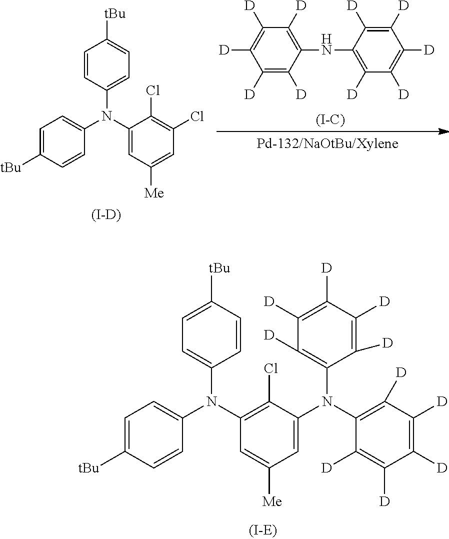

Under an atmosphere of nitrogen, a 1.62 M tert-butyllithium pentane solution (21.2 ml) was put in a flask containing intermediate (I-E) (10.0 g) and tert-butylbenzene (150 ml) at 0° C. After completion of dropwise addition, the temperature of the mixture was raised to 60° C., and the mixture was stirred for 0.5 hours. Thereafter, a component having a boiling point lower than that of tert-butylbenzene was distilled off under reduced pressure. The residue was cooled to −50° C., boron tribromide (8.6 g) was added thereto, the temperature of the mixture was raised to room temperature, and the mixture was stirred for 0.5 hours. Thereafter, the mixture was cooled again to 0° C., N,N-diisopropylethylamine (4.4 g) was added thereto, and the mixture was stirred at room temperature until heat generation was settled. Subsequently, the temperature of the mixture was raised to 100° C., and the mixture was heated and stirred for one hour. The reaction liquid was cooled to room temperature, an aqueous solution of sodium acetate that had been cooled in an ice bath and then ethyl acetate were added thereto, and the mixture was partitioned. The organic layer was concentrated, and then purified with a silica gel short pass column (eluent: toluene). The obtained crude product was dissolved in toluene. Thereafter, heptane was added thereto, and the precipitated crystal was filtered, and the filtered crystal was washed with cooled heptane to obtain compound (1-102) (3.1 g).

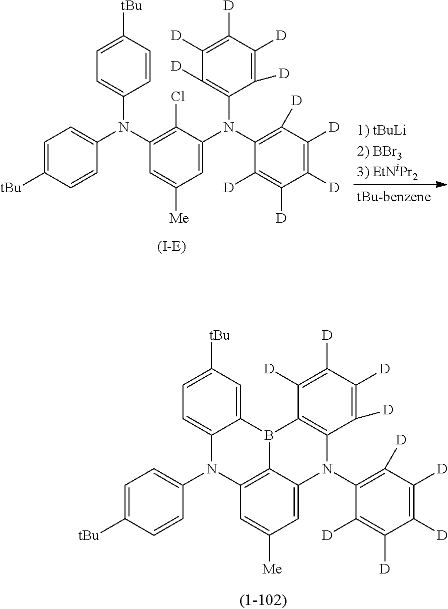 [SMILES: [2H]c1c([2H])c([2H])c(N(c2cc(C)cc(N(c3ccc(C(C)(C)C)cc3)c3ccc(C(C)(C)C)cc3)c2Cl)c2c([2H])c([2H])c([2H])c([2H])c2[2H])c([2H])c1[2H] ; [2H]c1c([2H])c([2H])c(N2c3cc(C)cc4c3B(c3cc(C(C)(C)C)ccc3N4c3ccc(C(C)(C)C)cc3)c3c([2H])c([2H])c([2H])c([2H])c32)c([2H])c1[2H]]

The structure of the compound thus obtained was identified by an NMR analysis.

¹H-NMR (CDCl₃): δ=1.46 (s, 9H), 1.47 (s, 9H), 2.16 (s, 3H), 5.92 (s, 1H), 6.00 (s, 1H), 6.69 (d, 1H), 7.25-7.28 (m, 2H), 7.49-7.51 (m, 1H), 7.66-7.69 (m, 2H), 8.92 (d, 1H).

### Synthesis Example (3): Synthesis of Compound (1-122)

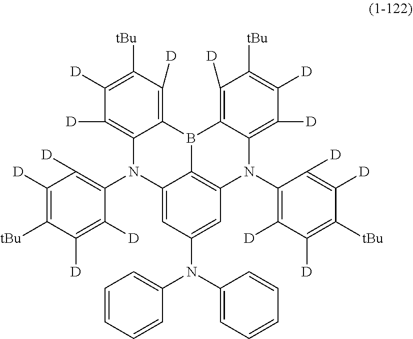 [SMILES: [2H]c1c([2H])c(C(C)(C)C)c([2H])c([2H])c1N1c2cc(N(c3ccccc3)c3ccccc3)cc3c2B(c2c([2H])c(C(C)(C)C)c([2H])c([2H])c21)c1c([2H])c(C(C)(C)C)c([2H])c([2H])c1N3c1c([2H])c([2H])c(C(C)(C)C)c([2H])c1[2H]]

Under an atmosphere of nitrogen, intermediate (I-F) (8.4 g), intermediate (I-H) (4.6 g), bis(dibenzylideneacetone) palladium (0.23 g), 2-dicyclohexylphosphino-2′,6′-dimethoxybiphenyl (SPhos, 0.32 g), sodium-t-butoxide (3.2 g), and xylene (40 ml) were put in a flask and heated at 100° C. for 1.5 hours. After a reaction, water and toluene were added to the reaction solution, followed by stirring. Thereafter, the organic layer was separated and washed with water. Thereafter, the organic layer was concentrated to obtain a crude product. The crude product was purified with a silica gel short pass column (eluent: toluene) to obtain intermediate (I-J) (8.6 g)

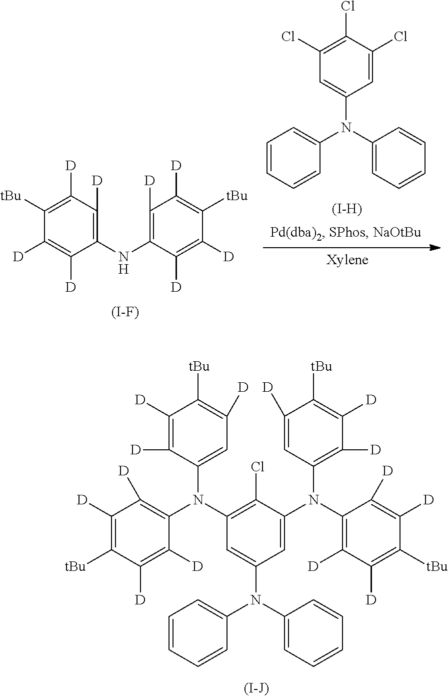

Under an atmosphere of nitrogen, a 1.62 M tert-butyllithium pentane solution (12.9 ml) was put in a flask containing intermediate (I-J) (8.6 g) and tert-butylbenzene (90 ml) at 0° C. After completion of dropwise addition, the temperature of the mixture was increased to 70° C., the mixture was stirred for 0.5 hours, and components having boiling points lower than that of tert-butylbenzene were distilled off under reduced pressure. The residue was cooled to −50° C., boron tribromide (5.0 g) was added thereto, the temperature of the mixture was raised to room temperature, and the mixture was stirred for 0.5 hours. Thereafter, the mixture was cooled again to 0° C., N,N-diisopropylethylamine (2.6 g) was added thereto, and the mixture was stirred at room temperature until heat generation was settled. Subsequently, the temperature of the mixture was raised to 100° C., and the mixture was heated and stirred for one hour. The reaction liquid was cooled to room temperature, an aqueous solution of sodium acetate that had been cooled in an ice bath and then ethyl acetate were added thereto, and the mixture was stirred for one hour. A yellow suspension was filtered, and the precipitate was washed twice with methanol and pure water, and again washed with methanol. The yellow crystal was heated and dissolved in chlorobenzene, and then purified with a silica gel short pass column (eluent: heated chlorobenzene). The obtained crude product was filtered by adding heptane, and then the crystal was washed with heptane to obtain compound (1-122) (6.5 g).

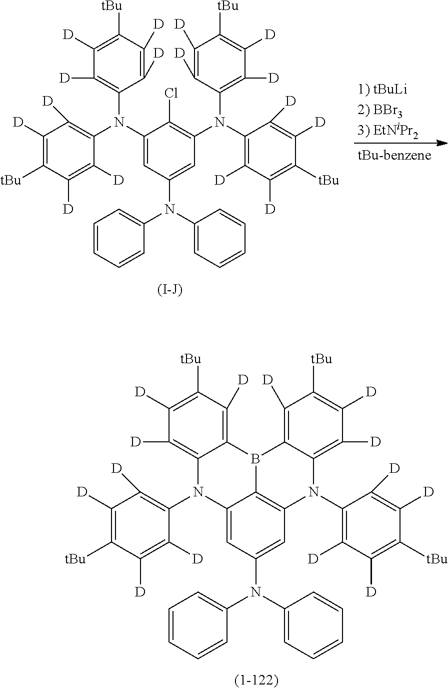 [SMILES: [2H]c1c([2H])c(C(C)(C)C)c([2H])c([2H])c1N(c1cc(N(c2ccccc2)c2ccccc2)cc(N(c2c([2H])c([2H])c(C(C)(C)C)c([2H])c2[2H])c2c([2H])c([2H])c(C(C)(C)C)c([2H])c2[2H])c1Cl)c1c([2H])c([2H])c(C(C)(C)C)c([2H])c1[2H] ; [2H]c1c([2H])c(C(C)(C)C)c([2H])c([2H])c1N1c2cc(N(c3ccccc3)c3ccccc3)cc3c2B(c2c([2H])c(C(C)(C)C)c([2H])c([2H])c21)c1c([2H])c(C(C)(C)C)c([2H])c([2H])c1N3c1c([2H])c([2H])c(C(C)(C)C)c([2H])c1[2H]]

The structure of the compound thus obtained was identified by an NMR analysis.

¹H-NMR (CDCl₃): δ=1.33 (s, 18H), 1.46 (s, 18H), 5.55 (s, 2H), 6.88 (t, 2H), 6.94 (d, 4H), 7.06 (dd, 4H).

### Synthesis Example (4): Synthesis of Compound (1-107)

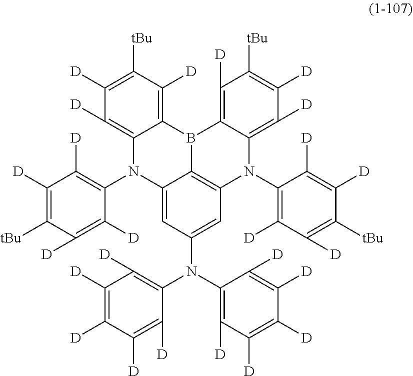 [SMILES: [2H]c1c([2H])c([2H])c(N(c2cc3c4c(c2)N(c2c([2H])c([2H])c(C(C)(C)C)c([2H])c2[2H])c2c([2H])c([2H])c(C(C)(C)C)c([2H])c2B4c2c([2H])c(C(C)(C)C)c([2H])c([2H])c2N3c2c([2H])c([2H])c(C(C)(C)C)c([2H])c2[2H])c2c([2H])c([2H])c([2H])c([2H])c2[2H])c([2H])c1[2H]]

Under an atmosphere of nitrogen, intermediate (I-F) (10.7 g), intermediate (I-A) (6.0 g), bis(dibenzylideneacetone) palladium (0.58 g), 2-dicyclohexylphosphino-2′,6′-dimethoxybiphenyl (SPhos, 0.82 g), sodium-t-butoxide (4.0 g), and xylene (60 ml) were put in a flask and heated at 100° C. for 1.5 hours. After a reaction, water and toluene were added to the reaction solution, followed by stirring. Thereafter, the organic layer was separated and washed with water. Thereafter, the organic layer was concentrated to obtain a crude product. The crude product was purified with a silica gel short pass column (eluent: toluene), and the obtained solid was washed with cooled heptane to obtain intermediate (I-K) (9.4 g).

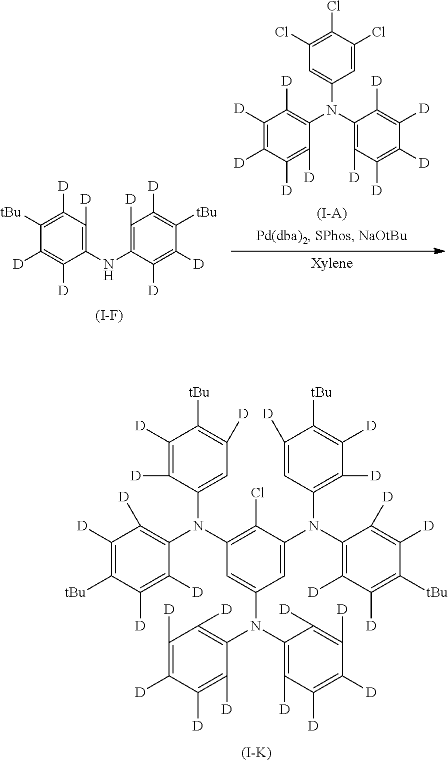

Under an atmosphere of nitrogen, a 1.62 M tert-butyllithium pentane solution (13.8 ml) was put in a flask containing intermediate (I-K) (8.6 g) and tert-butylbenzene (100 ml) at 0° C. After completion of dropwise addition, the temperature of the mixture was raised to 60° C., and the mixture was stirred for 0.5 hours. Thereafter, a component having a boiling point lower than that of tert-butylbenzene was distilled off under reduced pressure. The residue was cooled to −50° C., boron tribromide (5.4 g) was added thereto, the temperature of the mixture was raised to room temperature, and the mixture was stirred for 0.5 hours. Thereafter, the mixture was cooled again to 0° C., N,N-diisopropylethylamine (2.8 g) was added thereto, and the mixture was stirred at room temperature until heat generation was settled. Subsequently, the temperature of the mixture was raised to 100° C., and the mixture was heated and stirred for one hour. The reaction liquid was cooled to room temperature, an aqueous solution of sodium acetate that had been cooled in an ice bath and then ethyl acetate were added thereto, and the mixture was stirred for one hour. A yellow suspension was filtered, and the precipitate was washed twice with methanol and pure water, and again washed with methanol. The yellow crystal was heated and dissolved in chlorobenzene, and then purified with a silica gel short pass column (eluent: heated chlorobenzene). The obtained crude product was filtered by adding heptane, and then the crystal was washed with heptane to obtain compound (1-107) (5.9 g).

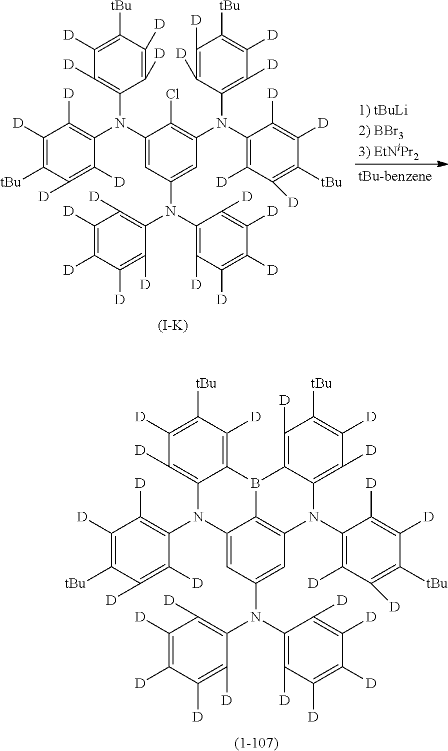

The structure of the compound thus obtained was identified by an NMR analysis.

¹H-NMR (CDCl₃): δ=1.32 (s, 18H), 1.46 (s, 18H), 5.55 (s, 2H).

Other polycyclic aromatic compounds according to an aspect of the present invention can be synthesized by a method in accordance with those in Synthesis Examples described above by appropriately changing the compounds of raw materials.

### Comparative Synthesis Example (1)

### Synthesis of Comparative Compound (1):2,12-di-t-butyl-5,9-bis(4-(t-butyl)phenyl)-N,N-dipheny-5,9-dihydro-5,9-diaza-13b-boranaphtho[3,2,1-de]anthracene-7-amine

Comparative compound (1) was synthesized using a similar method to that in Synthesis Example (1) described above.

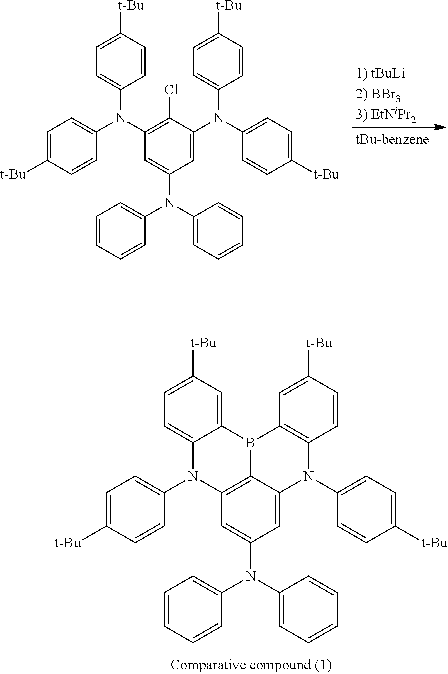 [SMILES: CC(C)(C)c1ccc(N(c2ccc(C(C)(C)C)cc2)c2cc(N(c3ccccc3)c3ccccc3)cc(N(c3ccc(C(C)(C)C)cc3)c3ccc(C(C)(C)C)cc3)c2Cl)cc1 ; CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1]

The structure of the compound thus obtained was identified by an NMR analysis.

¹H-NMR (CDCl₃): δ=1.33 (s, 18H), 1.46 (s, 18H), 5.55 (s, 2H), 6.75 (d, 2H), 6.89 (t, 2H), 6.94 (d, 4H), 7.06 (t, 4H), 7.13 (d, 4H), 7.43 to 7.46 (m, 6H), 8.95 (d, 2H).

Next, Examples of an organic EL element using the compound according to an aspect of the present invention will be described in order to describe the present invention in more detail, but the present invention is not limited thereto.

<Evaluation of Organic EL Element>

Organic EL elements according to Examples 1 to 3 and Comparative Example 1 were manufactured. For each of the elements, a voltage (V), an emission wavelength (nm), and an external quantum efficiency (%), which are characteristics at the time of light emission at 1000 cd/m², were measured. Subsequently, time during which 90% or more of initial luminance was held at the time of driving at a constant current at a current density of 10 mA/cm² was measured.

A quantum efficiency of a luminescent element includes an internal quantum efficiency and an external quantum efficiency. The internal quantum efficiency indicates a ratio at which external energy injected as electrons (or holes) into a light emitting layer of the luminescent element is purely converted into photons. Meanwhile, the external quantum efficiency is calculated based on the amount of these photons emitted to an outside of the luminescent element. A part of the photons generated in the light emitting layer is absorbed or reflected continuously inside the luminescent element, and is not emitted to the outside of the luminescent element. Therefore, the external quantum efficiency is lower than the internal quantum efficiency.

A method for measuring the external quantum efficiency is as follows. Using a voltage/current generator R6144 manufactured by Advantest Corporation, a voltage at which luminance of an element was 1000 cd/m² was applied to cause the element to emit light. Using a spectral radiance meter SR-3AR manufactured by TOPCON Co., spectral radiance in a visible light region was measured from a direction perpendicular to a light emitting surface. Assuming that the light emitting surface is a perfectly diffusing surface, a numerical value obtained by dividing a spectral radiance value of each measured wavelength component by wavelength energy and multiplying the obtained value by n is the number of photons at each wavelength. Subsequently, the number of photons was integrated in the observed entire wavelength region, and this number was taken as the total number of photons emitted from the element. A numerical value obtained by dividing an applied current value by an elementary charge is taken as the number of carriers injected into the element. The external quantum efficiency is a numerical value obtained by dividing the total number of photons emitted from the element by the number of carriers injected into the element.

The following Table 1 indicates a material composition of each layer and EL characteristic data in organic EL elements manufactured according to Example 1 and Comparative Example 1.

TABLE 1

| | Hole | Hole | Hole | Hole | | | Electron | Electron | |
|---|---|---|---|---|---|---|---|---|---|
| | injection | injection | transport | transport | Light emitting | | transport | transport | Negative |
| | layer 1 | layer 2 | layer 1 | layer 2 | layer (25 nm) | | layer 1 | layer 2 | electrode |
| | (40 nm) | (5 nm) | (15 nm) | (10 nm) | Host | Dopant | (5 nm) | (25 nm) | 1 nm/100 nm |
| Example 1 | HI | HAT-CN | HT-1 | HT-2 | BH-1 | 1-22 | ET-1 | ET-2 + | LiF/Al |
| | | | | | | | | Liq | |
| Comparative | HI | HAT-CN | HT-1 | HT-2 | BH-1 | Comparative | ET-1 | ET-2 + | LiF/Al |
| Example 1 | | | | | | compound | | Liq | |
| | | | | | | (1) | | | |

| | | | External | Time during which 90% |
|---|---|---|---|---|
| | | | quantum | or more of initial |
| | Wavelength | Voltage | efficiency | luminance is held |
| | (nm) | (V) | (%) | (Time) |
| Example 1 | 456 | 3.64 | 8.01 | 405 |
| Comparative | 455 | 3.69 | 7.45 | 334 |
| Example 1 | | | | |

In Table 1, “HI” represents N⁴,N^{4′}-diphenyl-N⁴,N^{4′}-bis(9-phenyl-9H-carbazol-3-yl)-[1,1′-biphenyl]-4,4′-diamine, “HAT-CN” represents 1,4,5,8,9,12-hexaazatriphenylene hexacarbonitrile, “HT-1” represents N-([1,1′-biphenyl]-4-yl)-9,9-dimethyl-N-(4-(9-phenyl-9H-carbazol-3-yl) phenyl)-9H-fluorene-2-amine[1,1′-biphenyl]-4-amine, “HT-2” represents N,N-bis(4-(dibenzo[b,d]furan-4-yl) phenyl)-[1,1′: 4′,1″-terphenyl]-4-amine, “BH-1” represents 2-(10-phenylanthracene-9-yl) naphtho[2,3-b]benzofuran, “ET-1” represents 4,6,8,10-tetraphenyl[1,4]benzoxaborinino[2,3,4-kl]phenoxaborinine, and “ET-2” represents 3,3′-((2-phenylanthracene-9,10-diyl) bis(4,1-phenylene)) bis(4-methylpyridine). Chemical structures thereof are indicated below together with “Liq”.

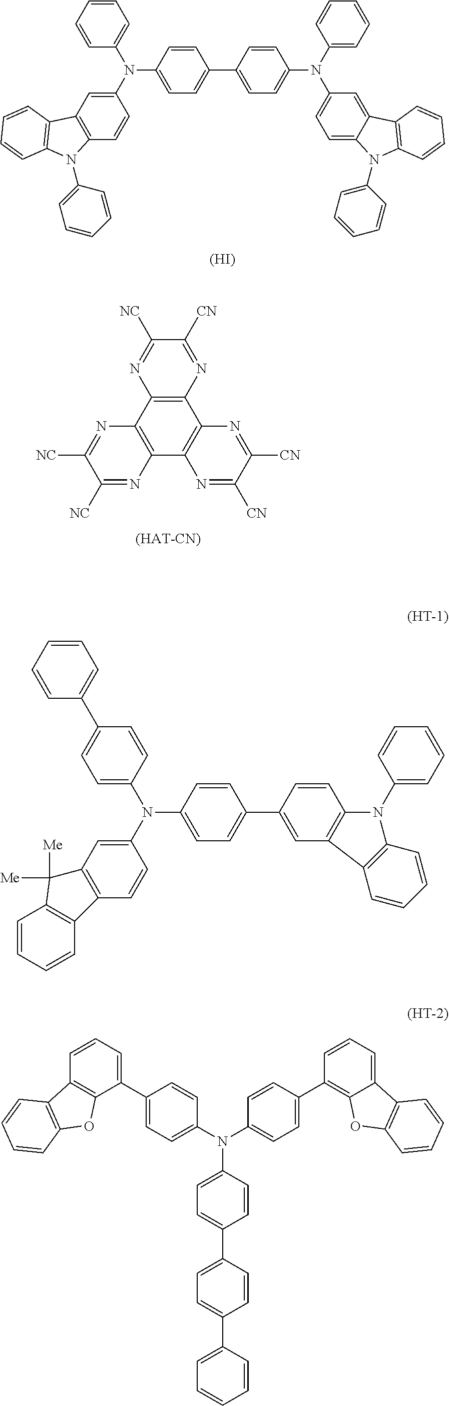 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; "(HI)" ; N#Cc1nc2c3nc(C#N)c(C#N)nc3c3nc(C#N)c(C#N)nc3c2nc1C#N ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

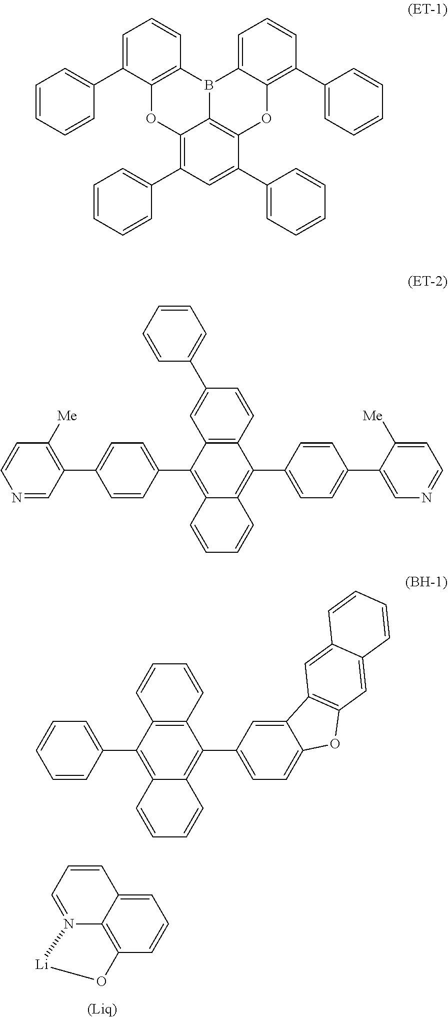

### Example 1

<Element in which Host is BH-1 and Dopant is Compound (1-22)>

A glass substrate (manufactured by Opto Science, Inc.) having a size of 26 mm×28 mm×0.7 mm, which was obtained by forming a film of ITO having a thickness of 180 nm by sputtering, and polishing the ITO film to 150 nm, was used as a transparent supporting substrate. This transparent support substrate was fixed to a substrate holder of a commercially available vapor deposition apparatus (manufactured by Sowa Shinku Co., Ltd.). Molybdenum vapor deposition boats containing HI, HAT-CN, HT-1, HT-2, BH-1, compound (1-22), ET-1, and ET-2, respectively, and aluminum nitride vapor deposition boats containing Liq, LiF, and aluminum, respectively, were attached thereto.

Layers as described below were formed sequentially on the ITO film of the transparent supporting substrate. A vacuum chamber was depressurized to 5×10⁻⁴ Pa. First, HI was heated and vapor-deposited so as to have a film thickness of 40 nm. Subsequently, HAT-CN was heated and vapor-deposited so as to have a film thickness of 5 nm. Subsequently, HT-1 was heated and vapor-deposited so as to have a film thickness of 15 nm. Subsequently, HT-2 was heated and vapor-deposited so as to have a film thickness of 10 nm. Thus, a hole layer formed of four layers was formed. Subsequently, BH-1 and compound (1-22) were simultaneously heated and vapor-deposited so as to have a film thickness of 25 nm. Thus, a light emitting layer was formed. The vapor deposition rate was regulated such that a weight ratio between BH-1 and compound (1-22) was approximately 98:2. Moreover, ET-1 was heated and vapor-deposited so as to have a film thickness of 5 nm. Subsequently, ET-2 and Liq were simultaneously heated and vapor-deposited so as to have a film thickness of 25 nm to form an electron layer formed of two layers. The vapor deposition rate was regulated such that the weight ratio between ET-2 and Liq was approximately 50:50. The vapor deposition rate for each layer was 0.01 to 1 nm/sec. Thereafter, LiF was heated and vapor-deposited at a vapor deposition rate of 0.01 to 0.1 nm/sec so as to have a film thickness of 1 nm. Subsequently, aluminum was heated and vapor-deposited so as to have a film thickness of 100 nm. Thus, a negative electrode was formed to obtain an organic EL element.

A direct current voltage was applied using an ITO electrode as a positive electrode and a LiF/aluminum electrode as a negative electrode, and characteristics at the time of light emission at 1000 cd/m² were measured. As a result, blue light emission with a wavelength of 456 nm was obtained, a driving voltage was 3.64 V, and an external quantum efficiency was 8.01%. Furthermore, time during which 90% or more of initial luminance was held was 405 hours.

### Comparative Example 1

<Element in which Host is BH-1 and Dopant is Comparative Compound (1)>

An organic EL element was obtained by a method in accordance with that of Example 1 except that the dopant material was changed from compound (1-22) to comparative compound (1). Characteristics at the time of light emission at 1000 cd/m² were measured. As a result, blue light emission with a wavelength of 455 nm was obtained, a driving voltage was 3.69 V, and an external quantum efficiency was 7.45%. Furthermore, time during which 90% or more of initial luminance was held was 334 hours.

The following Table 2 indicates a material composition of each layer and EL characteristic data in organic EL elements further manufactured according to Examples 2 and 3.

TABLE 2

| | | | | | Light | | | | |
|---|---|---|---|---|---|---|---|---|---|
| | Hole | Hole | Hole | Hole | emitting | | Electron | Electron | |
| | injection | injection | transport | transport | layer | | transport | transport | Negative |
| | layer 1 | layer 2 | layer 1 | layer 2 | (25 nm) | | layer 1 | layer 2 | electrode |
| | (40 nm) | (5 nm) | (45 nm) | (10 nm) | Host | Dopant | (5 nm) | (25 nm) | 1 nm/100 nm |
| Example 2 | HI | HAT-CN | HT-1 | HT-2 | BH-1 | 1-122 | ET-1 | ET-2 + Liq | LiF/Al |
| Example 3 | HI | HAT-CN | HT-1 | HT-2 | BH-1 | 1-107 | ET-1 | ET-2 + Liq | LiF/Al |

| | | | | Time during which |
|---|---|---|---|---|
| | | | External | 90% or more of |
| | | | quantum | initial luminance |
| | Wavelength | Voltage | efficiency | is held |
| | (nm) | (V) | (%) | (Time) |
| Example 2 | 456 | 3.75 | 7.91 | 348 |
| Example 3 | 456 | 3.67 | 7.95 | 375 |

### Example 2

<Element in which Host is BH-1 and Dopant is Compound (1-122)>

A glass substrate (manufactured by Opto Science, Inc.) having a size of 26 mm×28 mm×0.7 mm, which was obtained by forming a film of ITO having a thickness of 180 nm by sputtering, and polishing the ITO film to 150 nm, was used as a transparent supporting substrate. This transparent support substrate was fixed to a substrate holder of a commercially available vapor deposition apparatus (manufactured by Sowa Shinku Co., Ltd.). Tantalum vapor deposition boats containing HI, HAT-CN, HT-1, HT-2, BH-1, compound (1-222), ET-1, and ET-2, respectively, and aluminum nitride vapor deposition boats containing Liq, LiF, and aluminum, respectively, were attached thereto.

Layers as described below were formed sequentially on the ITO film of the transparent supporting substrate. A vacuum chamber was depressurized to 5×10⁻⁴ Pa. First, HI was heated and vapor-deposited so as to have a film thickness of 40 nm. Subsequently, HAT-CN was heated and vapor-deposited so as to have a film thickness of 5 nm. Subsequently, HT-1 was heated and vapor-deposited so as to have a film thickness of 45 nm. Subsequently, HT-2 was heated and vapor-deposited so as to have a film thickness of 10 nm. Thus, a hole layer formed of four layers was formed. Subsequently, BH-1 and compound (1-122) were simultaneously heated and vapor-deposited so as to have a film thickness of 25 nm. Thus, a light emitting layer was formed. The vapor deposition rate was regulated such that a weight ratio between BH-1 and compound (1-122) was approximately 98:2. Moreover, ET-1 was heated and vapor-deposited so as to have a film thickness of 5 nm. Subsequently, ET-2 and Liq were simultaneously heated and vapor-deposited so as to have a film thickness of 25 nm to form an electron layer formed of two layers. The vapor deposition rate was regulated such that the weight ratio between ET-2 and Liq was approximately 50:50. The vapor deposition rate for each layer was 0.01 to 1 nm/sec. Thereafter, LiF was heated and vapor-deposited at a vapor deposition rate of 0.01 to 0.1 nm/sec so as to have a film thickness of 1 nm. Subsequently, aluminum was heated and vapor-deposited so as to have a film thickness of 100 nm. Thus, a negative electrode was formed to obtain an organic EL element.

A direct current voltage was applied using an ITO electrode as a positive electrode and a LiF/aluminum electrode as a negative electrode, and characteristics at the time of light emission at 1000 cd/m² were measured. As a result, blue light emission with a wavelength of 456 nm was obtained, a driving voltage was 3.75 V, and an external quantum efficiency was 7.91%. Furthermore, time during which 90% or more of initial luminance was held was 348 hours.

<Element in which Host is BH-1 and Dopant is Compound (1-107)>

An organic EL element was obtained by a method in accordance with that of Example 2 except that the dopant material was changed from compound (1-122) to compound (1-107). Characteristics at the time of light emission at 1000 cd/m² were measured. As a result, blue light emission with a wavelength of 456 nm was obtained, a driving voltage was 3.67 V, and an external quantum efficiency was 7.95%. Furthermore, time during which 90% or more of initial luminance was held was 375 hours.

### INDUSTRIAL APPLICABILITY

In the present invention, by providing a novel deuterium-substituted polycyclic aromatic compound, it is possible to increase options of a material for an organic device such as a material for an organic EL element. Furthermore, by using the novel deuterium-substituted polycyclic aromatic compound as a material for an organic EL element, it is possible to provide, for example, an organic EL element having excellent luminous efficiency and element lifetime, a display apparatus including the organic EL element, a lighting apparatus including the organic EL element, and the like.

### REFERENCE NUMERALS OF FIGURES

100 Organic EL element
101 Substrate
102 Positive electrode
103 Hole injection layer
104 Hole transport layer
105 Light emitting layer
106 Electron transport layer
107 Electron injection layer
108 Negative electrode

What is claimed is:

1. A polycyclic aromatic compound represented by the following general formula (1) or a multimer of a polycyclic aromatic compound having a plurality of structures each represented by the following general formula (1) 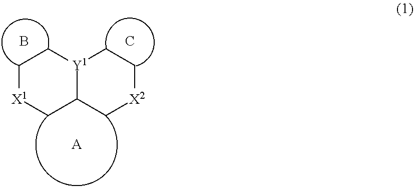
In the above formula (1),
ring A, ring B, and ring C each independently represent an aryl ring or a heteroaryl ring, while at least one hydrogen atom in these rings may be substituted,
Y¹ represents B, P, P═O, P═S, Al, Ga, As, Si—R, or Ge—R, while R in the Si—R and Ge—R represents an aryl, an alkyl or a cycloalkyl,
X¹ and X² each independently represent O, N—R, S, or Se, while R of the N—R represents an optionally substituted aryl, an optionally substituted heteroaryl, an optionally substituted alkyl, or an optionally substituted cycloalkyl, and R in the N—R may be bonded to the ring A, ring B, and/or ring C via a linking group or a single bond,
at least one hydrogen atom in a compound or a structure represented by formula (1) may be substituted by cyano or a halogen atom, and
at least one hydrogen atom in the compound or the structure represented by formula (1) is substituted by a deuterium atom.

2. The polycyclic aromatic compound or the multimer thereof according to claim 1, wherein
the ring A, ring B, and ring C each independently represent an aryl ring or a heteroaryl ring, while at least one hydrogen atom in these rings may be substituted by a substituted or unsubstituted aryl, a substituted or unsubstituted heteroaryl, a substituted or unsubstituted diarylamino, a substituted or unsubstituted diheteroarylamino, a substituted or unsubstituted arylheteroarylamino, a substituted or unsubstituted alkyl, a substituted or unsubstituted cycloalkyl, a substituted or unsubstituted alkoxy, or a substituted or unsubstituted aryloxy, and each of these rings has a 5-membered or 6-membered ring sharing a bond with a fused bicyclic structure at a center of the above formula constituted by Y¹, X¹, and X²,
Y¹ represents B, P, P═O, P═S, Al, Ga, As, Si—R, or Ge—R, while R in the Si—R and Ge—R represents an aryl, an alkyl or a cycloalkyl,
X¹ and X² each independently represent O, N—R, S, or Se, while R in the N—R represents an aryl optionally substituted by an alkyl or a cycloalkyl, a heteroaryl optionally substituted by an alkyl or a cycloalkyl, a cycloalkyl optionally substituted by an alkyl or a cycloalkyl, or alkyl optionally substituted by an alkyl or a cycloalkyl, R in the N—R may be bonded to the ring A, ring B, and/or ring C via —O—, —S—, —C(—R)₂—, or a single bond, and R in the —C(—R)₂— represents a hydrogen atom or an alkyl or a cycloalkyl,
at least one hydrogen atom in a compound or a structure represented by formula (1) may be substituted by cyano or a halogen atom,
in a case of a multimer, the multimer is a dimer or a trimer having two or three structures each represented by general formula (1), and
at least one hydrogen atom in the compound or the structure represented by formula (1) is substituted by a deuterium atom.

3. The polycyclic aromatic compound according to claim 1, represented by the following general formula (2) 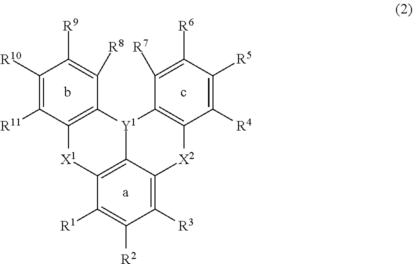
In the above formula (2),
R¹ to and R¹¹ each independently represent a hydrogen atom, an aryl, a heteroaryl, a diarylamino, a diheteroarylamino, an arylheteroarylamino, an alkyl, a cycloalkyl, an alkoxy, or an aryloxy, while at least one hydrogen atom in these may be substituted by an aryl, a heteroaryl, an alkyl, or a cycloalkyl, adjacent groups among R¹ to R¹¹ may be bonded to each other to form an aryl ring or a heteroaryl ring together with ring a, ring b, or ring c, at least one hydrogen atom in the ring thus formed may be substituted by an aryl, a heteroaryl, a diarylamino, a diheteroarylamino, an arylheteroarylamino, an alkyl, a cycloalkyl, an alkoxy, or an aryloxy, and at least one hydrogen atom in these may be substituted by an aryl, a heteroaryl, an alkyl, or a cycloalkyl,
Y¹ represents B, P, P═O, P═S, Al, Ga, As, Si—R, or Ge—R, while R in the Si—R and Ge—R represents an aryl having 6 to 12 carbon atoms, an alkyl having 1 to 6 carbon atoms or a cycloalkyl having 3 to 14 carbon atoms,
X¹ and X² each independently represent O, N—R, S, or Se, while R in the N—R represents an aryl having 6 to 12 carbon atoms, a heteroaryl having 2 to 15 carbon atoms, an alkyl having 1 to 6 carbon atoms, or a cycloalkyl having 3 to 14 carbon atoms, R in the N—R may be bonded to the ring a, ring b, and/or ring c via —O—, —S—, —C(—R)₂—, or a single bond, and R in the —C(—R)₂— represents an alkyl having 1 to 6 carbon atoms or a cycloalkyl having 3 to 14 carbon atoms,
at least one hydrogen atom in a compound represented by formula (2) may be substituted by cyano or a halogen atom, and
at least one hydrogen atom in the compound represented by formula (2) is substituted by a deuterium atom.

4. The polycyclic aromatic compound according to claim 3, wherein
R¹ to R¹¹ each independently represent a hydrogen atom, an aryl having 6 to 30 carbon atoms, a heteroaryl having 2 to 30 carbon atoms, a diarylamino (the aryl is an aryl having 6 to 12 carbon atoms), an alkyl having 1 to 24 carbon atoms, or a cycloalkyl having 3 to 24 carbon atoms, adjacent groups among R¹ to R¹¹ may be bonded to each other to form an aryl ring having 9 to 16 carbon atoms or a heteroaryl ring having 6 to 15 carbon atoms together with the ring a, ring b, or ring c, and at least one hydrogen atom in the ring thus formed may be substituted by an aryl having 6 to 10 carbon atoms, an alkyl having 1 to 12 carbon atoms, or a cycloalkyl having 3 to 16 carbon atoms,
Y¹ represents B, P, P═O, P═S, or Si—R, while R in the Si—R represents an aryl having 6 to 10 carbon atoms, an alkyl having 1 to 4 carbon atoms or a cycloalkyl having 5 to 10 carbon atoms,
X¹ and X² each independently represent O, N—R, or S, while R in the N—R represents an aryl having 6 to 10 carbon atoms, an alkyl having 1 to 4 carbon atoms, or a cycloalkyl having 5 to 10 carbon atoms,
at least one hydrogen atom in a compound represented by formula (2) may be substituted by cyano or a halogen atom, and
at least one hydrogen atom in the compound represented by formula (2) is substituted by a deuterium atom.

5. The polycyclic aromatic compound according to claim 3, wherein
R¹ to R¹¹ each independently represent a hydrogen atom, an aryl having 6 to 16 carbon atoms, a heteroaryl having 2 to 20 carbon atoms, a diarylamino (the aryl is an aryl having 6 to 10 carbon atoms), an alkyl having 1 to 12 carbon atoms, or a cycloalkyl having 3 to 16 carbon atoms,
Y¹ represents B, P, P═O, or P═S,
X¹ and X² each independently represent O or N—R, while R in the N—R represents an aryl having 6 to 10 carbon atoms, an alkyl having 1 to 4 carbon atoms or a cycloalkyl having 5 to 10 carbon atoms, and
at least one hydrogen atom in a compound represented by formula (2) is substituted by a deuterium atom.

6. The polycyclic aromatic compound according to claim 3, wherein
R¹ to R¹¹ each independently represent a hydrogen atom, an aryl having 6 to 16 carbon atoms, a diarylamino (the aryl is an aryl having 6 to 10 carbon atoms), an alkyl having 1 to 12 carbon atoms, or a cycloalkyl having 3 to 16 carbon atoms,
Y¹ represents B,
X¹ and X² both represent N—R, or X¹ represents N—R and X² represents O, and R in the N—R represents an aryl having 6 to 10 carbon atoms, an alkyl having 1 to 4 carbon atoms or a cycloalkyl having 5 to 10 carbon atoms, and
at least one hydrogen atom in a compound represented by formula (2) is substituted by a deuterium atom.

7. The polycyclic aromatic compound or the multimer thereof according to claim 1, substituted by a deuterium-substituted diarylamino group, a deuterium-substituted carbazolyl group, or a deuterium-substituted benzocarbazolyl group.

8. The polycyclic aromatic compound according to claim 3, wherein R² is a deuterium-substituted diarylamino group or a deuterium-substituted carbazolyl group.

9. The polycyclic aromatic compound or the multimer thereof according to claim 1, wherein the halogen is fluorine.

10. A polycyclic aromatic compound represented by any one of the following structural formulas

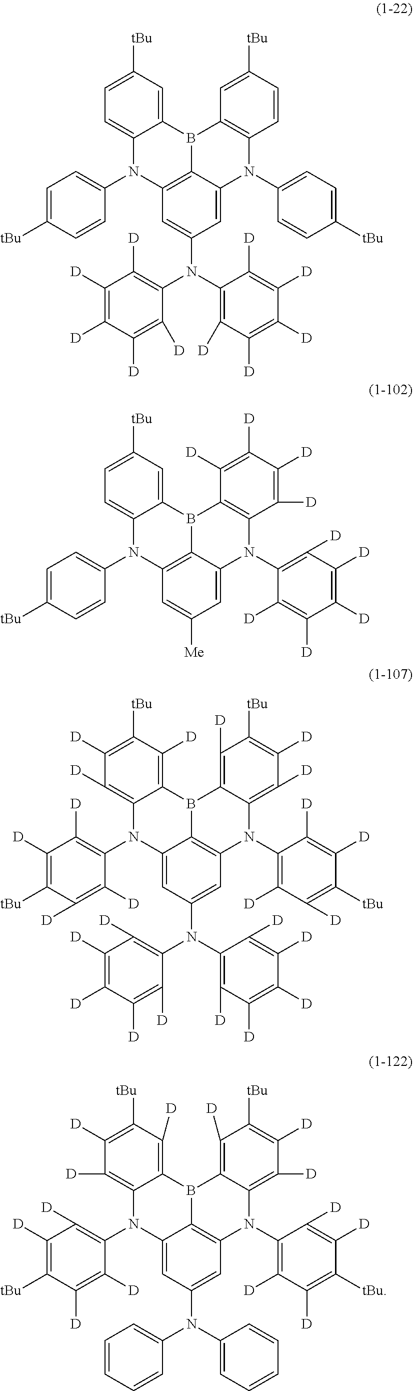

11. A material for an organic device, comprising the polycyclic aromatic compound or the multimer thereof according to claim 1.

12. The material for an organic device according to claim 11, wherein the material for an organic device is a material for an organic electroluminescent element, a material for an organic field effect transistor, or a material for an organic thin film solar cell.

13. The material for an organic electroluminescent element according to claim 12, wherein the material for an organic electroluminescent element is a material for a light emitting layer.

14. An organic electroluminescent element comprising: a pair of electrodes composed of a positive electrode and a negative electrode; and a light emitting layer disposed between the pair of electrodes and containing the material for a light emitting layer according to claim 13.

15. The organic electroluminescent element according to claim 14, wherein the light emitting layer includes a host and the material for a light emitting layer as a dopant.

16. The organic electroluminescent element according to claim 15, wherein the host is an anthracene-based compound, a fluorene-based compound, or a dibenzochrysene-based compound.

17. The organic electroluminescent element according to claim 14, further comprising an electron transport layer and/or an electron injection layer disposed between the negative electrode and the light emitting layer, wherein at least one of the electron transport layer and the electron injection layer contains at least one selected from the group consisting of a borane derivative, a pyridine derivative, a fluoranthene derivative, a BO-based derivative, an anthracene derivative, a benzofluorene derivative, a phosphine oxide derivative, a pyrimidine derivative, a carbazole derivative, a triazine derivative, a benzimidazole derivative, a phenanthroline derivative, and a quinolinol-based metal complex.

18. The organic electroluminescent element according to claim 17, wherein the electron transport layer and/or electron injection layer further include/includes at least one selected from the group consisting of an alkali metal, an alkaline earth metal, a rare earth metal, an oxide of an alkali metal, a halide of an alkali metal, an oxide of an alkaline earth metal, a halide of an alkaline earth metal, an oxide of a rare earth metal, a halide of a rare earth metal, an organic complex of an alkali metal, an organic complex of an alkaline earth metal, and an organic complex of a rare earth metal.

19. A display apparatus or a lighting apparatus comprising the organic electroluminescent element according to claim 14.
